(19) United States
(12) Patent Application Publication
(10) Pub. No.: US 2025/0006764 A1
(43) Pub. Date: Jan. 2, 2025

(54) LIGHT DETECTING DEVICE AND ELECTRONIC DEVICE

(71) Applicant: SONY SEMICONDUCTOR SOLUTIONS CORPORATION, Kanagawa (JP)

(72) Inventors: Kyohei MIZUTA, Kanagawa (JP); Yoshiki EBIKO, Kanagawa (JP); Yasufumi MIYOSHI, Kanagawa (JP); Kenji TAKEO, Kanagawa (JP); Tokihisa KANEGUCHI, Kanagawa (JP); Hokuto MIKI, Kanagawa (JP); Yoshiki SHIRASU, Kanagawa (JP); Tadamasa SHIOYAMA, Kanagawa (JP); Toshihiko HAYASHI, Kanagawa (JP); Naoyuki SATO, Kanagawa (JP)

(73) Assignee: SONY SEMICONDUCTOR SOLUTIONS CORPORATION, Kanagawa (JP)

(21) Appl. No.: 18/711,240

(22) PCT Filed: Nov. 25, 2022
(86) PCT No.: PCT/JP2022/043620

§ 371 Date: May 17, 2024

(30) Foreign Application Priority Data
Nov. 26, 2021 (JP) 2021-191629

(51) Int. Cl. H01L 27/146; G01S 7/4865; G01S 17/10

(52) U.S. Cl. CPC H01L 27/1463; G01S 7/4865; G01S 17/10; H01L 27/14623; H01L 27/14625; H01L 27/14629; H01L 27/14636; H01L 27/14683

(57) ABSTRACT

Improvement of pixel characteristics is achieved. A light detecting device includes a semiconductor layer and first and second separation areas disposed in the semiconductor layer. The first separation area includes an insulating film that fills a first dug part extending in a thickness direction of the semiconductor layer and of which a refractive index is lower than that of the semiconductor layer, and the second separation area includes a conductive film filling a second dug part extending in the thickness direction of the semiconductor layer.

### TECHNICAL FIELD

The present technology (a technology relating to the present disclosure) relates to a light detecting device and an electronic device and, more particularly, to an effective technology applied to a light detecting device having a photoelectric conversion area partitioned by a separation area extending in a thickness direction of a semiconductor layer and an electronic device including the light detecting device.

### BACKGROUND ART

In light detecting devices such as a solid-state imaging device, a distance measuring device, and the like, a semiconductor layer is partitioned by a separation area. In PTL 1, as a separation area partitioning a photoelectric conversion area of a semiconductor layer, an embedded-type separation area in which a dug part of a semiconductor layer is filled with conductive polysilicon with an insulating film therebetween is disclosed.

### CITATION LIST

### Patent Literature

PTL 1: JP 2019-214874A

### SUMMARY

### Technical Problem

However, in a light detecting device, a width of a separation area tends to be also miniaturized in accordance with miniaturization of a photoelectric conversion area. Although there is little influence in a case in which light of a wavelength of a visible range (visible light) is handled, in a case in which light of a wavelength of a near-infrared region (near-infrared light) is handled, the width of the separation area is too thin (too small), light incident in a photoelectric conversion area is not totally reflected in the separation area and is transmitted to the near photoelectric conversion area, and a quantum efficiency (QE) as a pixel characteristic is degraded (deteriorates). In addition, in the separation area that is filled with polysilicon of which a light absorption rate is high, light is absorbed by the polysilicon, and the quantum efficiency QE is degraded.

On the other hand, silicon (Si) has a low light absorption coefficient for near-infrared light and thus has a low quantum efficiency. Thus, in a case in which near-infrared light is handled, in order to improve the quantum efficiency QE, it has been reviewed to thicken the thickness of the semiconductor layer or to lengthen an optical path of the inside the semiconductor layer by disposing a diffraction/scattering section on a light incident face side of the semiconductor layer. However, in a case in which the semiconductor layer is formed to be thick, there is a problem in the transfer of signal electric charge from a photoelectric conversion unit to an electric charge maintaining section in a photoelectric conversion cell. The transfer of this signal electric charge has an influence on pixel characteristics.

An objective of the present technology is to provide a technology capable of improving pixel characteristics.

### Solution to Problem

(1) According to one aspect of the present technology, there is provided a light detecting device including: a semiconductor layer; and first and second separation areas disposed in the semiconductor layer, in which the first separation area includes an insulating material that fills a first dug part extending in a thickness direction of the semiconductor layer and of which a refractive index is lower than that of the semiconductor layer, and the second separation area includes a conductive material filling a second dug part extending in the thickness direction of the semiconductor layer.

(2) According to another aspect of the present technology, there is provided a light detecting device including: a semiconductor layer having a first face and a second face positioned on opposite sides in a thickness direction; a first separation area including an insulating material that is disposed in a first dug part extending in the thickness direction of the semiconductor layer and of which a refractive index is lower than that of the semiconductor layer; a photoelectric conversion area partitioned by the first separation area; a second separation area including a conductive material disposed in a second dug part extending in the thickness direction of the semiconductor layer and separating the photoelectric conversion area into a first area and a second area in one direction; a photoelectric conversion unit disposed in the first area; an electric charge maintaining section disposed on the first face side of the semiconductor layer in the second area; and a light blocking body disposed on the second face side of the semiconductor layer and overlapping the second area in a plan view.

(3) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit disposed in the first area; an electric charge maintaining section disposed on the first face side of the semiconductor layer in the second area; a light blocking body that is disposed on the second face side of the semiconductor layer and is disposed to overlap the second area in the plan view; and a light reflecting body that is disposed to overlap the second separation area in the plan view on the second face side of the semiconductor layer and of which a refractive index is lower than that of the semiconductor layer.

(4) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; first and second photoelectric conversion areas partitioned to be aligned in one direction by the first separation area; a second separation area that includes a conductive material disposed in a second dug part extending in the thickness direction of the semiconductor layer and separates each of the first and second photoelectric conversion areas into a first area and a second area in the one direction; a photoelectric conversion unit disposed in the first area of each of the first and second photoelectric conversion areas; and an electric charge maintaining section disposed in the second area of each of the first and second photoelectric conversion areas, in which the second areas of the first and second photoelectric conversion areas are aligned to be adjacent to each other in the one direction through the third separation area in the plan view.

(5) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer through an insulator of which a refractive index is lower than that of the semiconductor layer and separates the photoelectric conversion area into a first area and a second area in one direction; a photoelectric conversion unit disposed in the first area; and an electric charge maintaining section disposed in the second area, in which, in the second separation area, a film thickness of the insulator on the first area side of the conductive material is larger than a film thickness of the insulator on the second area side of the conductive material.

(6) According to another aspect of the present technology, there is provided a light detecting device including: a semiconductor layer having a first face and a second face positioned on opposite sides; a photoelectric conversion area disposed in the semiconductor layer with being partitioned by a first separation area; a second separation area that separates each photoelectric conversion area of the photoelectric conversion area into a first area and a second area aligned in one direction; a photoelectric conversion unit that is disposed in the first area and performs photoelectric conversion of light incident from the second face side of the semiconductor layer; and an electric charge maintaining section that is disposed in the second area and maintains the signal electric charge acquired through photoelectric conversion by the photoelectric conversion unit, in which the first separation area includes an insulating material that is disposed in a first dug part extending in the thickness direction of the semiconductor layer and of which a refractive index is lower than that of the semiconductor layer the second separation area includes a conductive material that is disposed in a second dug part extending in the thickness direction of the semiconductor layer through a separation insulating film of which a refractive index is lower than that of the semiconductor layer, and the width of the second area in the one direction is set such that, out of incidence light incident in the first area from the second face side of the semiconductor layer, a phase difference between reflection light reflected on a side face part of the second separation area and return light acquired in accordance with the incidence light being transmitted through the second separation area and the second area, being reflected on the first separation area, and returning to the first area becomes an integer multiple of the incidence light.

(7) According to another aspect of the present technology, there is provided a light detecting device including: a semiconductor layer having a first face and a second face positioned on opposite sides; a plurality of photoelectric conversion areas disposed in the semiconductor layer with being partitioned by a first separation area; a second separation area that separates each of the plurality of photoelectric conversion areas into a first area and a second area aligned in one direction; a photoelectric conversion unit that is disposed in the first area and performs photoelectric conversion of light incident from the second face side of the semiconductor layer; and an electric charge maintaining section that is disposed in the second area and maintains the signal electric charge acquired through photoelectric conversion by the photoelectric conversion unit, in which the first separation area includes an insulating material that is disposed in a first dug part extending in the thickness direction of the semiconductor layer and of which a refractive index is lower than that of the semiconductor layer, in which the second separation area includes a conductive material that is disposed in a second dug part extending in the thickness direction of the semiconductor layer through a separation insulating film of which a refractive index is lower than that of the semiconductor layer, and in which the plurality of photoelectric conversion areas include two or more types of photoelectric conversion areas of which widths of the second areas in the one direction are different from each other.

(8) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and photoelectrically converts light incident from the second face side of the semiconductor layer into signal electric charge; an electric charge maintaining section that is disposed in the second area and maintains the signal electric charge acquired through photoelectric conversion by the photoelectric conversion unit; and a dielectric in which an insulating film is disposed in a third dug part extending in a depth direction of the semiconductor layer through a fixed charge film.

(9) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and performs photoelectric conversion of light incident from the second face side of the semiconductor layer; an electric charge maintaining section that is disposed in the second area and maintains the signal electric charge acquired through photoelectric conversion by the photoelectric conversion unit; and a multilayer body disposed on the first face side of the semiconductor layer, in which the multilayer body includes a light reflecting body disposed to overlap the first area.

(10) According to another aspect of the present technology, there is provided a light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and performs photoelectric conversion of light incident from the second face side of the semiconductor layer; an electric charge maintaining section that is disposed in the second area and maintains the signal electric charge acquired through photoelectric conversion by the photoelectric conversion unit; and a multilayer body disposed on the first face side of the semiconductor layer, in which the multilayer body includes a light absorbing body disposed to overlap the first area and of which a light absorption rate is higher than that of the semiconductor layer.

(11) According to another aspect of the present technology, there is provided an electronic device including: a light detecting device; an optical lens forming image light from a subject on an imaging surface of the light detecting device; and a signal processing circuit performing signal processing on a signal output from the light detecting device.

### BRIEF DESCRIPTION OF DRAWINGS

FIG. 1 is a plane layout diagram schematically illustrating one configuration example of a solid-state imaging device according to a first embodiment of the present technology.

FIG. 2 is a block diagram illustrating one configuration example of the solid-state imaging device according to the first embodiment of the present technology.

FIG. 3 is an equivalent circuit diagram illustrating one configuration example of a pixel of the solid-state imaging device according to the first embodiment of the present technology.

FIG. 4 is a plan view schematically illustrating a plane pattern of a separation area in a pixel array portion of the solid-state imaging device according to the first embodiment of the present technology.

FIG. 5 is a longitudinal cross-sectional view schematically illustrating a longitudinal cross-sectional structure taken along line a4-a4 illustrated in FIG. 4.

FIG. 6 is a longitudinal cross-sectional view in which a part of FIG. 5 is enlarged.

FIG. 7A is an equivalent circuit diagram illustrating one configuration example of a pixel included in a pixel array portion of a solid-state imaging device according to a second embodiment of the present technology.

FIG. 7B is an equivalent circuit diagram illustrating one configuration example of a pixel included in the pixel array portion of the solid-state imaging device according to the second embodiment of the present technology.

FIG. 8 is a plan view illustrating a plane pattern of a separation area of the pixel array portion of the solid-state imaging device according to the second embodiment of the present technology.

FIG. 9 is a longitudinal cross-sectional view schematically illustrating a longitudinal cross-sectional structure taken along line a8-a8 illustrated FIG. 8.

FIG. 10 is a plan view schematically illustrating a plane pattern of a separation area in a pixel array portion of a solid-state imaging device according to a third embodiment of the present technology.

FIG. 11 is a longitudinal cross-sectional view schematically illustrating a longitudinal cross-sectional structure taken along line a10-a10 illustrated in FIG. 9.

FIG. 12 is a plan view schematically illustrating a plane pattern of a separation area in a pixel array portion of a solid-state imaging device according to a fourth embodiment of the present technology.

FIG. 13 is a longitudinal cross-sectional view schematically illustrating a longitudinal cross-sectional structure taken along line a12-a12 illustrated in FIG. 12.

FIG. 14 is an equivalent circuit diagram illustrating one configuration example of a pixel of a solid-state imaging device according to a fifth embodiment of the present technology.

FIG. 15 is an equivalent circuit diagram illustrating one configuration example of a pixel of a solid-state imaging device according to a sixth embodiment of the present technology.

FIG. 16 is an equivalent circuit diagram illustrating one configuration example of a pixel of a solid-state imaging device according to a seventh embodiment of the present technology.

FIG. 17 is a plan view schematically illustrating a plane pattern of a light blocking body of a pixel array portion of a solid-state imaging device according to an eighth embodiment of the present technology.

FIG. 18 is a longitudinal cross-sectional view schematically illustrating a longitudinal cross-sectional structure taken along line a17-a17 illustrated FIG. 17.

FIG. 19 is a plan view in which a part of FIG. 18 is enlarged.

FIG. 20 is a longitudinal cross-sectional view schematically illustrating a longitudinal cross-sectional structure taken along line a19-a19 illustrated in FIG. 19.

FIG. 21A is a diagram illustrating dimensions of a second light blocking part of the light blocking body.

FIG. 21B is a diagram schematically illustrating a light reflection state at the second light blocking part of the light blocking body.

FIG. 22A is a longitudinal cross-sectional view schematically illustrating the process of a method of manufacturing a solid-state imaging device according to an eighth embodiment of the present technology.

FIG. 22B is a longitudinal cross-sectional view schematically illustrating a process following FIG. 22A.

FIG. 22C is a longitudinal cross-sectional view schematically illustrating a process following FIG. 22B.

FIG. 22D is a longitudinal cross-sectional view schematically illustrating a process following FIG. 22C.

FIG. 22E is a longitudinal cross-sectional view schematically illustrating a process following FIG. 22D.

FIG. 22F is a longitudinal cross-sectional view schematically illustrating a process following FIG. 22E.

FIG. 22G is a longitudinal cross-sectional view schematically illustrating a process following FIG. 22F.

FIG. 22H is a longitudinal cross-sectional view schematically illustrating a process following FIG. 22G.

FIG. 22I is a longitudinal cross-sectional view schematically illustrating a process following FIG. 22H.

FIG. 23 is a plan view schematically illustrating Modified Example 8-1 of the eighth embodiment.

FIG. 24 is a plan view schematically illustrating Modified Example 8-2 of the eighth embodiment.

FIG. 25 is a plan view schematically illustrating Modified Example 8-3 of the eighth embodiment.

FIG. 26 is a longitudinal cross-sectional view schematically illustrating a longitudinal cross-sectional structure of Modified Example 8-4 of the eighth embodiment.

FIG. 27 is a plan view schematically illustrating a plane pattern of a light blocking body of a pixel array portion of a solid-state imaging device according to a ninth embodiment of the present technology.

FIG. 28 is a longitudinal cross-sectional view schematically illustrating a longitudinal cross-sectional structure taken along line a27-a27 illustrated FIG. 27.

FIG. 29A is a diagram illustrating dimensions of a second light blocking part of the light blocking body and an in-pixel separation area.

FIG. 29B is a diagram schematically illustrating a light reflection state of the second light blocking part of the light blocking body.

FIG. 30A is a longitudinal cross-sectional view schematically illustrating the process of a method of manufacturing a solid-state imaging device according to a ninth embodiment of the present technology.

FIG. 30B is a longitudinal cross-sectional view schematically illustrating a process following FIG. 30A.

FIG. 30C is a longitudinal cross-sectional view schematically illustrating a process following FIG. 30B.

FIG. 30D is a longitudinal cross-sectional view schematically illustrating a process following FIG. 30C.

FIG. 30E is a longitudinal cross-sectional view schematically illustrating a process following FIG. 30D.

FIG. 30F is a longitudinal cross-sectional view schematically illustrating a process following FIG. 30E.

FIG. 30G is a longitudinal cross-sectional view schematically illustrating a process following FIG. 30F.

FIG. 30H is a longitudinal cross-sectional view schematically illustrating a process following FIG. 30G.

FIG. 31 is a plan view schematically illustrating a plane pattern of a light blocking body of a pixel array portion of a solid-state imaging device according to a 10th embodiment of the present technology.

FIG. 32 is a longitudinal cross-sectional view schematically illustrating a longitudinal cross-sectional structure taken along line a31-a31 illustrated FIG. 31.

FIG. 33 is a diagram schematically illustrating a light reflection state of the second light blocking part of the light blocking body.

FIG. 34A is a longitudinal cross-sectional view schematically illustrating the process of a method of manufacturing a solid-state imaging device according to the tenth embodiment of the present technology.

FIG. 34B is a longitudinal cross-sectional view schematically illustrating a process following FIG. 34A.

FIG. 34C is a longitudinal cross-sectional view schematically illustrating a process following FIG. 34B.

FIG. 34D is a longitudinal cross-sectional view schematically illustrating a process following FIG. 34C.

FIG. 34E is a longitudinal cross-sectional view schematically illustrating a process following FIG. 34D.

FIG. 35 is a plan view schematically illustrating a plane pattern of a light blocking body of a pixel array portion of a solid-state imaging device according to an 11th embodiment of the present technology.

FIG. 36 is a longitudinal cross-sectional view schematically illustrating a longitudinal cross-sectional structure taken along line a35-a35 illustrated FIG. 35.

FIG. 37A is a diagram illustrating dimensions of a light reflecting body and an in-pixel separation area.

FIG. 37B is a diagram schematically illustrating a light reflection state of the light reflecting body.

FIG. 37C is a diagram illustrating a correlation between a length of the light reflecting body in a Z direction and transmittance.

FIG. 38A is a longitudinal cross-sectional view schematically illustrating the process of a method of manufacturing a solid-state imaging device according to an 11th embodiment of the present technology.

FIG. 38B is a longitudinal cross-sectional view schematically illustrating a process following FIG. 38A.

FIG. 38C is a longitudinal cross-sectional view schematically illustrating a process following FIG. 38B.

FIG. 38D is a longitudinal cross-sectional view schematically illustrating a process following FIG. 38C.

FIG. 38E is a longitudinal cross-sectional view schematically illustrating a process following FIG. 38D.

FIG. 38F is a longitudinal cross-sectional view schematically illustrating a process following FIG. 38E.

FIG. 39 is a longitudinal cross-sectional view schematically illustrating Modified Example 11-1 of the 11th embodiment.

FIG. 40 is a plan view schematically illustrating Modified Example 11-2 of the 11th embodiment.

FIG. 41 is a longitudinal cross-sectional view schematically illustrating a longitudinal cross-sectional structure taken along line a40-a40 illustrated FIG. 40.

FIG. 42 is a longitudinal cross-sectional view schematically illustrating Modified Example 11-3 of the 11th embodiment.

FIG. 43 is a longitudinal cross-sectional view schematically illustrating Modified Example 11-4 of the 11th embodiment.

FIG. 44 is a plan view schematically illustrating a plane pattern of a separation area in a pixel array portion of a solid-state imaging device according to a 12th embodiment of the present technology.

FIG. 45 is a longitudinal cross-sectional view schematically illustrating a longitudinal cross-sectional structure taken along line a44-a44 illustrated in FIG. 44.

FIG. 46A is a plan view in which a part of FIG. 18 is enlarged.

FIG. 46B is a plan view in which a part of FIG. 18 is enlarged.

FIG. 47A is a longitudinal cross-sectional view schematically illustrating the process of a method of manufacturing a solid-state imaging device according to a 12th embodiment of the present technology.

FIG. 47B is a longitudinal cross-sectional view schematically illustrating a process following FIG. 47A.

FIG. 47C is a longitudinal cross-sectional view schematically illustrating a process following FIG. 47B.

FIG. 47D is a longitudinal cross-sectional view schematically illustrating a process following FIG. 47C.

FIG. 47E is a longitudinal cross-sectional view schematically illustrating a process following FIG. 47D.

FIG. 47F is a longitudinal cross-sectional view schematically illustrating a process following FIG. 47E.

FIG. 47G is a longitudinal cross-sectional view schematically illustrating a process following FIG. 47F.

FIG. 47H is a longitudinal cross-sectional view schematically illustrating a process following FIG. 47G.

FIG. 48 is a longitudinal cross-sectional view schematically illustrating a penetration optical path of oblique light in Comparative Example 12-1.

FIG. 49 is a longitudinal cross-sectional view schematically illustrating a penetration optical path of oblique light in a 12th embodiment.

FIG. 50 is a longitudinal cross-sectional view illustrating a case in which a first dug part and a third dug part are formed in the same process in Comparative Example 12-2.

FIG. 51 is a longitudinal cross-sectional view schematically illustrating a longitudinal cross-sectional structure of Modified Example 12-1 of the 12th embodiment.

FIG. 52 is a longitudinal cross-sectional view schematically illustrating a longitudinal cross-sectional structure of Modified Example 12-2 of the 12th embodiment.

FIG. 53 is a longitudinal cross-sectional view schematically illustrating a longitudinal cross-sectional structure of Modified Example 12-3 of the 12th embodiment.

FIG. 54 is a longitudinal cross-sectional view schematically illustrating a longitudinal cross-sectional structure of Modified Example 12-4 of the 12th embodiment.

FIG. 55 is a plan view schematically illustrating a plane pattern of a separation area in a pixel array portion of a solid-state imaging device according to a 13th embodiment of the present technology.

FIG. 56 is a longitudinal cross-sectional view schematically illustrating a longitudinal cross-sectional structure taken along line a55-a55 illustrated in FIG. 55.

FIG. 57 is a longitudinal cross-sectional view in which a part of FIG. 56 is enlarged.

FIG. 58 is a diagram illustrating a correlation between a film thickness of an insulator and an average reflectivity.

FIG. 59A is a longitudinal cross-sectional view schematically illustrating the process of a method of manufacturing a solid-state imaging device according to the 13th embodiment of the present technology.

FIG. 59B is a longitudinal cross-sectional view schematically illustrating a process following FIG. 59A.

FIG. 59C is a longitudinal cross-sectional view schematically illustrating a process following FIG. 59B.

FIG. 59D is a longitudinal cross-sectional view schematically illustrating a process following FIG. 59C.

FIG. 59E is a longitudinal cross-sectional view schematically illustrating a process following FIG. 59D.

FIG. 59F is a longitudinal cross-sectional view schematically illustrating a process following FIG. 59E.

FIG. 59G is a longitudinal cross-sectional view schematically illustrating a process following FIG. 59F.

FIG. 59H is a longitudinal cross-sectional view schematically illustrating a process following FIG. 59G.

FIG. 59I is a longitudinal cross-sectional view schematically illustrating a process following FIG. 59H.

FIG. 59J is a longitudinal cross-sectional view schematically illustrating a process following FIG. 59I.

FIG. 60 is a longitudinal cross-sectional view schematically illustrating a longitudinal cross-sectional structure of a modified example of the 13th embodiment.

FIG. 61 is a plan view schematically illustrating a plane pattern of a separation area in a pixel array portion of a solid-state imaging device according to a 14th embodiment of the present technology.

FIG. 62 is a longitudinal cross-sectional view schematically illustrating a longitudinal cross-sectional structure taken along line a61-a61 illustrated in FIG. 61.

FIG. 63 is a longitudinal cross-sectional view in which a part of FIG. 62 is enlarged and is inverted vertically.

FIG. 64 is a diagram schematically illustrating an interference between reflection light reflected in an in-pixel separation area and return light reflected in an inter-pixel separation area.

FIG. 65 is a diagram illustrating a correlation between a width of a second area of the photoelectric conversion area and an optical reflectance at a side wall of the in-pixel separation area.

FIG. 66 is a plan view schematically illustrating a plane pattern of a separation area in a pixel array portion of a solid-state imaging device according to a 15th embodiment of the present technology.

FIG. 67 is a longitudinal cross-sectional view schematically illustrating a longitudinal cross-sectional structure taken along line a66-a66 illustrated in FIG. 66.

FIG. 68 is a longitudinal cross-sectional view schematically illustrating a longitudinal cross-sectional structure taken along line b66-b66 illustrated in FIG. 66.

FIG. 69 is a plan view schematically illustrating a plane pattern of a light blocking film.

FIG. 70 is a diagram illustrating a correlation between a width of a second area of the photoelectric conversion area and an optical reflectance at a side wall of the in-pixel separation area.

FIG. 71 is a plan view schematically illustrating a plane pattern of a separation area in a pixel array portion of a solid-state imaging device according to a 16th embodiment of the present technology.

FIG. 72 is a longitudinal cross-sectional view schematically illustrating a longitudinal cross-sectional structure taken along line a71-a71 illustrated in FIG. 71.

FIG. 73 is a longitudinal cross-sectional view schematically illustrating a longitudinal cross-sectional structure taken along line b71-b71 illustrated in FIG. 71.

FIG. 74A is a longitudinal cross-sectional view schematically illustrating the process of a method of manufacturing a solid-state imaging device according to the 16th embodiment of the present technology.

FIG. 74B is a longitudinal cross-sectional view schematically illustrating a process following FIG. 74A.

FIG. 74C is a longitudinal cross-sectional view schematically illustrating a process following FIG. 74B.

FIG. 74D is a longitudinal cross-sectional view schematically illustrating a process following FIG. 74C.

FIG. 74E is a longitudinal cross-sectional view schematically illustrating a process following FIG. 74D.

FIG. 74F is a longitudinal cross-sectional view schematically illustrating a process following FIG. 74E.

FIG. 74G is a longitudinal cross-sectional view schematically illustrating a process following FIG. 74F.

FIG. 75 is a plan view schematically illustrating a modified example of the 16th embodiment.

FIG. 76 is a plan view schematically illustrating a plane pattern of a separation area in a pixel array portion of a solid-state imaging device according to a 17th embodiment of the present technology.

FIG. 77 is a longitudinal cross-sectional view schematically illustrating a longitudinal cross-sectional structure taken along line a76-a76 illustrated in FIG. 76.

FIG. 78 is a longitudinal cross-sectional view schematically illustrating a longitudinal cross-sectional structure taken along line b76-b76 illustrated in FIG. 76.

FIG. 79 is a plan view schematically illustrating a plane pattern of a separation area in a pixel array portion of a solid-state imaging device according to a 18th embodiment of the present technology.

FIG. 80 is a longitudinal cross-sectional view schematically illustrating a longitudinal cross-sectional structure taken along line a79-a79 illustrated in FIG. 79.

FIG. 81 is a longitudinal cross-sectional view schematically illustrating a longitudinal cross-sectional structure of a solid-state imaging device according to a 19th embodiment of the present technology.

FIG. 82 is a longitudinal cross-sectional view schematically illustrating a longitudinal cross-sectional structure of a solid-state imaging device according to a 20th embodiment of the present technology.

FIG. 83A is a plan view schematically illustrating a plane pattern of a light reflecting body illustrated in FIG. 82.

FIG. 83B is a longitudinal cross-sectional view schematically illustrating reflection of light according to the light reflecting body.

FIG. 84A is a longitudinal cross-sectional view schematically illustrating the process of a method of manufacturing a solid-state imaging device according to the 20th embodiment of the present technology.

FIG. 84B is a longitudinal cross-sectional view schematically illustrating a process following FIG. 84A.

FIG. 84C is a longitudinal cross-sectional view schematically illustrating a process following FIG. 84B.

FIG. 84D is a longitudinal cross-sectional view schematically illustrating a process following FIG. 84C.

FIG. 84E is a longitudinal cross-sectional view schematically illustrating a process following FIG. 84D.

FIG. 84F is a longitudinal cross-sectional view schematically illustrating a process following FIG. 84E.

FIG. 84G is a longitudinal cross-sectional view schematically illustrating a process following FIG. 84F.

FIG. 84H is a longitudinal cross-sectional view schematically illustrating a process following FIG. 84G.

FIG. 84I is a longitudinal cross-sectional view schematically illustrating a process following FIG. 84H.

FIG. 84J is a longitudinal cross-sectional view schematically illustrating a process following FIG. 84I.

FIG. 85 is a longitudinal cross-sectional view schematically illustrating a longitudinal cross-sectional structure of a solid-state imaging device according to a 21st embodiment of the present technology.

FIG. 86 is a plan view schematically illustrating a plane pattern of a light absorbing body illustrated in FIG. 85.

FIG. 87A is a longitudinal cross-sectional view schematically illustrating the process of a method of manufacturing a solid-state imaging device according to a 21st embodiment of the present technology.

FIG. 87B is a longitudinal cross-sectional view schematically illustrating a process following FIG. 87A.

FIG. 87C is a longitudinal cross-sectional view schematically illustrating a process following FIG. 87B.

FIG. 87D is a longitudinal cross-sectional view schematically illustrating a process following FIG. 87C.

FIG. 87E is a longitudinal cross-sectional view schematically illustrating a process following FIG. 87D.

FIG. 87F is a longitudinal cross-sectional view schematically illustrating a process following FIG. 87E.

FIG. 87G is a longitudinal cross-sectional view schematically illustrating a process following FIG. 87F.

FIG. 87H is a longitudinal cross-sectional view schematically illustrating a process following FIG. 87G.

FIG. 87I is a longitudinal cross-sectional view schematically illustrating a process following FIG. 87H.

FIG. 88 is a longitudinal cross-sectional view schematically illustrating a longitudinal cross-sectional structure of a solid-state imaging device according to a 22nd embodiment of the present technology.

FIG. 89 is a plan view schematically illustrating a plane pattern of a light reflecting body illustrated in FIG. 88.

FIG. 90A is a longitudinal cross-sectional view schematically illustrating the process of a method of manufacturing a solid-state imaging device according to a 22nd embodiment of the present technology.

FIG. 90B is a longitudinal cross-sectional view schematically illustrating a process following FIG. 90A.

FIG. 90C is a longitudinal cross-sectional view schematically illustrating a process following FIG. 90B.

FIG. 90D is a longitudinal cross-sectional view schematically illustrating a process following FIG. 90C.

FIG. 90E is a longitudinal cross-sectional view schematically illustrating a process following FIG. 90D.

FIG. 90F is a longitudinal cross-sectional view schematically illustrating a process following FIG. 90E.

FIG. 90G is a longitudinal cross-sectional view schematically illustrating a process following FIG. 90F.

FIG. 90H is a longitudinal cross-sectional view schematically illustrating a process following FIG. 90G.

FIG. 91 is a diagram illustrating one configuration example of an electronic device according to a 23rd embodiment of the present technology.

### DESCRIPTION OF EMBODIMENTS

Embodiments of the present technology will be described below with reference to the drawings. In descriptions of the drawings referred to in the following description, same or similar portions will be denoted by same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined by considering the following descriptions.

In addition, of course the drawings include portions where mutual dimensional relationships and ratios differ between the drawings. Furthermore, the advantageous effects described in the present specification are merely exemplary and not intended as limiting, and other advantageous effects may be produced.

In addition, the following embodiments exemplify devices and methods for embodying the technical ideas of the present technology, and the configurations are not limited to those described below. That is, the technical ideas of the present technology can be variously modified within the technical scope described in the claims.

In addition, it is to be understood that definitions of directions such as up-down in the following descriptions are merely definitions provided for the sake of brevity and are not intended to limit the technical ideas of the present technique. For example, it is obvious that when a target is rotated 90° and observed, the top and bottom will be converted to the left and right and, obviously, if the target is rotated 180° and observed, the top and bottom will be read as reversed.

In the following embodiments, although a case in which, as conduction types of a semiconductor, a first conduction type is a p type, and a second conduction type is an n type will be described as an example, by selecting the conduction types to have the opposite relation, the first conduction type may be the n type, and the second conduction type may be the p type.

In the following embodiment, in the three directions orthogonal to each other in a space, a first direction and a second direction orthogonal to each other in the same plane are set to an X direction and a Y direction, respectively, and a third direction orthogonal to each of the first direction and the second direction is defined as a Z direction. In the following embodiments, a thickness direction of a semiconductor layer 20, which will be described later, is defined as the Z direction.

### First Embodiment

In this first embodiment, one example in which the present technology is applied to a solid-state imaging device that is a complementary metal oxide semiconductor (CMOS) image sensor of a backside illumination type as a light detecting device will be described.

In addition, in this first embodiment, for separation areas partitioning a semiconductor layer, an example in which an inter-pixel separation area corresponding to one specific example of “first separation area” of the present technology and an in-pixel separation area corresponding to one specific example of “second separation area” of the present technology are included will be described.

### <<Entire Configuration of Solid-State Imaging Device>>

First, the entire configuration of a solid-state imaging device 1A will be described.

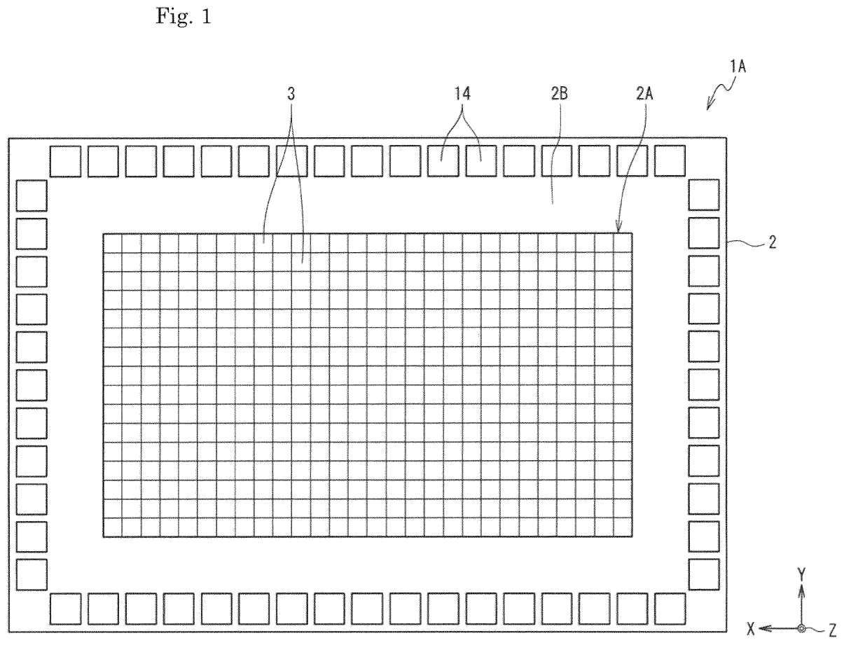

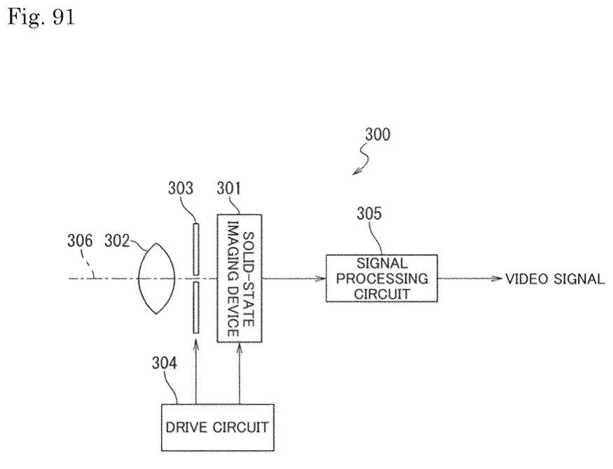

As illustrated in FIG. 1, the solid-state imaging device 1A according to a first embodiment of the present technology is configured to have a semiconductor chip 2 of which a two-dimensional planar shape in a plan view is a square shape as its main body. In other words, the solid-state imaging device 1A is mounted in the semiconductor chip 2, and the semiconductor chip 2 can be regarded as the solid-state imaging device 1A. This solid-state imaging device 1A (301), as illustrated in FIG. 91, takes in image light (incidence light 306) from a subject through an optical lens 302, converts a light quantity of incidence light 306 formed on an imaging surface as an image into an electric signal in units of pixels, and outputs the electric signal as a pixel signal.

As illustrated in FIG. 1, the semiconductor chip 2 in which the solid-state imaging device 1A is mounted includes a pixel array portion 2A of a square shape disposed in a center part and a peripheral portion 2B disposed on an outer side of this pixel array portion 2A to surround the pixel array portion 2A in a two-dimensional plane including an X direction and a Y direction that are orthogonal to each other. The semiconductor chip 2 is formed by fragmenting a plurality of chip formation areas formed in a semiconductor wafer for each chip formation area. Thus, the configuration of the solid-state imaging device 1A described below is similar on the whole also in a wafer state before fragmentation of the semiconductor wafer.

The pixel array portion 2A, for example, is a light reception surface receiving light condensed by the optical lens 302 (an optical system) illustrated in FIG. 91. Further, in the pixel array portion 2A, a plurality of pixels 3 are arranged in a matrix in a two-dimensional plane including the X direction and the Y direction. In other words, the pixels 3 are repeatedly disposed in each of the X direction and the Y direction that are orthogonal to each other inside a two-dimensional plane.

As illustrated in FIG. 1, in the peripheral portion 2B, a plurality of bonding pads 14 are disposed. Each of the plurality of bonding pads 14, for example, is disposed along one side among four sides in the two-dimensional plane of the semiconductor chip 2. Each of the plurality of bonding pads 14 functions as an input/output terminal that electrically connects the semiconductor chip 2 and an external device to each other.

### <Logic Circuit>

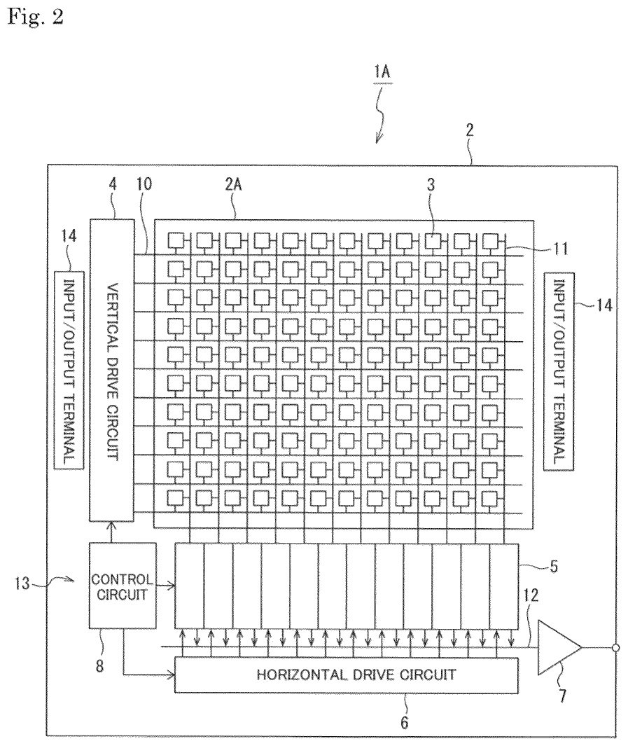

The semiconductor chip 2 includes the logic circuit 13 illustrated in FIG. 2. The logic circuit 13, as illustrated in FIG. 2, includes a vertical drive circuit 4, a column signal processing circuit 5, a horizontal drive circuit 6, an output circuit 7, a control circuit 8, and the like. The logic circuit 13, for example, is configured using a complementary MOS (CMOS) circuit having a metal oxide semiconductor field effect transistor (MOSFET) of an n-channel conduction type and a MOSFET of a p-channel conduction type as field effect transistors.

The vertical drive circuit 4, for example, is configured using a shift register. The vertical drive circuit 4 sequentially selects a desired pixel drive line 10, supplies a pulse for driving the pixels 3 to the selected pixel drive line 10, and drives the pixels 3 in units of rows. In other words, the vertical drive circuit 4 sequentially selectively scans the pixels 3 of the pixel array portion 2A in units of rows in a vertical direction and supplies a pixel signal from the pixel 3 based on a signal electric charge generated in accordance with a received light quantity by the photoelectric conversion unit (a photoelectric conversion element) of each pixel 3 to the column signal processing circuit 5 through the vertical signal line 11.

The column signal processing circuit 5, for example, is disposed for each column of the pixels 3 and performs signal processing such as noise removal and the like for signals output from the pixels 3 corresponding to one row for each pixel column. For example, the column signal processing circuit 5 performs signal processing such as correlated double sampling (CDS), analog digital (AD) conversion, and the like for removing a fixed pattern noise that is unique to each pixel.

For example, the horizontal drive circuit 6 is constituted of a shift register. The horizontal drive circuit 6 sequentially selects each column signal processing circuit 5 by sequentially outputting a horizontal scanning pulse to the column signal processing circuit 5 and outputs a pixel signal on which signal processing has been performed from each column signal processing circuit 5 to the horizontal signal line 12.

The output circuit 7 performs signal processing on the pixel signals sequentially supplied from the respective column signal processing circuits 5 through the horizontal signal line 12 and outputs resultant pixel signals. As the signal processing, for example, buffering, black level adjustment, a column deviation correction, various types of digital signal processing, and the like can be used.

The control circuit 8 generates a clock signal or a control signal as a reference for operations of the vertical drive circuit 4, the column signal processing circuit 5, the horizontal drive circuit 6, and the like on the basis of a vertical synchronization signal, a horizontal synchronization signal, and a master clock signal. In addition, the control circuit 8 outputs the generated clock signal or control signal to the vertical drive circuit 4, the column signal processing circuit 5, the horizontal drive circuit 6, and the like.

### <Circuit Configuration of Pixel>

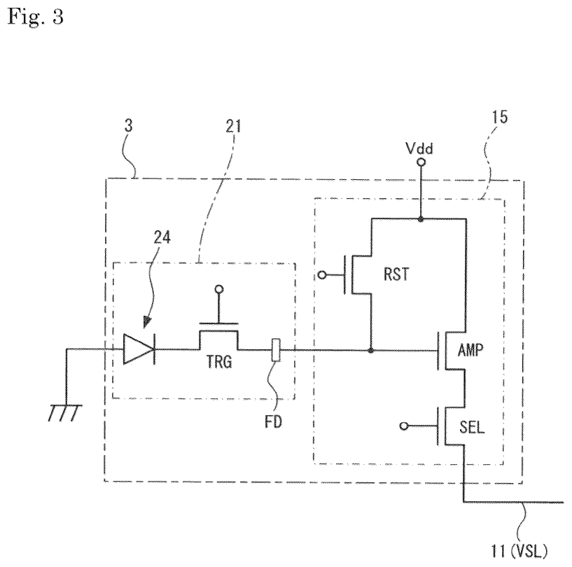

As illustrated in FIG. 3, each pixel 3 among the plurality of pixels 3 includes a photoelectric conversion area 21 and a reading circuit 15. The photoelectric conversion area 21 includes a photoelectric conversion unit 24, a transfer transistor TRG as a pixel transistor, and a floating diffusion region FD. The reading circuit 15 is electrically connected to the floating diffusion region FD of the photoelectric conversion area 21. In this first embodiment, as one example, although a circuit configuration in which one reading circuit 15 is assigned to one pixel 3 is employed, the circuit configuration is not limited thereto, and a circuit configuration in which one reading circuit 15 is shared by a plurality of pixels 3 may be employed. The floating diffusion region FD corresponds to one specific example of “electric charge maintaining section” of the present technology.

The photoelectric conversion unit 24 illustrated in FIG. 3, for example, is configured using a photodiode (PD) of a pn junction type and generates signal electric charge corresponding to a received light quantity. The photoelectric conversion unit 24 has a cathode side electrically connected to a source region of a transfer transistor TRG and an anode side electrically connected to a reference electric potential line (for example, the ground).

The transfer transistor TRG illustrated in FIG. 3 transmits signal electric charge acquired by photoelectric conversion using the photoelectric conversion unit 24 to a floating diffusion region FD. A source region of the transfer transistor RTL is electrically connected to the cathode side of the photoelectric conversion unit 24, and a drain region of the transfer transistor TRG is electrically connected to the floating diffusion region FD. A gate electrode of the transfer transistor TRG is electrically connected to a transfer transistor driving line among pixel drive lines 10 (see FIG. 2).

The floating diffusion region FD illustrated in FIG. 3 temporarily maintains (accumulates) signal electric charge transmitted from the photoelectric conversion unit 24 through the transfer transistor TRG.

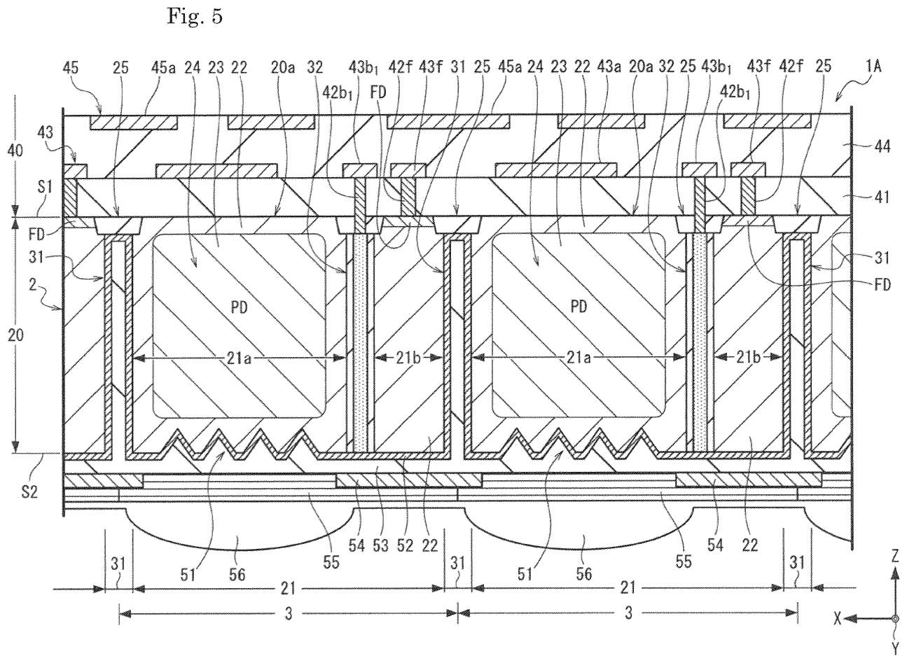

The photoelectric conversion area 21 including the photoelectric conversion unit 24, the transfer transistor TRG, and the floating diffusion region FD is mounted in a semiconductor layer 20 (see FIG. 5) to be described below.

The reading circuit 15 illustrated in FIG. 3 reads the signal electric charge stored in the floating diffusion region FD and outputs a pixel signal based on this signal electric charge. The reading circuit 15 includes, for example, an amplification transistor AMP, a selection transistor SEL, and a reset transistor RST as pixel transistors but is not limited thereto. Each of such transistors (AMP, SEL, and RST) and the transfer transistor TRG mentioned above, for example, is constituted by a MOSFET having a gate insulating film made of a silicon oxide film (SiO₂), a gate electrode, and one pair of main electrode regions functioning as a source region and a drain region as a field effect transistor. In addition, such a transistor may be a metal insulator semiconductor FET (MISFET) of which a gate insulating film is formed from a silicon nitride (Si3N4) film or a stacked film of a silicon nitride film and a silicon oxide film and the like.

As illustrated in FIG. 3, the amplification transistor AMP has a source region electrically connected to a drain region of the selection transistor SEL and a drain region electrically connected to a power source line Vdd and a drain region of the reset transistor RST. The gate electrode of the amplification transistor AMP is electrically connected to the floating diffusion region FD and a source region of the reset transistor RST.

In the selection transistor SEL, a source is electrically connected to the vertical signal line 11 (VSL), and a drain region is electrically connected to the source region of the amplification transistor AMP. A gate electrode of the selection transistor SEL is electrically connected to a selection transistor drive line among pixel drive lines 10 (see FIG. 2).

In the reset transistor RST, a source region is electrically connected to the floating diffusion region FD and the gate electrode of the amplification transistor AMP, and a drain region is electrically connected to the power source line Vdd and the drain region of the amplification transistor AMP. A gate electrode of the reset transistor RST is electrically connected to a reset transistor drive line among the pixel drive lines 10 (see FIG. 2).

When the transfer transistor TRG is turned on, the transfer transistor TRG transmits the electrical charge generated by the photoelectric conversion unit 24 to the floating diffusion region FD.

When the reset transistor RST is turned on, the reset transistor RST resets the electric potential (signal electric charge) of the floating diffusion region FD to the electric potential of the power source line Vdd. The selection transistor SEL controls an output timing of the pixel signal from the reading circuit 15.

The amplification transistor AMP generates a signal of a voltage corresponding to a level of the signal electric charge maintained in the floating diffusion region FD as a pixel signal. The amplification transistor AMP configures a source follower-type amplifier and outputs a pixel signal of a voltage corresponding to the level of the signal electric charge generated by the photoelectric conversion unit 24. When the selection transistor SEL is turned on, the amplification transistor AMP amplifies the electric potential of the floating diffusion region FD and outputs a voltage corresponding to the electric potential to the column signal processing circuit 5 through the vertical signal line 11 (VSL).

When the solid-state imaging device 1A according to this first embodiment operates, the signal electric charge generated by the photoelectric conversion unit 24 of the pixel 3 is maintained (accumulated) in the floating diffusion region FD through the transfer transistor TRG of the pixel 3. Then, the signal electric charge maintained in the floating diffusion region FD is read by the reading circuit 15 and is applied to the gate electrode of the amplification transistor AMP of the reading circuit 15. A control signal for selecting a horizontal line is applied to the gate electrode of the selection transistor SEL of the reading circuit 15 from the vertical shift register. Then, by causing the selection control signal to be in a high (H) level, the selection transistor SEL becomes conductive, and a current corresponding to an electric potential of the floating diffusion region FD which has been amplified by the amplification transistor AMP flows through the vertical signal line 11. In addition, by causing a reset control signal applied to the gate electrode of the reset transistor RST of the reading circuit 15 to be in the high (H) level, the reset transistor RST becomes conductive, and a signal electric charge accumulated in the floating diffusion region FD is reset.

In addition, the selection transistor SEL may be omitted as is necessary. In a case in which the selection transistor SEL is omitted, the source region of the amplification transistor AMP is electrically connected to the vertical signal line 11 (VSL).

### <<Specific Configuration of Solid-state Imaging Device>>

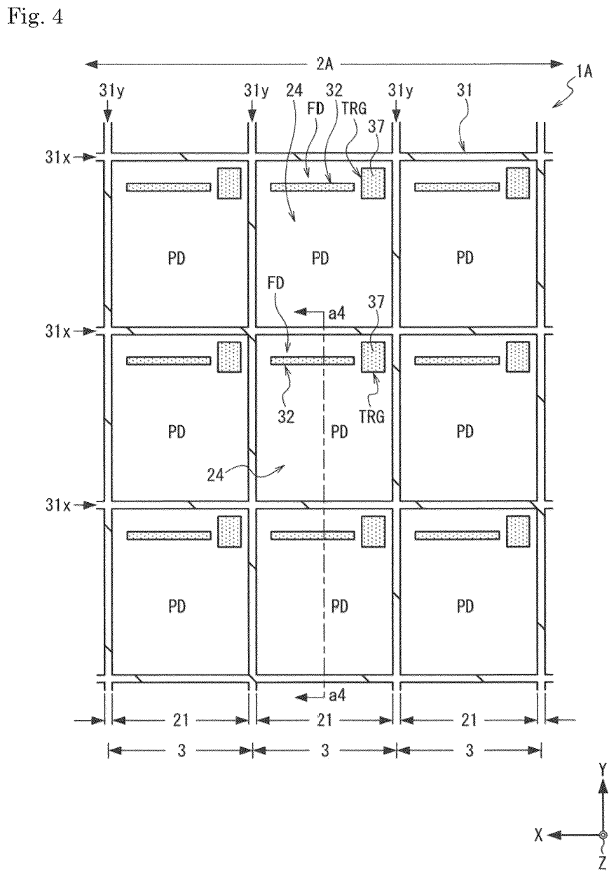

Next, a specific configuration of the semiconductor chip 2 (the solid-state imaging device 1A) will be described using FIGS. 4 to 6.

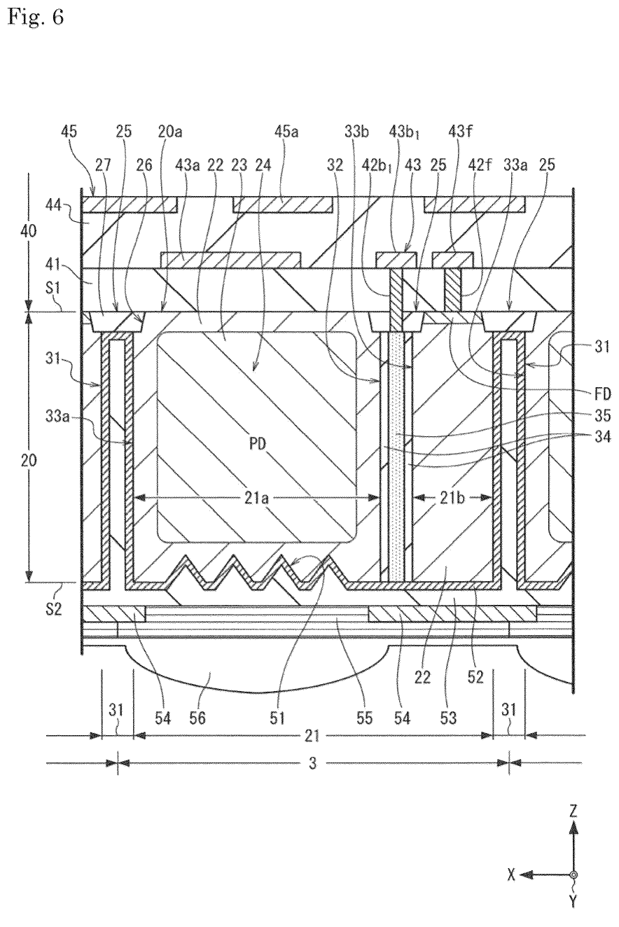

FIG. 4 is a plan view schematically illustrating a plane pattern of the inter-pixel separation area 31 in the pixel array portion 2A of the solid-state imaging device 1A. FIG. 5 is a longitudinal cross-sectional view schematically illustrating a longitudinal cross-sectional structure taken along line a4-a4 illustrated in FIG. 4. FIG. 6 is a longitudinal cross-sectional view in which a part of FIG. 5 is enlarged.

In addition, FIG. 4 is a plan view seen from a first face S1 side of the semiconductor layer 20 illustrated in FIG. 5. In order to allow the drawings to be easily seen, FIGS. 5 and 6 are vertically inverted with respect to FIG. 1. In FIGS. 5 and 6, layers higher than a wiring layer 45 of the second layer of multilayer wiring layers 40 to be described later are omitted.

### <Semiconductor Chip>

As illustrated in FIGS. 4 and 5, the semiconductor chip 2 includes a semiconductor layer 20 having a first face S1 and a second face S2 positioned on sides opposite to each other in a thickness direction (a Z direction) and an inter-pixel separation area 31 and an in-pixel separation area 32 partitioning this semiconductor layer 20. The inter-pixel separation area 31 corresponds to one specific example of “first separation area” of the present technology. The in-pixel separation area 32 corresponds to one specific example of “second separation area” of the present technology. In this first embodiment, the inter-pixel separation area 31 partitions the photoelectric conversion area 21 of the semiconductor layer 20, and the in-pixel separation area 32 partitions the inside of the photoelectric conversion area 21.

In addition, the semiconductor chip 2 includes a multilayer wiring layer (a wiring layer stacking body) 40 disposed on the first face S1 side of the semiconductor layer 20 and a fixed charge film 52, an insulating film 53, a light blocking film (a light blocking body) 54, a color filter 55, and a microlens (an on-chip lens) 56 that are sequentially disposed from this second face S2 side on the second face S2 side of the semiconductor layer 20.

### <Semiconductor Layer>

As illustrated in FIGS. 4 and 5, in the semiconductor layer 20, inter-pixel separation areas 31 extending in a thickness direction (a Z direction) of the semiconductor layer 20 and a plurality of photoelectric conversion areas 21 partitioned by these inter-pixel separation areas 31 are disposed. Each photoelectric conversion area 21 of the plurality of photoelectric conversion areas 21 is disposed for one pixel 3, and the photoelectric conversion areas 21 are adjacent to each other via the inter-pixel separation area 31 in the plan view. In other words, the solid-state imaging device 1A according to this first embodiment includes a plurality of photoelectric conversion areas 21 that are adjacently disposed through the inter-pixel separation areas 31 extending in a thickness direction (a Z direction) of the semiconductor layer 20 in the semiconductor layer 20.

In addition, as illustrated in FIG. 5, on the first face S1 side of the semiconductor layer 20, an element separation area (a field separation area) 25 and an element formation area 20a having an island shape partitioned by this element separation area 25 are disposed. The element formation area 20a is disposed for each pixel 3 (the photoelectric conversion area 21).

As the semiconductor layer 20, a Si substrate, a SiGe substrate, an InGaAs substrate, or the like can be used. In this first embodiment, as the semiconductor layer 20, for example, a semiconductor substrate of a p type formed from monocrystalline silicon is used.

Here, the first face S1 of the semiconductor layer 20 may be also referred to as an element formation face or a principal face, and the second face S2 side may be also referred to as a light incident face or a rear face. This solid-state imaging device 1A according to this first embodiment photoelectrically converts light incident from the second face (the light incident face; the rear face) S2 side of the semiconductor layer 20 in the photoelectric conversion area 21 disposed in the semiconductor layer 20.

In addition, the plan view represents a case seen from a direction along the thickness direction (the Z direction) of the semiconductor layer 20. Furthermore, the cross-sectional view represents a case in which a cross-section along the thickness direction (the Z direction) of the semiconductor layer 20 is seen from a direction orthogonal to the thickness direction (the Z direction) of the semiconductor layer 20 (the X direction or the Y direction). In addition, the photoelectric conversion area 21 may be also referred to as a photoelectric conversion cell.

### <Element Separation Area>

As illustrated in FIG. 6, the element separation area 25 is configured to have a shallow trench isolation (STI) structure in which an insulating film (a field insulating film) 27 is selectively embedded inside an indented shallow groove part (a field groove part) 26 on the second face S2 side from the first face S1 of the semiconductor layer 20, but is not limited thereto. As the insulating film 27, for example, a silicon oxide film can be used.

### <Element Formation Area>

As illustrated in FIG. 5, in the element formation area 20a partitioned by the element separation area 25, a well region 22 of a p type is disposed. In the element formation area 20a, the pixel transistors (AMP, SEL, RST, and TRG) described above are disposed. Here, for allowing the drawing to be easily seen, illustration of the pixel transistors is omitted in FIG. 5. In addition, in FIG. 4, the transfer transistor TRG is illustrated, and illustration of the other pixel transistors (AMP, SEL, and RST) is omitted. Furthermore, in FIG. 4, illustration of the element separation area 25 and the element formation area 20a illustrated in FIG. 5 is omitted.

### <Photoelectric Conversion Area>

As illustrated in FIG. 5, each photoelectric conversion area 21 among the plurality of photoelectric conversion areas (photoelectric conversion cells) 21 includes a well region 22 of a p type disposed in the semiconductor layer 20, a semiconductor area 23 of an n type disposed inside this well region 22 of a p type, and the floating diffusion region FD and the photoelectric conversion unit 24 described above. In addition, each photoelectric conversion area 21 further includes an element formation area 20a, an in-pixel separation area 32, and a diffraction scattering section 51.

### <Well Regions of p Type and Semiconductor Area of n Type>

As illustrated in FIG. 5, the well region 22 of a p type is disposed with a large width on the first face S1 side and the second face S2 side of the semiconductor layer 20. The well region 22 of the p type is composed of a semiconductor area of the p type.

The semiconductor area 23 of an n type, inside the well region 22 of the p type, in a state of being separated from the first face S1 and the second face S2 of the semiconductor layer 20 and the inter-pixel separation area 31, is disposed over the first face S1 side and the second face S2 side of the semiconductor layer 20. In other words, in the semiconductor area 23 of the n type, each of an upper face part of the first face S1 side of the semiconductor layer 20, a lower face part of the second face S2 side of the semiconductor layer 20, and a side face part of the inter-pixel separation area 31 is surrounded by the well region 22 of the p type. In other words, between the first face S1 of the semiconductor layer 20 and the upper face part of the semiconductor area 23 of the n type and between the second face S2 of the semiconductor layer 20 and the lower face part of the semiconductor area 23 of the n type, the well region 22 of the p type is disposed to overlap the semiconductor area 23 of the n type. In addition, between the inter-pixel separation area 31 and the semiconductor area 23 of the n type, the well region 22 of the p type extending in the thickness direction (the Z direction) of the semiconductor layer 20 is disposed.

### <Floating Diffusion and Photoelectric Conversion Unit>

As illustrated in FIG. 5, the floating diffusion region FD is disposed in a surface layer part of the well region 22 of the p type on the first face S1 side of the semiconductor layer 20. The floating diffusion region FD, for example, is composed of a semiconductor area of the n type (a floating diffusion region) of which an impurity density is higher than that of the semiconductor area 23 of the n type.

The photoelectric conversion unit 24 is mainly composed of the semiconductor area 23 of the n type and is configured as a photodiode (PD) of a pn junction type according to the well region 22 of the p type and the semiconductor area 23 of the n type.

### <Pixel Transistor>

The transfer transistor TRG included in the photoelectric conversion area 21, although not illustrated in detail, when described with reference to FIGS. 4 and 5, in the element formation area 20a of the first face S1 side of the semiconductor layer 20, includes a gate insulating film disposed on the well region 22 of the p type, a gate electrode 37 disposed on the well region 22 of the p type via the gate insulating film, and a channel formation area in which a channel (a conduction path) is formed in the well region 22 of the p type immediately below this gate electrode 37. In addition, the transfer transistor TRG further includes a photoelectric conversion unit 24 (a semiconductor area 23 of the n type) functioning as a source region and a floating diffusion region FD functioning as a drain region. This transfer transistor TRG controls a channel formed in the channel formation area in accordance with a gate voltage applied to the gate electrode 37. This transfer transistor TRG transmits signal electric charge that has been acquired (generated) through photoelectric conversion by the photoelectric conversion unit 24 from the photoelectric conversion unit 24 to the floating diffusion region FD through a channel formed in the channel formation area.

Each of the pixel transistors (AMP, SEL, and RST) included in the reading circuit 15, although not illustrated in detail, when described with reference to FIG. 5, for example, in the element formation area 20a of the first face S1 side of the semiconductor layer 20, includes a gate insulating film disposed on the well region 22 of the p type, a gate electrode disposed on the well region 22 of the p type with the gate insulating film therebetween, and a channel formation area in which a channel (a conduction path) is formed in the well region 22 of the p type immediately below this gate electrode. In addition, each of the pixel transistors (AMP, SEL, and RST) included in the reading circuit 15 further includes one pair of main electrode areas that are disposed inside the well region 22 of the p type while being separated in a channel length direction (a gate length direction) with the channel formation area interposed therebetween and function as a source region and a drain region. Such a pixel transistor controls a channel formed in the channel formation area in accordance with a gate voltage applied to the gate electrode.

### <Inter-pixel Separation Area>

As illustrated in FIGS. 5 and 6, the semiconductor layer 20 includes the inter-pixel separation area 31 as a first separation area and the in-pixel separation area 32 as a second separation area. In other words, the solid-state imaging device 1A according to this first embodiment includes the inter-pixel separation area 31 and the in-pixel separation area 32 as first and second separation areas partitioning the semiconductor layer 20.

As illustrated in FIG. 4, the inter-pixel separation area 31 includes first parts 31x extending in the X direction in the plan view and second parts 31y extending in the Y direction. The first parts 31x and the second parts 31y are orthogonal to each other.

The first parts 31x are repeatedly disposed in the Y direction with a predetermined space interposed therebetween. In addition, the second parts 31y are repeatedly disposed in the X direction with a predetermined space interposed therebetween. In other words, a plane pattern of the inter-pixel separation area 31 in the plan view is a plane pattern of a lattice shape. In each photoelectric conversion area 21 among the plurality of photoelectric conversion areas 21, both end sides in the X direction are partitioned by two second parts 31y of the separation area 31 that are adjacent to each other, and both end sides in the Y direction are partitioned by two first parts 31x of the separation area 31 that are adjacent to each other.

As illustrated in FIGS. 5 and 6, the inter-pixel separation area 31 extends in the thickness direction (the Z direction) of the semiconductor layer 20 and electrically and optically separates the photoelectric conversion areas 21 that are adjacent to each other in the plan view from each other. In the inter-pixel separation area 31, one end side is connected to the element separation area 25, and the other end side reaches the second face S2 of the semiconductor layer 20.

As illustrated in FIG. 6, the inter-pixel separation area 31 includes a fixed charge film 52 disposed along inner walls (a side wall and a bottom wall) of the dug part 33a extending in the depth direction (the Z direction) of the semiconductor layer 20 and an insulating film 53 that fills this dug part 33a through the fixed charge film 52 and is an insulating material having a refractive index lower than the semiconductor layer 20. In other words, the inter-pixel separation area 31 of this first embodiment includes the insulating film 53 as an insulating material of which a refractive index is lower than that of the semiconductor layer 20. In addition, as the insulating material having a refractive index lower than the semiconductor layer 20, air can be used as well In this case, the inter-pixel separation area 31 includes a cavity part filled with the air. This dug part 33a of the first embodiment corresponds to one specific example of “first dug part” of the present technology.

The fixed charge film 52 is disposed over the second face S2 of the semiconductor layer 20 and the dug part 33a of the semiconductor layer 20. The fixed charge film 52, for example, includes a dielectric film that generates negative fixed charge. For this dielectric film, as an example having a dielectric constant, hafnium oxide (HfO₂) can be used. In accordance with this fixed charge film 52, holes (h⁺) are induced in an interface part of the semiconductor layer 20 and the inter-pixel separation area 31, and pinning at this interface part can be secured, whereby generation of a dark current can be suppressed. For this dielectric film, additionally, zirconium oxide (ZrO₂), tantalum oxide (Ta₂O₅), and the like can be used.

The insulating film 53 is disposed over the second face S2 of the semiconductor layer 20 and the second dug part 33b of the semiconductor layer 20. As the insulating film 53, for example, a silicon oxide film can be used. The silicon oxide film has a refractive index that is lower than that of semiconductor materials such as Si, SiGe, InGaAs, and the like. The insulating film 53 covers the entire second face S2 side of the semiconductor layer 20 in the pixel array portion 2A such that the second face S2 (a light incident face) side of the semiconductor layer 20 becomes a flat face having no unevenness.

Here, as one example, for example, in the case of a wavelength of 940 nm, silicon, for example, has a refractive index of about 3.62, silicon oxide, for example, has a refractive index of about 1.45, and the air, for example, has a refractive index of about 1.00. In addition, as another example, in the case of a wavelength of 550 nm, silicon, for example, has a refractive index of about 4.08, silicon oxide, for example, has a refractive index of about 1.46, and the air, for example, has a refractive index of about 1.00.

### <In-Pixel Separation Area>

As illustrated in FIG. 4, the in-pixel separation area 32, for example, extends in the X direction in the plan view and is disposed to be separated from the inter-pixel separation area 31 (the first part 31x and the second part 31y). The in-pixel separation area 32 is disposed to be deviated to the inter-pixel separation area 31 from the center part of the photoelectric conversion area 21 in the plan view and selectively separates (divides) the photoelectric conversion area 21 into two areas (a first area 21a and a second area 21b) of which widths in the Y direction in the plan view are relatively different from each other. Out of the two areas (the first area 21a and the second area 21b) separated by the in-pixel separation area 32, a photoelectric conversion unit 24 is disposed in an area of a larger width in the Y direction (the first area 21a), and a floating diffusion region FD is disposed in an area of a smaller width in the Y direction (the second area 21b). In other words, the photoelectric conversion area 21 includes the photoelectric conversion unit 24 and the floating diffusion region FD separated from each other by the in-pixel separation area 32.

As illustrated in FIG. 6, the in-pixel separation area 32 extends in the thickness direction (the Z direction) of the semiconductor layer 20, a one end side is connected to the element separation area 25, and the other end side reaches the second face S2 of the semiconductor layer 20. The in-pixel separation area 32 includes a separation insulating film 34 disposed along a side wall of dug part 33b extending in the depth direction (the Z direction) of the semiconductor layer 20 and a conductive material 35 filling this dug part 33b through the separation insulating film 34. As the separation insulating film 34, for example, a silicon oxide film can be used. As the conductive material 35, for example, a semiconductor film in which an impurity for reducing a resistance value has been introduced can be used. This conductive material 35 of the first embodiment, for example, is composed of a doped polysilicon film of the p type in which Boron (B) has been introduced as an impurity but is not limited thereto. This dug part 33b of the first embodiment corresponds to a first specific example of “second dug part” of the present technology.

In addition, as illustrated in FIG. 4, the transfer transistor TRG is disposed to traverse between a terminal end part of the in-pixel separation area 32 in the X direction and the inter-pixel separation area 31 in the plan view. As illustrated in FIGS. 5 and 6, in each of two areas separated by the in-pixel separation area 32 of the photoelectric conversion area 21, a well region 22 of the p type is disposed. As a power supply electric potential, for example, a first reference electric potential of 0 V is applied to this well region 22 of the p type, and the electric potential of the well region 22 is fixed to this first reference electric potential.

### <Multilayer Wiring Layer>

As illustrated in FIG. 5, the multilayer wiring layer (a wiring layer stacking body) 40 is disposed on the first face S1 side that is a side opposite to the light incident face side (the second face S2 side) of the semiconductor layer 20. The multilayer wiring layer 40 is formed to have a stacking structure including an interlayer insulating film 41, a wiring layer 43 of the first layer, an interlayer insulating film 44, and a wiring layer 45 of the second layer that are sequentially stacked from the first face S1 side of the semiconductor layer 20 but is not limited thereto.

The interlayer insulating film 41 is disposed to cover gate electrodes of the pixel transistors (AMP, SEL, RST, and TRG) on the first face S1 side of the semiconductor layer 20. In FIG. 5, the pixel transistors are not illustrated.

In an upper layer of the interlayer insulating film 41, the wiring layer 43 of the first layer is disposed, and this wiring layer 43 of the first layer is covered with the interlayer insulating film 44 of the upper layer. In addition, in an upper layer of the interlayer insulating film 44, the wiring layer 45 of the second layer is disposed. Although not illustrated, the wiring layer 45 of the second layer is covered with an interlayer insulating film of an upper layer.

In each of the wiring layers 43 and 45 of the first and second layers, various wirings are formed. In FIG. 5, wirings 43a, 43b1, and 43f formed in the wiring layer 41 of the first layer and a wiring 45a formed in the wiring layer 45 of the second layer are illustrated.

As illustrated in FIG. 6, the wiring 43f is electrically connected to the floating diffusion region FD through a contact electrode (a conduction plug) 42f embedded in the interlayer insulating film 41. This wiring 43f is electrically connected to an input side (a gate electrode of the amplification transistor AMP and a source region of the reset transistor RST) of the reading circuit 15 illustrated in FIG. 3.

The wiring 43b1 is electrically connected to the conductive material 35 of the in-pixel separation area 32 through the contact electrode 42b1 embedded over the interlayer insulating film 41 and the element separation area 25. A second reference electric potential of a positive electric potential higher than the first reference electric potential applied to the well region 22 of the p type is applied to this wiring 43b1 as a power source electric potential. In other words, the second reference electric potential applied to the wiring 43b is applied to the conductive material 35 of the in-pixel separation area 32 through the contact electrode 42b1, and the electric potential of the conductive material 35 is fixed to this second reference electric potential. As the second reference electric potential, for example, 2.7 V is applied.

Each of the wiring layers 43 and 45, for example, is composed of a metal film of copper (Cu), an alloy having Cu as its principal body, or the like. Each of the interlayer insulating films 41 and 44, for example, is composed of one single-layer film out of a silicon oxide film, a silicon nitride (Si₃N₄) film, or a silicon carbide (SiCN) film or a stacked film acquired by stacking two or more such layers. Each of the contact electrodes 42b₁ and 42f, for example, is composed of a high melting point metal film such as a tungsten (W) film, a titanium (Ti) film, or the like.

### <Diffraction Scattering Section>

As illustrated in FIG. 6, the diffraction scattering section 51 has a configuration in which periodical unevenness is provided in an interface of the light incident face side (the second face S2 side) of the semiconductor layer 20. The diffraction scattering section 51 is disposed to overlap the photoelectric conversion unit 24 for each photoelectric conversion area 21 in the plan view.

The unevenness of the diffraction scattering section 51 becomes a diffraction lattice and can take a long optical path of the inside of the photoelectric conversion unit 24 in accordance with higher-order components diffracting in an inclination direction and particularly improve the sensitivity of a near-infrared component. More specifically, as this diffraction scattering section 51, for example, a tetragonal pyramid formed using wet etching of the Si (111) plane using alkaline ionized water (AKW) can be applied. The diffraction scattering section 51 is not limited thereto and may be formed using dry etching. Furthermore, by forming a shape of which a cross-sectional area changes in the depth direction, reflection is suppressed, and thus the sensitivity is slightly improved as well.

### <Light Blocking Film>

As illustrated in FIG. 6, the light blocking film 54 is disposed on a side opposite to the semiconductor layer 20 side of the insulating film 53. The light blocking film 54 becomes a lattice-shaped plane pattern in which a plane pattern in the plan view opens the light reception face side of each of a plurality of photoelectric conversion areas 21 such that light incident in a predetermined photoelectric conversion area 21 does not leak into a nearby photoelectric conversion area 21. The light blocking film 54 is configured in a lattice-shaped plane pattern that is the same as the lattice-shaped plane pattern of the inter-pixel separation area 31 and is disposed at a position overlapping the inter-pixel separation area 31 in the plan view. In addition, the light blocking film 54, in the photoelectric conversion area 21, has a width to be selectively thickened to cover an area between the inter-pixel separation area 31 and the in-pixel separation area 32 in the plan view, more specifically, the well region 22 of the p type and the floating diffusion region FD. In other words, the floating diffusion region FD is disposed at a position overlapping the light blocking film 54 in the plan view. As this light blocking film 54, for example, a tungsten (W) film having a light blocking property is used.

### <Color Filter and Microlens>

As illustrated in FIGS. 5 and 6, a color filter 55 is disposed on a side (the light incident face side) opposite to the semiconductor layer 20 side of the light blocking film 54 for each photoelectric conversion area 21 (each pixel 3). The color filter 55 separates colors of incidence light incident from the light incident face side of the semiconductor chip 2. As the color filters 55, there are a first color filter of red (R), a second color filter of green (G), and a third color filter of blue (B). In this first embodiment, for example, color filters 55 of three colors R, G, and B are included.

The microlens 56 is disposed on a side (the light incident face side) opposite to the light blocking film 54 of the color filter 55 for each photoelectric conversion area 21 (each pixel 3). The microlens 56 condenses irradiation light and causes the condensed light to be incident in the photoelectric conversion area 21 with high efficiency.

### <Photoelectric Conversion Unit>

The photoelectric conversion unit 24 illustrated in FIGS. 5 and 6 performs photoelectric conversion of light of a wavelength of a visible region (hereinafter, referred to as visible light) or light of a wavelength of a near infrared region (hereinafter, referred to as near-infrared light (NIR)). The photoelectric conversion unit 24, by enlarging the thickness of the semiconductor layer 20 to be larger than that of a case in which visible light is photoelectrically converted (a case in which visible light is handled), can perform photoelectric conversion of near-infrared light (handle near-infrared light). Thus, by selecting the thickness of the semiconductor layer 20 such that the photoelectric conversion unit 24 can perform photoelectric conversion of near-infrared light, light (visible light or near-infrared light) to be handled can be selected in accordance with the use of an electronic device in which the solid-state imaging device 1A is embedded. In this first embodiment, the thickness of the semiconductor layer is set to a thickness for which photoelectric conversion of near-infrared light can be performed but is not limited thereto.

Here, the wavelength range of the near-infrared light (a near infrared ray) is approximately 700 nm to 2500 nm, and the wavelength range of visible light (a visible ray) is approximately a lower limit of 360 to 400 nm to an upper limit of 760 to 830 nm.

In addition, the thickness of the semiconductor layer 20 in the photoelectric conversion area 21 handling visible light is generally 2.5 μm or more, and the thickness of the semiconductor layer 20 in the photoelectric conversion area 21 handling near-infrared light may be 6 μm or more.

### Main Effects of First Embodiment

Next, the main effects of this first embodiment will be described.

The solid-state imaging device 1A according to this first embodiment includes the inter-pixel separation area 31 corresponding to one specific example of “first separation area” of the present technology and the in-pixel separation area 32 corresponding to one specific example of “second separation area” of the present technology. The inter-pixel separation area 31 has a configuration in which the dug part 33a extending in the thickness direction (the Z direction) of the semiconductor layer 20 is filled with the insulating film 53 as an insulating material having a refractive index lower than the semiconductor layer 20. For this reason, compared to a conventional inter-pixel separation area in which the dug part 33a is filled with a doped polysilicon film as a conductive material, light absorption in the inter-pixel separation area 31 can be suppressed, in other words, light reflection in the inter-pixel separation area 31 can be increased, and improvement of a quantum efficiency QE and suppression of a high mixed color (a high modulation transfer function (MTF) characteristic) as pixel characteristics can be achieved.

On the other hand, the in-pixel separation area 32 is formed to have a configuration in which the dug part 33b extending in the thickness direction of the semiconductor layer 20 is filled with the conductive material 35. For this reason, by applying a positive electric potential to the conductive material 35 of the in-pixel separation area 32, the potential of the semiconductor layer 20 on the side wall of the in-pixel separation area 32 changes, and when a signal electric charge acquired through photoelectric conversion using the photoelectric conversion unit 24 is transmitted to the floating diffusion region FD, it can be caused to function as an assistance electrode assisting transmission of a signal electric charge to the floating diffusion region FD, and improvement of transmission characteristics as pixel characteristics can be achieved. This improvement of the transmission characteristics is especially effective in a case in which near-infrared light is photoelectrically converted by enlarging the thickness of the semiconductor layer 20.

Thus, according to the solid-state imaging device 1A of this first embodiment, improvement of the pixel characteristics can be achieved.

In addition, as in this first embodiment, also in a case in which the thickness of the semiconductor layer 20 is enlarged or a case in which the diffraction scattering section 51 is disposed in the photoelectric conversion area 21 such that near-infrared light can be photoelectrically converted using the photoelectric conversion unit 24, a high MTF characteristic can be realized while a high quantum efficiency QE is secured.

In addition, since light reflection in the inter-pixel separation area 31 can be increased, miniaturization of the width of the inter-pixel separation area 31 and miniaturization of the photoelectric conversion area 21 can be achieved.

In addition, the solid-state imaging device 1A of this first embodiment includes the light blocking film 54 on the light incident face side (the second face S2 side) of the semiconductor layer 20 that is configured to have a selectively thickened width to cover the floating diffusion region FD disposed between the inter-pixel separation area 31 and the in-pixel separation area 32. For this reason, emission of light to the floating diffusion region FD can be suppressed, and parasitic light sensitivity (PLS) characteristics can be improved.

In addition, in the first embodiment described above, a case in which the thickness of the semiconductor layer 20 is set to be large such that near-infrared light can be photoelectrically converted by the photoelectric conversion unit 24 has been described. However, the present technology can be applied also to a case in which the thickness of the semiconductor layer 20 is set to be thin such that visible light can be selectively photoelectrically converted by the photoelectric conversion unit 24.

In addition, in the first embodiment described above, a case in which each of the inter-pixel separation area 31 and the in-pixel separation area 32 reaches the second face S2 of the semiconductor layer 20 has been described. However, the present technology can be applied also to a case in which each of the inter-pixel separation area 31 and the in-pixel separation area 32 is separated from the second face S2 of the semiconductor layer 20.

In addition, in the first embodiment described above, a case in which the silicon film into which an impurity for reducing a resistance value has been introduced is used as the conductive material 35 of the in-pixel separation area 32 has been described. However, since the silicon film has light absorption, from the point of view of light, it is preferable to use a high-melting point metal film having conductivity such as tungsten, titanium, or the like, a metal film having conductivity such as aluminum (Al) or the like, or an alloy film.

Furthermore, the in-pixel separation area 32 can be also used as a transfer transistor also having an assistance function for assisting transmission of a signal electric charge to the floating diffusion region FD.

### Second Embodiment

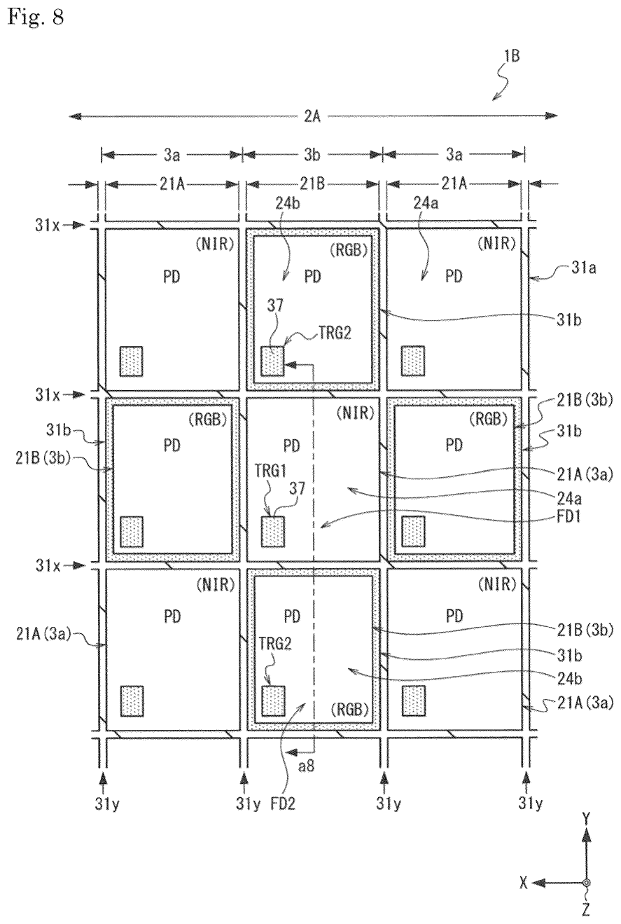

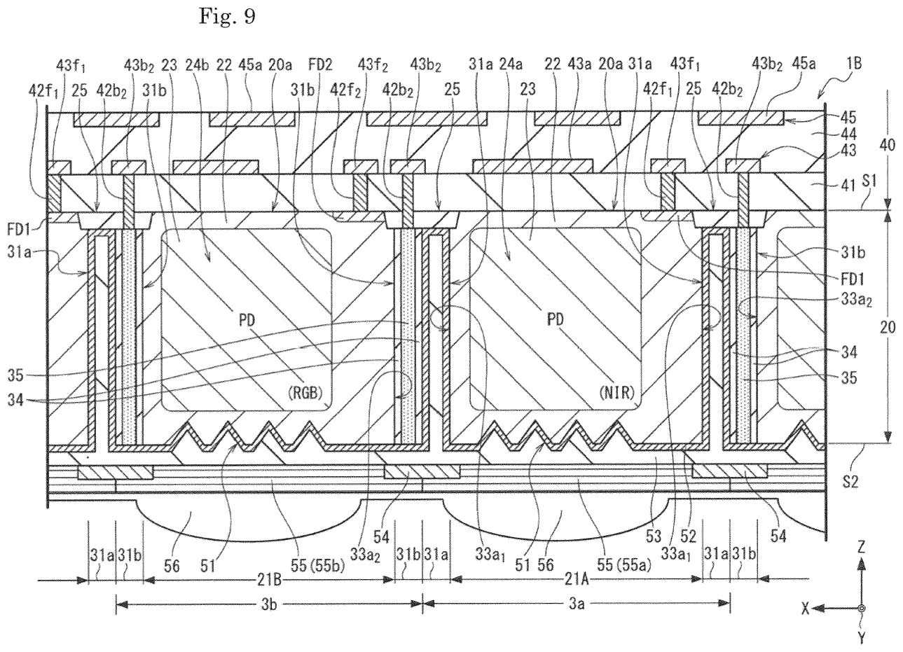

In the first embodiment described above, the solid-state imaging device 1A including the inter-pixel separation area 31 corresponding to one specific example of “first separation area” of the present technology and the in-pixel separation area 32 corresponding to one specific example of “second separation area” of the present technology has been described. In contrast to this, in this second embodiment, as illustrated in FIGS. 8 and 9, a solid-state imaging device 1B including a first inter-pixel separation area 31a corresponding to one specific example of “first separation area” of the present technology and a second inter-pixel separation area 31b corresponding to one specific example of “second separation area” of the present technology will be described.

The solid-state imaging device 1B according to the second embodiment of the present technology basically has a configuration similar to the solid-state imaging device 1A according to the first embodiment described above, and there are following different configurations.

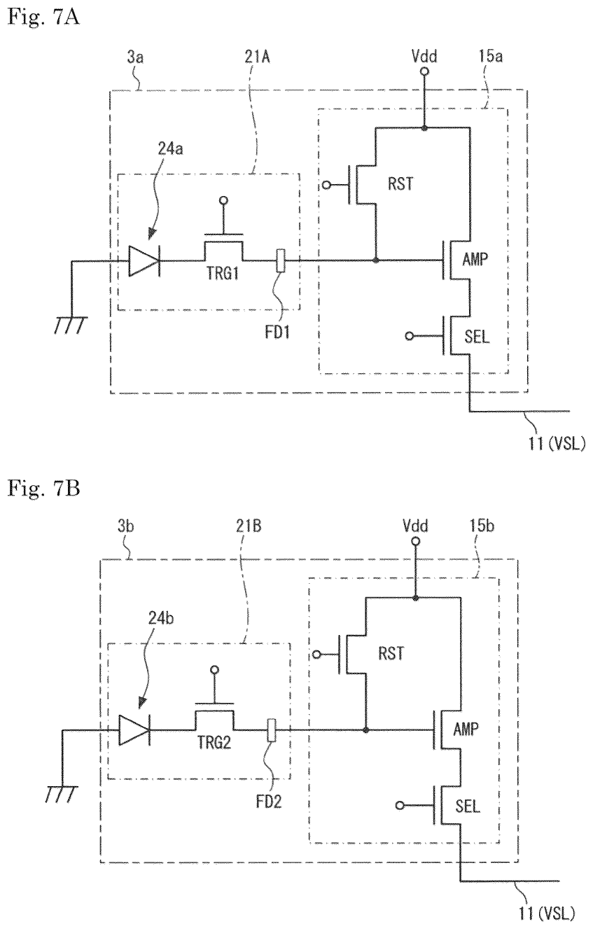

In other words, the solid-state imaging device 1B according to this second embodiment includes a pixel 3a illustrated in FIG. 7A and a pixel 3b illustrated in FIG. 7B in place of the pixel 3 according to the first embodiment described above illustrated in FIG. 3. In addition, the solid-state imaging device 1B according to this second embodiment includes a first inter-pixel separation area 31a and a second inter-pixel separation area 31b in place of the inter-pixel separation area 31 and the in-pixel separation area 32 according to the first embodiment described above illustrated in FIGS. 4 and 5. The other configurations are basically similar to those according to the first embodiment.

### <Circuit Configuration of Pixel>

As illustrated in FIG. 7A, the pixel 3a includes a first photoelectric conversion area 21A and a reading circuit 15a. The first photoelectric conversion area 21A includes a photoelectric conversion unit 24a, a transfer transistor TRG1 as a pixel transistor, and a floating diffusion region FD1 as an electric charge maintaining section. The reading circuit 15a is electrically connected to the floating diffusion region FD1 of the first photoelectric conversion area 21A.

As illustrated in FIG. 7B, the pixel 3b includes a second photoelectric conversion area 21B and a reading circuit 15b. The second photoelectric conversion area 21B includes a photoelectric conversion unit 24b, a transfer transistor TRG2 as a pixel transistor, and a floating diffusion region FD2 as an electric charge maintaining section. The reading circuit 15b is electrically connected to the floating diffusion region FD2 of the second photoelectric conversion area 21B. In this second embodiment, as illustrated in FIGS. 7A and 7B, as one example, although a circuit configuration in which one reading circuit 15a or 15b is assigned to one pixel 3a or 3b is formed, the circuit configuration is not limited thereto, and a circuit configuration in which one reading circuit 15a is shared by a plurality of pixels 3a, and one reading circuit 15b is shared by a plurality of pixels 3b may be employed.

The photoelectric conversion unit 24a illustrated in FIG. 7A, for example, is composed of a photodiode (PD) of a pn junction type. The photoelectric conversion unit 24a generates (performs photoelectric conversion of) a signal electric charge corresponding to a light reception amount of light of a wavelength of a near infrared area (near-infrared light) and maintains the signal electric charge. The photoelectric conversion unit 24a has a cathode side electrically connected to the source region of the transfer transistor TRG1 and an anode side electrically connected to a reference electric potential line (for example, the ground).

The transfer transistor TRG1 illustrated in FIG. 7A transmits the signal electric charge acquired through photoelectric conversion using the photoelectric conversion unit 24a to the floating diffusion region FD1. The source region of the transfer transistor RTG1 is electrically connected to the cathode side of the photoelectric conversion unit 24a, and the drain region of the transfer transistor TRG is electrically connected to the floating diffusion region FD1. A gate electrode of the transfer transistor TRG1 is electrically connected to a transfer transistor drive line among pixel drive lines 10 (see FIG. 2).

The floating diffusion region FD1 illustrated in FIG. 7A temporarily maintains (accumulates) a signal electric charge transmitted from the photoelectric conversion unit 24a through the transfer transistor TRG1.

The first photoelectric conversion area 21A including the photoelectric conversion unit 24a, the transfer transistor TRG1, and the floating diffusion region FD1 is mounted in the semiconductor layer 20 illustrated in FIG. 9.

The reading circuit 15a illustrated in FIG. 7A reads a signal electric charge maintained in the floating diffusion region FD1 and outputs a pixel signal based on this signal electric charge. The reading circuit 15a has a configuration similar to the reading circuit 15 of the first embodiment described above and, for example, includes an amplification transistor AMP, a selection transistor SEL, and a reset transistor RST as pixel transistors but is not limited thereto.

The photoelectric conversion unit 24b illustrated in FIG. 7B, for example, is composed of a photodiode (PD) of a pn junction type. The photoelectric conversion unit 24b generates (performs photoelectric conversion of) light of a wavelength of a visible region (visible light) into a signal electric charge corresponding to a light reception amount and maintains the signal electric charge. The photoelectric conversion unit 24b has a cathode side electrically connected to a source region of the transfer transistor TRG2 and an anode side electrically connected to a reference electric potential line (for example, the ground).

The transfer transistor TRG2 illustrated in FIG. 7B transmits a signal electric charge acquired through photoelectric conversion using the photoelectric conversion unit 24b to the floating diffusion region FD2. A source region of the transfer transistor RTG2 is electrically connected to the cathode side of the photoelectric conversion unit 24b, and a drain region of the transfer transistor TRG2 is electrically connected to the floating diffusion region FD2. A gate electrode of the transfer transistor TRG2 is electrically connected to a transfer transistor drive line among the pixel drive lines 10 (see FIG. 2).

The floating diffusion region FD2 illustrated in FIG. 7B temporarily maintains (accumulates) a signal electric charge transmitted from the photoelectric conversion unit 24b through the transfer transistor TRG2.

The second photoelectric conversion area 21B including the photoelectric conversion unit 24b, the transfer transistor TRG2, and the floating diffusion region FD2 is mounted in the semiconductor layer 20 illustrated in FIG. 9.

The reading circuit 15b illustrated in FIG. 7B reads a signal electric charge maintained in the floating diffusion region FD2 and outputs a pixel signal based on this signal electric charge. The reading circuit 15b has a configuration similar to the reading circuit 15 of the first embodiment described above and, for example, includes an amplification transistor AMP, a selection transistor SEL, and a reset transistor RST as pixel transistors but is not limited thereto.

### <Semiconductor Layer>

As illustrated in FIGS. 8 and 9, in the semiconductor layer 20, the first and second inter-pixel separation areas 31a and 31b extending in the thickness direction (the Z direction) of the semiconductor layer 20, the first photoelectric conversion area 21A partitioned by this first inter-pixel separation area 31a, and the second photoelectric conversion area 21B partitioned by this second inter-pixel separation area 31b are disposed. As illustrated in FIG. 8, in the pixel array portion 2A, the first photoelectric conversion area 21A and the second photoelectric conversion area 21B, for example, are disposed to be alternately repeated in each of the X direction and the Y direction that are orthogonal to each other inside a two-dimensional plane. In other words, in the pixel array portion 2A of this second embodiment, the pixel 3a including the first photoelectric conversion area 21A and the pixel 3b including the second photoelectric conversion area 21B are disposed to be alternately repeated in each of the X direction and the Y direction. In FIG. 8, five first photoelectric conversion areas 21A (the pixels 3a: NIR) and four second photoelectric conversion areas 21B (the pixels 3b: RGB) are illustrated.

### <Photoelectric Conversion Area>

As illustrated in FIG. 9, the first photoelectric conversion area 21A basically has a configuration similar to the photoelectric conversion area 21 of the first embodiment described above. In other words, similar to the photoelectric conversion area 21 of the first embodiment described above, the first photoelectric conversion area 21A includes a well region 22 of the p type, a semiconductor area 23 of the n type, a floating diffusion region FD1, a photoelectric conversion unit 24a, a transfer transistor TRG1 (see FIG. 8), an element formation area 20a, and a diffraction scattering section 51. In the first photoelectric conversion area 21A, the in-pixel separation area 32 according to the first embodiment illustrated in FIGS. 4 and 5 described above is not included.

As illustrated in FIG. 9, the second photoelectric conversion area 21B basically has a configuration similar to the photoelectric conversion area 21 of the first embodiment described above. In other words, similar to the photoelectric conversion area 21 of the first embodiment described above, the second photoelectric conversion area 21B includes a well region 22 of the p type, a semiconductor area 23 of the n type, a floating diffusion region FD2, a photoelectric conversion unit 24b, a transfer transistor TRG2 (see FIG. 8), an element formation area 20a, and a diffraction scattering section 51. Also in the second photoelectric conversion area 21B, the in-pixel separation area 32 according to the first embodiment illustrated in FIGS. 4 and 5 described above is not included.

As illustrated in FIG. 9, similar to the floating diffusion region FD of the first embodiment described above, each of the floating diffusion regions FD1 and FD2 is disposed in a surface layer part of the well region 22 of the p type on the first face S1 side of the semiconductor layer 20. Each of the floating diffusion regions FD1 and FD2 is configured using a semiconductor area (a floating diffusion region) of the n type of which an impurity density is higher than that of the semiconductor area 23 of the n type.

Similar to the photoelectric conversion unit 24 of the first embodiment described above, each of the photoelectric conversion units 24a and 24b is mainly configured using a semiconductor area 23 of the n type and is configured as a photodiode (PD) of the pn junction type using a well region 22 of the p type and a semiconductor area 23 of the n type.

### <First and Second Inter-pixel Separation Area>

As illustrated in FIG. 8, similar to the inter-pixel separation area 31 of the first embodiment illustrated in FIG. 4 described above, the first inter-pixel separation area 31a includes first parts 31x extending in the X direction in the plan view and second parts 31y extending in the Y direction. The first parts 31x and the second parts 31y are orthogonal to each other.

The first parts 31x are repeatedly disposed in the Y direction with a predetermined space interposed therebetween. In addition, the second parts 31y are repeatedly disposed in the X direction with a predetermined space interposed therebetween. In other words, a plane pattern of the first inter-pixel separation area 31a in the plan view is a plane pattern of a lattice shape. In the first photoelectric conversion area 21A, both end sides in the X direction are partitioned by two second parts 31y of the separation area 31a that are adjacent to each other, and both end sides in the Y direction are partitioned by two first parts 31x of the separation area 31 that are adjacent to each other.

As illustrated in FIG. 8, the second inter-pixel separation area 31b is disposed to be adjacent to the first inter-pixel separation area 31a inside an area partitioned by the first inter-pixel separation area 31a. This second inter-pixel separation area 31b has a plane pattern in the plan view to be a circular shape and is in contact with the first part 31x and the second part 31y of the first inter-pixel separation area 31a. In other words, the second photoelectric conversion area 21B has both end sides in the X direction in the plan view being partitioned by the second inter-pixel separation area 31b and both end sides in the Y direction being partitioned by the second inter-pixel separation area 31b. In addition, the first photoelectric conversion area 21A and the second photoelectric conversion area 21B are adjacent to each other through the first and second inter-pixel separation areas 31a and 31b that are adjacent to each other. The first photoelectric conversion area 21A and the second photoelectric conversion area 21B that are adjacent to each other are electrically and optically separated by the first and second inter-pixel separation areas 31a and 31b.

As illustrated in FIG. 9, the first inter-pixel separation area 31a extends in the thickness direction (the Z direction) of the semiconductor layer 20 and electrically and optically separates the first photoelectric conversion area 21A and the second photoelectric conversion area 21B that are adjacent to each other in the plan view. The first inter-pixel separation area 31a has one end side connected to the element separation area 25 and the other side reaching the second face S2 of the semiconductor layer 20.

The first inter-pixel separation area 31a includes a fixed charge film 52 disposed along an inner wall (a side wall and a bottom wall) of the dug part 33a₁ extending in the depth direction (the Z direction) of the semiconductor layer 20 and an insulating film 53 that fills this dug part 33a₁ through the fixed charge film 52 and serves as an insulating material of which a refractive index is lower than that of the semiconductor layer 20. In addition, as the insulating material of which the refractive index is lower than that of the semiconductor layer 20, the air can be used as well. In such a case, the first inter-pixel separation area 31a includes a cavity part in which the air is filled. The dug part 33a₁ of this second embodiment corresponds to one specific example of “first dug part” of the present technology.

As illustrated in FIG. 9, the second inter-pixel separation area 31b extends in the thickness direction (the Z direction) of the semiconductor layer 20 and electrically and optically separates the first photoelectric conversion area 21A and the second photoelectric conversion area 21B that are adjacent to each other in the plan view. The second inter-pixel separation area 31b has one end side connected to the element separation area 25 and the other end side reaching the second face S2 of the semiconductor layer 20.

The second inter-pixel separation area 31b includes a separation insulating film 34 disposed along an inner wall (a side wall and a bottom wall) of the second dug part 33a2 extending in the depth direction (the Z direction) of the semiconductor layer 20 and a conductive material 35 that fills this dug part 33a2 through the separation insulating film 34 and has a refractive index lower than the semiconductor layer 20. As the separation insulating film 34, for example, a silicon oxide film can be used. As the conductive material 35, for example, a semiconductor film into which an impurity for reducing a resistance value has been introduced can be used. The conductive material 35 of this second embodiment, for example, is composed of a doped polysilicon film of the p type into which boron (B) has been introduced as an impurity but is not limited thereto. The dug part 33b2 of this second embodiment corresponds to one specific example of “second dug part” of the present technology.

### <Wiring>

As illustrated in FIG. 9, the conductive material 35 of the second inter-pixel separation area 31b is electrically connected to a wiring 43b2 formed in the wiring layer 43 of the first layer through a contact electrode 42b2 embedded in the interlayer insulating film 41 and the element separation area 25. Differently from the first embodiment described above, a third reference electric potential of a negative electric potential that is lower than the first reference electric potential applied to the well region 22 of the p type is applied to this wiring 43b2 as a power source electric potential. In other words, the conductive material 35 of the second inter-pixel separation area 31b is supplied with the second reference electric potential applied to the wiring 43b2 through the contact electrode 42b2 and has its electric potential fixed to this third reference electric potential. As the third reference electric potential, for example, −1.2 V is applied. By applying the third reference electric potential of the negative electric potential to the conductive material 35 of the second inter-pixel separation area 31b, the potential of the semiconductor layer 20 on the side wall of the second inter-pixel separation area 31b changes, and a saturated electric charge amount Qs can be raised, whereby improvement of the pixel characteristics can be achieved.

As illustrated in FIG. 9, the floating diffusion region FD1 of the first photoelectric conversion area 21A is electrically connected to a wiring 43f₁ formed in the wiring layer 43 of the first layer through a contact electrode 42f₁ embedded in the interlayer insulating film 41. This wiring 43f₁ is electrically connected to an input side of the reading circuit 15a (the gate electrode of the amplification transistor AMP and the source region of the reset transistor RST) illustrated in FIG. 7A.

As illustrated in FIG. 9, the floating diffusion region FD2 of the second photoelectric conversion area 21B is electrically connected to a wiring 43f2 formed in the wiring layer of the first layer through a contact electrode 42f2 embedded in the interlayer insulating film 41. This wiring 43f2 is electrically connected to an input side of the reading circuit 15b (the gate electrode of the amplification transistor AMP and the source region of the reset transistor RST) illustrated in FIG. 7B.

Here, spectrum diffraction of near-infrared light and visible light, for example, can be performed using the color filter 55. More specifically, by disposing a color filter 55a through which near-infrared light is transmitted to overlap the first photoelectric conversion area 21A in the plan view, near-infrared light can be caused to be incident in the first photoelectric conversion area 21A (the first photoelectric conversion unit 24a). In addition, by disposing a color filter 55b through which visible light is transmitted to overlap the second photoelectric conversion area 21B in the plan view, visible light can be caused to incident in the second photoelectric conversion area 21B (the second photoelectric conversion unit 24b).

In addition, in this second embodiment, although the color filter 55 (55a) is disposed to overlap the first photoelectric conversion area 21A in the plan view, in the first photoelectric conversion area 21A including the first photoelectric conversion unit 24a performing photoelectric conversion of near-infrared light, the color filter 55 does not necessarily need to be disposed.

### Main Effect of Second Embodiment

The solid-state imaging device 1B according to this second embodiment includes the first inter-pixel separation area 31a as “first separation area” of the present technology, the first photoelectric conversion area 21A partitioned by this first inter-pixel separation area 31a, the second inter-pixel separation area 31b as “second separation area” of the present technology, and the second photoelectric conversion area 21B partitioned by this second inter-pixel separation area 31b. Similar to inter-pixel separation area 31 of the first embodiment described above, the first inter-pixel separation area 31a has a configuration in which the insulating film 53 as an insulating material having a refractive index lower than the semiconductor layer 20 is filled in the dug part 33a₁ extending in the thickness direction (the Z direction) of the semiconductor layer 20. For this reason, similar to the first embodiment described above, compared to a conventional in-pixel separation area in which a doped polysilicon film is filled in the dug part 33a₁ as a conductive material, light absorption in the first inter-pixel separation area 31a is suppressed, in other words, light reflection in the first inter-pixel separation area 31a can be increased, and, also in a case in which the first photoelectric conversion area 21A including the first photoelectric conversion unit 24a that performs photoelectric conversion of near-infrared light and the second photoelectric conversion area 21B including the second photoelectric conversion unit 24b that performs photoelectric conversion of visible light are mixed, improvement of a quantum efficiency QE and high mixed color suppression (a high MTF characteristic) can be achieved.

On the other hand, similar to the in-pixel separation area 32 of the first embodiment described above, the second inter-pixel separation area 31b has a configuration in which the conductive material 35 fills the dug part 33a2 extending in the thickness direction of the semiconductor layer 20. For this reason, by applying a negative electric potential to the conductive material 35 of the second inter-pixel separation area 31b, the potential of the semiconductor layer 20 on the side wall of the second inter-pixel separation area 31b changes, and the saturated electric charge amount Qs in the second photoelectric conversion area 21B in which the second photoelectric conversion unit 24b performing photoelectric conversion of visible light is disposed can be raised, whereby improvement of the pixel characteristics can be achieved.

Thus, also in the solid-state imaging device 1B according to this second embodiment, improvement of the pixel characteristics can be achieved.

In addition, since light reflection in the first inter-pixel separation area 31a can be increased, also in the solid-state imaging device 1B according to this second embodiment, miniaturization of the width of the first inter-pixel separation area 31a can be achieved, and miniaturization of each of the first photoelectric conversion area 21A and the second photoelectric conversion area 21B can be achieved.

In addition, in this second embodiment, although the floating diffusion regions FD1 and FD2 and the light blocking film 54 do not overlap each other in the plan view, as illustrated in FIG. 6 of the first embodiment described above, the width of the light blocking film 54 may be selectively thickened such that it covers the floating diffusion regions FD1 and FD2.

### Third Embodiment

This third embodiment is acquired by combining the inter-pixel separation area 31 and the in-pixel separation area 32 of the first embodiment described above illustrated in FIGS. 4 and 5 and the first photoelectric conversion area 21A and the second photoelectric conversion area 21B of the second embodiment described above illustrated in FIGS. 8 and 9.

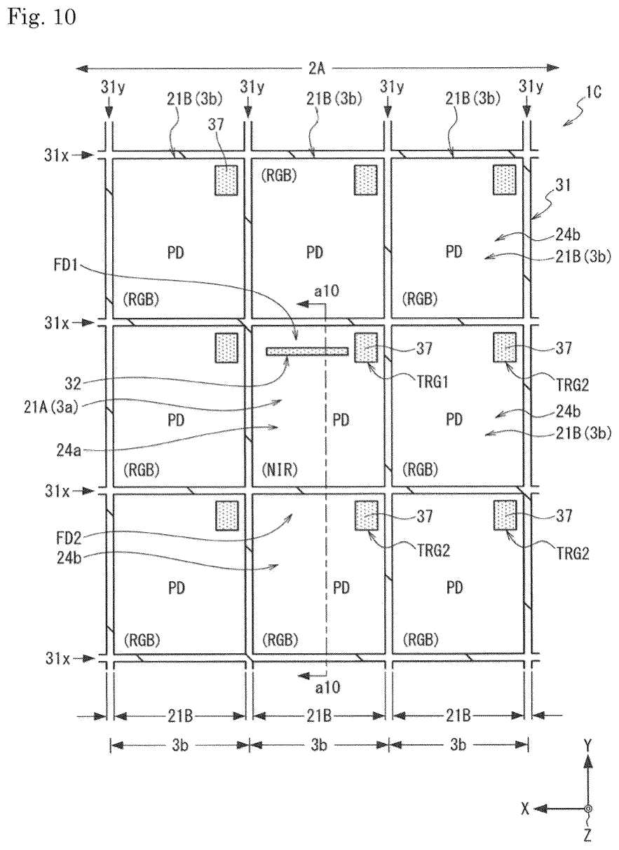

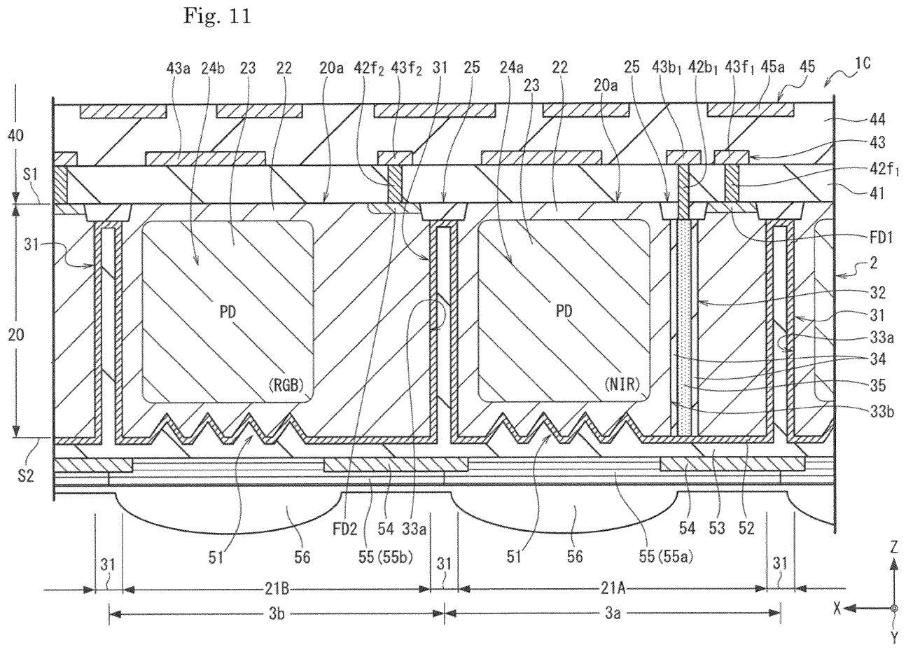

In other words, as illustrated in FIGS. 10 and 11, a solid-state imaging device 1C according to the third embodiment of the present technology includes a first photoelectric conversion area 21A and a second photoelectric conversion area 21B that are partitioned by an inter-pixel separation area 31 to be adjacent to each other. In at least one of the first photoelectric conversion area 21A and the second photoelectric conversion area 21B, for example, in the first photoelectric conversion area 21A, the in-pixel separation area 32 is disposed. In other words, in this third embodiment, the first photoelectric conversion area 21A includes the in-pixel separation area 32, and the second photoelectric conversion area 21B does not include the in-pixel separation area 32. In this third embodiment, the inter-pixel separation area 31 corresponds to one specific example of “first separation area” of the present technology, and the in-pixel separation area 32 corresponds to one specific example of “second separation area” of the present technology. The other configurations are basically similar to those of the first embodiment described above.

As illustrated in FIG. 10, in a pixel array portion 2A of this third embodiment, pixels 3a including the first photoelectric conversion area 21A and pixels 3b including the second photoelectric conversion area 21B are disposed. The pixels 3b are repeatedly disposed in each of the X direction and the Y direction that are orthogonal to each other inside a two-dimensional plane. The pixels 3a are scattered inside a pixel group in which a plurality of the pixels 3b are aligned and configure pixel columns together with the pixels 3b. FIG. 10 illustrates a disposition pattern in which 8 pixels 3b are disposed on the periphery of one pixel 3a as one example. The pixels 3a may be periodically disposed or may be randomly disposed.

As illustrated in FIG. 11, a conductive material 35 of the in-pixel separation area 32 is electrically connected to a wiring 43b₁ of a wiring layer 43 of the first layer through a contact electrode 42b₁ embedded over an interlayer insulating film 41 and an element separation area 25. Similar to the first embodiment described above, a second reference electric potential of a positive electric potential higher than a first reference electric potential applied to the well region 22 of the p type is applied to this wiring 43b₁ as a power source electric potential. In other words, the conductive material 35 of the in-pixel separation area 32 is supplied with the second reference electric potential applied to the wiring 43b₁ through the contact electrode 42b₁ and has an electric potential fixed to this second reference electric potential.

As illustrated in FIG. 11, a floating diffusion region FD1 of the first photoelectric conversion area 21A is electrically connected to a wiring 43f₁ formed in the wiring layer 43 of the first layer through a contact electrode 42f₁ embedded in the interlayer insulating film 41. This wiring 43f₁ is electrically connected to an input side of a reading circuit 15a (a gate electrode of an amplification transistor AMP and a source region of a reset transistor RST) of the second embodiment described above illustrated in FIG. 7A.

As illustrated in FIG. 11, a floating diffusion region FD2 of the second photoelectric conversion area 21B is electrically connected to a wiring 43f2 formed in the wiring layer of the first layer through a contact electrode 42f2 embedded in the interlayer insulating film 41. This wiring 43f2 is electrically connected to an input side of a reading circuit 15b (a gate electrode of the amplification transistor AMP and a source region of the reset transistor RST) of the second embodiment described above illustrated in FIG. 7B.

### Main Effect of Third Embodiment

The solid-state imaging device 1C according to this third embodiment includes the inter-pixel separation area 31 corresponding to one specific example of “first separation area” of the present technology and the first photoelectric conversion area 21A and the second photoelectric conversion area 21B partitioned by this inter-pixel separation area 31. Similar to the inter-pixel separation area 31 of the first embodiment described above, the inter-pixel separation area 31 of this third embodiment has a configuration in which the dug part 33a extending in the thickness direction (the Z direction) of the semiconductor layer 20 is filled with the insulating film 53 as an insulating material having a lower refractive index than the semiconductor layer 20. For this reason, similar to the first embodiment described above, compared to a conventional inter-pixel separation area in which the dug part 33a is filled with a doped polysilicon film as a conductive material, light absorption in the first inter-pixel separation area 31 can be suppressed, in other words, light reflection in the first inter-pixel separation area 31a can be increased, and, also in a case in which the first photoelectric conversion area 21A including the first photoelectric conversion unit 24a that performs photoelectric conversion of near-infrared light and the second photoelectric conversion area 21B including the second photoelectric conversion unit 24b that performs photoelectric conversion of visible light are mixed, improvement of a quantum efficiency QE and high mixed color suppression (a high MTF characteristic) can be achieved. On the other hand, similar to the in-pixel separation area 32 of the first embodiment described above, the in-pixel separation area 32 of the third embodiment has a configuration in which the conductive material 35 fills the dug part 33b extending in the thickness direction of the semiconductor layer 20. For this reason, similar to the first embodiment described above, by applying a positive electric potential to the conductive material 35 of the in-pixel separation area 32, the potential of the semiconductor layer 20 on the side wall of the in-pixel separation area 32 changes, and when a signal electric charge acquired through photoelectric conversion using the photoelectric conversion unit 24a is transmitted to the floating diffusion region FD1, it can be caused to function as an assistance electrode assisting transmission of a signal electric charge to the floating diffusion region FD1, and improvement of transmission characteristics as pixel characteristics can be achieved.

Thus, also in the solid-state imaging device 1C according to this first embodiment, improvement of the pixel characteristics can be achieved.

In addition, since light reflection in the inter-pixel separation area 31 can be increased, also in the solid-state imaging device 1C according to this first embodiment, miniaturization of the width of the inter-pixel separation area 31 can be achieved, and miniaturization of each of the first photoelectric conversion area 21A (the pixel 3a) and the second photoelectric conversion area 21B (the pixel 3b) can be achieved.

In addition, similar to the first embodiment described above, the solid-state imaging device 1C of this third embodiment includes the light blocking film 54 on the light incident face side (the second face S2 side) of the semiconductor layer 20 that is configured to have a selectively thickened width to cover the floating diffusion regions FD1 and FD2 disposed between the inter-pixel separation area 31 and the in-pixel separation area 32. Thus, also in the solid-state imaging device 1C according to this third embodiment, similar to the solid-state imaging device 1A according to the first embodiment described above, PLS characteristics (parasitic light sensitivity characteristics) can be enhanced.

In addition, in the third embodiment described above, a case in which the in-pixel separation area 32 functioning as an assistance electrode is disposed in the first photoelectric conversion area 21A has been described. However, the in-pixel separation area 32 functioning as an assistance electrode may be disposed in the second photoelectric conversion area 21B or may be disposed in both the first photoelectric conversion area 21A and the second photoelectric conversion area 21B. Here, as in this third embodiment, it is preferable that the in-pixel separation area 32 functioning as an assistance electrode be disposed in the first photoelectric conversion area 21A including the photoelectric conversion unit 24a that performs photoelectric conversion of near-infrared light.

### Fourth Embodiment

This fourth embodiment is acquired by building the in-pixel separation area 32 of the first embodiment described above illustrated in FIGS. 4 and 5 into the second embodiment described above.

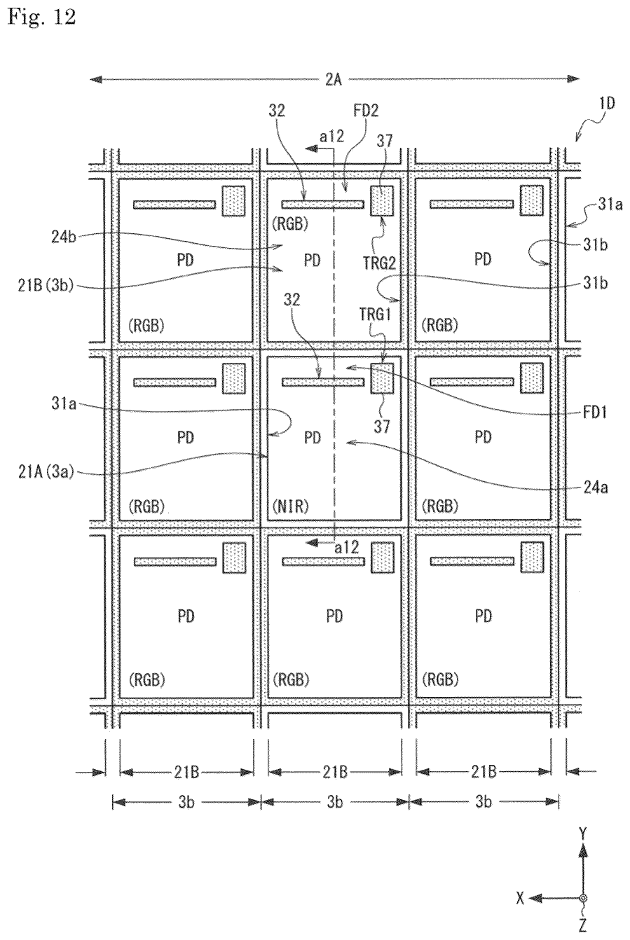

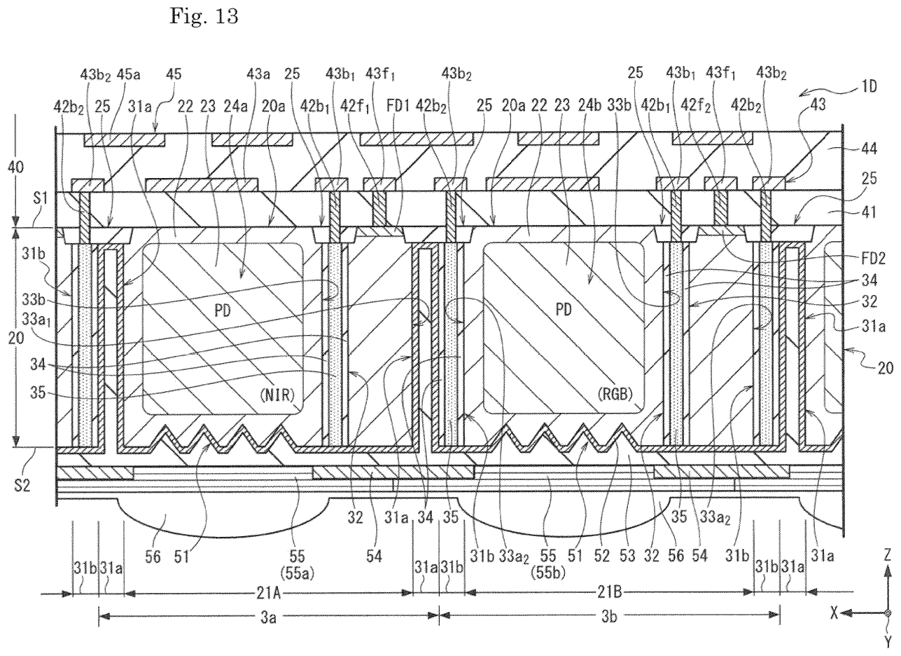

In other words, as illustrated in FIGS. 12 and 13, a solid-state imaging device 1D according to the fourth embodiment of the present technology includes first inter-pixel separation areas 31a, second inter-pixel separation areas 31b, and in-pixel separation areas 32. In this fourth embodiment, the first inter-pixel separation area 31a corresponds to one specific example of “first separation area” of the present technology, the second inter-pixel separation area 31b corresponds to one specific example of “second separation area” of the present technology, and the in-pixel separation area 32 corresponds to a third separation area of the present technology.

In addition, the solid-state imaging device 1D according to the fourth embodiment of the present technology includes first photoelectric conversion areas 21A partitioned by the first inter-pixel separation areas 31a and second photoelectric conversion areas 21B partitioned by the second inter-pixel separation areas 31b. The in-pixel separation area 32 is disposed in each of the first photoelectric conversion area 21A and the second photoelectric conversion area 21B.

As illustrated in FIG. 13, the first photoelectric conversion area 21A basically has a configuration similar to the first photoelectric conversion area 21A of the second embodiment described above. In other words, similar to the photoelectric conversion area 21 of the second embodiment described above, the first photoelectric conversion area 21A includes a well region 22 of the p type, a semiconductor area 23 of the n type, a floating diffusion region FD1, a photoelectric conversion unit 24a, a transfer transistor TRG1 (see FIG. 8), an element formation area 20a, and a diffraction scattering section 51. The first photoelectric conversion area 21A of this fourth embodiment includes an in-pixel separation area 32. The in-pixel separation area 32 is disposed to be separate from the first inter-pixel separation area 31a.

As illustrated in FIG. 13, the second photoelectric conversion area 21B basically has a configuration similar to the photoelectric conversion area 21B of the second embodiment described above. In other words, similar to the photoelectric conversion area 21 of the second embodiment described above, the second photoelectric conversion area 21B includes a well region 22 of the p type, a semiconductor area 23 of the n type, a floating diffusion region FD1, a photoelectric conversion unit 24a, a transfer transistor TRG1 (see FIG. 8), an element formation area 20a, and a diffraction scattering section 51. The second photoelectric conversion area 21B of this fourth embodiment includes an in-pixel separation area 32. The in-pixel separation area 32 is disposed to be separate from the second inter-pixel separation area 31b.

### <Electric Potential Fixation>

As illustrated in FIG. 13, a conductive material 35 of the in-pixel separation area 32 included in the first photoelectric conversion area 21A is electrically connected to a wiring 43b₁ of a wiring layer 43 of the first layer through a contact electrode 42b₁ embedded over an interlayer insulating film 41 and an element separation area 25. Similarly, a conductive material 35 of the in-pixel separation area 32 included in the second photoelectric conversion area 21B is electrically connected to a wiring 43b₁ of a wiring layer 43 of the first layer through a contact electrode 42b₁ embedded over the interlayer insulating film 41 and the element separation area 25. Similar to the first embodiment described above, a second reference electric potential of a positive electric potential higher than a first reference electric potential applied to the well region 22 of the p type is applied to such a wiring 43b₁ as a power source electric potential. In other words, the conductive material 35 of the in-pixel separation area 32 is supplied with the second reference electric potential applied to the wiring 43b₁ through the contact electrode 42b₁ and has an electric potential fixed to this second reference electric potential.

As illustrated in FIG. 13, a conductive material 35 of the second inter-pixel separation area 31b is electrically connected to a wiring 43b2 formed in the wiring layer 43 of the first layer through a contact electrode 42b2 embedded over the interlayer insulating film 41 and the element separation area 25. Similar to the second embodiment described above, a third reference electric potential of a negative electric potential lower than the first reference electric potential applied to the well region 22 of the p type is applied to this wiring 43b2 as a power source electric potential. In other words, the conductive material 35 of the second inter-pixel separation area 31b is supplied with the third reference electric potential applied to the wiring 43b2 through the contact electrode 42b2 and has an electric potential fixed to this second reference electric potential.

### Main Effects of Fourth Embodiment

The solid-state imaging device 1D according to this fourth embodiment includes the first inter-pixel separation area 31a corresponding to one specific example of “first separation area” of the present technology, the first photoelectric conversion area 21A partitioned by this first inter-pixel separation area 31a, the second inter-pixel separation area 31b corresponding to one specific example of “second separation area” of the present technology, and the second photoelectric conversion area 21B partitioned by this second inter-pixel separation area 31b. Similar to the inter-pixel separation area 31 of the second embodiment described above, the first inter-pixel separation area 31a has a configuration in which the dug part 33a₁ extending in the thickness direction (the Z direction) of the semiconductor layer 20 is filled with the insulating film 53 as an insulating material having a refractive index lower than the semiconductor layer 20. For this reason, similar to the second embodiment described above, also in a case in which the first photoelectric conversion area 21A including the first photoelectric conversion unit 24a that performs photoelectric conversion of near-infrared light and the second photoelectric conversion area 21B including the second photoelectric conversion unit 24b that performs photoelectric conversion of visible light are mixed, improvement of a quantum efficiency QE and high mixed color suppression (a high MTF characteristic) can be achieved.

On the other hand, similar to the in-pixel separation area 32 of the first embodiment described above, the second inter-pixel separation area 31b has a configuration in which the conductive material 35 fills the dug part 33a2 extending in the thickness direction of the semiconductor layer 20. For this reason, similar to the first embodiment described above, by applying a negative electric potential to the conductive material 35 of the second inter-pixel separation area 31b, the saturated electric charge amount Qs in the second photoelectric conversion area 21B in which the second photoelectric conversion unit 24b performing photoelectric conversion of visible light is disposed can be raised, whereby improvement of the pixel characteristics can be achieved.

In addition, similar to the second in-pixel separation area 32 of the second embodiment described above, the second inter-pixel separation area 31b has a configuration in which the dug part 33a2 extending in the thickness direction of the semiconductor layer 20 is filled with the conductive material 35. For this reason, by applying a negative electric potential to the conductive material 35 of the second inter-pixel separation area 31b, the potential of the semiconductor layer 20 on the side wall of the second inter-pixel separation area 31b changes, and the saturated electric charge amount Qs in the second photoelectric conversion area 21B in which the second photoelectric conversion unit 24b performing photoelectric conversion of visible light is disposed can be raised, whereby improvement of the pixel characteristics can be achieved. Thus, also in the solid-state imaging device 1D according to this fourth embodiment, improvement of the pixel characteristics can be achieved.

In addition, since light reflection in the first inter-pixel separation area 31a can be increased, also in the solid-state imaging device 1D according to this fourth embodiment, miniaturization of the width of the first inter-pixel separation area 31a can be achieved, and miniaturization of each of the first photoelectric conversion area 21A and the second photoelectric conversion area 21B can be achieved.

In addition, similar to the first embodiment described above, the solid-state imaging device 1D of this fourth embodiment includes the light blocking film 54 on the light incident face side (the second face S2 side) of the semiconductor layer 20 that is configured to have a selectively thickened width to cover the floating diffusion regions FD1 and FD2 disposed between the first inter-pixel separation area 31a and the in-pixel separation area 32. Thus, also in the solid-state imaging device 1D according to this fourth embodiment, similar to the solid-state imaging device 1A according to the first embodiment described above, PLS characteristics (parasitic light sensitivity characteristics) can be enhanced.

In addition, in the fourth embodiment described above, a case in which the in-pixel separation area 32 functioning as an assistance electrode is disposed in each of both the first and second photoelectric conversion areas 21A and 21B has been described. However, the in-pixel separation area 32 functioning as an assistance electrode may be disposed in any one of the first and second photoelectric conversion areas 21A and 21B. Here, it is preferable that the in-pixel separation area 32 functioning as an assistance electrode be disposed in the first photoelectric conversion area 21A including the photoelectric conversion unit 24a that performs photoelectric conversion of near-infrared light.

### Fifth Embodiment

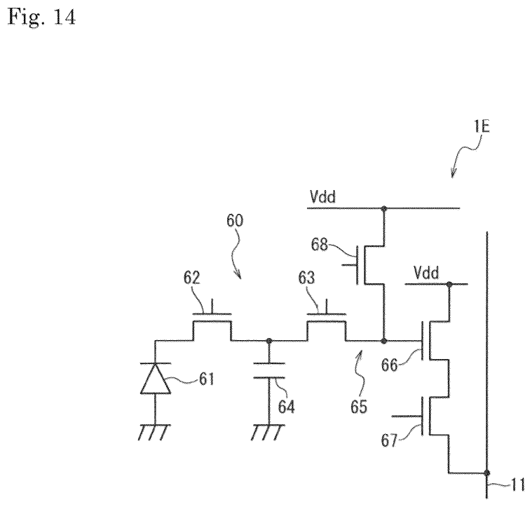

FIG. 14 is an equivalent circuit diagram illustrating one configuration example of a pixel of a solid-state imaging device according to a fifth embodiment of the present technology.

The solid-state imaging device 1E according to the fifth embodiment of the present technology includes a pixel 60 illustrated in FIG. 14. Although one pixel 60 is illustrated in FIG. 14, similar to the pixel 3 of the first embodiment described above illustrated in FIG. 1, the pixel 60 is repeatedly disposed in each of the X direction and the Y direction, thereby configuring a pixel array portion.

As illustrated in FIG. 14, the pixel 60 includes a photoelectric conversion unit (a photoelectric conversion element PD) 61, a first transfer transistor (TRG) 62, a second transfer transistor (TRG) 63, a memory unit 64, a floating diffusion (FD) region 65, an amplification transistor (AMP) 66, a selection transistor (SEL) 67, and a reset transistor (RST) 68. The memory unit 64 is one specific example of “electric charge maintaining section” of the present technology.

The photoelectric conversion unit 61 receives light emitted to the pixel 60 and generates and accumulates electric charge corresponding to an amount of the light.

The first transfer transistor 62 is driven in accordance with a transmission signal supplied from a vertical drive unit, and when the first transfer transistor 62 becomes on, electric charge accumulated in the photoelectric conversion unit 61 is transmitted to the memory unit 64.

The second transfer transistor 63 is driven in accordance with a transmission signal supplied from a vertical drive unit, and when the second transfer transistor 63 becomes on, signal electric charge accumulated in the memory unit 64 is transmitted to the floating diffusion region 65.

The memory unit 64 accumulates signal electric charge transmitted from the photoelectric conversion unit 61 through the first transfer transistor 62.

The floating diffusion region 65 is a floating diffusion region having a predetermined capacity formed at a connection point between the second transfer transistor 63 and a gate electrode of the amplification transistor 66 and accumulates signal electric charge transmitted from the memory unit 64 through the second transfer transistor 63.

The amplification transistor 66 is connected to a power source line Vdd and outputs a pixel signal of a level corresponding to signal electric charge accumulated in the floating diffusion region 65.

The selection transistor 67 is driven in accordance with a selection signal supplied from the vertical drive unit, and when the selection transistor 67 becomes on, a state in which a pixel signal output from the amplification transistor 66 can be read into a vertical signal line 11 from the amplification transistor 66 through the selection transistor 67 is formed.

The reset transistor 68 is driven in accordance with a reset signal supplied from the vertical drive unit, and when the reset transistor 58 becomes on, electric charge accumulated in the FD 55 is discharged to the power source Vdd through the reset transistor 58, and the floating diffusion region 65 is reset.

In the solid-state imaging device 1E having the pixel 60 configured in this way, a global shutter system is employed, and signal electric charge can be transmitted from the photoelectric conversion unit 61 to the memory unit 64 simultaneously for all the pixels 60, whereby exposure timings of all the pixels 60 can be configured to be the same. In accordance with this, occurrence of distortion in an image can be avoided.

In this fifth embodiment, although not illustrated in detail in the drawing, when described with reference to FIGS. 4 and 5, the photoelectric conversion unit (a photoelectric conversion element PD) 61, the first transfer transistor (TRG) 62, the second transfer transistor (TRG) 63, the memory unit 64, the floating diffusion (FD) region 65, the amplification transistor (AMP) 66, the selection transistor (SEL) 67, and the reset transistor (RST) 68 are mounted in the photoelectric conversion area 21 partitioned by the inter-pixel separation area 31. This photoelectric conversion area 21 is selectively separated into two areas of which widths in the Y direction in the plan view are relatively different from each other by the in-pixel separation area 32 disposed to be separate from the inter-pixel separation area 31. Out of two areas separated by the in-pixel separation area 32, the photoelectric conversion unit 61 is disposed in the area of a larger width in the Y direction, and the memory unit 54 is disposed in the area of a smaller width in the Y direction.

Also in the solid-state imaging device 1E according to this fifth embodiment, effects similar to those of the solid-state imaging device 1A according to the first embodiment described above can be acquired.

### Sixth Embodiment

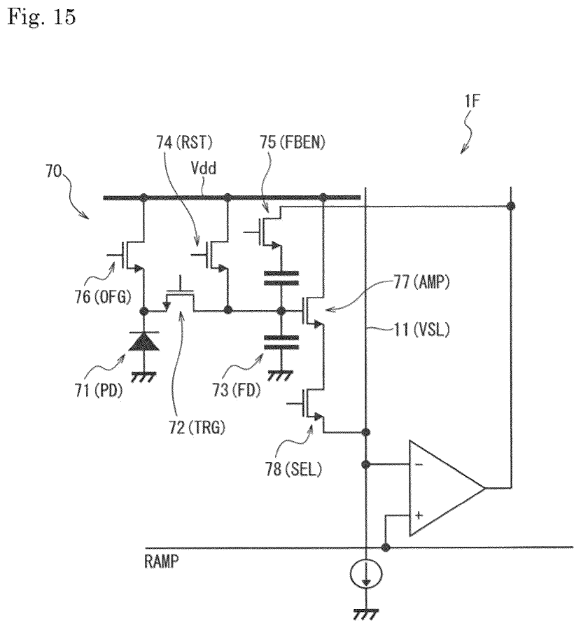

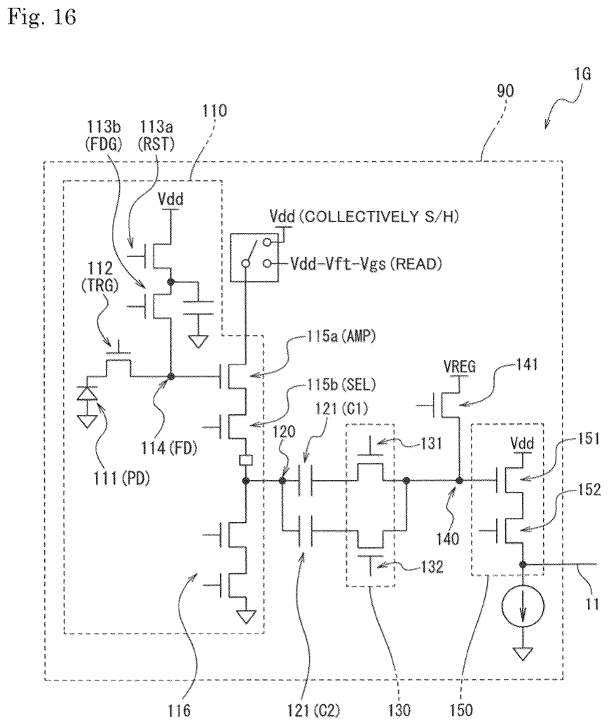

FIG. 15 is an equivalent circuit diagram illustrating one configuration example of a pixel of a solid-state imaging device according to a sixth embodiment of the present technology.

The solid-state imaging device 1F according to the sixth embodiment of the present technology includes a pixel 70 illustrated in FIG. 15. Although one pixel 70 is illustrated in FIG. 15, similar to the pixel 3 of the first embodiment described above illustrated in FIG. 1, the pixel 70 is repeatedly disposed in each of the X direction and the Y direction, thereby configuring a pixel array portion. The solid-state imaging device 1F having these pixels 70 employs a global shutter system of a charge domain type.

As illustrated in FIG. 15, the pixel 70, for example, includes a photoelectric conversion unit (a photoelectric conversion element PD) 71, a transfer transistor (TRG) 72, a floating diffusion (FD) region 73 as an electric charge maintaining section and an electric charge voltage converting unit, a reset transistor (RST) 74, a feedback enable transistor (FBEN) 75, a discharge transistor (OFG) 76, an amplification transistor (AMP) 77, a selection transistor (SEL) 78, and the like. The floating diffusion region 73 corresponds to one specific example of “electric charge maintaining section” of the present technology.

In this embodiment, all the transfer transistor 72, the FD 73, the reset transistor 74, the feedback enable transistor 75, the discharge transistor 76, the amplification transistor P77, and the selection transistor 78 as pixel transistors are MOS transistors of the n channel conduction type. Driving signals are supplied to gate electrodes of such pixel transistors (72, 74, 75, 76, 77, and 78). Each driving signal is a pulse signal in which a high-level state is an active state, that is, an on state, and a low-level state is an inactive state, that is, an off state. Hereinafter, setting a driving signal to the active state is also referred to turning a driving signal on and setting a driving signal to the inactive state is also referred to as turning the driving signal off.

The photoelectric conversion unit 71, for example, is a photoelectric conversion element formed from a photodiode of a pn junction, receives light from a subject, generates electric charge corresponding to a reception light amount through photoelectric conversion, and accumulates the electric charge.

The transfer transistor 72 is connected between the photoelectric conversion unit 71 and the floating diffusion region 73 and transmits signal electric charge accumulated in the photoelectric conversion unit 71 to the floating diffusion region 73 in accordance with a driving signal applied to the gate electrode of the transfer transistor 72.

The floating diffusion region 73 is an area for temporarily maintaining signal electric charge accumulated in the floating diffusion region 73 for realizing a global shutter function. In addition, the floating diffusion region 73 is also a floating diffusion region that converts signal electric charge transmitted from the photoelectric conversion unit 71 through the transfer transistor 72 into an electric signal (for example, a voltage signal) and outputs the electric signal. The reset transistor 74 is connected to the floating diffusion region 73, and the vertical signal line 11 is connected to the floating diffusion region through the amplification transistor 77 and the selection transistor 78.

The reset transistor 74 has a drain region connected to the feedback enable transistor 75 and a source region connected to the floating diffusion region FD 73. The reset transistor 74 initializes, that is, resets the floating diffusion region 73 in accordance with a driving signal applied to the gate electrode.

The feedback enable transistor 75 performs control of a reset voltage applied to the reset transistor 74.

The discharge transistor 76 has a drain region connected to the power source Vdd and a source region connected to the photoelectric conversion unit 71. A cathode of the photoelectric conversion unit 71 is commonly connected to the source region of the discharge transistor 76 and the source region of the transfer transistor 72. The transfer transistor 76 initializes, that is, resets the photoelectric conversion unit 71 in accordance with a driving signal applied to the gate electrode thereof. “Resets the photoelectric conversion unit 71” has a meaning of depleting the photoelectric conversion unit 71.

The amplification transistor 77 has a gate electrode connected to the floating diffusion region 73 and a drain region connected to the power source Vdd and serves as an input unit of a source follower circuit reading signal electric charge acquired through photoelectric conversion by the photoelectric conversion unit 71. In other words, by connecting the source region of the amplification transistor 77 to the VSL 117 through the selection transistor 78, the amplification transistor 77 configures a source follower circuit together with a constant current source connected to one end of the vertical signal line 11.

The selection transistor 78 is connected between the source region of the amplification transistor 77 and the vertical signal line 11, and a selection signal is supplied to the gate electrode of the selection transistor 78. The selection transistor 78 becomes a conductive state when a selection signal thereof becomes on, and the pixel 70 in which the selection transistor 78 is disposed becomes a selected state. When the pixel 70 becomes the selected state, a pixel signal output from the amplification transistor 77 is read by the column signal processing circuit 5 (see FIG. 2) through the vertical signal line 11.

When described with reference to FIG. 2, in the pixel array portion 2A of this embodiment, a plurality of pixel drive lines 10, for example, are wired for each pixel row. Each driving signal is supplied to the selected pixels 70 from the vertical drive circuit unit 4 through the plurality of pixel drive lines 10.

In the solid-state imaging device 1F having the pixels 70 configured in this way, a global shutter system is employed, signal electric charge can be transmitted from the photoelectric conversion unit 71 to the floating diffusion (FD) region 73 simultaneously for all the pixels 70, and exposure timings of all the pixels 70 can be configured to be the same. In accordance with this, an occurrence of distortion in an image can be avoided.

In this sixth embodiment, although not illustrated in detail, when described with reference to FIGS. 4 and 5, the photoelectric conversion unit (a photoelectric conversion element PD) 71, the transfer transistor (TRG) 72, the floating diffusion (FD) region 73, the reset transistor (RST) 74, the feedback enable transistor (FBEN) 75, the discharge transistor (OFG) 76, the amplification transistor (AMP) 77, and the selection transistor (SEL) 78 are mounted in the photoelectric conversion area 21 partitioned by the inter-pixel separation area 31. This photoelectric conversion area 21 is selectively separated into two areas of which widths in the Y direction in the plan view are relatively different from each other by the in-pixel separation area 32 disposed to be separate from the inter-pixel separation area 31. Out of two areas separated by the in-pixel separation area 32, the photoelectric conversion unit 71 is disposed in the area of a larger width in the Y direction, and the floating diffusion (FD) region 73 is disposed in the area of a smaller width in the Y direction.

Also in the solid-state imaging device 1F according to this sixth embodiment, effects similar to those of the solid-state imaging device 1A according to the first embodiment described above can be acquired.

### Seventh Embodiment

FIG. 16 is an equivalent circuit diagram illustrating one configuration example of a pixel of a solid-state imaging device according to a seventh embodiment of the present technology.

The solid-state imaging device 1G according to the seventh embodiment of the present technology includes a pixel 90 illustrated in FIG. 16. Although one pixel 90 is illustrated in FIG. 16, similar to the pixel 3 of the first embodiment described above illustrated in FIG. 1, the pixel 90 is repeatedly disposed in each of the X direction and the Y direction, thereby configuring a pixel array portion. The solid-state imaging device 1G having these pixels 90 employs a global shutter system of a voltage domain.

As illustrated in FIG. 16, the pixel 90 includes a former-stage circuit 110, capacitance elements 121 and 122, a selection circuit 130, a later-stage reset transistor 141, and a later-stage circuit 150.

The former-stage circuit 110 includes a photoelectric conversion unit (PD) 111, a transfer transistor (TRG) 112, a reset transistor (RST) 113a, a switching transistor (FDG) 113b, a floating diffusion region (FD) 114, a former-stage amplification transistor (AMP) 115a, a former-stage selection transistor 115b, and a current source transistor 116. The floating diffusion region (FD) 114 corresponds to one specific example of “electric charge maintaining section” of the present technology.

The photoelectric conversion unit 111 generates electric charge through photoelectric conversion. The transfer transistor 112 transmits electric charge from the photoelectric conversion unit 111 to the floating diffusion region 114 in accordance with a transmission signal trg from a vertical drive circuit 4 (see FIG. 2).

The reset transistor 113 performs initialization by extracting signal electric charge from the floating diffusion region 114 in accordance with an FD reset signal rst from the vertical drive circuit 4.

The floating diffusion region 114 accumulates electric charge and generates a voltage corresponding to an electric charge amount. The former-stage amplification transistor 115a amplifies a level of the voltage of the floating diffusion region 114 and outputs the amplified voltage to the former-stage node 120.

Source regions of the reset transistor 113 and the former-stage amplification transistor 115 are connected to a power source voltage Vdd. The current source transistor 116 is connected to the drain region of the former-stage amplification transistor 115a. This current source transistor 116 supplies a current id1 in accordance with control of the vertical drive circuit 4.

One end of each of the capacitance elements 121 and 122 is commonly connected to the former-stage node 120, and the other end of each thereof is connected to the selection circuit 130.

The selection circuit 130 includes a selection transistor 131 and a selection transistor 132. The selection transistor 131 opens or closes a path between the capacitance element 121 and the later-stage node 140 in accordance with a selection signal Ør from the vertical drive circuit 4. The selection transistor 132 opens or closes a path between the capacitance element 122 and the later-stage node 140 in accordance with a selection signal Øs from the vertical drive circuit 4.

The later-stage reset transistor 141 initializes the level of the later-stage node 140 to a predetermined electric potential Vreg in accordance with a later-stage reset signal rstb from the vertical drive circuit 4. An electric potential different from the power source electric potential Vdd (for example, an electric potential lower than Vdd) is set to the electric potential Vreg.

The later-stage circuit 150 includes a later-stage amplification transistor 151 and a later-stage selection transistor 152. The later-stage amplification transistor 151 amplifies the level of the later-stage node 140. The later-stage selection transistor 152 outputs a signal of a level amplified by the later-stage amplification transistor 151 to the vertical signal line 11 (see FIG. 2) as a pixel signal in accordance with a later-stage selection signal se1b from the vertical drive circuit 4.

The vertical drive circuit 4 of this embodiment supplies the FD reset signal rst of the high level and a transmission signal trg to all the pixels at an exposure start time. In accordance with this, the photoelectric conversion unit 111 is initialized. Hereinafter, this control will be referred to as “PD reset”.

Immediately before an exposure end, the vertical drive circuit 4 supplies the FD reset signal rst of the high level over a pulse period while the later-stage reset signal rstb and the selection signal Ør are set to the high level in all the pixels. In accordance with this, the floating diffusion region 114 is initialized, and a level corresponding to the level of the floating diffusion region 114 at that time is maintained in the capacitance element 121. Hereinafter, this control will be referred to as “FD reset”.

Hereinafter, the level of the floating diffusion region 114 at the time of FD resetting and levels corresponding to the level (the maintaining level of the capacitance element 121 and the level of the vertical signal line 11) will be collectively referred to as “P phase” or “reset level”.

The vertical drive circuit 4, at the time of exposure ending, supplies the transmission signal trg of the high level over the pulse period while setting the later-stage reset signal rstb and the selection signal Øs to the high level in all the pixels. In accordance with this, signal electric charge corresponding to an exposure amount is transmitted to the floating diffusion region 114, and a level corresponding to the level of the floating diffusion region 114 at that time is maintained in the capacitance element 122.

Hereinafter, the level of the floating diffusion region 114 at the time of transmission of signal electric charge and levels corresponding to the level (the maintaining level of the capacitance element 122 and the level of the vertical signal line 11) will be collectively referred to as “D phase” or “signal level”.

The exposure control of starting and ending the exposure at the same time for all the pixels in this way is called a global shutter system. The former-stage circuit 110 of all the pixels generates a reset level and a signal level in order through the exposure control. The reset level is held by the capacitance element 121, and the signal level is held by the capacitance element 122.

After the end of exposure, the vertical drive circuit 4 sequentially selects a row and sequentially outputs a reset level and a signal level of the row. When the reset level is output, the vertical drive circuit 4 supplies the selection signal Ør of the high level over a predetermined period while setting the FD reset signal rst of the selected row and the later-stage selection signal se1b to the high level. In this manner, the capacitance element 121 is connected to the later-stage node 140, and the reset level is read.

The vertical drive circuit 4 supplies the later-stage reset signal rstb of the high level over the pulse period while maintaining the FD reset signal rst and the later-stage selection signal se1b of the selected row to be at the high level. In this manner, the level of the later-stage node 140 is initialized. At this time, both the selection transistor 331 and the selection transistor 132 are in an open state, and the capacitance elements 121 and 122 are disconnected from the later-stage node 140.

After the initialization of the later-stage node 140, the vertical drive circuit 4 supplies the selection signal Øs of the high level over a predetermined period while maintaining the FD reset signal rst of the selected row and the later-stage selection signal se1b to be in the high level. In this manner, the capacitance element 122 is connected to the later-stage node 140, and the signal level is read.

The selection circuit 130 of the selected row sequentially performs control of connecting the capacitance element 121 to the later-stage node 140, control of disconnecting the capacitance elements 121 and 122 from the later-stage node 140, and control of connecting the capacitance element 122 to the later-stage node 140 through the reading control described above. In addition, when the capacitance elements 121 and 122 are disconnected from the later-stage node 140, the later-stage reset transistor 141 of the selected row initializes the level of the later-stage node 140. Also, the later-stage circuit 150 of the selected row sequentially reads the reset level and the signal level from the capacitance elements 121 and 122 through the later-stage node 140 and outputs the reset level and the signal level to the vertical signal line 11.

In this seventh embodiment, although not illustrated in detail in the drawing, when described with reference to FIGS. 4 and 5, the photoelectric conversion unit (a photoelectric conversion element PD) 111, the transfer transistor (TRG) 112, and the floating diffusion (FD) region 114 are mounted in the photoelectric conversion area 21 partitioned by the inter-pixel separation area 31. This photoelectric conversion area 21 is selectively separated into two areas of which widths in the Y direction in the plan view are relatively different from each other by the in-pixel separation area 32 disposed to be separate from the inter-pixel separation area 31. Out of two areas separated by the in-pixel separation area 32, the photoelectric conversion unit 111 is disposed in the area of a larger width in the Y direction, and the floating diffusion (FD) region 114 is disposed in the area of a smaller width in the Y direction.

Also in the solid-state imaging device 1G according to this seventh embodiment, effects similar to those of the solid-state imaging device 1A according to the first embodiment described above can be acquired.

### Eighth Embodiment

In this eighth embodiment, mainly a light blocking body 80H will be described.

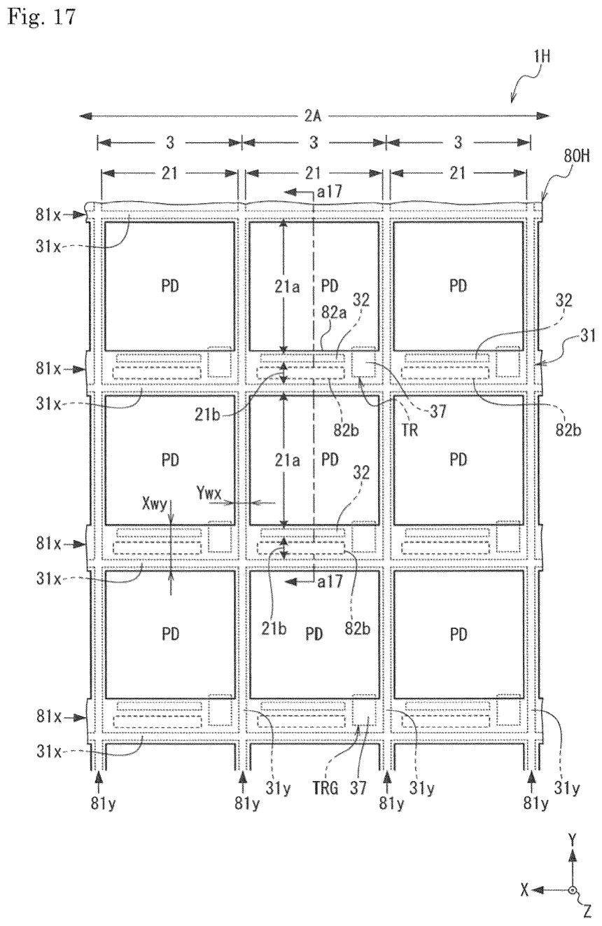

FIG. 17 is a plan view schematically illustrating a plane pattern of a light blocking body of a pixel array portion of a solid-state imaging device according to this eighth embodiment.

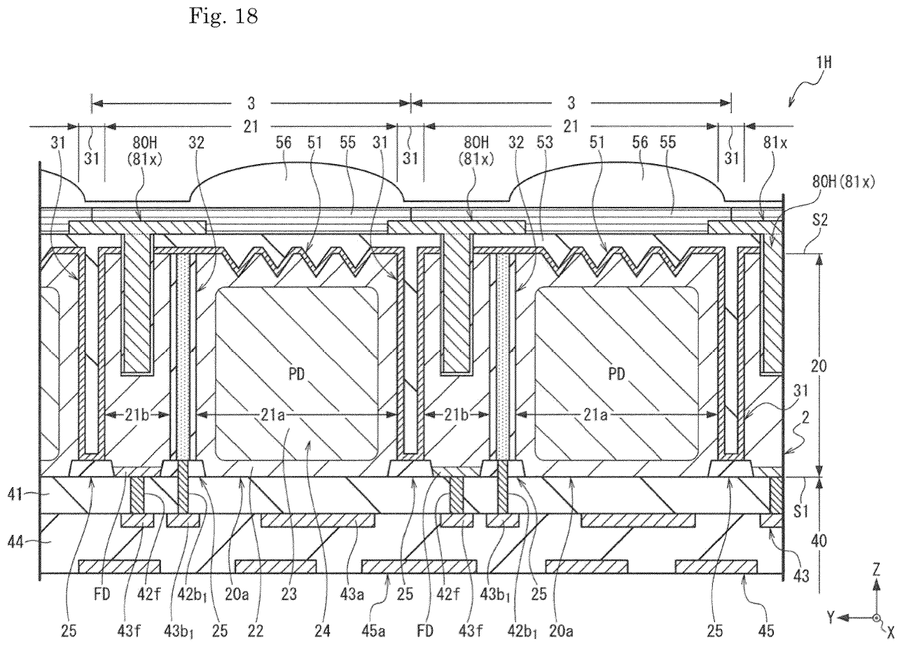

FIG. 18 is a longitudinal cross-sectional view schematically illustrating a longitudinal cross-sectional structure taken along line a17-a17 illustrated FIG. 17.

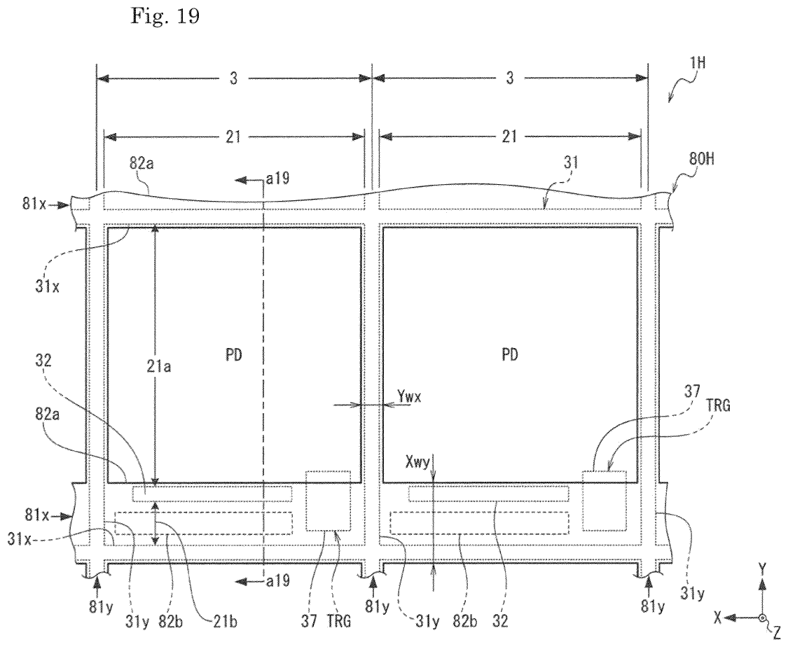

FIG. 19 is a plan view in which a part of FIG. 18 is enlarged.

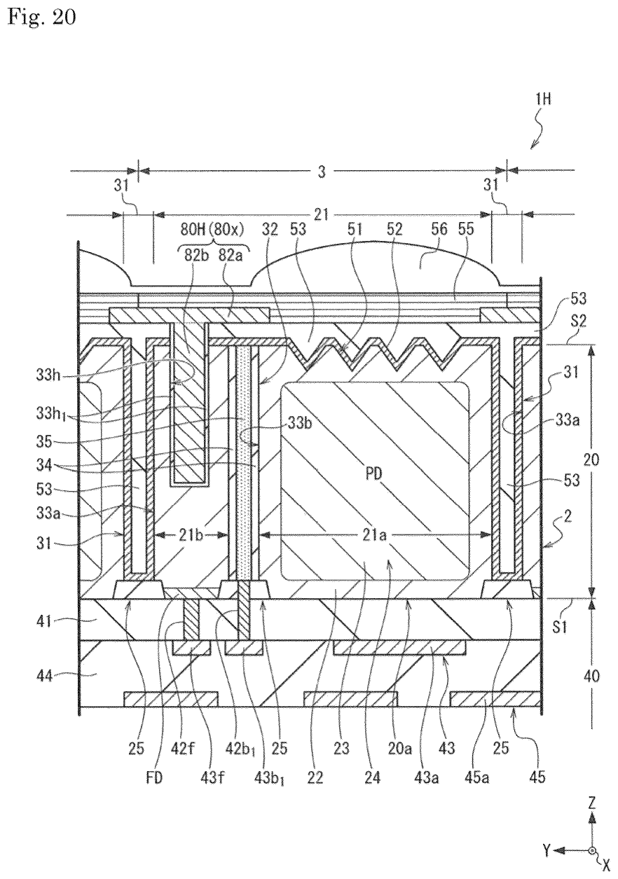

FIG. 20 is a longitudinal cross-sectional view schematically illustrating a longitudinal cross-sectional structure taken along line a19-a19 illustrated in FIG. 19.

FIGS. 17 and 19 are plan views seen from a second face S2 side (a light incident face side) of a semiconductor layer 20 illustrated in FIGS. 18 and 20. FIGS. 18 and 20 are vertically inverted with respect to FIGS. 5 and 6 of the first embodiment described above.

### <<Configuration of Solid-state Imaging Device>>

The solid-state imaging device 1H according to the eighth embodiment of the present technology basically has a configuration similar to the solid-state imaging device 1A according to the first embodiment described above, and there are differences in the following configurations.

In other words, as illustrated in FIGS. 17 to 20, the solid-state imaging device 1H according to the eighth embodiment of the present technology includes a light blocking body 80H in place of the light blocking film 54 of the above-described first embodiment illustrated in FIGS. 4 and 5. The other configurations are basically similar to the first embodiment, the same reference signs will be assigned to the same configuration, and duplicate description will be omitted.

As illustrated in FIGS. 17 and 18, the light blocking body 80H of this eighth embodiment is disposed on the second face S2 side of the semiconductor layer 20 and overlaps each of a second area 21b of the photoelectric conversion area 21 and the floating diffusion region FD of the inside of the second area 21b in the plan view. The light blocking body 80H is disposed over the inside and the outside of the second area 21b in the thickness direction (the Z direction) of the semiconductor layer 20.

As illustrated in FIG. 17, the light blocking body 80H includes first linear parts 81x that extend in the X direction and are repeatedly disposed with a predetermined disposition pitch in the Y direction and second linear parts 81y that extend in the Y direction with intersecting the first linear parts 81x and are repeatedly disposed with a predetermined disposition pitch in the X direction. The first linear part 81x overlaps the first part 31x of the inter-pixel separation area 31 in the plan view, and the second linear part 81y overlaps the second part 31y of the inter-pixel separation area 31 in the plan view. In other words, similar to the light blocking film 54 of the first embodiment described above, also the light blocking body 80H of this eighth embodiment has a lattice-shaped plane pattern in which the plane pattern in the plan view opens the light reception face side (the second face S2 side) of each of a plurality of photoelectric conversion areas 21 such that light incident in a predetermined photoelectric conversion area 21 does not leak into a nearby photoelectric conversion area 21. A width Xwy of the first linear part 81x in the Y direction is configured to be larger than a width Ywx of the second linear part 81y in the X direction.

In addition, as illustrated in FIGS. 19 and 20, the light blocking body 80H includes a first light blocking part 82a that is disposed on the outer side of the second face S2 of the semiconductor layer 20 and overlaps the second area 21b of the photoelectric conversion area 21 in the plan view and a second light blocking part 82b that protrudes from this first light blocking part 82a to the inside of the second area 21b of the photoelectric conversion area 21. These first light blocking part 82a and the second light blocking part 82b are configured in the first linear part 81x. In other words, the first linear part 81x includes the first light blocking part 82a and the second light blocking part 82b.

Here, as described in the first embodiment, the in-pixel separation area 32, for example, extends in the X direction in the plan view and is disposed to be separate from the inter-pixel separation area 31 (the first part 31x and the second part 31y). The in-pixel separation area 32 is disposed to be inclined to the inter-pixel separation area 31 side from the center part of the photoelectric conversion area 21 in the plan view in the Y direction and selectively separates (divides) the photoelectric conversion area 21 into two areas (a first area 21a and a second area 21b) of which widths in the Y direction in the plan view are relatively different from each other. Out of two areas (the first area 21a and the second area 21b) separated by the in-pixel separation area 32, the photoelectric conversion unit 24 is disposed in the first area 21a of a larger width in the Y direction, and the floating diffusion region FD is disposed in the second area 21b of a smaller width in the Y direction. In other words, the in-pixel separation area 32 separates the photoelectric conversion area 21 into the first area 21a and the second area 21b in one direction (the Y direction).

As illustrated in FIG. 20, the second light blocking part 82b transverses the second face S2 of the semiconductor layer 20 in the thickness direction (the Z direction) of the semiconductor layer 20. The second light blocking part 82b is separate from each of the inter-pixel separation area 31 and the in-pixel separation area 32 in the disposition direction (the Y direction) of the first area 21a and the second area 21b.

In addition, the second light blocking part 82b is disposed inside a dug part 33h disposed over the insulating film 53 and the semiconductor layer 20 through the insulating film 33h₁. The insulating film 33h₁ is disposed mainly for the purpose of electrically insulating and separating the second light blocking part 82b and the semiconductor layer 20 from each other. In FIG. 20, although the insulating film 33h₁ is disposed over the semiconductor layer 20 from the insulating film 53, the insulating film 33h₁ may be disposed only on the semiconductor layer 20 side.

As illustrated in FIG. 20, the first light blocking part 82a is disposed on a side opposite to the semiconductor layer 20 side of the insulating film 53. On the other hand, the second light blocking part 82b reaches the inside of the second area 21b (the inside of the semiconductor layer 20) by passing through the insulating film 53.

As illustrated in FIGS. 19 and 20, the light blocking body 80H extends over two photoelectric conversion areas 21 that are adjacent to each other in the X direction inside a two-dimensional plane but is not limited thereto. The first light blocking part 82a continuously extends over two photoelectric conversion areas 21 that are adjacent to each other in the X direction as well. On the other hand, the second light blocking part 82b is disposed to be separate for each photoelectric conversion area 21 aligned in the X direction. In other words, differently from the first light blocking part 82a, the second light blocking part 82b does not continuously extend over two photoelectric conversion areas 21 that are adjacent to each other in the Y direction.

The second light blocking part 82b extends in the X direction together with the in-pixel separation area 32 in the plan view. It is preferable that a length of the second light blocking part 82b in the X direction be equal to a length of the in-pixel separation area 32 in the X direction or be longer than a length of the in-pixel separation area 32 in the X direction. In this eighth embodiment, the length of the second light blocking part 82b in the X direction is longer than the length of the in-pixel separation area 32 in the X direction.

The first light blocking part 82a, mainly, in the second area 21b of the photoelectric conversion area 21, blocks light on an outer side of the second face S2 of the semiconductor layer 20 and suppresses arrival of light at the floating diffusion region FD disposed on the first face S1 side of the semiconductor layer 20. On the other hand, the second light blocking part 82b, in the second area 21b of the photoelectric conversion area 21, blocks light in an inner part of the second face S2 side of the semiconductor layer 20 and suppresses arrival of light at the floating diffusion region FD disposed on the first face S1 side of the semiconductor layer 20. In other words, the light blocking body 80H blocks light penetrating into (incident in) the second area 21b of the photoelectric conversion area 21 on the second face S2 side of the semiconductor layer 20 and suppresses arrival of light at the floating diffusion region FD disposed on the first face S1 side of the semiconductor layer 20 inside the second area 21b of the photoelectric conversion area 21.

As the light blocking body 80H, it is preferable to use a metal film of, for example, titanium (Ti), tungsten (W), aluminum (Al), or the like or an alloy film as a material having a superior light blocking property and having an optical reflectance higher than a silicon oxide film or a silicon film. In this eighth embodiment, as the light blocking body 80H, for example, a tungsten (W) film is used.

Here, in this eighth embodiment, the inter-pixel separation area 31, the in-pixel separation area 32, and the floating diffusion region FD respectively correspond to “first separation area”, “second separation area”, and “electric charge maintaining section” of the present technology.

### <<Method of Manufacturing Solid-state Imaging Device>>

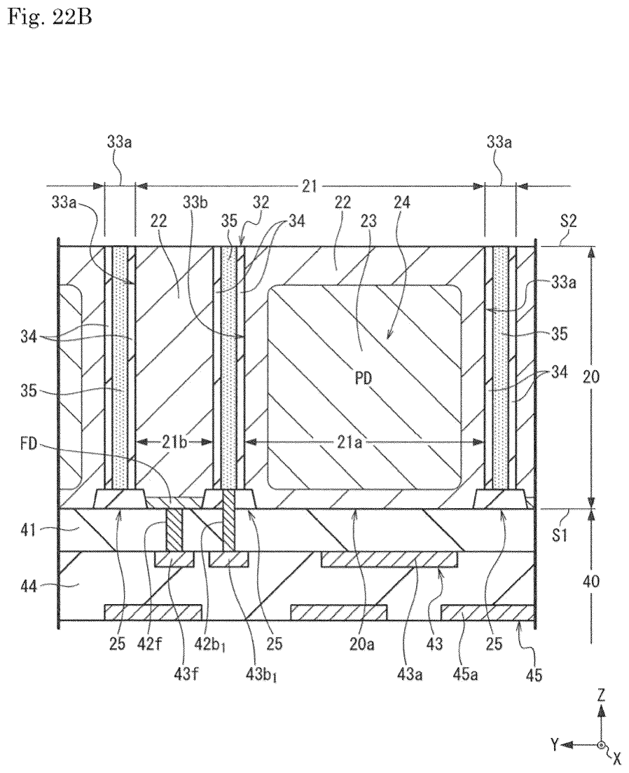

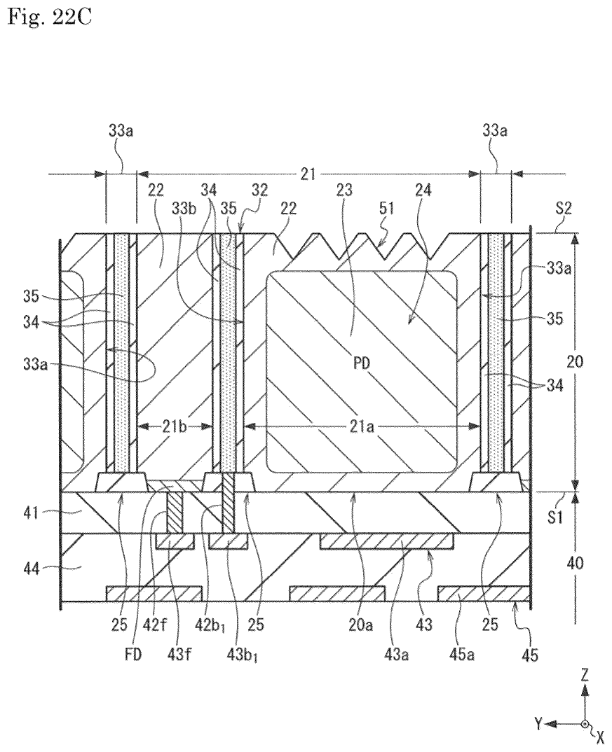

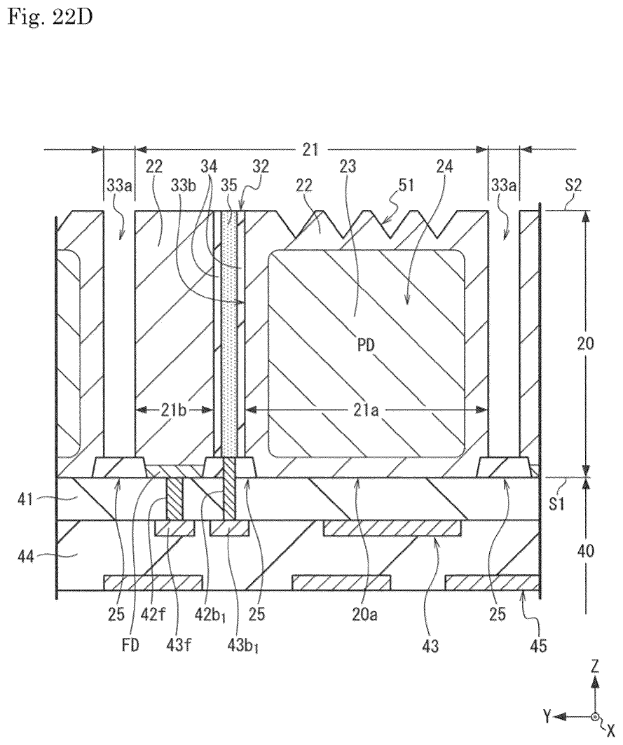

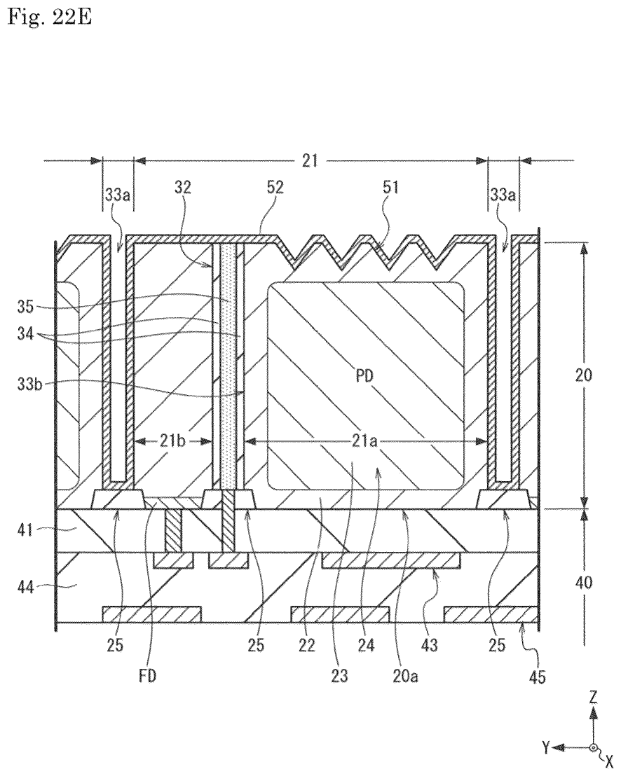

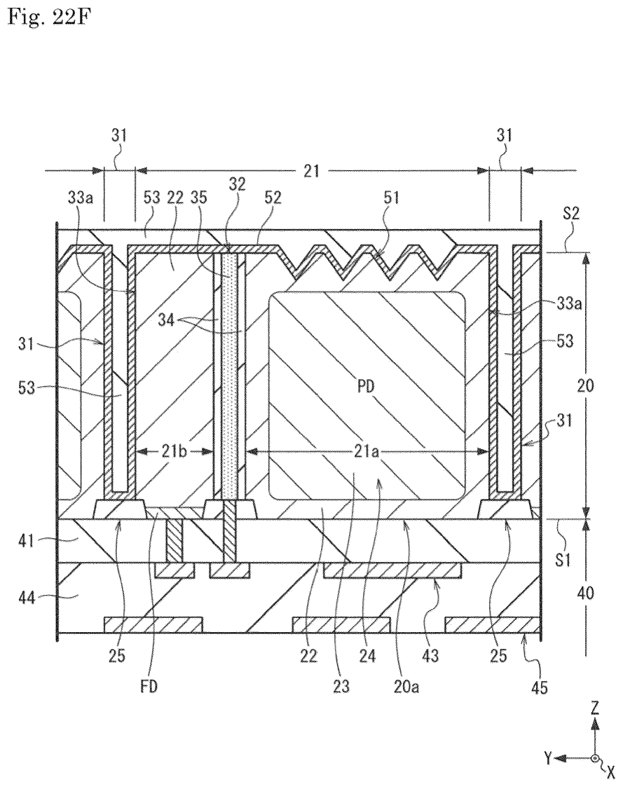

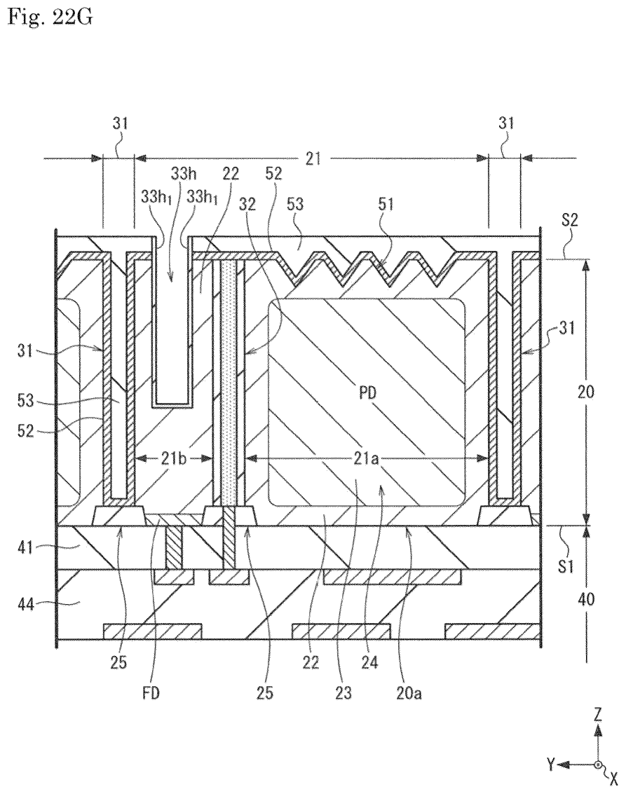

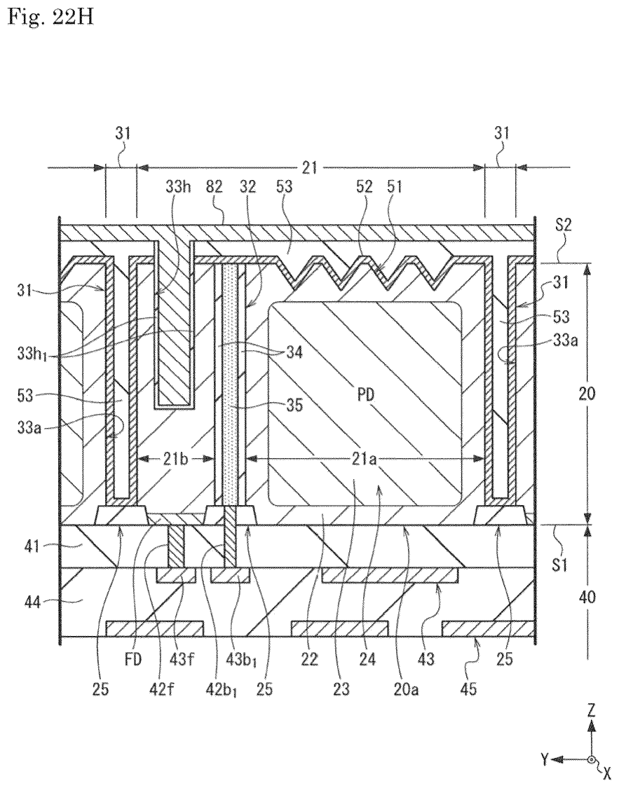

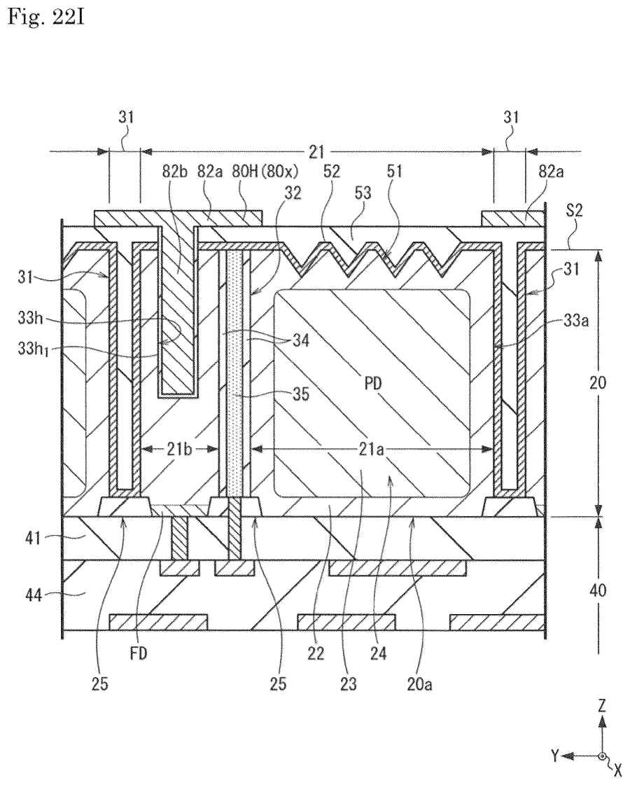

Next, a method of manufacturing the solid-state imaging device 1H according to the eighth embodiment of the present technology will be described with reference to FIGS. 22A to 22I.

In this eighth embodiment, manufacturing of the light blocking body 80H included in the method of manufacturing the solid-state imaging device 1H will be particularly described.

First, as illustrated in FIG. 22A, together with forming a photoelectric conversion area 21, an element separation area 25, a dug part 33a, an in-pixel separation area 32, and the like on the semiconductor layer 20, a multilayer wiring layer 40 is formed on the first face S1 side of the semiconductor layer 20.

The in-pixel separation area 32 includes a separation insulating film 34 disposed along a side wall of the inside of the dug part 33b extending in the depth direction (the Z direction) of the semiconductor layer 20 and a conductive material 35 filling this dug part 33b through the separation insulating film 34.

The dug part 33a serves as a base of the inter-pixel separation area 31 illustrated in FIG. 22F. Similar to the dug part 33b of the in-pixel separation area 32, the dug part 33a extends in the depth direction (the Z direction) of the semiconductor layer 20 and is filled with the conductive material 35 through the separation insulating film 34 on the inside. The dug part 33a partitions the photoelectric conversion area 21 for each photoelectric conversion area 21. The dug parts 33a and 33b, for example, are formed in the same process.

The photoelectric conversion area 21 includes an element formation area 20a, a well region 22 of the p type, a semiconductor area 23 of the n type, a photoelectric conversion unit 24 (PD), an element separation area (a field separation area) 25, pixel transistors (AMP, SEL, RST, and TR) formed in the element formation area 20a, and the like. In addition, the photoelectric conversion area 21 includes a floating diffusion region FD, an in-pixel separation area 32, and a first area 21a and a second area 21b separated by this in-pixel separation area 32.

The well region 22 of the p type is formed in the first area 21a and the second area 21b of the photoelectric conversion area 21. The element formation area 20a, the semiconductor area 23 of the n type, and the photoelectric conversion unit 24 are formed in the first area 21a of the photoelectric conversion area 21. Then, the floating diffusion region FD is formed on the first face S1 side of the semiconductor layer 20 in the second area 21b of the photoelectric conversion area 21. As the semiconductor layer 20, for example, a semiconductor substrate of the p type formed from monocrystalline silicon is used but the semiconductor layer 20 is not limited thereto.

Next, after a multilayer wiring layer 40 is formed on the first face S1 side of the semiconductor layer 20, the thickness of the semiconductor layer 20 is formed to be thin, for example, by cutting the second face S2 side of the semiconductor layer 20 using a CMP method, as illustrated in FIG. 22B, the in-pixel separation area 32 is exposed from the second face S2 of the semiconductor layer 20, and the separation insulating film 34 and the conductive material 35 of the inside of the dug part 33a are exposed.

Next, after the in-pixel separation area 32 and the separation insulating film 34 and the conductive material 35 of the inside of the dug part 33a are exposed from the second face S2 of the semiconductor layer 20, as illustrated in FIG. 22C, in the first area 21a of the photoelectric conversion area 21, a diffraction scattering section 51 is formed on the second face S2 of the semiconductor layer 20.

Next, after the diffraction scattering section 51 is formed, as illustrated in FIG. 22D, the separation insulating film 34 and the conductive material 35 of the inside of the dug part 33a are selectively removed. By using a known photolithographic technology and an anisotropic dry etching technology, the separation insulating film 34 and the conductive material 35 of the inside of the dug part 33a can be selectively removed.

Next, after the separation insulating film 34 and the conductive material 35 of the inside of the dug part 33a are selectively removed, as illustrated in FIGS. 22E, a fixed charge film 52 covering the inner wall (a side wall and a bottom wall) of the dug part 33a and the second face S2 of the semiconductor layer 20 is formed as a film. The fixed charge film 52, on the second face S2 side of the semiconductor layer 20, is formed over the first area 21a and the second area 21b of the photoelectric conversion area 21, and the diffraction scattering section 51 of the first area 21a is covered with the fixed charge film 52.

Next, after the fixed charge film 52 is formed, as illustrated in FIG. 22F, an insulating film 53 is formed on the entire face of the second face S2 side of the semiconductor layer 20 including the inside of the dug part 33a. For example, after a silicon oxide film is formed using a CVD method, by planarizing the surface side of this silicon oxide film using a CMP method through cutting, an insulating film 53 can be formed.

In this process, an inter-pixel separation area 31 in which the insulating film 53 is embedded inside of the dug part 33a through the fixed charge film 52 is formed, and a photoelectric conversion area 21 of which the periphery is partitioned by this inter-pixel separation area 31 and the inside is separated into the first area 21a and the second area 21b by the in-pixel separation area 32 is formed.

Next, after the insulating film 53 is formed, as illustrated in FIG. 22G, together with forming a dug part 33h that extends from the surface of the insulating film 53 to the inside of the second area 21b of the photoelectric conversion area 21, an insulating film 33h₁ covering the inner wall (the side wall and the bottom wall) of the dug part 33a is formed. The dug part 33h can be formed by using a known photolithographic technology and an anisotropic dry etching technology. As the insulating film 33h₁, for example, a silicon oxide film can be used, and this silicon oxide film can be formed using a deposition method or a thermal oxidation method.

Next, after the dug part 33h and the insulating film 33h₁ are formed, as illustrated in FIG. 22H, a light blocking film 82 is formed on the entire face on the insulating film 53 including the inside of the dug part 33h. The light blocking film 82, for example, can be formed by forming a metal film or an alloy film of titanium (Ti), tungsten (W), aluminum (Al), or the like having a superior light blocking property and having an optical reflectance higher than a silicon oxide film or a silicon film using a known film formation technology. The light blocking film 82 is formed over a plurality of photoelectric conversion areas 21 and is formed such that it covers the first area 21a and the second area 21b of each of the plurality of photoelectric conversion areas 21 in the plan view and embeds the dug part 33h₁ of the second area 21b of each thereof. The light blocking film 82 in an embedded part 33h is formed through the insulating film 33h.

Next, by patterning the light blocking film 82, as illustrated in FIG. 22I, a light blocking body 80H that covers the second area 21b of the photoelectric conversion area 21 and the floating diffusion region FD and extends over the inside and outside of the second area 21b in the thickness direction (the Z direction) of the semiconductor layer 20 is formed. The patterning of the light blocking film 82 can be performed using a known photolithographic technology and an anisotropic dry etching technology.

In this process, the light blocking body 80H includes a first light blocking part 82a that is disposed on an outer side of the second area 21b of the photoelectric conversion area 21 (an outer side of the first face S1 of the semiconductor layer 20) through the insulating film 53 in the thickness direction (the Z direction) of the semiconductor layer 20 and overlaps the second area 21b and the floating diffusion region FD in the plan view and a second light blocking part 82b that goes through the insulating film 53 and the fixed charge film 52 from this first light blocking part 82a and protrudes to the inside of the second area 21b. When described with reference to FIG. 17, the light blocking body 80H includes first linear parts 81x that extend in the X direction and are repeatedly disposed with a predetermined disposition pitch in the Y direction and second linear parts 81y that extend in the Y direction with intersecting the first linear parts 81x and are repeatedly disposed with a predetermined disposition pitch in the X direction. The light blocking body 80H is formed in a lattice-shaped plane pattern overlapping the lattice-shaped plane pattern of the inter-pixel separation area 31 in the plan view. The first light blocking part 82a and the second light blocking part 82b are formed in the first linear part 81x.

Next, after the light blocking body 80H is formed, by forming a color filter 55 and a microlens 56 on a side opposite to the semiconductor layer 20 side of the light blocking body 80H in this order, states illustrated in FIGS. 17 to 20 are formed.

In addition, in the solid-state imaging device 1H, by dividing a semiconductor wafer including the semiconductor layer 20 and the multilayer wiring layer 40 for each chip formation area, the state of the semiconductor chip 2 illustrated in FIG. 1 is formed.

### <Function of Light Blocking Body>

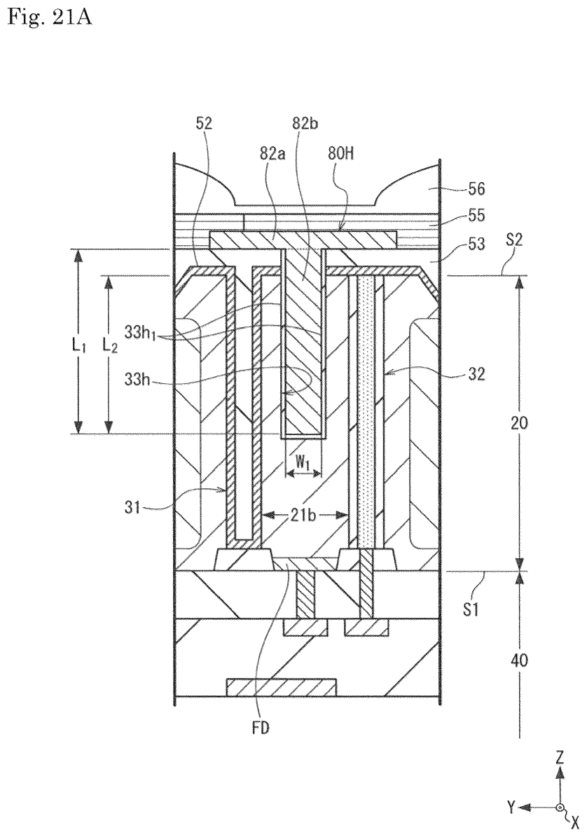

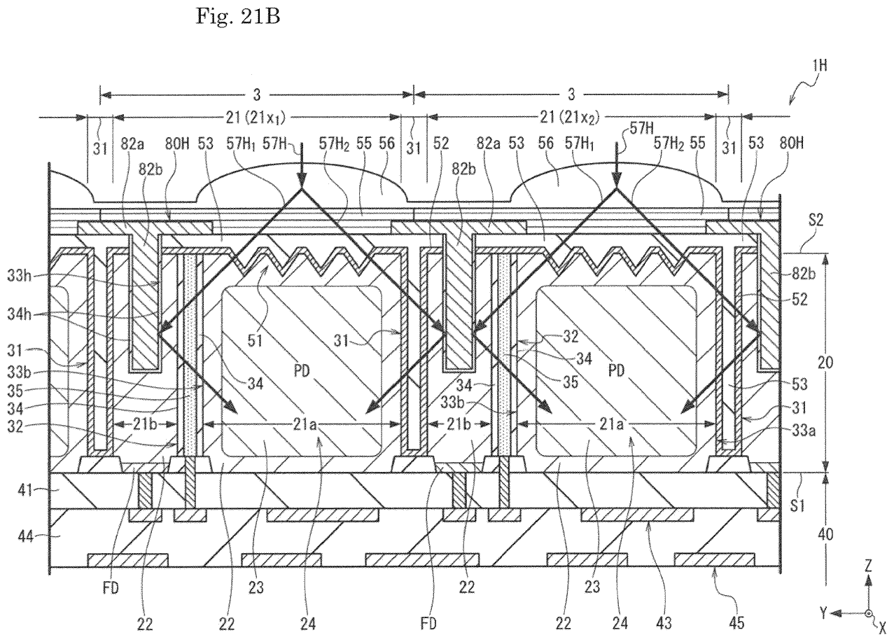

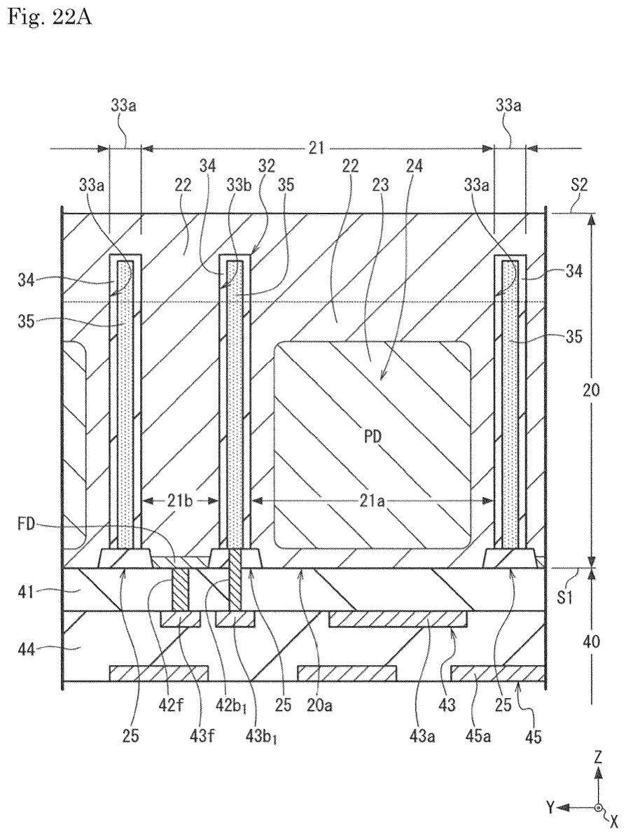

Next, the function of the light blocking body 80H will be described with reference to FIGS. 21B and 6.

As illustrated in FIG. 21B, in one photoelectric conversion area 21 (one pixel 3), emission light 57H emitted to the microlens 56 becomes oblique light 57H₁, is transmitted through the microlens 56, the color filter 55, the insulating film 53, the fixed charge film 52, the diffraction scattering section 51, and the like, and penetrates into (incident in) the first area 21a (the photoelectric conversion unit 24 (PD)) of the photoelectric conversion area 21 from the second face S2 of the semiconductor layer 20. The oblique light 57H₁ that has penetrated into the first area 21a reaches (is emitted) from the first area 21a side to the in-pixel separation area 32.

As the oblique light 57H₁ reaching the in-pixel separation area 32, while there is oblique light that is reflected on the in-pixel separation area 32 and returns to the first area 21a of the photoelectric conversion area 21, there is oblique light that is transmitted through the in-pixel separation area 32 and penetrates into the second area 21b of the photoelectric conversion area 21. Particularly, in the case of the in-pixel separation area 32 including a silicon film as the conductive material 35, the light blocking property of the silicon film is insufficient, and thus there is concern that the oblique light 57H₁ may penetrate into the second area 21b.

Here, when described with reference to the light blocking film 54 of the first embodiment described above illustrated in FIG. 6, as in the light blocking film 54 illustrated in FIG. 6, in a case in which the second light blocking part 82b of this eighth embodiment illustrated in FIG. 21B is not included, the oblique light 57H₁ that has penetrated into the second area 21b of the photoelectric conversion area 21 reaches the floating diffusion region FD disposed on the first face S1 side of the semiconductor layer 20 in the second area 21b. The reach of the oblique light 57H₁ at this floating diffusion region FD has an influence on the parasitic light sensitivity characteristics, and thus it is important to suppress penetration of the oblique light to the second area 21b as possibly as can be.

In contrast to this, as illustrated in FIG. 21B, the light blocking body 80H of this eighth embodiment includes the second light blocking part 82b protruding from the first light blocking part 82a to the inside of the second area 21b. For this reason, oblique light 75a that has been transmitted through the in-pixel separation area 32 from the first area 21a of the photoelectric conversion area 21 is reflected on the second light blocking part 82b and returns to the first area 21a. In other words, the light blocking body 80H of this eighth embodiment can block oblique light 75H₁ that has been transmitted through the in-pixel separation area 32 from the first area 21a side of the photoelectric conversion area 21 using the second light blocking part 82b and suppress arrival of the oblique light 75H₁ at the floating diffusion region FD.

In addition, the oblique light 75H₁ that has been transmitted through the in-pixel separation area 32 from the first area 21a side is reflected on the second light blocking part 82b and returns to the first area 21a, and thus improvement of the quantum efficiency QE can be achieved.

In addition, as illustrated in FIG. 21B, in two photoelectric conversion areas 21 (21X₁, 21X₂) that are adjacent to each other through the inter-pixel separation area 31 in the plan view, oblique light 57H₂ that has been transmitted through inter-pixel separation area 31 from the first area 21a side of one photoelectric conversion area 21X₁ is reflected on the second light blocking part 82b of the light blocking body 80H in the second area 21b of the other photoelectric conversion area 21X₂ and returns to the first area 21a (the photoelectric conversion unit 24 (FD)) of the one photoelectric conversion area 21X₁. For this reason, the improvement of the quantum efficiency can be further achieved.

In addition, the oblique light 57H₂ that has been transmitted through the inter-pixel separation area 31 from the first area 21a side of the one photoelectric conversion area 21X₁ can return to the first area 21a of the one photoelectric conversion area 21X₁, and thus a mixed color between two photoelectric conversion areas 21 (between pixels 3) that are adjacent to each other can be suppressed as well.

In addition, as illustrated in FIG. 21B, since the light blocking body 80H of this eighth embodiment also includes the first light blocking part 82a that is disposed on an outer side of the second face S2 of the semiconductor layer 20 and overlaps the second area 21b of the photoelectric conversion area 21 in the plan view, similar to the light blocking film 54 of the first embodiment describe above, light penetrating into the second area 21b from the second face S2 of the semiconductor layer 20 in the second area 21b of the photoelectric conversion area 21 is blocked by the first light blocking part 82a, and arrival of light at the floating diffusion region FD can be suppressed.

### Main Effects of Eighth Embodiment

Next, main effects of this eighth embodiment will be described.

Similar to the solid-state imaging device 1A according to the first embodiment described above, the solid-state imaging device 1H according to this eighth embodiment includes the inter-pixel separation areas 31 and the in-pixel separation areas 32. Thus, also in the solid-state imaging device 1H according to this eighth embodiment, similar to the solid-state imaging device 1A according to the first embodiment described above, improvement of the quantum efficiency QE and mixed color suppression (MTF) can be achieved as pixel characteristics, and improvement of transmission characteristics as pixel characteristics can be achieved.

In addition, the light blocking body 80H of this eighth embodiment includes the first light blocking part 82a that is disposed on the outer side of the second face S2 of the semiconductor layer 20 and overlaps the second area 21b of the photoelectric conversion area 21 in the plan view. For this reason, similar to the solid-state imaging device 1A of the first embodiment described above, light penetrating into the second area 21b from the second face S2 of the semiconductor layer 20 in the second area 21b of the photoelectric conversion area 21 is blocked by the first light blocking part 82a, arrival of light at the floating diffusion region FD can be suppressed, and the parasitic light sensitivity characteristics (PLS) can be enhanced.

In addition, the light blocking body 80H of this eighth embodiment includes the second light blocking part 82b protruding to the inside of the second area 21b of the photoelectric conversion area 21 from the first light blocking part 82a. For this reason, the oblique light 75H₁ that has been transmitted through the in-pixel separation area 32 from the first area 21a side of the photoelectric conversion area 21 is blocked by the second light blocking part 82b, arrival of the oblique light 75H₁ at the floating diffusion region FD can be suppressed, and, in combination with an effect of enhancing the parasitic light sensitivity characteristics according to the first light blocking part 82a, further enhancement of the parasitic light sensitivity characteristics (PLS) can be achieved.

In addition, the oblique light 75H₁ that has been transmitted through the in-pixel separation area 32 from the first area 21a side is reflected on the second light blocking part 82b and returns to the first area 21a, and thus improvement of the quantum efficiency QE can be achieved as well.

Furthermore, in two photoelectric conversion areas 21 (21X₁, 21X₂) that are adjacent to each other through the inter-pixel separation area 31 in the plan view, oblique light 57H₂ that has been transmitted through the inter-pixel separation area 31 from the first area 21a side of one photoelectric conversion area 21X₁ is reflected on the second light blocking part 82b of the light blocking body 80H in the second area 21b of the other photoelectric conversion area 21X₂ and returns to the first area 21a (the photoelectric conversion unit 24 (FD)) of the one photoelectric conversion area 21X₁. Thus, according to the solid-state imaging device 1H according to this eighth embodiment, in combination with an effect of the quantum efficiency QE according to light reflection in the inter-pixel separation area 31, improvement of the quantum efficiency QE can be achieved.

In addition, according to the solid-state imaging device 1H according to this eighth embodiment, the oblique light 57H₂ that has been transmitted through the inter-pixel separation area 31 from the first area 21a side of one photoelectric conversion area 21X₁ is configured to be able to return to the first area 21a of the one photoelectric conversion area 21X₁, and thus, in combination with a mixed color suppression effect according to light reflection in the inter-pixel separation area 31, further mixed color suppression can be achieved.

When described with reference to FIG. 21A, an effect of suppression of arrival of oblique light (57H₁, 57H₂) at the floating diffusion region FD mainly depends on (is in proportion to) an embedding length L₂ in which the second light blocking part 82b is embedded inside of the second area 21b in an entire length L₁ in which the second light blocking part 82b protrudes from the first light blocking part 82a to a tip end protruding to the second area 21b (the semiconductor layer 20). On the other hand, the entire length L₁ of the second light blocking part 82b and the width W1 thereof in the Y direction have influences on a manufacturing yield. Thus, it is preferable that the entire length L₁ of the second light blocking part 82b in the Z direction or the embedding length L₂ thereof be separate from the floating diffusion region FD by ½ of the thickness of the semiconductor layer 20 or more in consideration of the effect of suppression of arrival of the oblique light (57H₁, 57H₂) at the floating diffusion region FD and the manufacturing yield.

In addition, in this eighth embodiment, although the second light blocking part 82b is separate from each of the inter-pixel separation area 31 and the in-pixel separation area 32 in the Y direction, the second light blocking part 82b may be brought into contact with at least one of the inter-pixel separation area 31 and the in-pixel separation area 32.

### Modified Example of Eighth Embodiment

### Modified Example 8-1

In the eighth embodiment described above, the first light blocking part 82a extending in the X direction with a constant width in the Y direction has been described as a configuration of the light blocking body 80H. However, the present technology is not limited to the eighth embodiment described above.

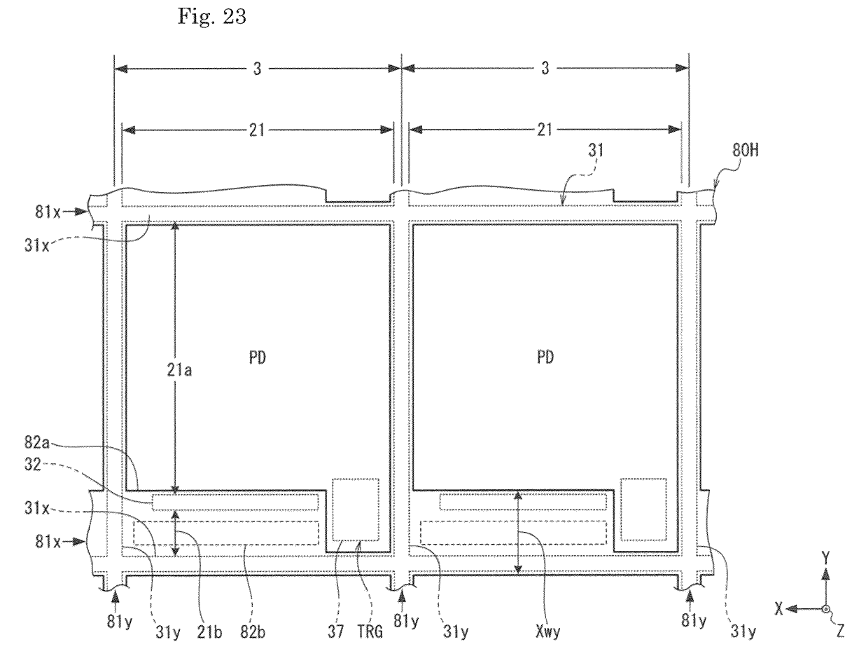

For example, as illustrated in FIG. 23, the width Xwy of the first light blocking part 82a in the Y direction may be configured to be partly narrow. In this case, the width Xwy of a part, in which the first light blocking part 82a does not overlap the floating diffusion region FD in the plan view, in the Y direction be narrow.

### Modified Example 8-2

In the eighth embodiment described above, the light blocking body 80H including the first linear part 81x, the second linear part 81y, the first light blocking part 82a, and the second light blocking part 82b has been described. However, the present technology is not limited to the eighth embodiment described above.

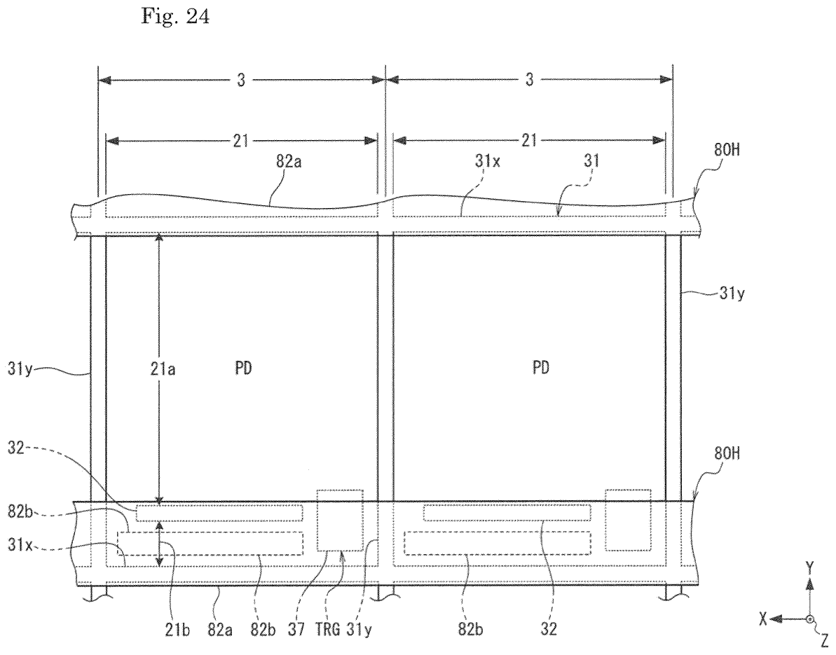

For example, as illustrated in FIG. 24, as the configuration of the light blocking body 80H, a configuration in which the first linear part 81x and the second linear part 81y are omitted, and a first light blocking part 82a and a second light blocking part 82b alone are included may be employed.

### Modified Example 8-3

In the eighth embodiment described above, as the configuration of the light blocking body 80H, a case in which the first light blocking part 82a continuously extends over two photoelectric conversion areas 21 that are adjacent to each other in the X direction has been described. However, the present technology is not limited to the eighth embodiment described above.

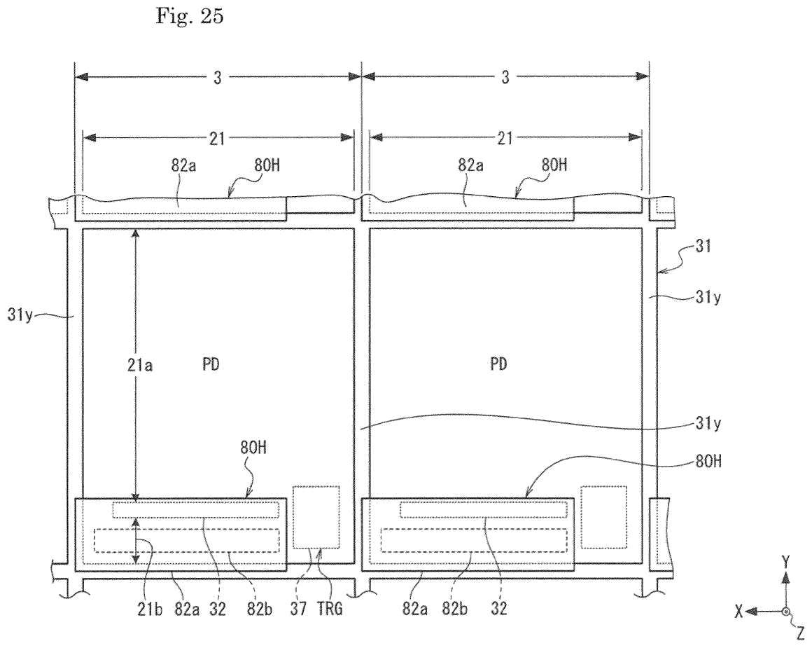

For example, as illustrated in FIG. 25, a configuration in which the first light blocking part 82a is scattered in each of two photoelectric conversion areas 21 that are adjacent to each other in the X direction may be employed.

### Modified Example 8-4

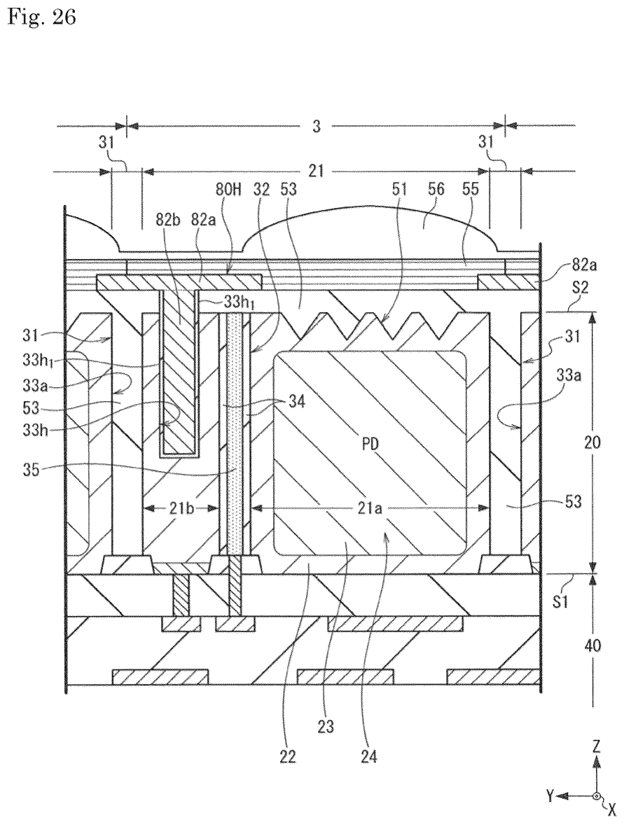

In the eighth embodiment described above, although a case in which the present technology is applied to the solid-state imaging device 1H including the fixed charge film 52 has been described, as illustrated in FIG. 26, the present technology can be applied also to a solid-state imaging device 1H not including the fixed charge film.

### Ninth Embodiment

In this ninth embodiment, similar to the eighth embodiment described above, a light blocking body 80I will be mainly described.

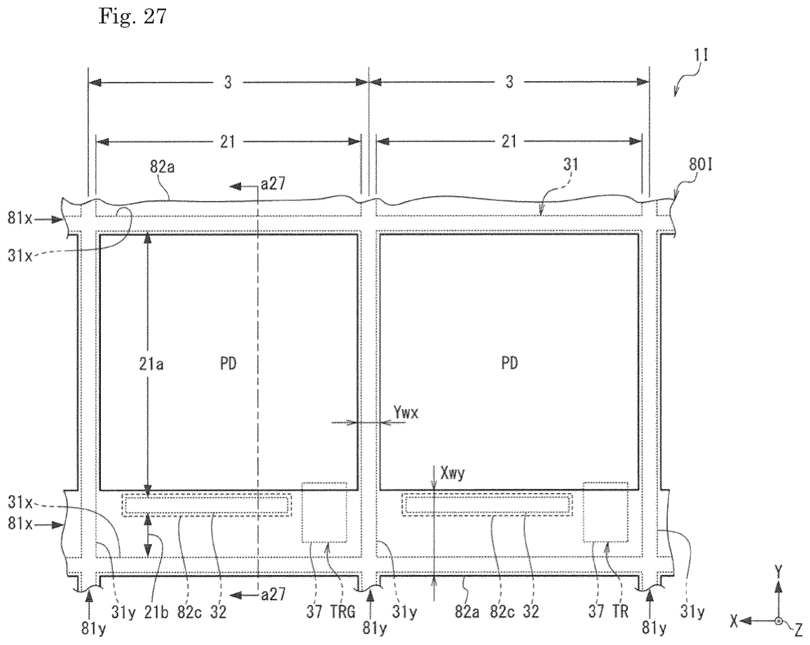

FIG. 27 is a plan view schematically illustrating a plane pattern of a light blocking body of a pixel array portion of a solid-state imaging device according to this ninth embodiment.

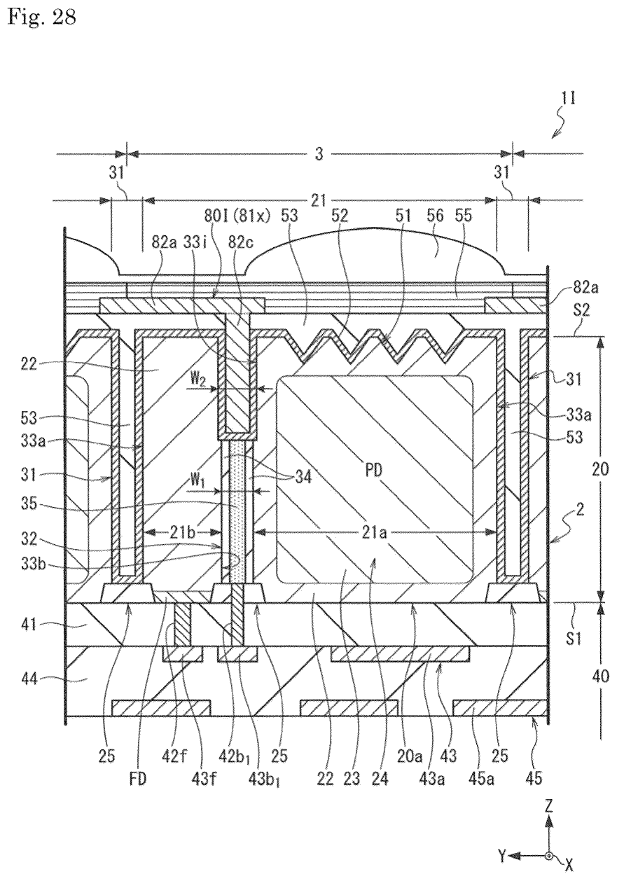

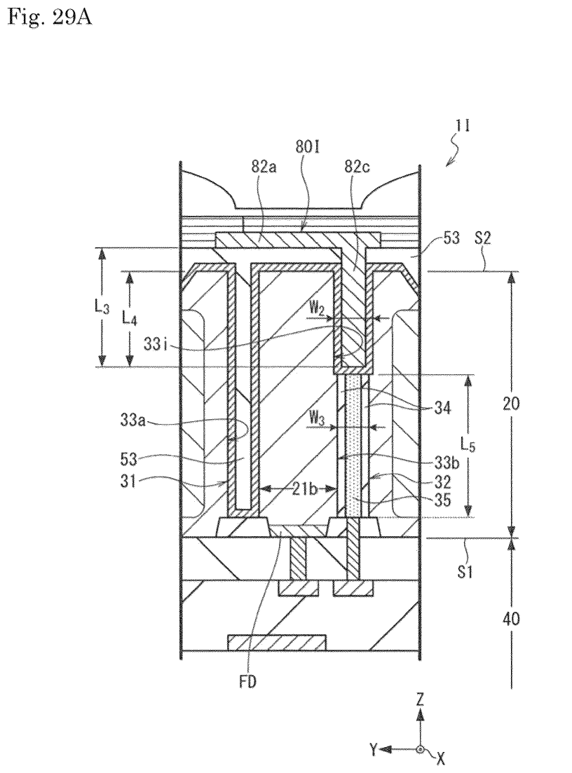

FIG. 28 is a longitudinal cross-sectional view schematically illustrating a longitudinal cross-sectional structure taken along line a27-a27 illustrated FIG. 27.

FIG. 27 is a plan view seen from a second face S2 side (a light incident face side) of a semiconductor layer 20 illustrated in FIG. 28. FIG. 28 is vertically inverted with respect to FIGS. 5 and 6 of the first embodiment described above.

### <<Configuration of Solid-state Imaging Device>>

A solid-state imaging device 1I according to the ninth embodiment of the present technology basically has a configuration similar to the solid-state imaging device 1A according to the first embodiment described above, and there are differences in the following configurations.

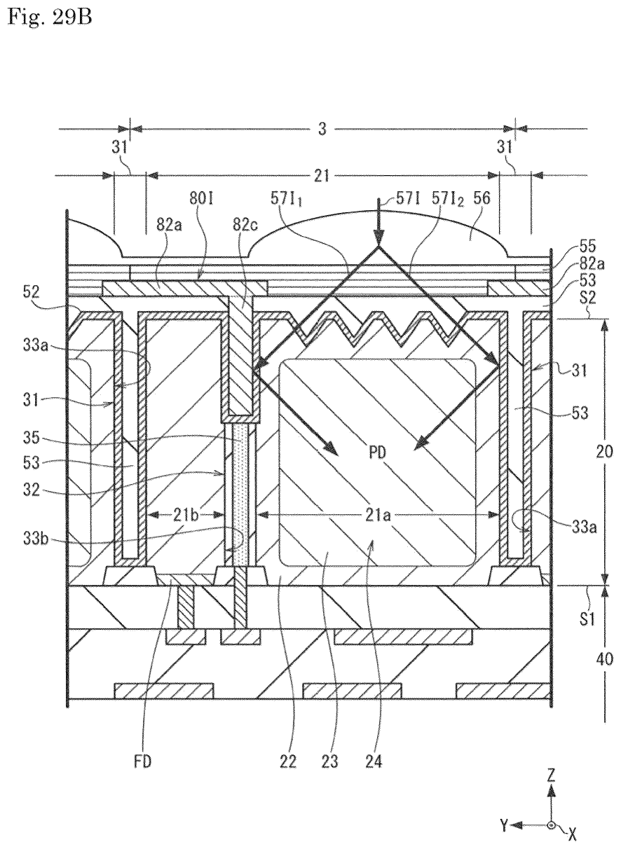

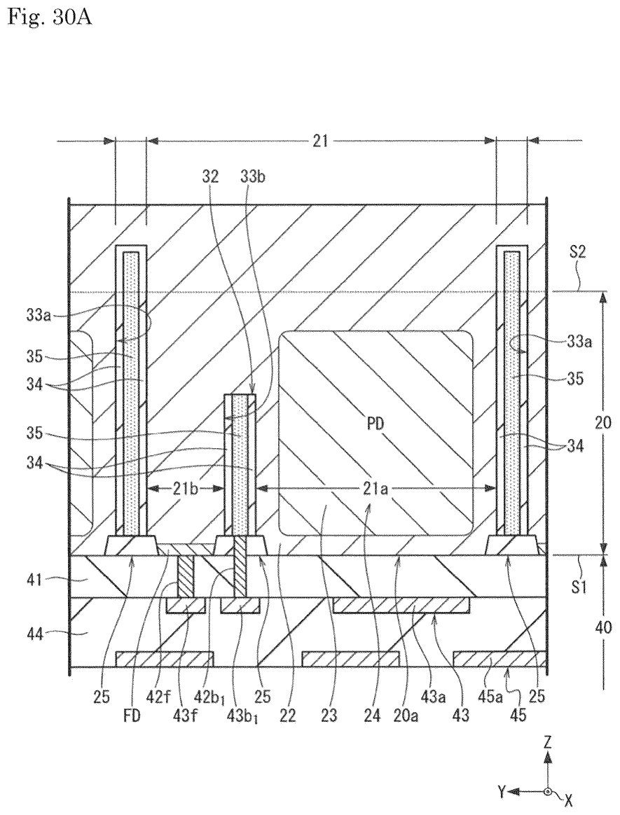

In other words, as illustrated in FIGS. 27 and 28, the solid-state imaging device 1I according to the ninth embodiment of the present technology includes a light blocking body 80I in place of the light blocking film 54 of the above-described first embodiment illustrated in FIGS. 5 and 6. Relating to this light blocking body 80I, a length L₅ (see FIG. 29B) of an in-pixel separation area 32 in the Z direction is shorter than the length of the inter-pixel separation area 31 in the Z direction. In other words, the in-pixel separation area 32 of this ninth embodiment has the length L₅ extending from the first face S1 side to the second face S2 side of the semiconductor layer 20 to be shorter than that of the in-pixel separation area 32 of the above-described first embodiment illustrated in FIGS. 5 and 6. The other components are similar to those of the first embodiment as a whole, the same reference signs will be assigned to the same components, and duplicate description will be omitted.

As illustrated in FIGS. 27 and 28, the light blocking body 80I of this ninth embodiment is disposed on the second face S2 side of the semiconductor layer 20 and overlaps a second area 21b of a photoelectric conversion area 21 and a floating diffusion region FD in the plan view. The light blocking body 80I overlaps the in-pixel separation area 32 in the plan view and is disposed over the inside and outside of the semiconductor layer 20 on the second face S2 side of the semiconductor layer 20.

Although not illustrated in detail in FIG. 27, when described with reference to FIG. 17 of the eighth embodiment described above, similar to the light blocking body 80H of the eighth embodiment described above, the light blocking body 80I includes first linear parts 81x that extend in the X direction and are repeatedly disposed with a predetermined disposition pitch in the Y direction and second linear parts 81y that intersect these first linear parts 81x, extend in the Y direction, and are repeatedly disposed with a predetermined disposition pitch in the X direction. The first linear part 81x overlaps a first part 31x of the inter-pixel separation area 31 in the plan view, and the second linear part 81y overlaps a second part 31y of the inter-pixel separation area 31 in the plan view. In other words, also in the light blocking body 80I of this ninth embodiment, similar to the light blocking body 80H of the eighth embodiment described above, a lattice-shaped plane pattern in which a plane pattern in the plan view opens the light reception face side (the second face S2 side) of each of a plurality of photoelectric conversion areas 21 such that light incident in a predetermined photoelectric conversion area 21 does not leak into a nearby photoelectric conversion area 21 is formed. A width Xwy of the first linear part 81x in the Y direction is configured to be larger than a width Ywx of the second linear part 81y in the X direction.

As illustrated in FIGS. 27 and 28, the light blocking body 80I includes a first light blocking part 82a that is disposed on the outer side of the second face S2 of the semiconductor layer 20 and overlap the second area 21b of the photoelectric conversion area 21 and the floating diffusion region FD in the plan view and a second light blocking part 82c that overlaps the in-pixel separation area 32 in the plan view and protrudes from the first light blocking part 82a to the inside of the semiconductor layer 20. These first light blocking part 82a and second light blocking part 82c are configured in the first linear part 81x. In other words, the first linear part 81x of this ninth embodiment includes the first light blocking part 82a and the second light blocking part 82c.

As illustrated in FIG. 28, the second light blocking part 82c is disposed inside a dug part 33i as a third dug part extending from the second face S2 side of the semiconductor layer 20 toward the in-pixel separation area 32 through the fixed charge film 52. The in-pixel separation area 32 of this ninth embodiment, as illustrated in FIG. 29A, has a length L₅ in the Z direction along the thickness direction of the semiconductor layer 20 to be shorter than a length of the inter-pixel separation area 31 in the Z direction. In addition, the length L₅ of the in-pixel separation area 32 of the ninth embodiment in the Z direction is shorter than the length of the in-pixel separation area 32 of the first embodiment in the Z direction. The in-pixel separation area 32 of this ninth embodiment extends from the element separation area 25 of the first face S1 side of the semiconductor layer 20 toward the second face S2 side and is separate from the second face S2 of the semiconductor layer 20.

As illustrated in FIG. 29A, the dug part 33i transverses the second face S2 of the semiconductor layer 20 from an upper surface of a side opposite to the semiconductor layer 20 side of the insulating film 53 and reaches a tip end of the in-pixel separation area 32. The second light blocking part 82c extends from the first light blocking part 82a toward the tip end of the in-pixel separation area 32 and is disposed inside of the dug part 33i through the fixed charge film 52.

The fixed charge film 52 inside the dug part 33i is disposed along the side wall and the bottom wall of the dug part 33i. The fixed charge film 52 on the side wall of the dug part 33i electrically insulates and separates the semiconductor layer 20 and the second light blocking part 82c of the light blocking body 80I from each other. In addition, the fixed charge film 52 on the bottom wall of the dug part 33i electrically insulates and separates the second light blocking part 82c of the light blocking body 80I and the conductive material 35 of the in-pixel separation area 32 from each other.

Here, as illustrated in FIG. 29A, the in-pixel separation area 32 of this ninth embodiment extends over from the element separation area 25 to the dug part 33i. The length L₅ of the in-pixel separation area 32 of this case is a distance from the bottom face of the element separation area 25 to the dug part 33i. Although not illustrated in the drawing, in a case in which the in-pixel separation area 32 extends over from the first face S1 of the semiconductor layer 20 to the dug part 33i, a distance from the first face S1 of the semiconductor layer 20 to the dug part 33i becomes the length L₅ of the in-pixel separation area 32.

In addition, a face of the semiconductor layer 20 that is brought into contact with the bottom face of the element separation area (a field separation area) 25 can be regarded as the first face S1.

As illustrated in FIG. 29A, the in-pixel separation area 32 and the dug part 33i have different widths (W₂ and W₃) of the first area 21a and the second area 21b of the photoelectric conversion area 21 in a direction along the disposition direction (one direction). In this ninth embodiment, although the width W₂ of the dug part 33i is larger than the width W₃ of the in-pixel separation area 32, the width W₃ of the in-pixel separation area 32 may be configured to be larger than the width W₂ of the dug part 33i. In other words, from the point of view of patterning accuracy and characteristics, it is preferable to satisfy “W₂>W₃” or “W₂<W₃”.

As illustrated in FIGS. 27 and 28, the light blocking body 80I extends over two photoelectric conversion areas 21 that are adjacent to each other in the X direction inside a two-dimensional plane but is not limited thereto. Also the first light blocking part 82a continuously extends over two photoelectric conversion areas 21 that are adjacent to each other in the X direction. On the other hand, the second light blocking part 82c is disposed to be separate for each photoelectric conversion area 21 aligned in the X direction. In other words, different from the first light blocking part 82a, the second light blocking part 82c does not continuously extend over two photoelectric conversion areas 21 that are adjacent to each other in the Y direction.

The second light blocking part 82c extends in the X direction together with the in-pixel separation area 32 in the plan view. It is preferable that the length of the second light blocking part 82c in the X direction be equal to the length of the in-pixel separation area 32 in the X direction or be larger than the length of the in-pixel separation area 32 in the X direction. In this ninth embodiment, the length of the second light blocking part 82c in the X direction is larger than the length of the in-pixel separation area 32 in the X direction.

The first light blocking part 82a, mainly, in the second area 21b of the photoelectric conversion area 21, blocks light on the outside of the second face S2 of the semiconductor layer 20 and suppresses arrival of light at the floating diffusion region FD disposed on the first face S1 side of the semiconductor layer 20. On the other hand, the second light blocking part 82c, mainly, in the photoelectric conversion area 21, mainly blocks light on the inside of the second face S2 side of the semiconductor layer 20 and suppresses arrival of light at the floating diffusion region FD disposed on the first face S1 side of the semiconductor layer 20.

In other words, the light blocking body 80I blocks light penetrating (incident in) the second area 21b of the photoelectric conversion area 21 on the second face S2 side of the semiconductor layer 20 and suppresses arrival of light at the floating diffusion region FD disposed on the first face S1 side of the semiconductor layer 20 inside the second area 21b of the photoelectric conversion area 21.

As the light blocking body 80I, it is preferable to use a metal film of, for example, titanium (Ti), tungsten (W), aluminum (Al), or the like or an alloy film as a material having a superior light blocking property and having an optical reflectance higher than a silicon oxide film or a silicon film. In this ninth embodiment, as the light blocking body 80I, for example, a tungsten (W) film is used.

Here, in this ninth embodiment, the inter-pixel separation area 31 corresponds to “first separation area” of the present technology, and the in-pixel separation area 32 corresponds to “second separation area” of the present technology. In addition, in this ninth embodiment, the dug part 33a, the dug part 33b, and the dug part 33i corresponds to “first dug part”, “second dug part”, and “third dug part” of the present technology. Furthermore, in this ninth embodiment, a disposition direction of the first area 21a and the second area 21b of the photoelectric conversion area 21 corresponds to “one direction” of the present technology.

### <<Method of Manufacturing Solid-state Imaging Device>>

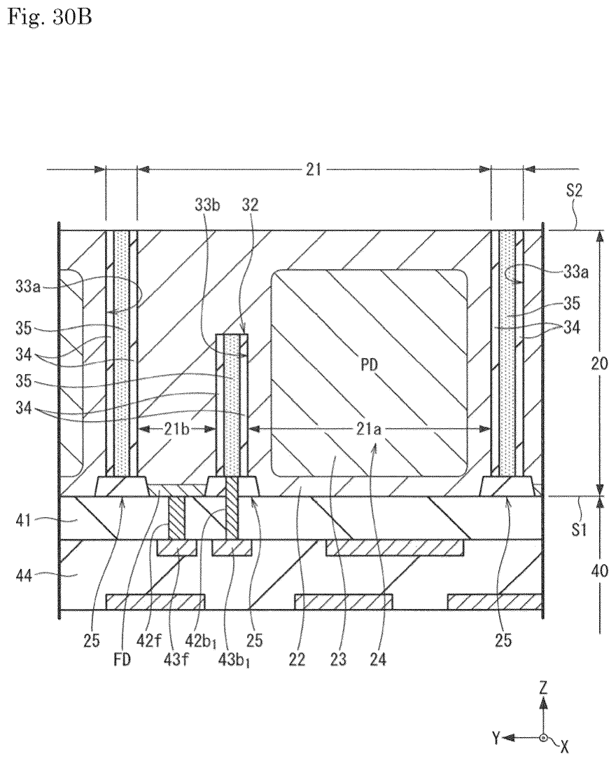

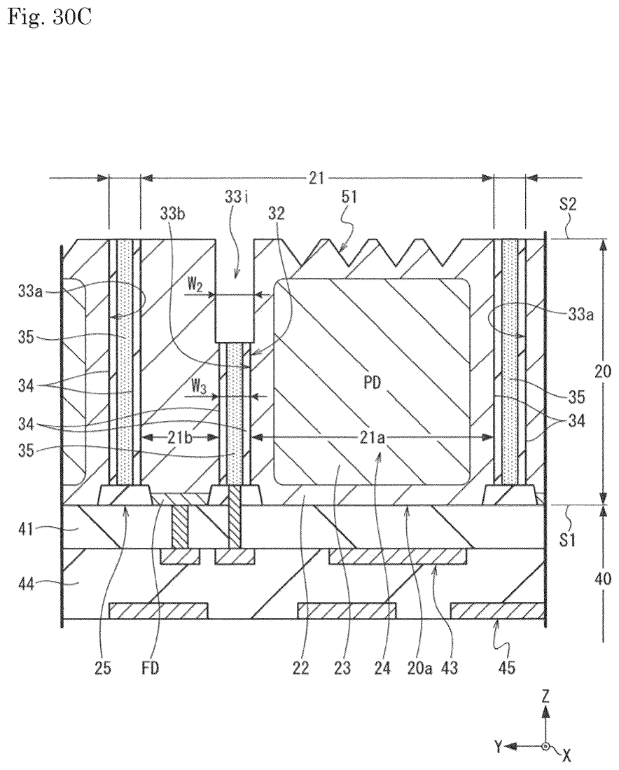

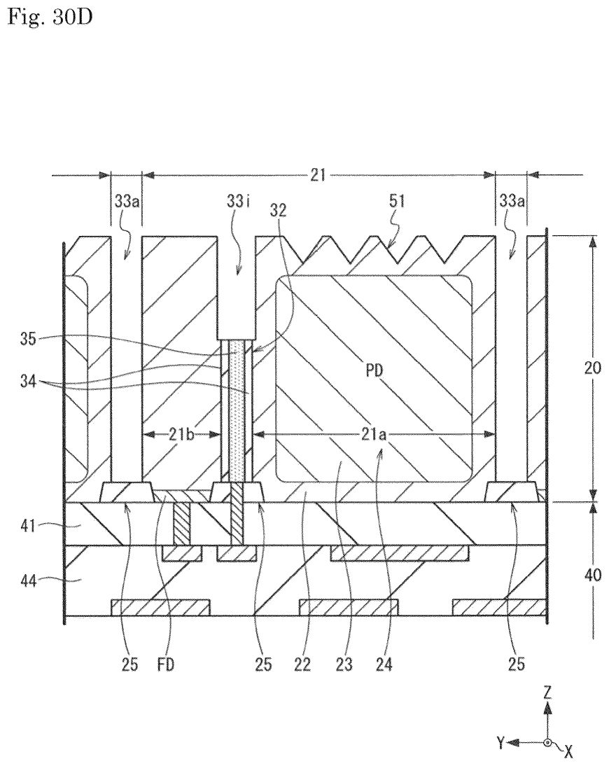

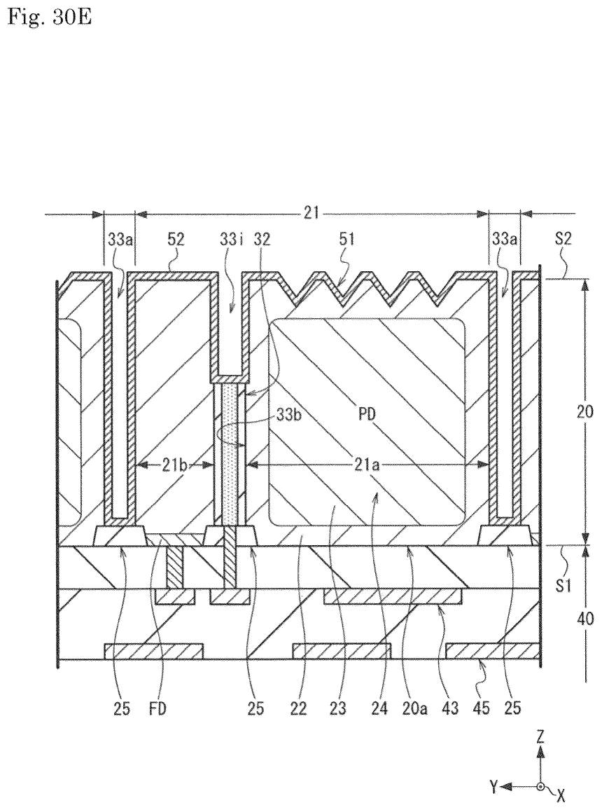

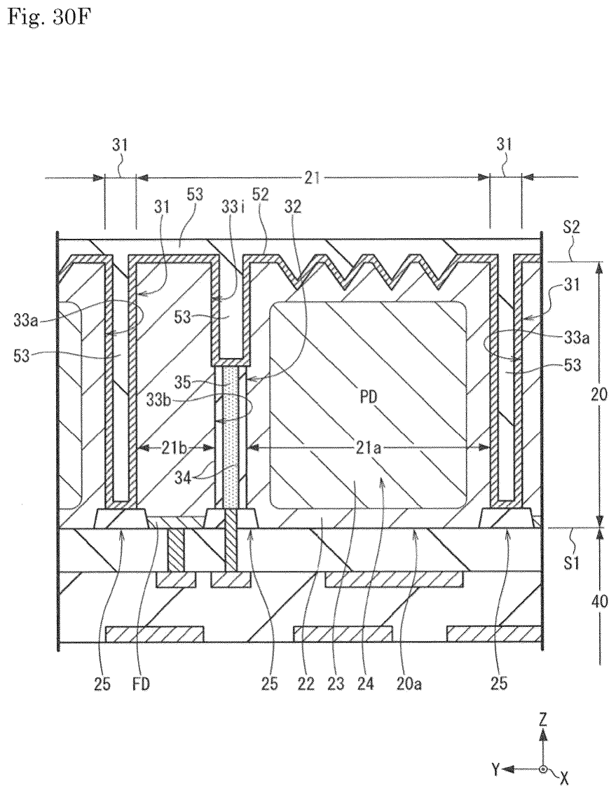

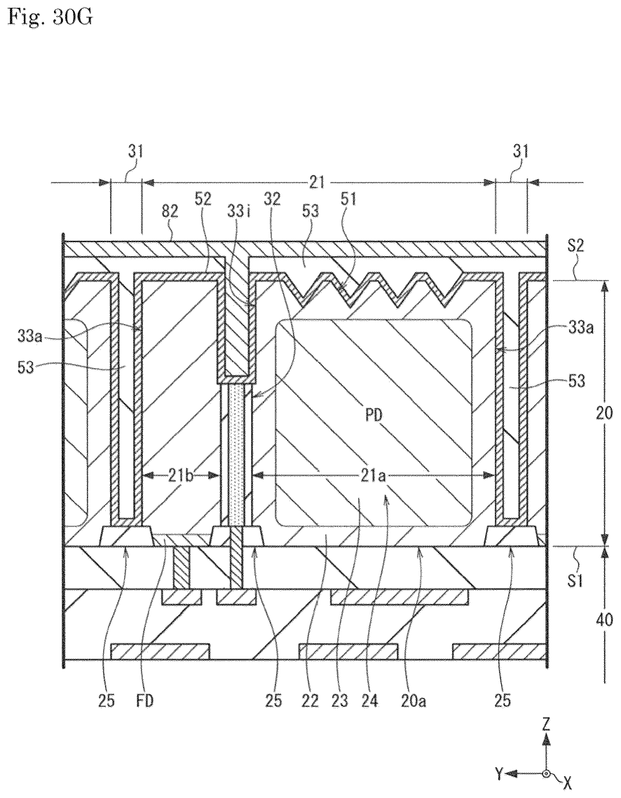

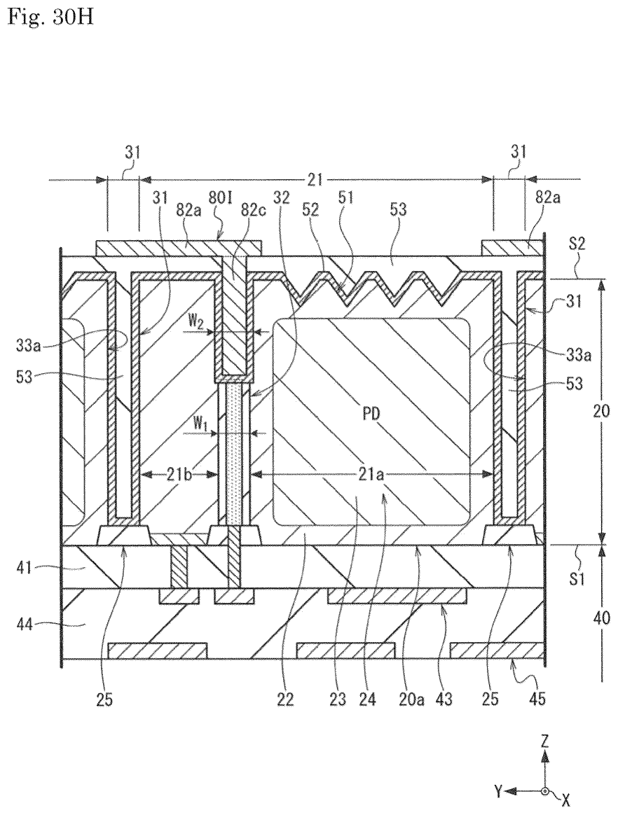

Next, a method of manufacturing the solid-state imaging device 1I according to the ninth embodiment of the present technology will be described with reference to FIGS. 30A to 30H. Also in this ninth embodiment, manufacturing of the light blocking body 80I included in the method of manufacturing the solid-state imaging device 1I will be particularly described.

First, as illustrated in FIG. 30A, together with forming a photoelectric conversion area 21, an element separation area 25, a dug part 33a, an in-pixel separation area 32, and the like on the semiconductor layer 20, a multilayer wiring layer 40 is formed on the first face S1 side of the semiconductor layer 20.

The in-pixel separation area 32 includes a separation insulating film 34 disposed along a side wall of the dug part 33b extending in the depth direction (the Z direction) of the semiconductor layer 20 and a silicon film as a conductive material 35 filling this dug part 33b through the separation insulating film 34. This in-pixel separation area 32 has a length L₄ (see FIG. 29A) in the Z direction that grows from the first face S1 side of the semiconductor layer 20 toward the second face S2 to be shorter than a length of the in-pixel separation area 32 in the Z direction represented in FIG. 22A of the eighth embodiment described above.

The dug part 33a becomes the base of the inter-pixel separation area 31 illustrated in FIG. 30F. Similar to the dug part 33b of the in-pixel separation area 32, the dug part 33a extends in the depth direction (the Z direction) of the semiconductor layer 20 and has the inside filled with the conductive material 35 through the separation insulating film 34. The dug part 33a partitions the photoelectric conversion area 21 for each photoelectric conversion area 21. The dug parts 33a and 33b of this ninth embodiment have different Z-direction lengths, thus are different from the eighth embodiment described above, and are formed in separate processes.

The photoelectric conversion area 21 includes an element formation area 20a, a well region 22 of the p type, a semiconductor area 23 of the n type, a photoelectric conversion unit 24 (PD), an element separation area (a field separation area) 25, pixel transistors (AMP, SEL, RST, and TR) formed in the element formation area 20a, and the like. The photoelectric conversion area 21 includes a floating diffusion region FD, an in-pixel separation area 32, and a first area 21a and a second area 21b separated by this in-pixel separation area 32.

The well region 22 of the p type is formed in the first area 21a and the second area 21b of the photoelectric conversion area 21. The element formation area 20a, the semiconductor area 23 of the n type, and the photoelectric conversion unit 24 are formed in the first area 21a of the photoelectric conversion area 21. The floating diffusion region FD is formed on the first face S1 side of the semiconductor layer 20 in the second area 21b of the photoelectric conversion area 21. As the semiconductor layer 20, for example, a semiconductor substrate of the p type formed from monocrystalline silicon is used, but the semiconductor layer is not limiter thereto.

Next, after a multilayer wiring layer 40 is formed on the first face S1 side of the semiconductor layer 20, the thickness of the semiconductor layer 20 is formed to be thin, for example, by cutting the second face S2 side of the semiconductor layer 20 using a CMP method, and as illustrated in FIG. 30B, the separation insulating film 34 and the conductive material 35 of the inside of the dug part 33a are exposed.

Next, after the separation insulating film 34 and the conductive material 35 of the inside of the dug part 33a are exposed, as illustrated in FIG. 30C, in the first area 21a of the photoelectric conversion area 21, together with forming a diffraction scattering section 51 on the second face S2 of the semiconductor layer 20, a dug part 33i reaching from the second face S2 side of the semiconductor layer 20 to the tip end of the in-pixel separation area 32 and overlaps the in-pixel separation area 32 in the plan view is formed. The shape and the dimension of this dug part 33i regulate a shape and a dimension of the second light blocking part 82c of the light blocking body 80I illustrated in FIG. 30H. In this ninth embodiment, for example, the width W₂ of the dug part 33i is formed to be larger than the width W₃ of the in-pixel separation area 32 but is not limited thereto. The formation of the dug part 33i is performed using a known photolithographic technology and an anisotropic dry etching technology. Although the dug part 33i and the diffraction scattering section 51 are formed in separate processes, any one of the dug part 33i and the diffraction scattering section 51 may be formed first.

Next, after the diffraction scattering section 51 and the dug part 33i are formed, as illustrated in FIG. 30D, the separation insulating film 34 and the conductive material 35 of the inside of the dug part 33a are selectively removed. The separation insulating film 34 and the conductive material film 35 of the inside of the dug part 33a can be selectively removed using a known photolithographic technology and an anisotropic dry etching technology.

Next, after the separation insulating film 34 and the conductive material film 35 of the inside of the dug part 33a are selectively removed, as illustrated in FIG. 30E, a fixed charge film 52 covering an inner wall (a side wall and a bottom wall) of the inside of each of the dug parts 33a and 33i and the second face S2 of the semiconductor layer 20 is formed. The fixed charge film 52, on the second face S2 side of the semiconductor layer 20, is formed over the first area 21a and the second area 21b of the photoelectric conversion area 21, and the diffraction scattering section 51 of the first area 21a is covered with the fixed charge film 52.

Next, after the fixed charge film 52 is formed, as illustrated in FIG. 30F, an insulating film 53 is formed on the entire face of the second face S2 side of the semiconductor layer 20 including the inside of each of the dug parts 33a and 33i. For example, after a silicon oxide film is formed using a CVD method, the insulating film 53 can be formed by cutting and planarizing the surface side of this silicon oxide film using a CMP method.

In this process, an inter-pixel separation area 31 in which the insulating film 53 is embedded inside the dug part 33a through the fixed charge film 52 is formed, and the periphery of this inter-pixel separation area 31 is partitioned, whereby a photoelectric conversion area 21 of which the inside is separated into a first area 21a and a second area 21b by the in-pixel separation area 32 is formed.

Next, after the insulating film 53 is formed, the insulating film 53 on the dug part 33i and the insulating film 53 of the inside of the dug part 33i are selectively removed. The selective removal of this insulating film 53 is performed using a known photolithographic technology and an anisotropic dry etching technology.

Next, after the insulating film 53 is selectively removed, as illustrated in FIG. 30G, a light blocking film 82 is formed on the entire face of the insulating film 53 including the inside of the dug part 33i. The light blocking film 82, for example, can be formed by forming a metal film or an alloy film of titanium (Ti), tungsten (W), or the like having an optical reflectance higher than a silicon oxide film or a silicon film using a known film formation technology. The light blocking film 82 is formed over a plurality of photoelectric conversion areas 21 and is formed such that it covers the first area 21a and the second area 21b of each of the plurality of photoelectric conversion areas 21 in the plan view and embeds the dug part 33i of the second area 21b of each thereof. The light blocking film 82 in the embedded part 33i is formed through the fixed charge film 52.

Next, the light blocking film 82 is patterned, and as illustrated in FIG. 30H, the light blocking body 80I that covers the second area 21b of the photoelectric conversion area 21 and extends over the inside and outside of the second face S2 of the semiconductor layer 20 is formed. The patterning of the light blocking film 82 can be performed using a known photolithographic technology and an anisotropic dry etching technology.

In this process, the light blocking body 80I includes a first light blocking part 82a that is disposed on the outer side of the second area 21b of the photoelectric conversion area 21 (the outer side of the first face S1 of the semiconductor layer 20) through the insulating film 53 and overlaps the second area 21b and the floating diffusion region FD in the plan view and a second light blocking part 82c that goes through the insulating film 53 from this first light blocking part 82a and protrudes to the inside of the semiconductor layer 20. When described with reference to FIG. 17, the light blocking body 80I includes first linear parts 81x that extend in the X direction and are repeatedly disposed with a predetermined disposition pitch in the Y direction and second linear parts 81y that extends in the Y direction with intersecting the first linear parts 81x and are repeatedly disposed with a predetermined disposition pitch in the X direction. The light blocking body 80I is formed in a lattice-shaped plane pattern overlapping the lattice-shaped plane pattern of the inter-pixel separation area 31 in the plan view. The first light blocking parts 82a and the second light blocking parts 82c are formed in the first linear part 81x.

Next, after the light blocking body 80I is formed, by forming a color filter 55 and a microlens 56 on a side opposite to the semiconductor layer 20 of the light blocking body 80I in this order, a state illustrated in FIGS. 27 and 28 is formed.

In addition, also in the solid-state imaging device 1I according to this ninth embodiment, by dividing a semiconductor wafer including the semiconductor layer 20 and the multilayer wiring layer 40 for each chip formation area, the state of the semiconductor chip 2 illustrated in FIG. 1 is formed.

### <Function of Light Blocking Body>

Next, the function of the light blocking body 80I will be described with reference to FIGS. 29B and 6.

As illustrated in FIG. 29B, in one photoelectric conversion area 21 (one pixel 3), emission light 57I emitted to the microlens 56 becomes oblique light 5711, is transmitted (goes) through the microlens 56, the color filter 55, the insulating film 53, the fixed charge film 52, the diffraction scattering section 51, and the like, and penetrates (is incident) into the first area 21a (the photoelectric conversion unit 24 (PD)) of the photoelectric conversion area 21 from the second face S2 side of the semiconductor layer 20. The oblique light 5711 that has penetrated into the first area 21a reaches (is emitted to) the second light blocking part 82c of the light blocking body 80I from the first area 21a side.

Here, when described with reference to the light blocking film 54 of the above-described first embodiment illustrated in FIG. 6, similar to the light blocking film 54 illustrated in FIG. 6, in a case in which the second light blocking part 82c of this ninth embodiment illustrated in FIG. 29B is not included, the oblique light 5711 that has penetrated into the second area 21b of the photoelectric conversion area 21 reaches (is emitted to) the in-pixel separation area 32 from the first area 21a side.

As the oblique light 5711 reaching the in-pixel separation area 32, while there is oblique light that is reflected on the in-pixel separation area 32 and returns to the first area 21a of the photoelectric conversion area 21, there is also oblique light that is transmitted through the in-pixel separation area 32 and penetrates into the second area 21b of the photoelectric conversion area 21. Particularly, in the case of the in-pixel separation area 32 including a silicon film as the conductive material 35, the silicon film has an insufficient light blocking property, and thus there is concern that the oblique light 5711 may penetrate into the second area 21b.

In a case in which the oblique light 5711 has penetrated into the second area 21b of the photoelectric conversion area 21, the oblique light 5711 arrives at the floating diffusion region FD disposed on the first face S1 side of the semiconductor layer 20 in the second area 21b. Since the arrival of the oblique light 57H₁ at this floating diffusion region FD has an influence on the parasitic light sensitivity characteristics, it is important to suppress penetration of oblique light into the second area 21b as possibly as can.

In contrast to this, as illustrated in FIG. 29B, the light blocking body 80I of this ninth embodiment includes the second light blocking part 82c that overlaps the in-pixel separation area 32 in the plan view and protrudes from the first light blocking part 82a of the outer side of the second face S2 of the semiconductor layer 20 to the inside of the semiconductor layer 20. For this reason, the oblique light 57H₁ that has penetrated into the first area 21a of the photoelectric conversion area 21 reaches (is emitted to) the second light blocking part 82c of the light blocking body 80I from the first area 21a side and is reflected on the second light blocking part 82c to return to the second area 21b. In other words, the light blocking body 80I of this ninth embodiment blocks the oblique light 5711 that has penetrated into the second area 21b from the first area 21a side of the photoelectric conversion area 21 in the second light blocking part 82c and can suppress arrival of the oblique light 5711 at the floating diffusion region FD.

In addition, since the oblique light 5711 that has reached (been emitted to) the second light blocking part 82c of the light blocking body 80I from the first area 21a side is reflected on the second light blocking part 82c to return to the first area 21a of the photoelectric conversion area 21, improvement of the quantum efficiency QE can be achieved as well.

In addition, as illustrated in FIG. 29B, oblique light 5712 that has reached (been emitted to) the inter-pixel separation area 31 from the first area 21a side of the photoelectric conversion area 21 is mainly reflected on the inter-pixel separation area 31 to return to the first area 21a (the photoelectric conversion unit 24 (PD)).

In addition, as illustrated in FIG. 29B, since the light blocking body 80I of this ninth embodiment also includes the first light blocking part 82a that is disposed on the outer side of the second face S2 of the semiconductor layer 20 and overlaps the second area 21b of the photoelectric conversion area 21 in the plan view, similar to the light blocking film 54 of the first embodiment described above, light that has penetrated into the second area 21b from the second face S2 of the semiconductor layer 20 in the second area 21b of the photoelectric conversion area 21 is blocked by the first light blocking part 82a, and arrival of light to the floating diffusion region FD can be suppressed.

### Main Effects of Ninth Embodiment

Next, main effects of this ninth embodiment will be described.

Similar to the solid-state imaging device 1A according to the first embodiment described above, the solid-state imaging device 1I according to this ninth embodiment includes the inter-pixel separation area 31 and the in-pixel separation area 32. Thus, also in the solid-state imaging device 1I according to this ninth embodiment, similar to the solid-state imaging device 1A according to the first embodiment described above, improvement of the quantum efficiency QE as a pixel characteristic and high mixed-color suppression (MTF) can be achieved, and improvement of transmission characteristics as pixel characteristics can be achieved.

In addition, the light blocking body 80I of this ninth embodiment includes the first light blocking part 82a that is disposed on the outer side of the second face S2 of the semiconductor layer 20 and overlaps the second area 21b of the photoelectric conversion area 21 in the plan view. For this reason, similar to the solid-state imaging device 1A of the first embodiment described above, light that has penetrated into the second area 21b from the second face S2 side (the light incident face side) of the semiconductor layer 20 in the second area 21b of the photoelectric conversion area 21 is blocked by the first light blocking part 82a, arrival of light at the floating diffusion region FD can be suppressed, and the parasitic light sensitivity characteristics (PLS) can be enhanced.

In addition, the light blocking body 80I of this ninth embodiment includes the second light blocking part 82c that overlaps the in-pixel separation area 32 in the plan view and protrudes from the first light blocking part 82a to the inside of the semiconductor layer 20. For this reason, oblique light 5711 that has penetrated from the first area 21a side of the photoelectric conversion area 21 into the second area 21b is blocked by the second light blocking part 82c, the arrival of the oblique light 5711 at the floating diffusion region FD can be suppressed, and in combination with an effect of enhancement of the parasitic light sensitivity characteristics (PLS) using the first light blocking part 82a, further more enhancement of the parasitic light sensitivity characteristics (PLS) can be achieved.

In addition, the oblique light 7511 incident in the second light blocking part 82c of the light blocking body 80I from the first area 21a side is reflected on the second light blocking part 82c to return to the first area 21a, and thus improvement of the quantum efficiency QE can be achieved as well.

In addition, when described with reference to FIG. 29A, an effect of suppression of arrival of the oblique light 5711 at the floating diffusion region FD depends on (is in proportion to) an embedding length L₄ in which mainly the second light blocking part 82c is embedded inside of the semiconductor layer 20 out of an entire length L₃ with which the second light blocking part 82c protrudes from the first light blocking part 82a to a tip end protruding to the semiconductor layer 20.

On the other hand, a function of the in-pixel separation area 32 for assisting transmission of signal electric charge to the floating diffusion region FD as an assistance electrode is mainly in proportion to the length L₅ of the in-pixel separation area 32 in the Z direction.

Thus, for example, in a case in which a light blocking property is emphasized, it is preferable that the embedding length L₄ of the second light blocking part 82c be configured to be larger than the length L₅ of the in-pixel separation area 32 (L₄>L₅), and in a case in which transmission is emphasized, it is preferable that the length L₅ of the in-pixel separation area 32 be configured to be larger than the embedding length L₄ of the second light blocking part 82c (L₅>L₄).

In addition, in the ninth embodiment described above, although a case in which the present technology is applied to the solid-state imaging device 1I including the fixed charge film 52 has been described, the present technology can be also applied to a solid-state imaging device 1I not including a fixed charge film.

### 10th Embodiment

In this 10th embodiment, similar to the eighth embodiment described above, a light blocking body 80J will be mainly described.

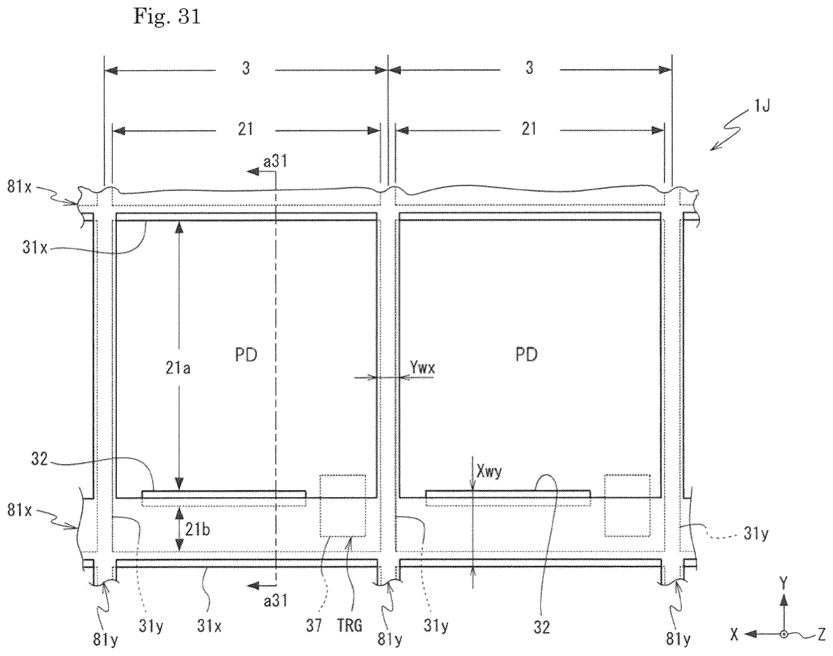

FIG. 31 is a plan view schematically illustrating a plane pattern of a light blocking body of a pixel array portion of a solid-state imaging device according to this 10th embodiment.

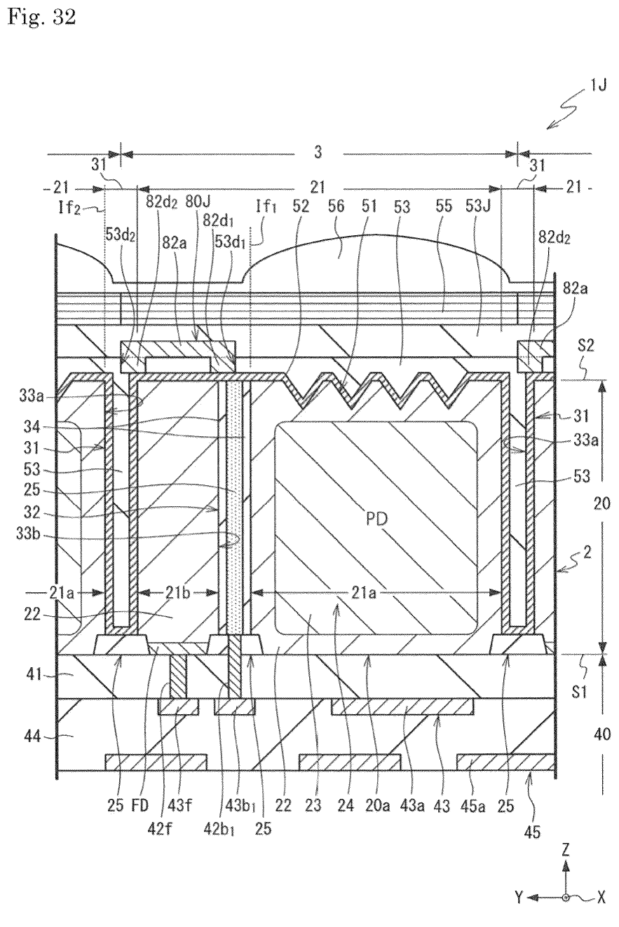

FIG. 32 is a longitudinal cross-sectional view schematically illustrating a longitudinal cross-sectional structure taken along line a31-a31 illustrated FIG. 31.

In addition, FIG. 31 is a plan view seen from a second face S2 side (a light incident face side) of a semiconductor layer 20 illustrated in FIG. 32. FIG. 32 is vertically inverted with respect to FIGS. 5 and 6 of the first embodiment described above.

### <<Configuration of Solid-state Imaging Device>>

The solid-state imaging device 1J according to the 10th embodiment of the present technology basically has a configuration similar to the solid-state imaging device 1A according to the first embodiment described above, and there are following different configurations.

In other words, as illustrated in FIGS. 31 and 32, the solid-state imaging device 1J according to the 10th embodiment of the present technology includes a light blocking body 80J in place of the light blocking film 54 of the above-described first embodiment illustrated in FIGS. 5 and 6. Relating to this light blocking body 80J, an insulating film 53J disposed between an insulating film 53 and a color filter 55 is further included. The other components are similar to those of the first embodiment as a whole, the same reference signs will be assigned to the same components, and duplicate description will be omitted.

As illustrated in FIGS. 31 and 32, the light blocking body 80J of this ninth embodiment is disposed on the second face S2 side of the semiconductor layer 20 and overlaps a second area 21b of a photoelectric conversion area 21 and a floating diffusion region FD in the plan view. The light blocking body 80J is disposed over the inside and outside of the insulating film 53 in a thickness direction (the Z direction) of the insulating film 53.

Although not illustrated in detail in FIG. 31, when described with reference to FIG. 17 of the eighth embodiment described above, similar to the light blocking body 80H of the eighth embodiment described above, the light blocking body 80J includes first linear parts 81x that extend in the X direction and are repeatedly disposed with a predetermined disposition pitch in the Y direction and second linear parts 81y that intersect these first linear parts 81x, extend in the Y direction, and are repeatedly disposed with a predetermined disposition pitch in the X direction. The first linear part 81x overlaps a first part 31x of the inter-pixel separation area 31 in the plan view, and the second linear part 81y overlaps a second part 31y of the inter-pixel separation area 31 in the plan view. In other words, also in the light blocking body 80J of this 10th embodiment, similar to the light blocking body 80H of the eighth embodiment described above, a lattice-shaped plane pattern in which a plane pattern in the plan view opens the light reception face side (the second face S2 side) of each of a plurality of photoelectric conversion areas 21 such that light incident in a predetermined photoelectric conversion area 21 does not leak into a nearby photoelectric conversion area 21 is formed. A width Xwy of the first linear part 81x in the Y direction is configured to be larger than a width Ywx of the second linear part 81y in the X direction.

As illustrated in FIGS. 31 and 32, the light blocking body 80J includes a first light blocking part 82a that is disposed on a side opposite to the semiconductor layer 20 side of the insulating film 53 and overlaps the second area 21b of the photoelectric conversion area 21 and the floating diffusion region FD in the plan view, a second light blocking part 82d₁ that overlaps the in-pixel separation area 32 in the plan view and protrudes from the first light blocking part 82a to the inside of the insulating film 53, and a third light blocking part 82d2 that overlaps the inter-pixel separation area 31 in the plan view and protrudes from the first light blocking part 82a to the inside of the insulating film 53. These first light blocking part 82a, second light blocking part 82d₁, and third light blocking part 82d2 are configured in the first linear part 81x. In other words, the first linear part 81x of this 10th embodiment includes the first to third light blocking parts 82a, 82d₁, and 82d2.

As illustrated in FIG. 32, the first light blocking part 82a of the light blocking body 80J is covered with an insulating film 53J disposed on a side opposite to the semiconductor layer 20 side of the insulating film 53. In other words, the light blocking body 80J is included in an insulating layer that includes the insulating films 53 and 53J. The insulating film 53J, for example, is composed of a silicon oxide film.

As illustrated in FIG. 32, the second light blocking part 82d₁ of the light blocking body 80J is disposed in a dug part 53d₁ of the insulating film 53. The third light blocking part 82d2 of the light blocking body 80J is disposed in a dug part 53d2 of the insulating film 53. The second light blocking part 82d₁ and the dug part 53d₁ and the third light blocking part 82d2 and the dug part 53d2 are disposed to be separate from each other in a disposition direction (the Y direction) of the first area 21a and the second area 21b of the photoelectric conversion area 21.

As illustrated in FIG. 32, each of the first light blocking part 82a, the second light blocking part 82d₁, and the third light blocking part 82d2 of the light blocking body 80J is positioned on a second area 21b side of the first area 21a in the disposition direction (the Y direction) of the first area 21a and the second area 21b of the photoelectric conversion area 21. More specifically, each of the first light blocking part 82a and the second light blocking part 82d₁ is positioned on a second area 21b side of an interface part If₁ between the first area 21a and the in-pixel separation area 32 in the plan view, and each of the first light blocking part 82a and the third light blocking part 82d2 is positioned on a second area 21b side of an interface part If₂ between the inter-pixel separation area 31 between two photoelectric conversion areas 21 adjacent to each other in the Y direction and the first area 21a brought into contact with this inter-pixel separation area 31. In other words, the light blocking body 80J overlaps each of the in-pixel separation area (the second separation area) 32 and the inter-pixel separation area (the first separation area) 31 in the plan view and is positioned on the second area 21b side of the first area 21a of the photoelectric conversion area 21 in the disposition direction (the Y direction) of the first area 21a and the second area 21b of the photoelectric conversion area 21.

In FIG. 31, although not illustrated in detail, similar to the second light blocking parts 82b and 82c of the eighth and ninth embodiments described above, each of the second and third light blocking parts 82d₁ and 82d₂ extends also in the X direction together with the in-pixel separation area 32 in the plan view. It is preferable that a length of each of the second and third light blocking parts 82d₁ and 82d₂ in the X direction be equivalent to a length of the in-pixel separation area 32 in the X direction or be larger than the length of the in-pixel separation area 32 in the X direction. In this eighth embodiment, the length of each of 82d₁ and 82d₂ in the X direction is larger than the in-pixel separation area 32 in the X direction.

The first light blocking part 82a, mainly, in the second area 21b of the photoelectric conversion area 21, blocks light in an outer part of a side opposite to the semiconductor layer 20 side of the insulating film 53 and suppresses arrival of light at the floating diffusion region FD disposed on the first face S1 side of the semiconductor layer 20. On the other hand, the second and third light blocking parts 82d₂ and 82d₃ block light in an inner part of the insulating film 53 and suppresses arrival of light at the floating diffusion region FD disposed on the first face S1 side of the semiconductor layer 20.

In other words, the light blocking body 80J blocks light penetrating into (incident in) the second area 21b of the photoelectric conversion area 21 on the second face S2 side of the semiconductor layer 20 and suppresses arrival of light at the floating diffusion region FD disposed on the first face S1 side of the semiconductor layer 20 inside the second area 21b of the photoelectric conversion area 21.

As the light blocking body 80J, it is preferable to use a metal film of, for example, titanium (Ti), tungsten (W), aluminum (Al), or the like or an alloy film having a superior light blocking property and having an optical reflectance higher than a silicon oxide film or a silicon film. In this 10th embodiment, as the light blocking body 80J, for example, a tungsten (W) film is used.

Here, in this 10th embodiment, the inter-pixel separation area 31 corresponds to “first separation area” of the present technology, and the in-pixel separation area 32 corresponds to “second separation area” of the present technology. In addition, in this 10th embodiment, the disposition direction of the first area 21a and the second area 21b of the photoelectric conversion area 21 corresponds to “one direction” of the present technology.

As illustrated in FIG. 31, the light blocking body 80J extends over two photoelectric conversion areas 21 that are adjacent to each other in the X direction inside a two-dimensional plane but is not limited thereto. The first light blocking part 82a continuously extends over two photoelectric conversion areas 21 that are adjacent to each other in the X direction as well.

### <<Method of Manufacturing Solid-state Imaging Device>>

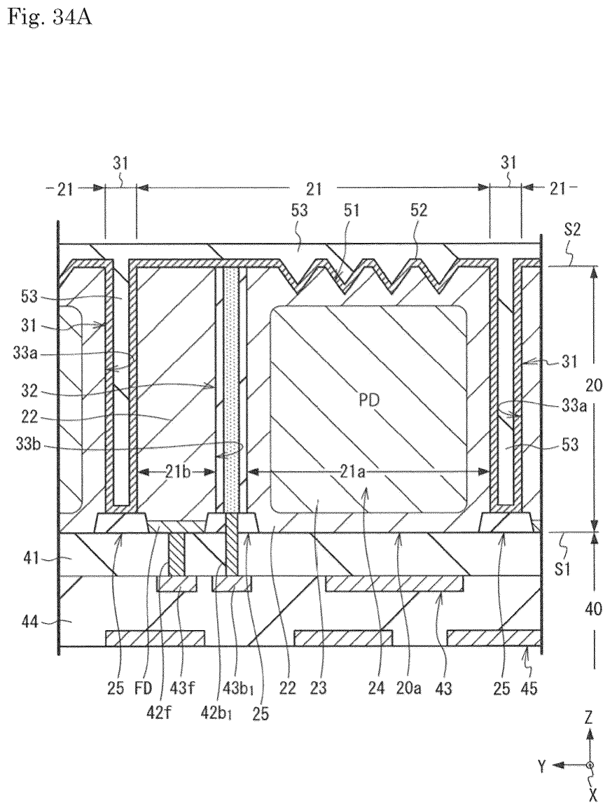

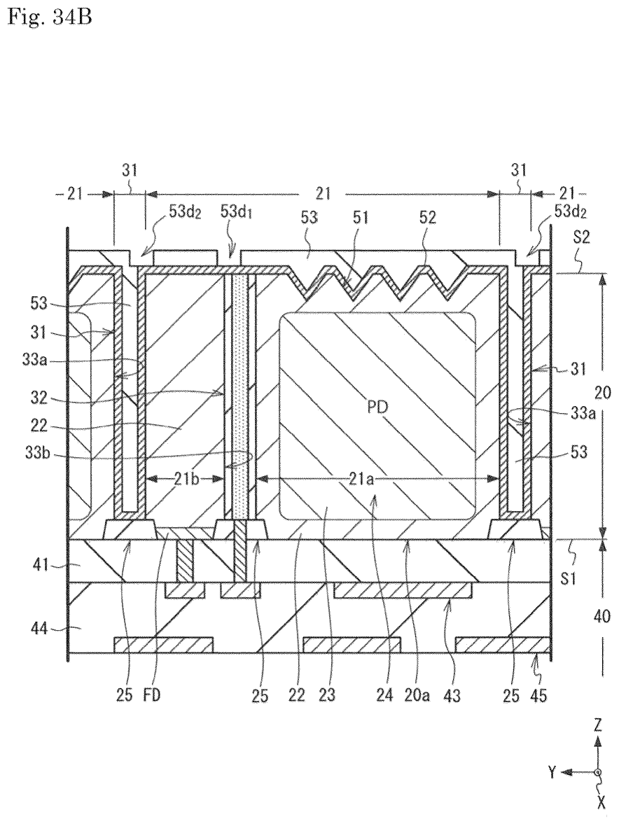

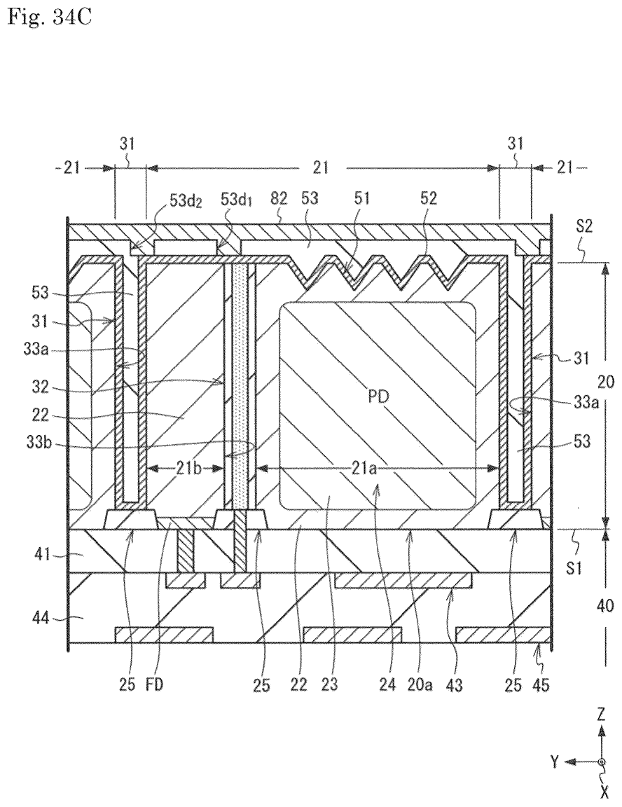

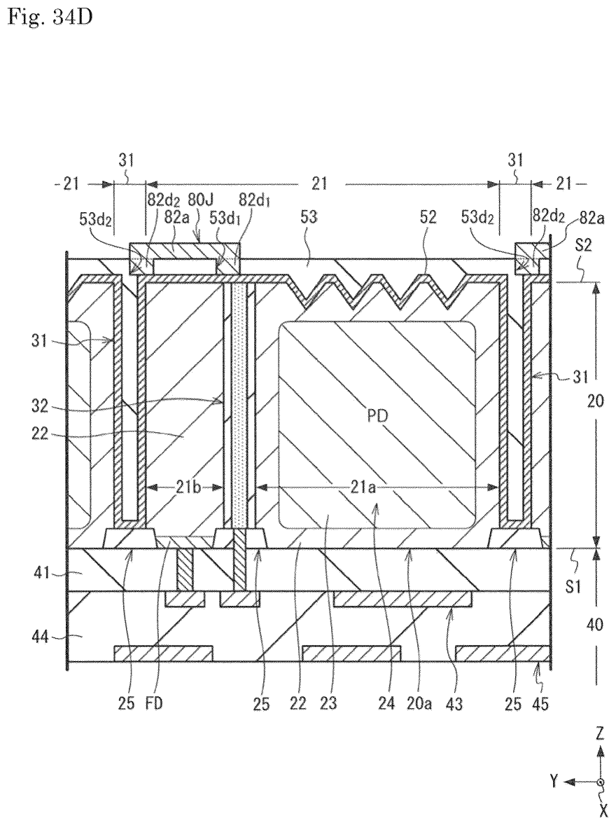

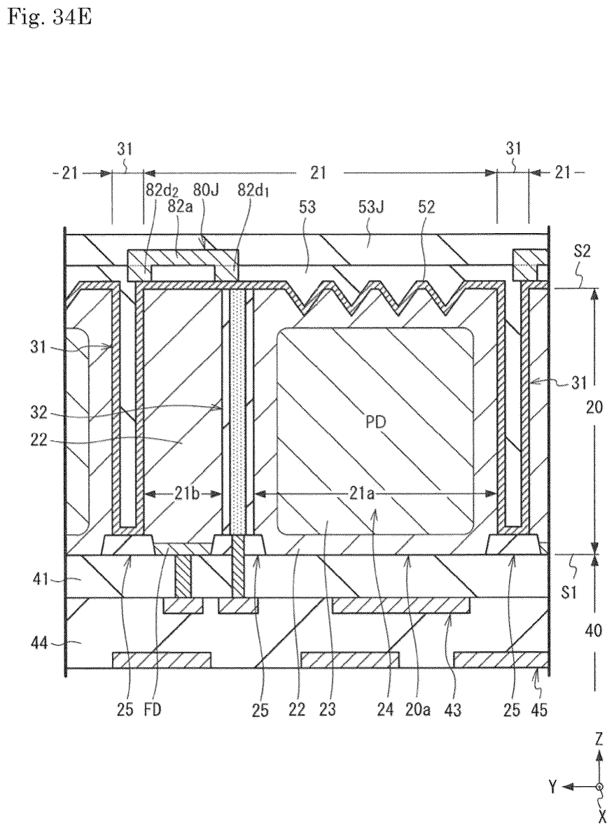

Next, a method of manufacturing the solid-state imaging device 1J according to the 10th embodiment of the present technology will be described with reference to FIGS. 34A to 34E. Also in this eighth embodiment, manufacturing of the light blocking body 80I included in the method of manufacturing the solid-state imaging device 1I will be particularly described.

First, processes similar to those of the eighth embodiment described above are performed, and, as illustrated in FIG. 34A, components up to the insulating film 53 are formed.

Next, as illustrated in FIG. 34B, in the insulating film 53, a dug part 53d₁ overlapping the in-pixel separation area 32 in the plan view and a dug part 53d₂ overlapping the inter-pixel separation area 31 in the plan view are formed. Each of the dug parts 53d₁ and 53d₂ is formed by selectively etching the insulating film 53 using a known photolithographic technology and an anisotropic dry etching technology. Each of the dug parts 53d₁ and 53d₂ is formed to be positioned on the second area 21b side of the first area 21a of the photoelectric conversion area 21.

Next, after each of the dug parts 53d₁ and 53d₂ is formed, as illustrated in FIG. 34C, a light blocking film 82 is formed on the entire face on the insulating film 53 including an inner part of each of the dug parts 53d₁ and 53d₂. The light blocking film 82, for example, can be formed by forming a metal film of titanium (Ti), tungsten (W), aluminum (Al), or the like or an alloy film having an optical reflectance to be higher than a silicon oxide film or a silicon film using a known film formation technology. The light blocking film 82 is formed over a plurality of photoelectric conversion areas 21 and is formed to embed the dug parts 53d₁ and 53d₂ of each of the photoelectric conversion areas 21.

Next, after the light blocking film 82 is formed, by patterning the light blocking film 82, as illustrated in FIG. 34D, a light blocking body 80J that covers the second area 21b of the photoelectric conversion area 21 and extends over the inside and outside of the insulating film 53 of the second face S2 side of the semiconductor layer 20 is formed. The patterning of the light blocking film 82 can be performed using a known photolithographic technology and an anisotropic dry etching technology.

In this process, the light blocking body 80J includes a first light blocking part 82a that is disposed on a side opposite to the semiconductor layer 20 side of the insulating film 53 and overlaps the second area 21b of the photoelectric conversion area 21 in the plan view, a second light blocking part 82d₁ that overlaps the in-pixel separation area 32 in the plan view and protrudes from the first light blocking part 82a to the inside of the insulating film 53, and a third light blocking part 82d₂ that overlaps the inter-pixel separation area 31 in the plan view and protrudes from the first light blocking part 82a to the inside of the insulating film 53. When described with reference to FIG. 17, the light blocking body 80J includes first linear parts 81x that extend in the X direction and are repeatedly disposed with a predetermined disposition pitch in the Y direction and second linear parts 81y that extend in the Y direction with intersecting the first linear parts 81x and are repeatedly disposed with a predetermined disposition pitch in the X direction. The light blocking body 80J is formed in a lattice-shaped plane pattern overlapping the lattice-shaped plane pattern of the inter-pixel separation area 31 in the plan view. The first light blocking part 82a, the second light blocking part 82d₁, and the third light blocking part 82d₂ are formed in the first linear part 81x.

Next, after the light blocking body 80J is formed, as illustrated in FIG. 34E, on a side opposite to the semiconductor layer 20 side of the insulating film 53, an insulating film 53J covering the light blocking body 80J is formed.

Thereafter, on a side opposite to the semiconductor layer 20 side of the insulating film 53J, by forming a color filter 55, a microlens 56, and the like in this order, a state illustrated in FIGS. 31 and 32 is formed.

In addition, also in the solid-state imaging device 1J according to this 10th embodiment, by dividing a semiconductor wafer including the semiconductor layer 20 and the multilayer wiring layer 40 for each chip formation area, the state of the semiconductor chip 2 illustrated in FIG. 1 is formed.

### <Function of Light Blocking Body>

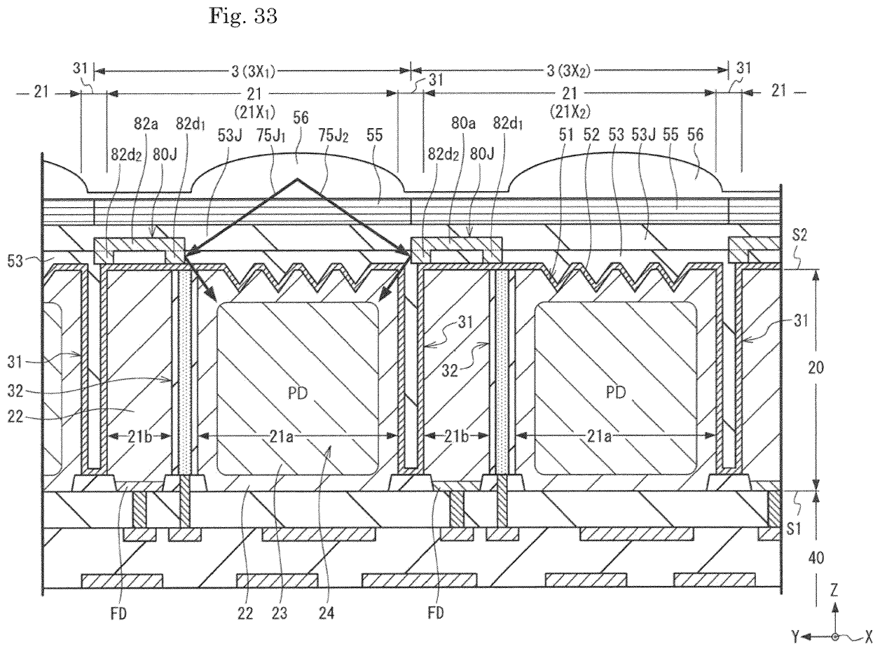

Next, the function of the light blocking body 80J will be described with reference to FIGS. 33 and 6.

As illustrated in FIG. 33, in one photoelectric conversion area 21 (one pixel 3), oblique light 57J₁ is radially emitted from the microlens 56 is transmitted through the color filter 55, the insulating film 53J, and the insulating film 53, and reaches (is emitted to) the second light blocking part 82d₁ of the light blocking body 80J. Then, the oblique light 57J₁ that has reached the second light blocking part 82d₁ is reflected on the second light blocking part 82d₁ and penetrates into the first area 21a (the photoelectric conversion unit 24 (PD)) of the photoelectric conversion area 21 from the second face S2 side of the semiconductor layer 20. In other words, the light blocking body 80J of this 10th embodiment blocks the oblique light 57J₁ penetrating into the second area 21b of the photoelectric conversion area 21 from the periphery of the first light blocking part 82a of the light blocking body 80J using the second light blocking part 82d₁ and can suppress arrival of the oblique light 57J₁ at the floating diffusion region FD.

Here, when described with reference to the light blocking film 54 of the above-described first embodiment illustrated in FIG. 5, as illustrated in FIG. 5, by configuring the light blocking film 54 to have a first protrusion structure penetrating from the second area 21b side of the photoelectric conversion area 21 into the first area 21a side in the plan view, oblique light penetrating from the periphery of the light blocking film 54 to the second area 21b of the photoelectric conversion area 21 can be blocked.

However, in a case in which the light blocking film 54 is configured to have the first protrusion structure described above, the amount of light penetrating into the first area 21a of the photoelectric conversion area 21 decreases, and the quantum efficiency QE becomes low.

In contrast to this, the light blocking body 80J of this 10th embodiment can block oblique light 57J₁ penetrating into the second area 21b of the photoelectric conversion area 21 from the periphery of the first light blocking part 82a using the second light blocking part 82d₁ protruding from the first light blocking part 82a to the inside of the insulating film 53, and thus, unlike the light blocking film 54 illustrated in FIG. 5, the first light blocking part 82a does not need to have a first protrusion structure. Thus, the light blocking body 80J of this 10th embodiment can block oblique light 57J₁ penetrating into the second area 21b of the photoelectric conversion area 21 from the periphery of the first light blocking part 82d₂ while securing the amount of light penetrating into the first area 21a (the photoelectric conversion unit 24 (PD)) of the photoelectric conversion area 21.

In addition, the oblique light 75J1 that has reached the second light blocking part 82d₁ of the light blocking body 80J is reflected on this second light blocking part 82d₁ and penetrates into the first area 21a, and thus improvement of the quantum efficiency QE can be achieved as well.

In addition, as illustrated in FIG. 33, in two pixels 3 (3X₁ and 3X₂) that are adjacent to each other in the Y direction, oblique light 57J₂ radially emitted from the microlens 56 of one pixel 3X₁ is transmitted through the color filter 55, the insulating film 53J, and the insulating film 53 and reaches (is emitted to) the third light blocking part 82d₂ of the light blocking body 80J of the other pixel 3X₂. Then, the oblique light 57J₂ that has reached the third light blocking part 82d₂ of the light blocking body 80J of the other pixel 3X₂ is reflected on this second light blocking part 82d₂ and penetrates into the first area 21a (the photoelectric conversion unit 24 (PD)) of the photoelectric conversion area 21 of one pixel 3X₁ from the second face S2 side of the semiconductor layer 20. In other words, the light blocking body 80J of this 10th embodiment, oblique light 57J₂ penetrating into the second area 21b of the photoelectric conversion area 21 of the other pixel 3X₂ from one pixel 3X₁ is blocked using the third light blocking part 82d₂ and can suppress arrival of the oblique light 57J₂ at the floating diffusion region FD.

Here, when described with reference to the light blocking film 54 of the above-described first embodiment illustrated in FIG. 5, as illustrated in FIG. 5, in two pixels 3 (3X₁ and 3X₂) that are adjacent to each other in the Y direction, by configuring a second protrusion structure in which the light blocking film 54 of the other pixel 3X₂ protrudes from the second area 21b side of the photoelectric conversion area 21 of the other pixel 3X₂ to the first area 21a side of the photoelectric conversion area 21 of one pixel 3X₁ in the plan view, oblique light penetrating from the one pixel 3X₁ to the second area 21b of the photoelectric conversion area 21 of the other pixel 3X₂ can be blocked.

However, in a case in which the light blocking film 54 of the other pixel 3X₂ is configured to have the second protrusion structure described above, similar to the case of the first protrusion structure described above, the amount of light penetrating into the first area 21a (the photoelectric conversion unit 24 (PD)) of the photoelectric conversion area 21 of one pixel 3X₁ decreases, and the quantum efficiency QE becomes low.

In contrast to this, by using the third light blocking part 82d₂ protruding from the first light blocking part 82a to the inside of the insulating film 53, in two pixels 3 (3X₁ and 3X₂) that are adjacent to each other in the Y direction, oblique light 57J₂ penetrating from one pixel 3X₁ into the second area 21b of the photoelectric conversion area 21 of the other pixel 3X₂ can be blocked, and thus, unlike the light blocking film 54 illustrated in FIG. 5, the light blocking body 80J of this 10th embodiment does not need to be configured to have the second protrusion structure. Thus, the light blocking body 80J of this 10th embodiment can suppress the oblique light 57J₂ penetrating from one pixel 3X₁ into the second area 21b of the photoelectric conversion area 21 of the other pixel 3X₂ while securing the amount of light penetrating into the first area 21a (the photoelectric conversion unit 24 (PD)) of the photoelectric conversion area 21 of the one pixel 3X₁.

In addition, the oblique light 75J₂ that has reached the third light blocking part 82d₂ of the light blocking body 80J of the other pixel 3X₂ from one pixel 3X₁ is reflected on this third light blocking part 82d₂ and penetrates into the first area 21a of the photoelectric conversion area 21 of the one pixel 3X₁, and thus improvement of the quantum efficiency QE of the one pixel 3X₁ can be achieved as well.

As above, it is preferable that each of the first light blocking part 82a, the second light blocking part 82d₁, and the third light blocking part 82d₂ of the light blocking body 80J overlap the second area 21b of the photoelectric conversion area 21 in the plan view in the disposition direction (the Y direction) of the first area 21a and the second area 21b of the photoelectric conversion area 21 and be positioned on the second area 21b side of the first area 21a of the photoelectric conversion area 21.

In addition, since the oblique light 57J₁ and 57J₂ can penetrate into the second area 21b of the photoelectric conversion area 21 more easily in proportion to the film thickness of the insulating film 53, in the case of the light blocking film 54 illustrated in FIG. 5, a width of a portion overlapping the first area 21a of the photoelectric conversion area 21 in the plan view in the Y direction needs to be enlarged in accordance with the film thickness of the insulating film 53.

In contrast to this, in the case of the light blocking body 80J of this first embodiment, by changing a length (a height, a depth) of each of the second light blocking part 82d₁ and the third light blocking part 82d₂ in the Z direction in accordance with the film thickness of the insulating film 53, penetration of the oblique light 57J₁ and 57J₂ into the second area 21a of the photoelectric conversion area 21 can be suppressed without intervening penetration of light into the first area 21a (the photoelectric conversion unit 24 (PD)) of the photoelectric conversion area 21.

### Main Effects of 10th Embodiment

Next, the main effects of this 10th embodiment will be described.

Similar to the solid-state imaging device 1A according to the first embodiment described above, the solid-state imaging device 1J according to this 10th embodiment includes the inter-pixel separation area 31 and the in-pixel separation area 32. Thus, also in the solid-state imaging device 1J according to this 10th embodiment, similar to the solid-state imaging device 1A according to the first embodiment described above, improvement of the quantum efficiency QE as a pixel characteristic and mixed color suppression (MTF) can be achieved, and improvement of transmission characteristics as pixel characteristics can be achieved.

In addition, the light blocking body 80J of this 10th embodiment includes the first light blocking part 82a that is disposed on a side opposite to the semiconductor layer 20 side of the insulating film 53 and overlaps the in-pixel separation area 32 in the plan view. For this reason, similar to the solid-state imaging device 1A of the first embodiment described above, light penetrating into the second area 21b from the second face S2 side (the light incident face side) of the semiconductor layer 20 in the second area 21b of the photoelectric conversion area 21 is blocked using the first light blocking part 82a, and arrival of light at the floating diffusion region FD disposed in the second area 21b can be suppressed, whereby the parasitic light sensitivity characteristics (PLS) can be enhanced.

In addition, the light blocking body 80J of this 10th embodiment includes the second light blocking part 82d₁ that overlaps the in-pixel separation area 32 in the plan view and protrudes from the first light blocking part 82a to the inside of the insulating film 53. For this reason, the oblique light 57J₁ penetrating into the second area 21b of the photoelectric conversion area 21 from the periphery of the first light blocking part 82a of the light blocking body 80J is blocked using the second light blocking part 82d₁, and arrival of the oblique light 57J₁ at the floating diffusion region FD disposed in the second area 21b can be suppressed, and in combination with the effect of enhancement of the parasitic light sensitivity characteristics according to the first light blocking part 82a, further enhancement of the parasitic light sensitivity characteristics (PLS) can be achieved.

In addition, the oblique light 75a that has reached the second light blocking part 82d₁ of the light blocking body 80J is reflected on this second light blocking part 82d₁ and penetrates into the first area 21a (the photoelectric conversion unit 24 (PD)), whereby improvement of the quantum efficiency QE can be achieved as well.

In addition, the light blocking body 80J of this 10th embodiment includes the third light blocking part 82d₂ that overlaps the inter-pixel separation area 31 in the plan view and protrudes from the first light blocking part 82a to the inside of the insulating film 53. For this reason, in two pixels 3 (3X₁ and 3X₂) that are adjacent to each other in the Y direction, oblique light 57J₂ penetrating from one pixel 3X₁ into the second area 21b of the photoelectric conversion area 21 of the other pixel 3X₂ is blocked using the third light blocking part 82d₂, and arrival of oblique light 57J₁ at the floating diffusion region FD disposed in the second area 21b of the photoelectric conversion area 21 of the other pixel 3X₂ can be suppressed, and in combination with the mixed color suppression effect according to reflection of light on the inter-pixel separation area 31, further more mixed color suppression can be achieved.

In addition, since the oblique light 57J₂ that has reached the third light blocking part 82d₂ of the light blocking body 80J of the other pixel 3X₂ from one pixel 3X₁ is reflected on this third light blocking part 82d₂ and penetrates into the first area 21a (the photoelectric conversion unit 24 (PD)) of the photoelectric conversion area 21 of the one pixel 3X₁, further more improvement of the quantum efficiency QE can be achieved as well.

Furthermore, in the 10th embodiment described above, although a case in which the present technology is applied to the solid-state imaging device 1J including the fixed charge film 52 has been described, the present technology can be applied also to a solid-state imaging device 1J not including the fixed charge film.

### 11th Embodiment

In this 11th embodiment, a light reflecting body 85K will be mainly described.

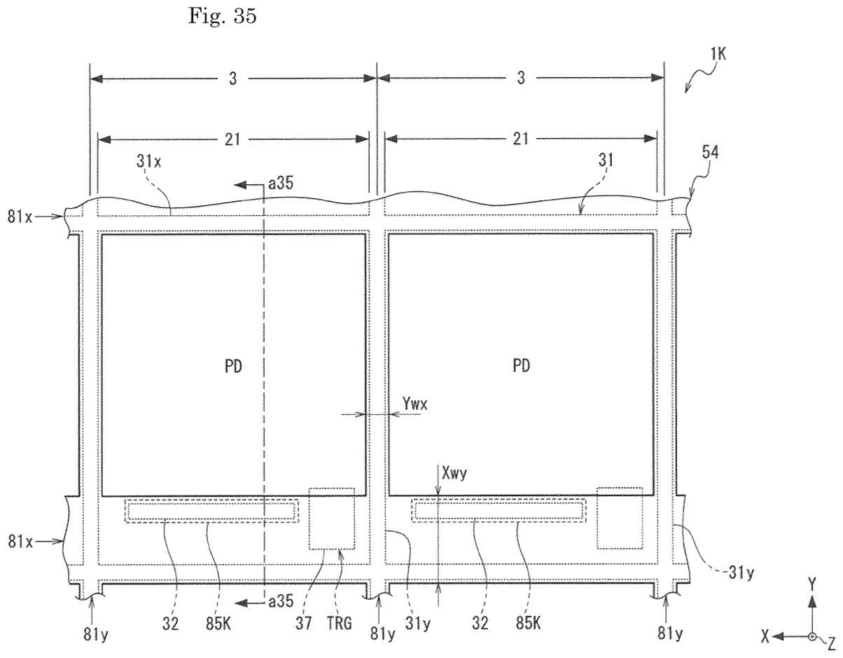

FIG. 35 is a plan view schematically illustrating a plane pattern of a light blocking body and a light reflecting body of a pixel array portion of a solid-state imaging device according to this 11th embodiment.

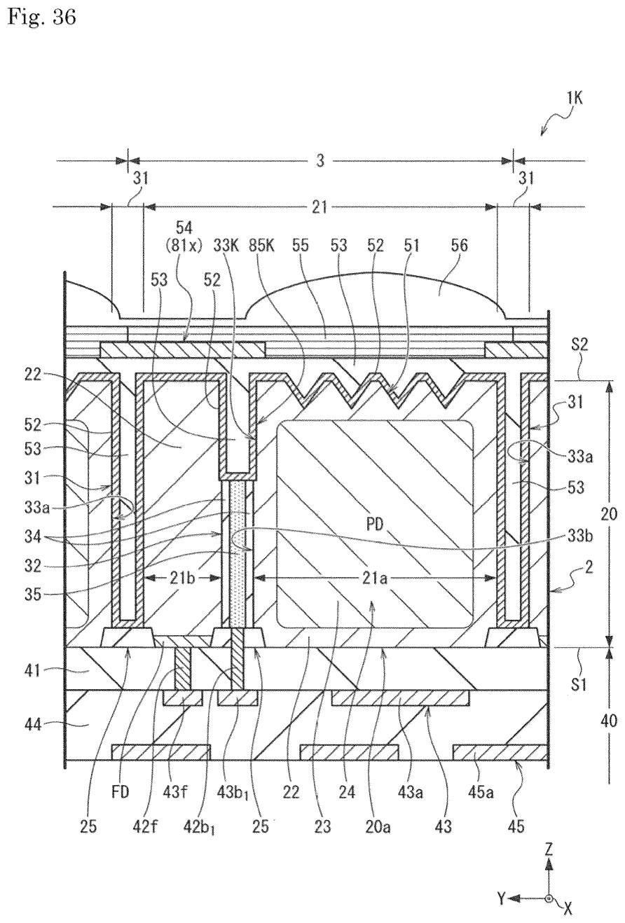

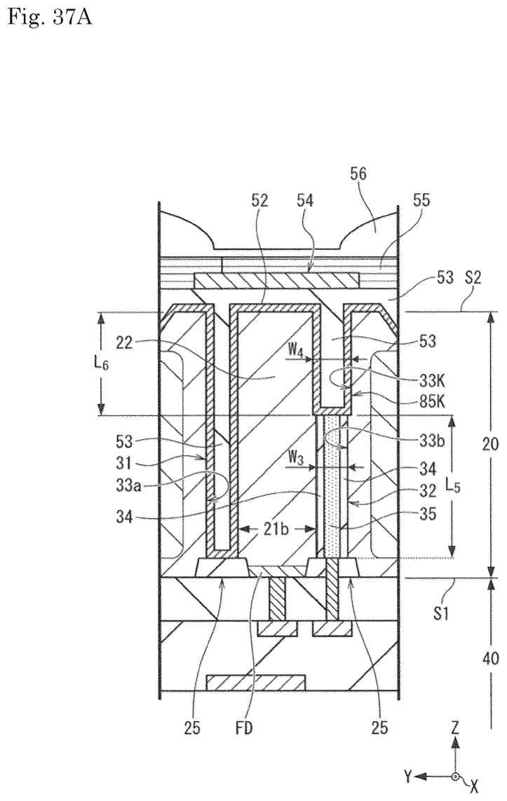

FIG. 36 is a longitudinal cross-sectional view schematically illustrating a longitudinal cross-sectional structure taken along line a35-a35 illustrated FIG. 35.

In addition, FIG. 35 is a plan view seen from the second face S2 side (the light incident face side) of the semiconductor layer 20 illustrated in FIG. 36. FIG. 36 is vertically inverted with respect to FIGS. 5 and 6 of the first embodiment described above.

### <<Configuration of Solid-state Imaging Device>>

A solid-state imaging device 1K according to the 11th embodiment of the present technology basically has a configuration similar to the solid-state imaging device 1A according to the first embodiment described above, and there are differences in the following configurations.

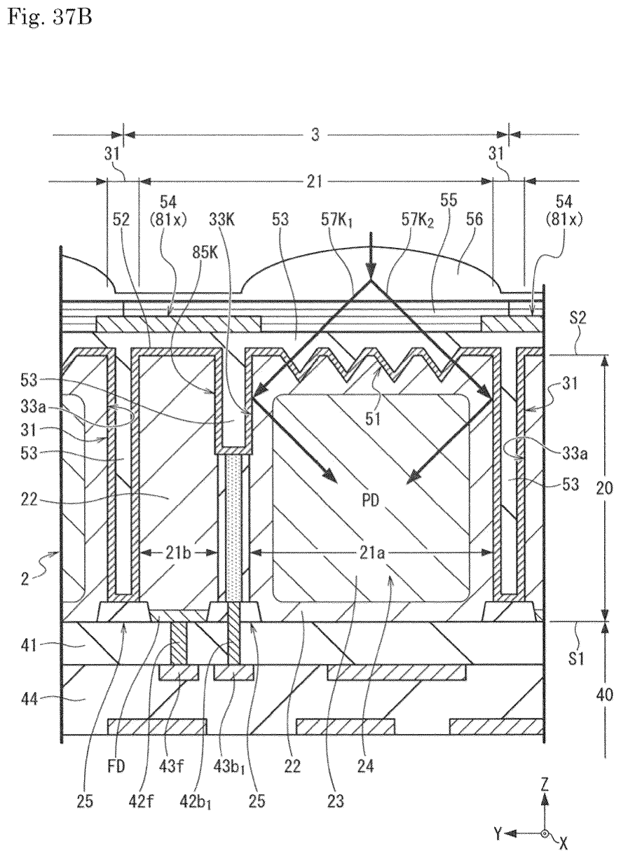

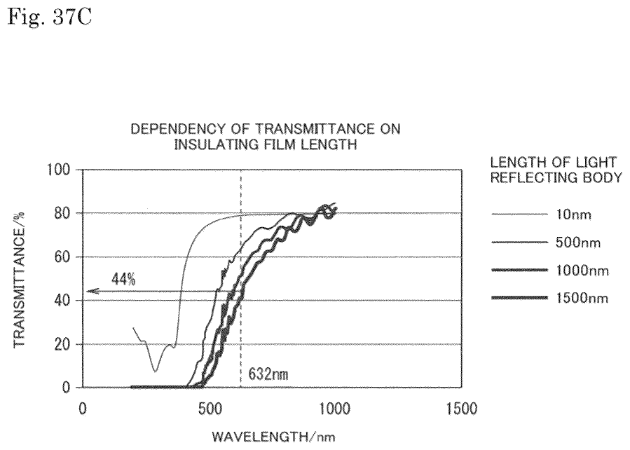

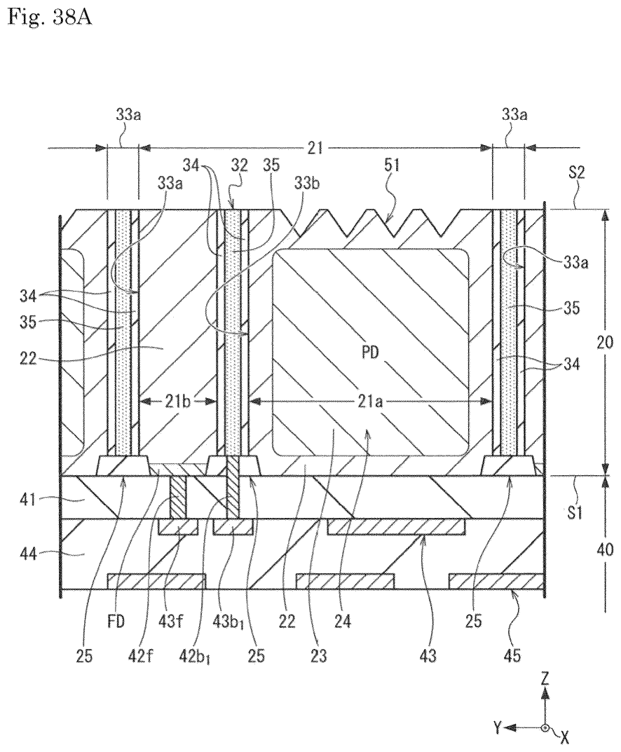

In other words, as illustrated in FIGS. 35 and 36, the solid-state imaging device 1K according to the 11th embodiment of the present technology further includes the light reflecting body 85K that is disposed to overlap an in-pixel separation area 32 in the plan view on a second face S2 side of the semiconductor layer 20 and has a refractive index lower than the semiconductor layer 20. Relating to this light reflecting body 85K, a length L₅ (see FIG. 37A) of the in-pixel separation area 32 in the Z direction is shorter than a length of an inter-pixel separation area 31 in the Z direction. In other words, the in-pixel separation area 32 of this 11th embodiment has a length L₅ extending from the first face S1 side of the semiconductor layer 20 to the second face S2 side to be shorter than that of the in-pixel separation area 32 of the above-described first embodiment illustrated in FIGS. 5 and 6. The other components are similar to those of the first embodiment as a whole, the same reference signs will be assigned to the same components, and duplicate description will be omitted.

As illustrated in FIG. 36, the light reflecting body 85K includes an insulating film 53 that is disposed inside a dug part 33K as a third dug part, which extends from the second face S2 side of the semiconductor layer 20 toward the in-pixel separation area 32, through a fixed charge film 52. As the insulating film 53, for example, a silicon oxide film can be used. The silicon oxide film has a refractive index lower than a semiconductor material such as Si, SiGe, InGaAs, or the like.

The fixed charge film 52 is disposed over a dug part 33a, the second face S2 of the semiconductor layer 20, and the dug part 33K. The fixed charge film 52 in the dug part 33K is disposed along an inner face (a side wall and a bottom wall) of the inside of the dug part 33K.

Here, inside the dug part 33K, a film thickness of the fixed charge film 52 is very small relative to the film thickness of the insulating film 53. In FIG. 36, in order to allow easy understanding of the configuration of the fixed charge film 52, the film thickness of the fixed charge film is drawn to be larger than an actual ratio. Thus, the insulating film 53 and the fixed charge film 52 can be regarded altogether as the light reflecting body 85K.

The fixed charge film 52, for example, includes a film of hafnium oxide (HfO₂), zirconium oxide (ZrO₂), tantalum oxide (Ta₂O₅), or the like as a dielectric film that generates negative fixed charge. Such a dielectric film has a refractive index lower than a semiconductor material such as Si, SiGe, InGaAs, or the like. Thus, also from this point, the insulating film 53 and the fixed charge film 52 can be regarded altogether as the light reflecting body 85K.

In addition, as one example, for example, in the case of light of a wavelength of 940 nm, silicon, for example, has a refractive index of about 3.62, silicon oxide, for example, has a refractive index of about 1.45, and the air, for example, has a refractive index of about 1.00.

In addition, as another example, for example, in the case of light of a wavelength of 550 nm, silicon, for example, has a refractive index of about 4.08, silicon oxide, for example, has a refractive index of about 1.46, and the air, for example, has a refractive index of about 1.00.

As illustrated in FIG. 37A, the in-pixel separation area 32 of this 11th embodiment has a length L₅ in the Z direction along the thickness direction of the semiconductor layer 20 to be shorter than a length of the inter-pixel separation area 31 in the Z direction. In addition, the length L₅ of the in-pixel separation area 32 of this 11th embodiment in the Z direction is shorter than the length of the in-pixel separation area 32 of the first embodiment described above in the Z direction. The in-pixel separation area 32 of this 11th embodiment extends from the element separation area 25 of the first face S1 side of the semiconductor layer 20 toward the second face S2 side and is separate from the second face S2 of the semiconductor layer 20.

As illustrated in FIG. 37A, the dug part 33K and the light reflecting body 85K extend from the second face S2 of the semiconductor layer 20 towards a tip end of the in-pixel separation area 32 and reaches at the tip end of the in-pixel separation area 32. In this 11th embodiment, the light reflecting body 85K and the in-pixel separation area 32 end at a position at which tip ends thereof are in contact with each other inside the semiconductor layer 20.

Here, as illustrated in FIG. 37A, the in-pixel separation area 32 of this 11th embodiment extends from the element separation area 25 over the dug part 33K. The length L₅ of the in-pixel separation area 32 of this case is a distance from the bottom face of the element separation area 25 to the dug part 33K. Although not illustrated in the drawing, in a case in which the in-pixel separation area 32 extends over the dug part 33i from the first face S1 of the semiconductor layer 20, a distance from the first face S1 of the semiconductor layer 20 to the dug part 33i becomes the length L₅ of the in-pixel separation area 32.

In addition, a face of the semiconductor layer 20 that is brought into contact with the bottom face of the element separation area (a field separation area) 25 may be regarded as the first face S1.

As illustrated in FIG. 37A, the in-pixel separation area 32 and the dug part 33K have different widths (W₃ and W₄) thereof in a direction (the Y direction) along the disposition direction (one direction) of the first area 21a and the second area 21b of the photoelectric conversion area 21. In this 11th embodiment, the width W₄ of the dug part 33K is configured to be larger than the width W₃ of the in-pixel separation area 32, the width W₃ of the in-pixel separation area 32 may be configured to be larger than the width W₄ of the dug part 33K. In other words, from the point of view of patterning accuracy and characteristics, it is preferable to satisfy “W₄>W₃” or “W₄<W₃”.

Although not illustrated in detail in FIG. 35, when described with reference to FIG. 17 of the eighth embodiment described above, similar to the light blocking body 80H of the eighth embodiment described above, the light blocking film 54 includes first linear parts 81x that extend in the X direction and are repeatedly disposed with a predetermined disposition pitch in the Y direction and second linear parts 81y that extend in the Y direction with intersecting the first linear parts 81x and are repeatedly disposed with a predetermined disposition pitch in the X direction. The first linear part 81x overlaps the first part 31x of the inter-pixel separation area 31 in the plan view, and the second linear part 81y overlaps the second part 31y of the inter-pixel separation area 31 in the plan view. In other words, similar to the light blocking body 80H of the eighth embodiment described above, also in the light blocking film 54 of this 11th embodiment, a lattice-shaped plane pattern in which a plane pattern in the plan view opens the light reception face side (the second face S2 side) of each of a plurality of photoelectric conversion areas 21 such that light incident in a predetermined photoelectric conversion area 21 does not leak into a nearby photoelectric conversion area 21 is formed. A width Xwy of the first linear part 81x in the Y direction is configured to be larger than a width Ywx of the second linear part 81y in the X direction.

As illustrated in FIG. 36, the light blocking film 54 is disposed on a side opposite to the semiconductor layer 20 side of the insulating film 53 and overlaps the in-pixel separation area 32 in the plan view. In addition, the light blocking film 54, in the photoelectric conversion area 21, is disposed to cover the second area 21b between the inter-pixel separation area 31 and the in-pixel separation area 32 in the plan view, more specifically, the well region 22 of the p type and the floating diffusion region FD. In other words, the floating diffusion region FD is disposed at a position overlapping the light blocking film 54 in the plan view. As this light blocking film 54, for example, a tungsten (W) film having a light blocking property is used.

Here, in this 11th embodiment, the inter-pixel separation area 31 corresponds to one specific example of “first separation area” of the present technology, and the in-pixel separation area 32 corresponds to one specific example of “second separation area” of the present technology. In addition, in this 11th embodiment, the dug part 33a, the dug part 33b, and the dug part 33K respectively correspond to specific examples of “first dug part”, “second dug part”, and “third dug part” of the present technology. Furthermore, in this 11th embodiment, the disposition direction of the first area 21a and the second area 21b of the photoelectric conversion area 21 corresponds to one specific example of “one direction” of the present technology, and the light blocking film 54 corresponds to one specific example of “light blocking body”.

### <<Method of Manufacturing Solid-state Imaging Device>>

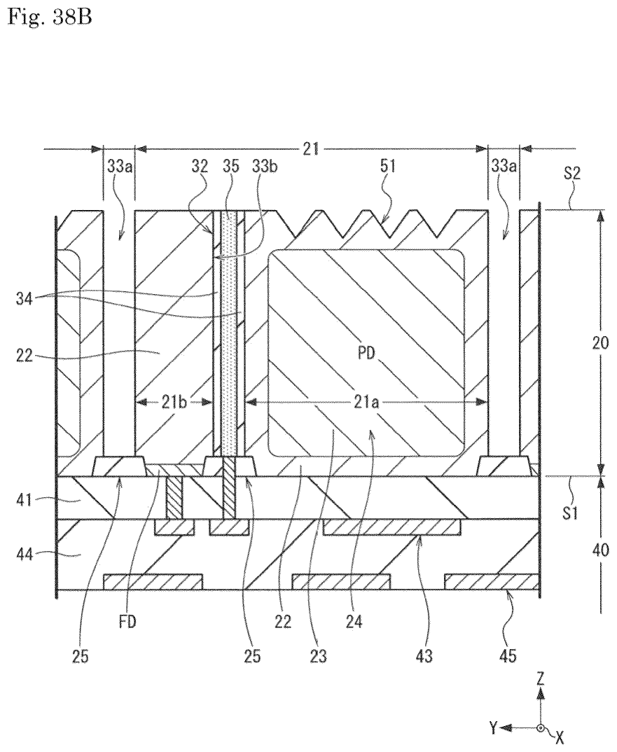

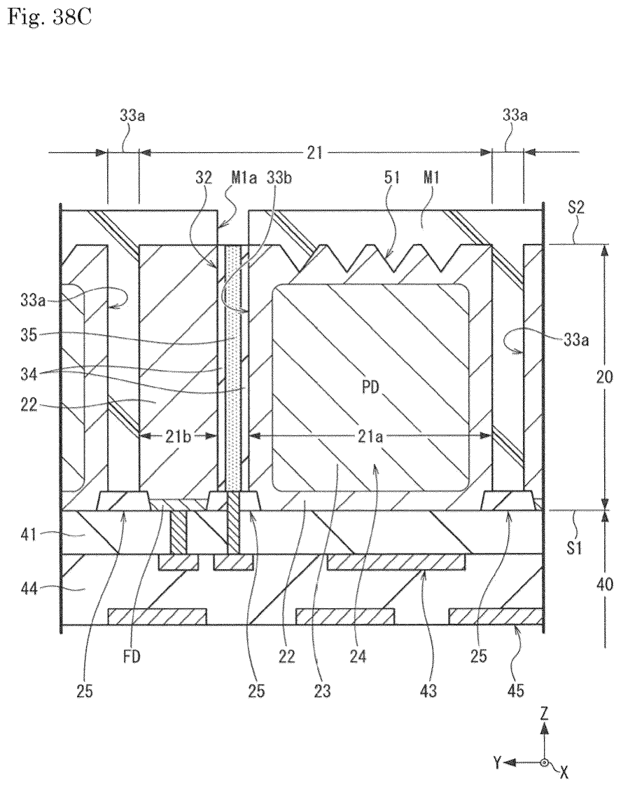

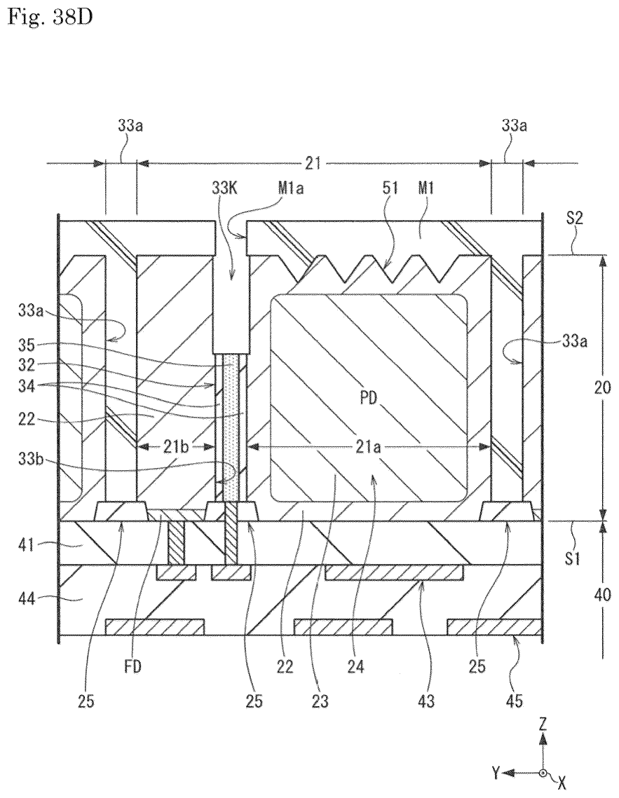

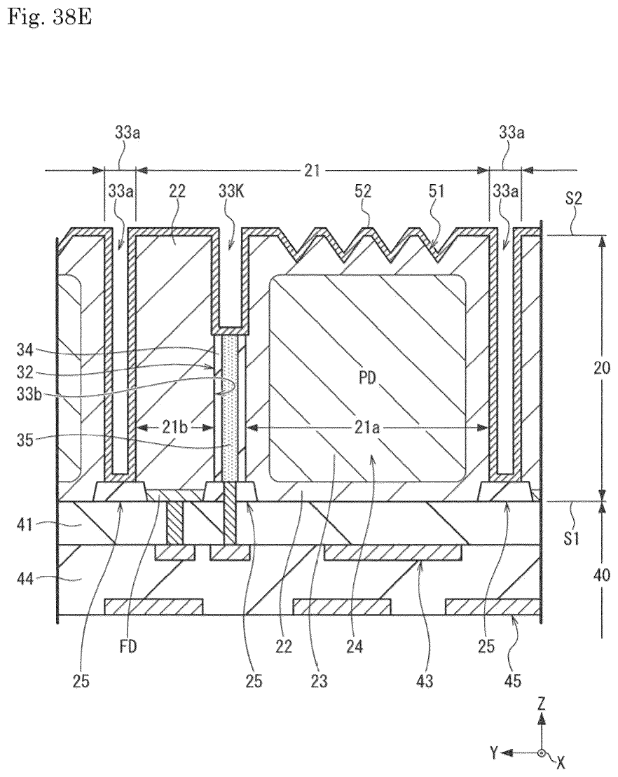

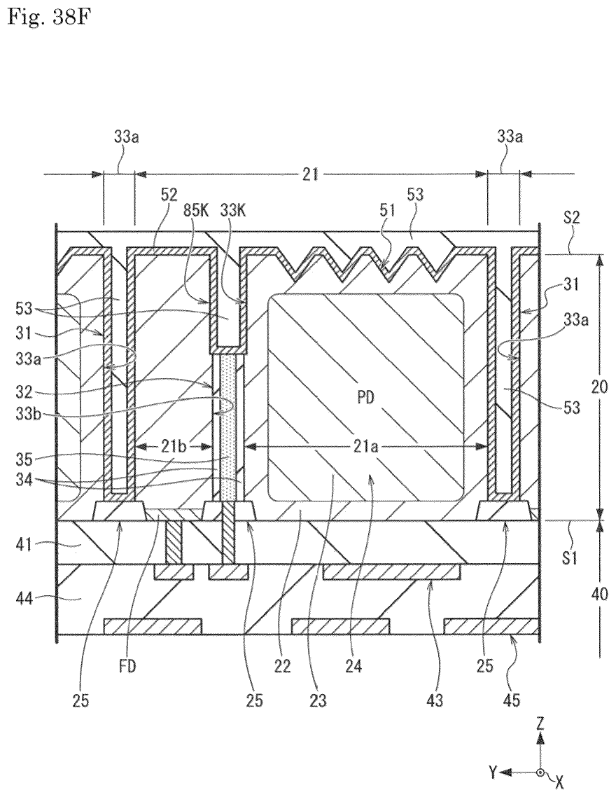

Next, a method of manufacturing the solid-state imaging device 1K according to the 11th embodiment of the present technology will be described with reference to FIGS. 38A to 38F.

In this 11th embodiment, manufacturing of the light reflecting body 85K included in the method of manufacturing the solid-state imaging device 1I will be particularly described.

First, processes similar to those of the eighth embodiment described above are performed, and, as illustrated in FIG. 38A, processes up to the process of forming a diffraction scattering section 51 in the second face S2 of the semiconductor layer 20 in the first area 21a of the photoelectric conversion area 21 are performed.

Next, after the diffraction scattering section 51 is formed, as illustrated in FIG. 38B, the separation insulating film 34 and the conductive material 35 of the inside of the dug part 33a are selectively removed. By using a known photolithographic technology and an anisotropic dry etching technology, the separation insulating film 34 and the conductive material 35 of the inside of the dug part 33a can be selectively removed.

Next, after the separation insulating film 34 and the conductive material 35 are selectively removed, as illustrated in FIGS. 38C, a mask M1 having an opening part Mla in which the in-pixel separation area 32 is exposed is formed on the second face S2 side of the semiconductor layer 20, for example, using a photolithographic technology. Each of the first area 21a and the second area 21b of the photoelectric conversion area 21 has the second face S2 side of the semiconductor layer 20 covered with the mask M1, and the inside of the dug part 33a is filled with a part of the mask M1.

Next, the mask M1 is used as an etching mask, and the conductive material 35 and the separation insulating film 34 exposed from the opening part M1a of the mask M1 are selectively etched, whereby, as illustrated in FIG. 3D, a dug part 33K is formed.

In this process, the dug part 33K extends from the second face S2 side of the semiconductor layer 20 toward the first face S1 side with overlapping the in-pixel separation area 32 in the plan view and is formed in a state of being in contact with the tip end of the in-pixel separation area 32. While the dug part 33K is formed with a predetermined depth, the length of the in-pixel separation area 32 is shortened in inverse proportion to the depth of this dug part 33K.

Next, after the mask M1 is removed, as illustrated in FIG. 38E, a fixed charge film 52 that covers along the inner wall (the side all and the bottom wall) of the inside of each of the dug parts 33a and 33K and covers the second face S2 of the semiconductor layer 20 is formed. The fixed charge film 52 is formed over the first area 21a and the second area 21b of the photoelectric conversion area 21 on the second face S2 side of the semiconductor layer 20, and the diffraction scattering section 51 of the first area 21a is covered with the fixed charge film 52.

Next, after the fixed charge film 52 is formed, as illustrated in FIG. 38F, an insulating film 53 is formed on the entire face of the second face S2 side of the semiconductor layer 20 including the inside of each of the dug parts 33a and 33K. For example, after a silicon oxide film is formed using a CVD method, by planarizing the surface side of this silicon oxide film using a CMP method through cutting, an insulating film 53 can be formed.

In this process, an inter-pixel separation area 31 in which the insulating film 53 is embedded inside of the dug part 33a through the fixed charge film 52 is formed, and a photoelectric conversion area 21 of which the periphery is partitioned by this inter-pixel separation area 31 and the inside is separated into the first area 21a and the second area 21b by the in-pixel separation area 32 is formed.

In addition, in this process, a light reflecting body 85K including the fixed charge film 52 and the insulating film 53 is formed inside the dug part 33K.

Next, after the insulating film 53 is formed, on a side opposite to the semiconductor layer 20 side of this insulating film 53, by forming the light blocking film 54, the color filter 55, the microlens 56, and the like in this order, a state illustrated in FIGS. 31 and 32 is formed.

In addition, also in the solid-state imaging device 1K according to this 11th embodiment, by dividing a semiconductor wafer including the semiconductor layer 20 and the multilayer wiring layer 40 for each chip formation area, the state of the semiconductor chip 2 illustrated in FIG. 1 is formed.

### <Function of Light Reflecting Body>

Next, the function of the light reflecting body 80K will be described using FIGS. 37B and 6.

As illustrated in FIG. 37B, in one photoelectric conversion area 21 (one pixel 3), oblique light 57K₁ emitted radially from the microlens 56 is transmitted (passes) through the color filter 55, the insulating film 53, the fixed charge film 52, and the diffraction scattering section 51, and the like and penetrates (is incident) into the first area 21a (the photoelectric conversion unit 24 (PD)) of the photoelectric conversion area 21 from the second face S2 side of the semiconductor layer 20. Then, the oblique light 57K₁ that has penetrated into the first area 21a reaches (is emitted to) the light reflecting body 85K from the first area 21a side. Then, the oblique light 57K₁ that has reached the light reflecting body 85K is reflected on the light reflecting body 85K and returns to the first area 21a of the photoelectric conversion area 21. In other words, the light reflecting body 85K of this 11th embodiment reflects the oblique light 57K₁ penetrating into the second area 21b from the first area 21a side of the photoelectric conversion area 21 on the light reflecting body 85K and can suppress arrival of the oblique light 57K₁ at the floating diffusion region FD disposed in the second area 21b of the photoelectric conversion area 21.

In addition, the oblique light 57K₁ that has reached (been emitted to) the light reflecting body 85K from the first area 21a side of the photoelectric conversion area 21 is reflected on this light reflecting body 85K and returns to the first area 21a of the photoelectric conversion area 21, and thus improvement of the quantum efficiency QE can be achieved as well.

In addition, the oblique light 57K₂ that is radially emitted from the microlens 56 is transmitted (passes) through the color filter 55, the insulating film 53, the fixed charge film 52, the diffraction scattering section 51, and the like and penetrates (is incident) into the first area 21a (the photoelectric conversion unit 24 (PD)) of the photoelectric conversion area 21 from the second face S2 side of the semiconductor layer 20. Then, the oblique light 57K₂ that has penetrated into the first area 21a is reflected on the inter-pixel separation area 31 and returns to the first area 21b (the photoelectric conversion unit 24 (PD)).

Here, by disposing the light reflecting body 85K, penetration of the oblique light 57K₁ into the second area 21b of the photoelectric conversion area 21 can be suppressed, and thus a total amount of light penetrated from the first area 21a of the photoelectric conversion area 21 into the second area 21b decreases.

FIG. 37C is a diagram illustrating a correlation between transmittance in the in-pixel separation area 32 and a length L₆ (see FIG. 37A) of the light reflecting body 85K (a diagram illustrating insulating film length dependency of the transmittance). The in-pixel separation area 32 includes a silicon film having an insufficient light blocking property as the conductive material 35, and the light reflecting body 85K includes an insulating film 53 of which a refractive index is lower than that of the semiconductor layer 20.

From FIG. 37C, for example, by substituting up to a deep area of 1.5 μm or more from the second face (the light incidence face) S2 of the semiconductor layer 20 with the light reflecting body 85K, the transmittance of light (a wavelength of 632 nm) penetrating into the second area 21b from the first area 21a of the photoelectric conversion area 21 can be decreased by 50% or more. Thus, it is preferable that the length L₆ of the light reflecting body extending from the second face S2 of the semiconductor layer 20 toward the first face S1 be 1.5 μm or more.

### Main Effects of 11th Embodiment

Next, the main effects of this 11th embodiment will be described.

Similar to the solid-state imaging device 1A according to the first embodiment described above, the solid-state imaging device 1K according to this 11th embodiment includes the inter-pixel separation area 31 and the in-pixel separation area 32. Thus, also in the solid-state imaging device 1K according to this 11th embodiment, similar to the solid-state imaging device 1A according to the first embodiment described above, improvement of the quantum efficiency QE and high mixed color suppression (MTF) as pixel characteristics can be achieved, and improvement of transmission characteristics as pixel characteristics can be achieved.

In addition, the solid-state imaging device 1K according to this 11th embodiment includes the light blocking film 54 that is disposed on the outer side of the second face S2 of the semiconductor layer 20 and overlaps the second area 21b of the photoelectric conversion area 21 in the plan view. For this reason, similar to the solid-state imaging device 1A of the first embodiment described above, light that has penetrated into the second area 21b from the second face S2 side (the light incidence face side) of the semiconductor layer 20 in the second area 21b of the photoelectric conversion area 21 is blocked by the first light blocking part 82a, and arrival of light to the floating diffusion region FD can be suppressed, whereby the parasitic light sensitivity characteristics (PLS) can be enhanced.

Furthermore, the solid-state imaging device 1K according to the 11th embodiment includes the light reflecting body 85K that is disposed to overlap the in-pixel separation area 32 in the plan view on the second face S2 side (the light incidence face side) of the semiconductor layer 20 and has a refractive index lower than the semiconductor layer 20. For this reason, since the oblique light 57K₁ that has reached the light reflecting body 85K from the first area 21a side of the photoelectric conversion area 21 is reflected on the light reflecting body 85K and returns to the first area 21a, arrival of the oblique light 5711 at the floating diffusion region FD disposed in the second area 21b of the photoelectric conversion area 21 can be suppressed, and in combination with the effect of enhancement of the parasitic light sensitivity characteristics according to the light blocking film 54, further more enhancement of the parasitic light sensitivity characteristics (PLS) can be achieved.

In addition, the oblique light 75K₁ is reflected on the light reflecting body 85K and returns to the first area 21a, and thus improvement of the quantum efficiency QE can be achieved as well.

### Modified Example of 11th Embodiment

### Modified Example 11-1

In the 11th embodiment described above, although the light reflecting body 85K including the insulating film 53 and the fixed charge film 52 has been described, the present technology is not limited to the light reflecting body 85K of the 11th embodiment described above.

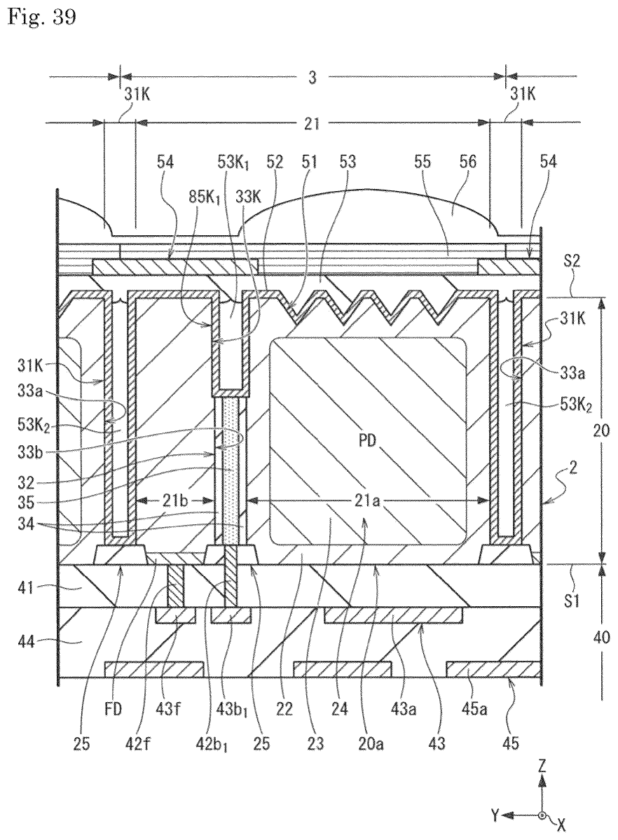

For example, as illustrated in FIG. 39, a light reflecting body 85K₁ including a cavity part 53k₁ filled with the air of which a refractive index is lower than that of the semiconductor layer 20 and a fixed charge film 52 can be used. In this case, an inter-pixel separation area 31K including a cavity part 53k₂ filled with the air of which a refractive index is lower than that of the semiconductor layer 20 and a fixed charge film 52 may be used as a first separation area.

### Modified Example 11-2

In addition, in the 11th embodiment described above, a case in which the length of the light reflecting body 85K in the X direction is set as a length for which the light reflecting body and a gate electrode of the transfer transistor TRG do not overlap each other in the plan view has been described. However, the present technology is not limited to the light reflecting body 85K of the 11th embodiment.

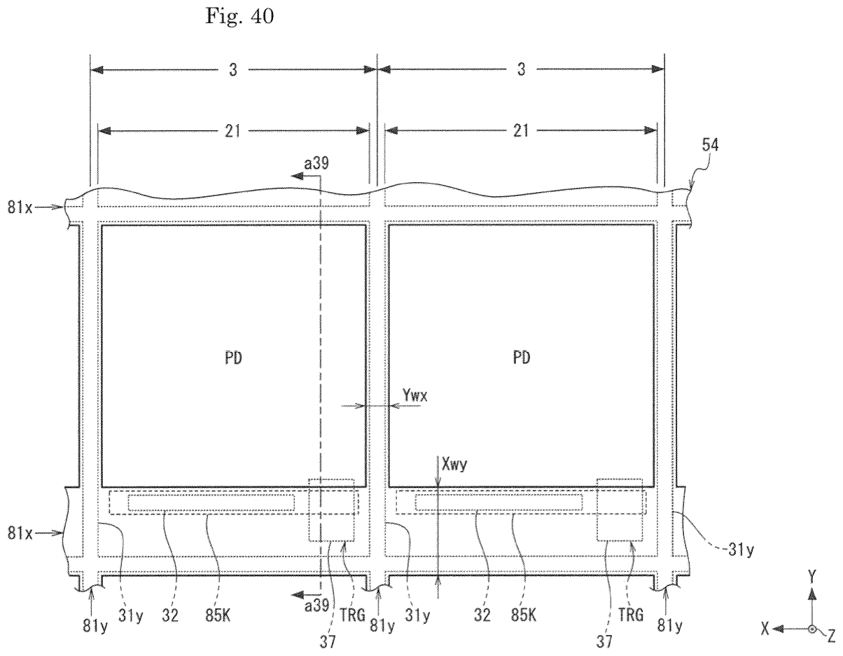

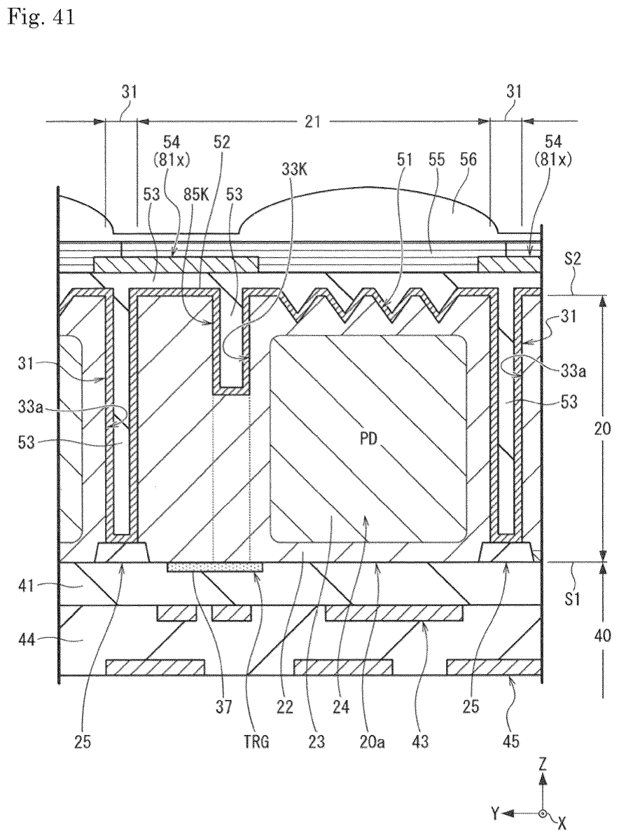

For example, as illustrated in FIGS. 40 and 41, the length of the light reflecting body 85K in the X direction may be set as a length for which the gate electrode 37 of the transfer transistor TRG and the light reflecting body 85K overlap each other in the plan view.

In addition, although not illustrated in the drawing, when described with reference to FIG. 40, each of two inter-pixel separation areas 31 that are separate from each other in the X direction among inter-pixel separation areas 31 surrounding one photoelectric conversion area 21 and the light reflecting body 85K may be integrated together.

### Modified Example 11-3

In addition, in the 11th embodiment described above, a case in which the in-pixel separation area 32 ends at the tip end of the light reflecting body 85K in the thickness direction (the Z direction) of the semiconductor layer 20 has been described. However, the present technology is not limited to the light reflecting body 85K of the 11th embodiment described above.

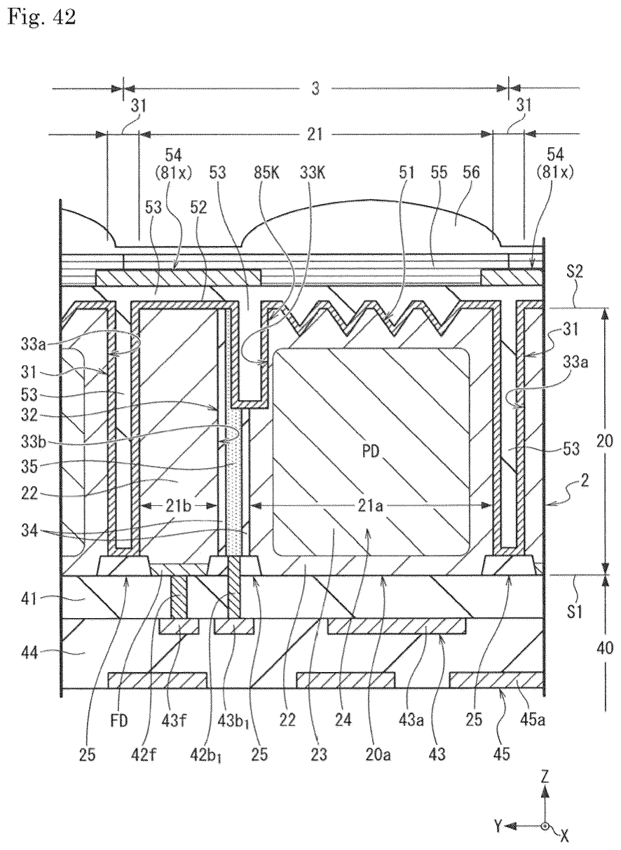

For example, as illustrated in FIG. 42, a configuration in which the light reflecting body 85K is deviated (offset) to a further first area 21a side of the photoelectric conversion area 21 than the in-pixel separation area 32 in the Y direction (one direction), and the conductive material 35 of the in-pixel separation area 32 is disposed between the light reflecting body 85K and the second area 21b may be employed. In other words, a configuration in which the light reflecting body 85K is disposed on a first area 21a side of the in-pixel separation area 32 in the disposition direction (the Y direction) of the first area 21a and the second area 21b of the photoelectric conversion area 21, and the silicon film 35 as the conductive material 35 of the in-pixel separation area 32 is disposed between the light reflecting body 85K and the second area 21b may be employed.

In this case, a configuration in which the conductive material 35 of the in-pixel separation area 32 is further closer to the second face S2 side of the semiconductor layer 20 compared to the 11th embodiment described above is formed, and thus, compared to the 11th embodiment, improvement of electric charge transmission characteristics can be achieved.

### Modified Example 11-4

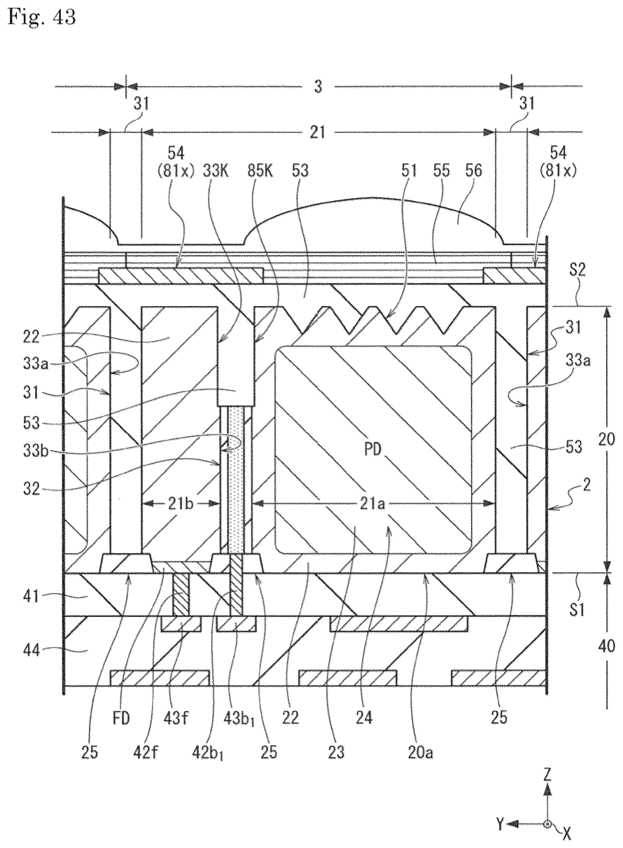

In addition, in the 11th embodiment described above, although the light reflecting body 85K including the insulating film 53 and the fixed charge film 52 has been described, as illustrated in FIG. 43, the light reflecting body 85K may be configured not to include the fixed charge film 52.

### 12th Embodiment

In this 12th embodiment, mainly, disposition of a photoelectric conversion area will be described.

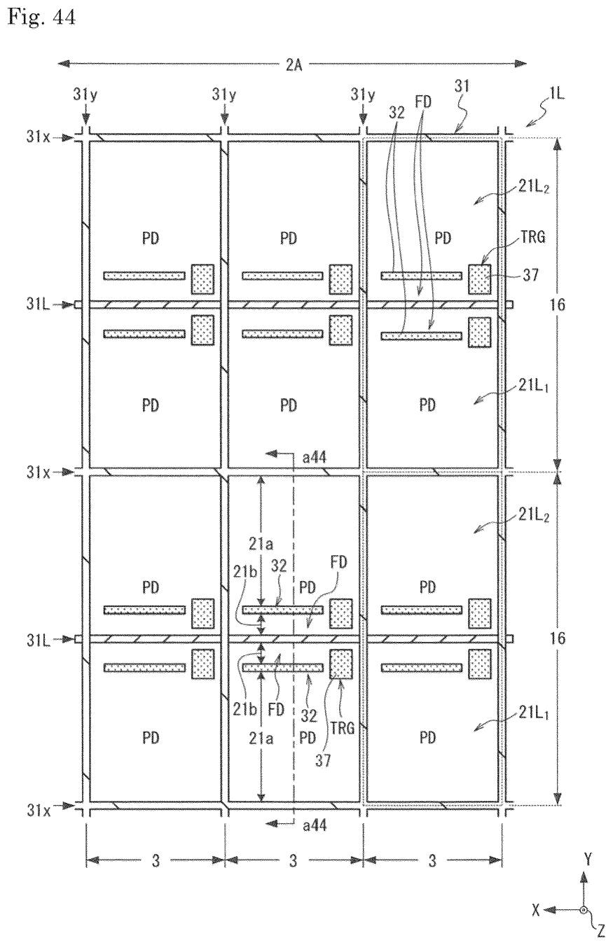

FIG. 44 is a plan view schematically illustrating a plane pattern of a separation area in a pixel array portion of a solid-state imaging device according to this 12th embodiment.

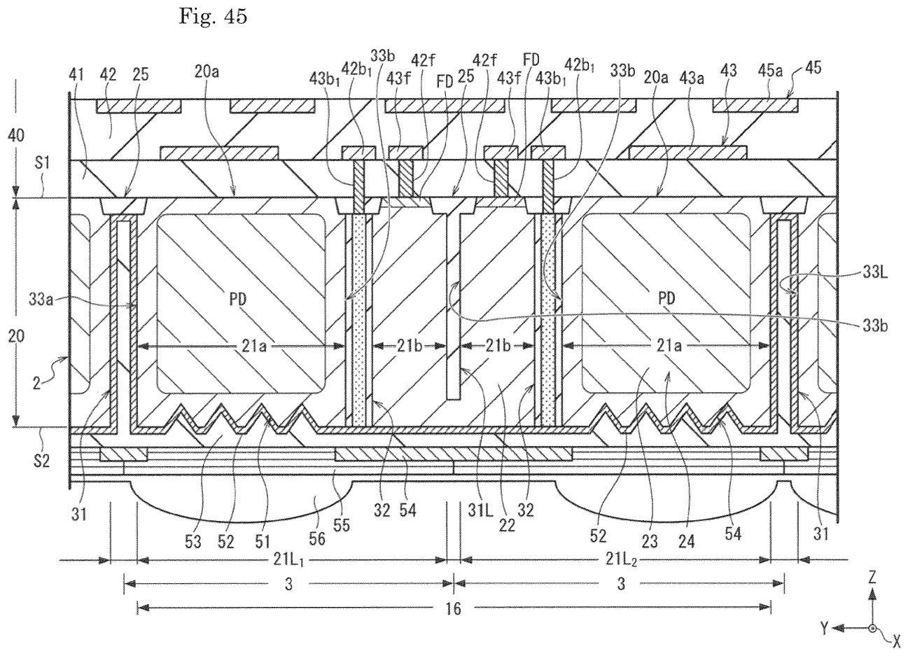

FIG. 45 is a longitudinal cross-sectional view schematically illustrating a longitudinal cross-sectional structure taken along line a44-a44 illustrated in FIG. 44.

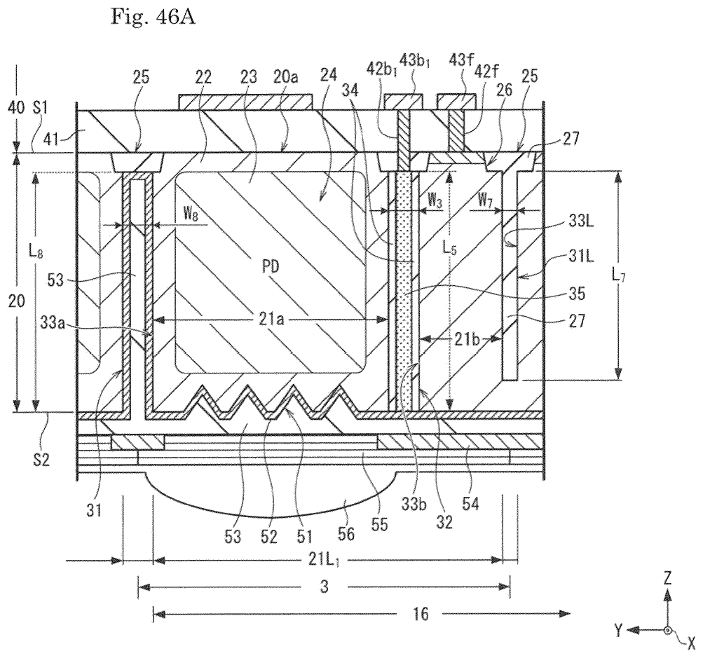

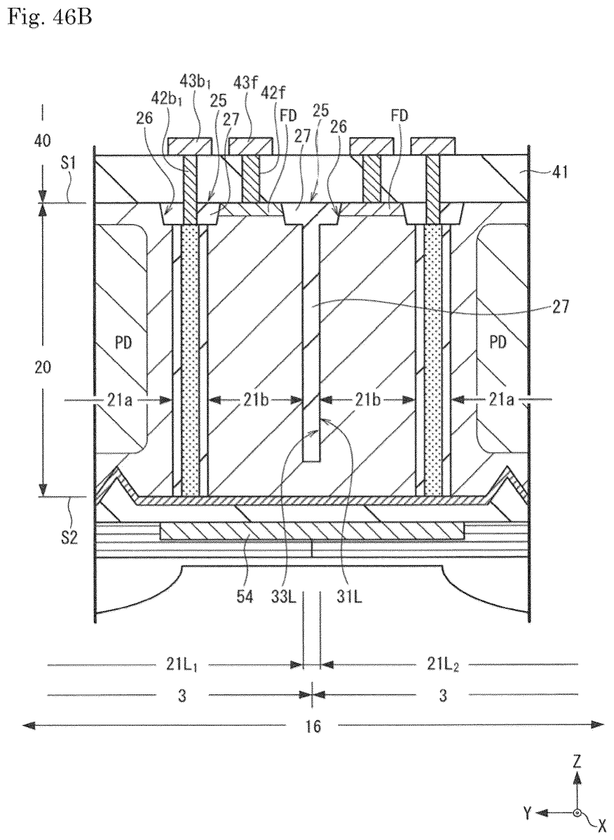

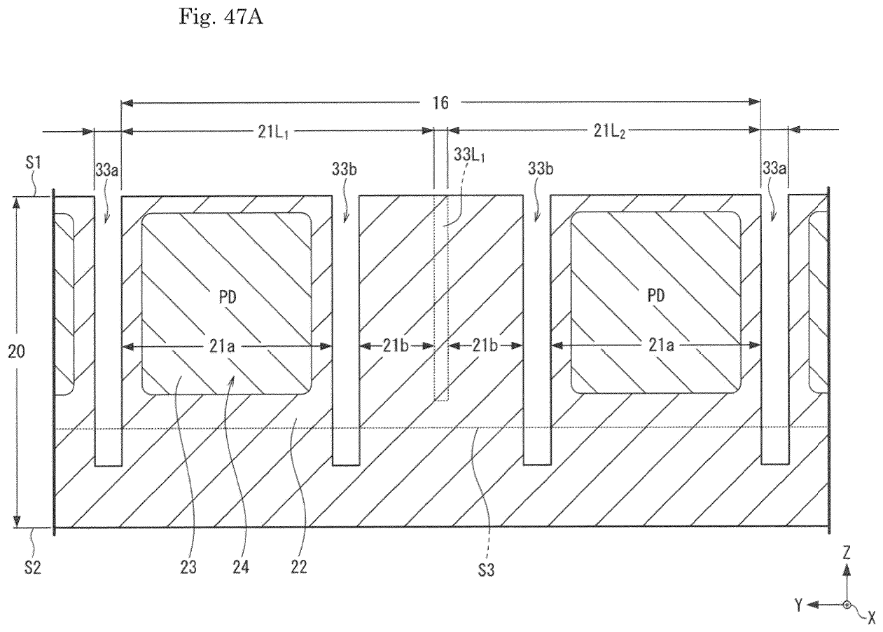

FIG. 46 is a longitudinal cross-sectional view in which a part of FIG. 45 is enlarged.

In this 12th embodiment, an inter-pixel separation area 31 corresponds to one specific example of “first separation area” of the present technology, and an in-pixel separation area 32 corresponds to one specific example of “second separation area” of the present technology. In addition, in this 12th embodiment, an insulating film 53 and a conductive material 35 respectively correspond to specific examples of “insulating material” and “conductive material” of the present technology. In addition, in this 12th embodiment, a dug part 33a, a dug part 33b, and a dug part 33L respectively correspond to specific examples of “first dug part”, “second dug part”, and “third dug part” of the present technology. Furthermore, in this 12th embodiment, a photoelectric conversion area 21L₁ and a photoelectric conversion area 21L₂ respectively correspond to specific examples of “first photoelectric conversion area” and “second photoelectric conversion area”. In addition, a disposition direction of a first area 21a and a second area 21b of the photoelectric conversion areas 21L₁ and 21L₂ corresponds to one specific example of “one direction” of the present technology.

### <<Configuration of Solid-state Imaging Device>>

The solid-state imaging device 1L according to the 12th embodiment of the present technology basically has a configuration similar to the solid-state imaging device 1A according to the first embodiment described above, and there are following different configurations.

In other words, as illustrated in FIGS. 44 and 45, the solid-state imaging device 1L according to this 12th embodiment includes a photoelectric conversion cell (a photoelectric conversion area group) 16 including a photoelectric conversion area 21L₁ and a photoelectric conversion area 21L₂ partitioned to be aligned in the Y direction by the inter-pixel separation area 31. In addition, the solid-state imaging device 1L according to this 12th embodiment includes an in-cell inter-pixel separation area 31L that separates the photoelectric conversion area 21L₁ and the photoelectric conversion area 21L₂ from each other. The other configurations are similar to those according to the first embodiment as a whole.

As illustrated in FIG. 44, the photoelectric conversion cell 16 includes two photoelectric conversion areas 21L₁ and 21L₂ that are disposed in 1×2 arrangement in which there is one photoelectric conversion area in the X direction, and there are two photoelectric conversion areas in the Y direction. The photoelectric conversion cells 16 are repeatedly disposed in each of the X direction and the Y direction and build a pixel array portion similar to the pixel array portion 2A illustrated in FIG. 1. Each of the photoelectric conversion areas 21L₁ and 21L₂ included in the photoelectric conversion cell 16 is individually disposed in correspondence with a pixel 3.

As illustrated in FIG. 45, each of the photoelectric conversion area 21L₁ and the photoelectric conversion area 21L₂ included in the photoelectric conversion cell 16 has a configuration similar to the photoelectric conversion area 21 of the first embodiment described above. In other words, each of the first and second photoelectric conversion areas 21L₁ and 21L₂ includes an in-pixel separation area 32, a well region 22 of the p type disposed in the semiconductor layer 20, a semiconductor area 23 of the n type disposed inside the well region 22 of the p type, a photoelectric conversion unit 24 (PD), and a floating diffusion region FD. In addition, each of the first and second photoelectric conversion areas 21L₁ and 21L₂ includes an element formation area 20a, an in-pixel separation area 32, and a diffraction scattering section 51.

As illustrated in FIG. 44, in the inter-pixel separation area 31, first parts 31x extending in the X direction are repeatedly disposed in the Y direction for every one photoelectric conversion cell 16 (for every two photoelectric conversion areas 21L₁ and 21L₂), and second parts 31y extending in the Y direction are repeatedly disposed in the X direction for every one photoelectric conversion cell 16 (for every one photoelectric conversion area 21L₁ or 21L₂). In other words, similar to the first embodiment described above, the inter-pixel separation area 31 has a plane pattern in the plan view to be a plane pattern of a lattice shape. In each photoelectric conversion cell 16, both Y-direction end sides of two photoelectric conversion areas 21L₁ and 21L₂ that are aligned in the Y direction are partitioned by two first parts 31x of the inter-pixel separation area 31 that are adjacent to each other, and both X-direction end sides of two photoelectric conversion areas 21L₁ and 21L₂ that are aligned in the Y direction are partitioned by two second parts 31y of the inter-pixel separation area 31 that are adjacent to each other. In addition, in each photoelectric conversion cell 16, the photoelectric conversion area 21L₁ and the photoelectric conversion area 21L₂ are separated (divided) by the in-cell inter-pixel separation area 31L extending in the X direction.

As illustrated in FIGS. 44 and 45, similar to the in-pixel separation area 32 of the first embodiment described above, the in-pixel separation area 32 separates each of the photoelectric conversion areas 21L₁ and 21L₂ into a first area 21a and a second area 21b in the Y direction. In the first area 21a, a well region 22 of the p type, a semiconductor area 23 of the n type, a photoelectric conversion unit 24 (PD), an element formation area 20a, a diffraction scattering section 51, and the like are disposed. In the second area 21b, a well region 22 of the p type, a floating diffusion region FD, and the like are disposed. Similar to the first embodiment described above, in the element formation area 20a, pixel transistors (AMP, SEL, RST, and TRG) are disposed.

Here, in order to allow the drawings to be easily seen, similar to FIGS. 4 and 5 of the first embodiment described above, only the transfer transistor TRG among the pixel transistors is illustrated in FIG. 44, and illustration of the pixel transistors is omitted in FIG. 45.

As illustrated in FIGS. 44 and 45, there is a difference in the disposition order of the first area 21a and the second area 21b in the Y direction (one direction) between the photoelectric conversion area 21L₁ and the photoelectric conversion area 21L₂. More specifically, when directed toward the same orientation (direction) in the Y direction, the first area 21a and the second area 21b are disposed in this order in the photoelectric conversion area 21L₁, and the second area and the first area are disposed in this order in the photoelectric conversion area 21L₂. In other words, in the photoelectric conversion cell 16, the second areas 21b of the photoelectric conversion area 21L₁ and the photoelectric conversion area 21L₂ are adjacent to each other through the in-cell inter-pixel separation area 31L in the plan view. In other words, the photoelectric conversion cell 16 includes first and second photoelectric conversion areas 21L₁ and 21L₂ of which the second areas 21b are disposed to be adjacent to each other in the Y direction through the in-cell inter-pixel separation area 31L in the plan view.

### <In-Cell Inter-Pixel Separation Area>

As illustrated in FIG. 46, the in-cell inter-pixel separation area 31L extends in the thickness direction (the Z direction) of the semiconductor layer 20. The in-cell inter-pixel separation area 31L has one end side being connected to the element separation area 25 and the other end side being separate from the second face S2 of the semiconductor layer 20.

The in-cell inter-pixel separation area 31L includes an insulating film 27 as an insulating material that is disposed in the dug part 33L extending in the thickness direction (the Z direction) of the semiconductor layer 20 and has a refractive index lower than that of the semiconductor layer 20. The dug part 33L has one end side being connected to the element separation area 25 and the other end side being separate from the second face S2 of the semiconductor layer 20. The insulating film 27 of the inside of the in-cell inter-pixel separation area 31L is formed in the same process as that of the insulating film 27 of the element separation area 25. As the insulating film 27, for example, a silicon oxide film can be used. The silicon oxide film has a refractive index to be lower than that of a semiconductor material such as Si, SiGe, InGaAs, or the like.

As illustrated in FIG. 46A, the in-cell inter-pixel separation area 31L and the inter-pixel separation area 31 have different widths (W₇ and W₈) in a direction along the disposition direction (one direction) of the first area 21a and the second area 21b of the photoelectric conversion area 21. More specifically, the width W₇ of the in-cell inter-pixel separation area 31L is configured to be smaller than the width W₇ of the inter-pixel separation area 31 (W₇<W₈).

In the in-cell inter-pixel separation area 31L and the in-pixel separation area 32, the width W₇ of the in-cell inter-pixel separation area 31L is configured to be smaller than the width W₃ of the in-pixel separation area 32 (W₇<W₃).

The width of the dug part 33L is configured to be smaller than the width of each of the dug parts 33a and 33b.

As illustrated in FIG. 46A, the in-cell inter-pixel separation area 31L, the inter-pixel separation area 31, and the in-pixel separation area 32 have different lengths (L₇, L₈, and L₅) in the thickness direction (the Z direction) of the semiconductor layer 20. More specifically, the length L₇ of the in-cell inter-pixel separation area 31L is configured to be smaller than the length L₈ of the inter-pixel separation area 31 and the length L₅ of the in-pixel separation area 32. A depth of the dug part 33L in the Z direction is configured to be smaller than a depth of each of the dug parts 33a and 33b in the Z direction.

Here, the in-cell inter-pixel separation area 31L extends from the element separation area 25 to the second face S2 of the semiconductor layer 20 and is separate from the second face S2 of the semiconductor layer 20. The length L₇ of the in-cell inter-pixel separation area 31L of this case is a distance from the bottom face of the element separation area 25 to the tip end. Although not illustrated in the drawing, in a case in which the in-cell inter-pixel separation area 31L extends from the first face S1 of the semiconductor layer 20 toward the second face S2, a distance from the first face S1 of the semiconductor layer 20 to the tip end becomes the length L₇ of the in-cell inter-pixel separation area 31L.

In addition, a face of the semiconductor layer 20 that is brought into contact with the bottom face of the element separation area (the field separation area) 25 can be also regarded as a first face S1.

The dug part 33a of the inter-pixel separation area 31 and the dug part 33b of the in-pixel separation area 32 have the same designed values of lengths and widths. On the other hand, the dug part 33L of the in-cell inter-pixel separation area 31L and the dug parts 33a and 33b have different lengths and widths. In other words, the dug part 33L of the in-cell inter-pixel separation area 31L is formed in a process different from that of the dug part 33a of the inter-pixel separation area 31 and the dug part 33b of the in-pixel separation area 32.

As illustrated in FIGS. 45 and 46B, the light blocking film 54 is disposed on the second face S2 side of the semiconductor layer 20. The light blocking film 54 overlaps the second area 21b of each of two photoelectric conversion areas 21L₁ and 21L₂ and is continuously disposed over the second area 21b of each thereof.

### <<Method of Manufacturing Solid-state Imaging Device>>

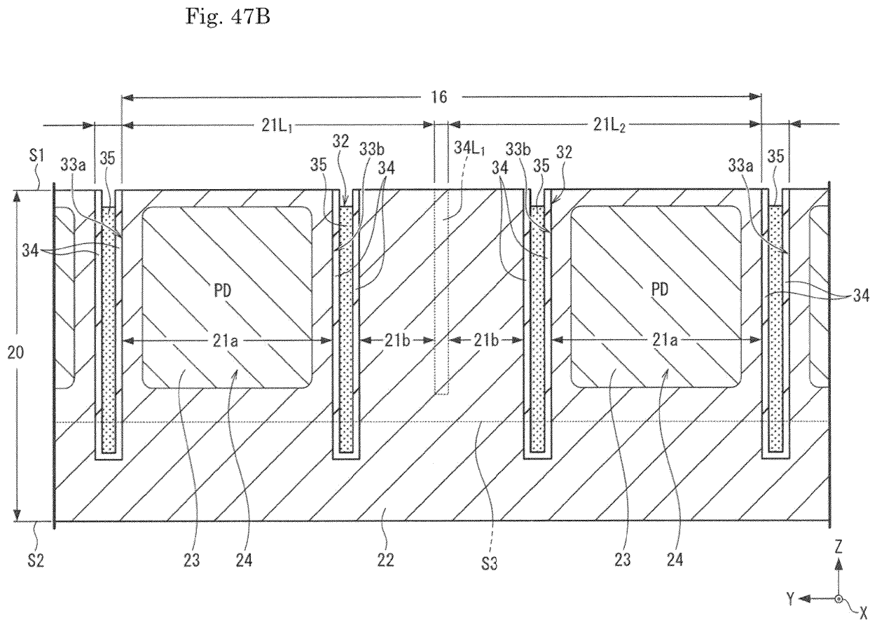

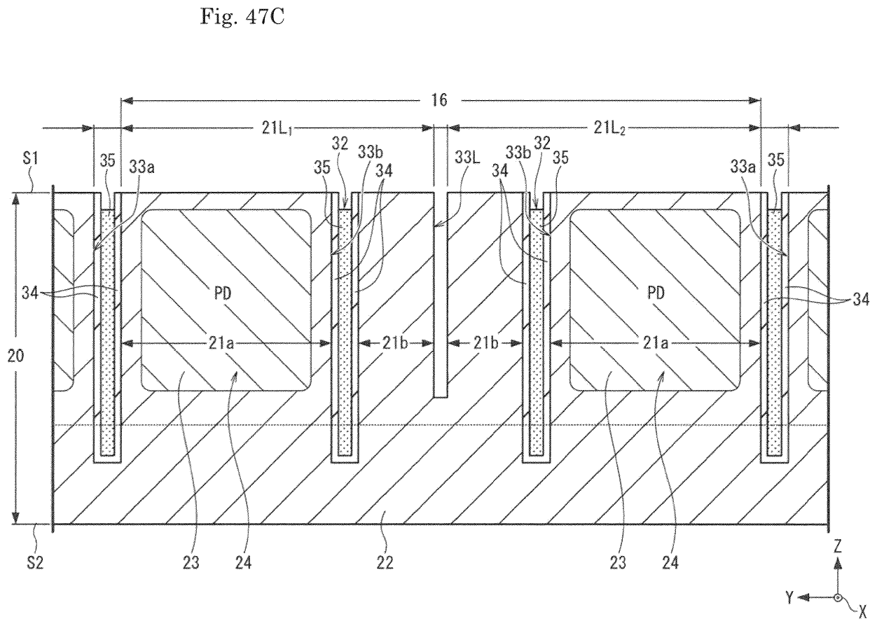

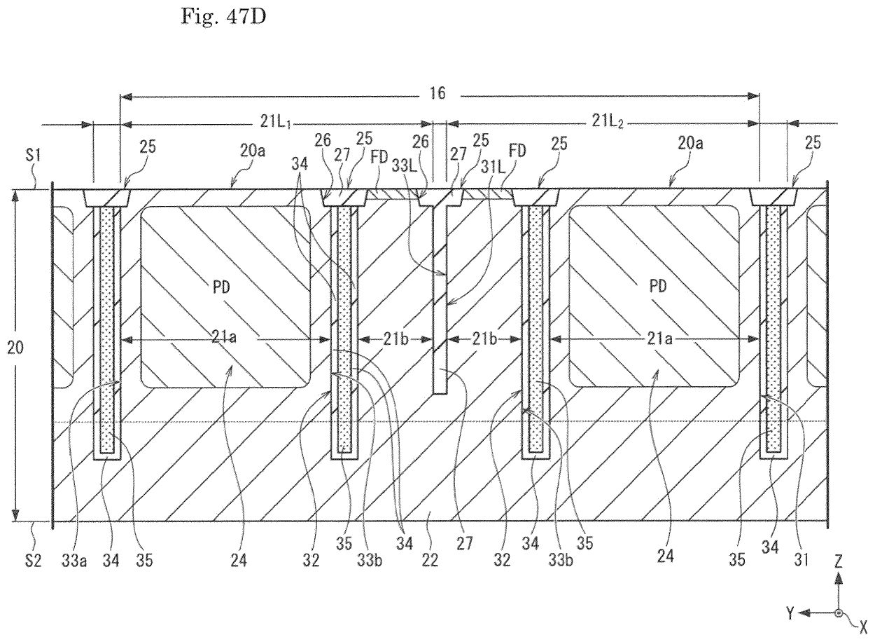

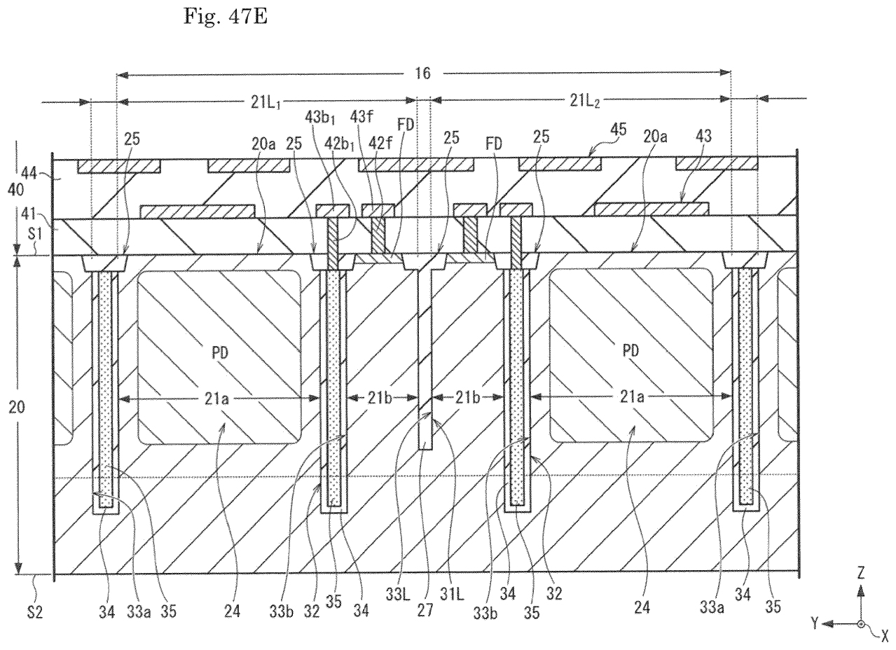

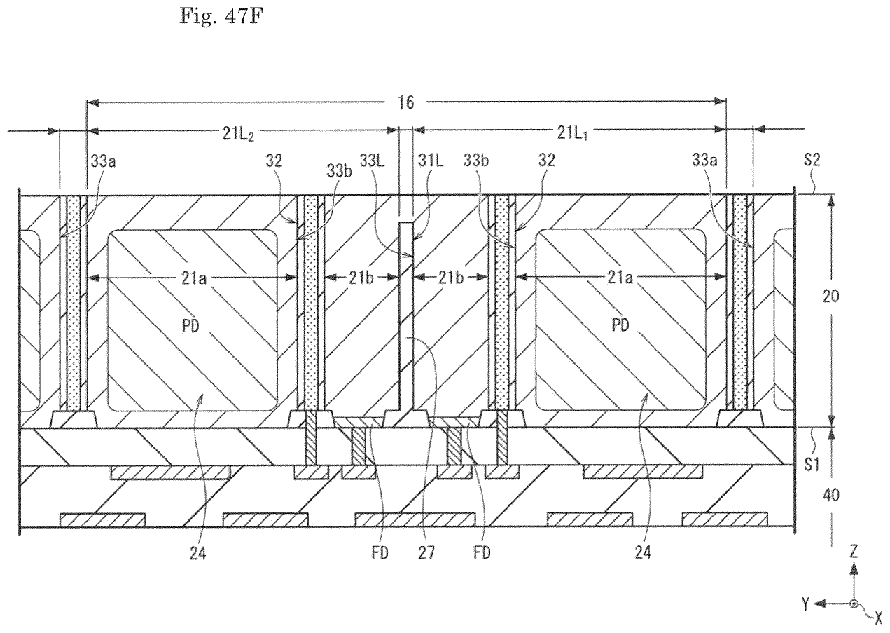

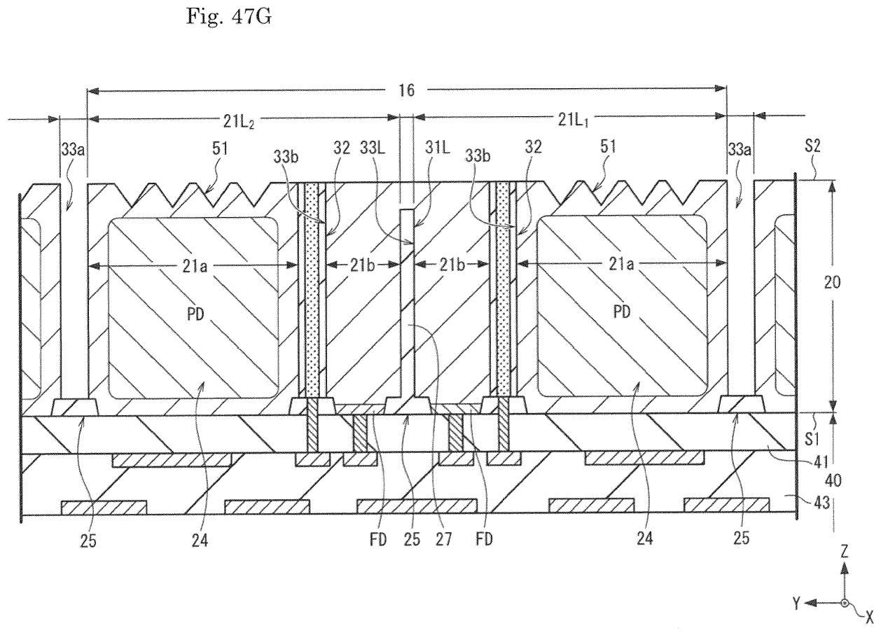

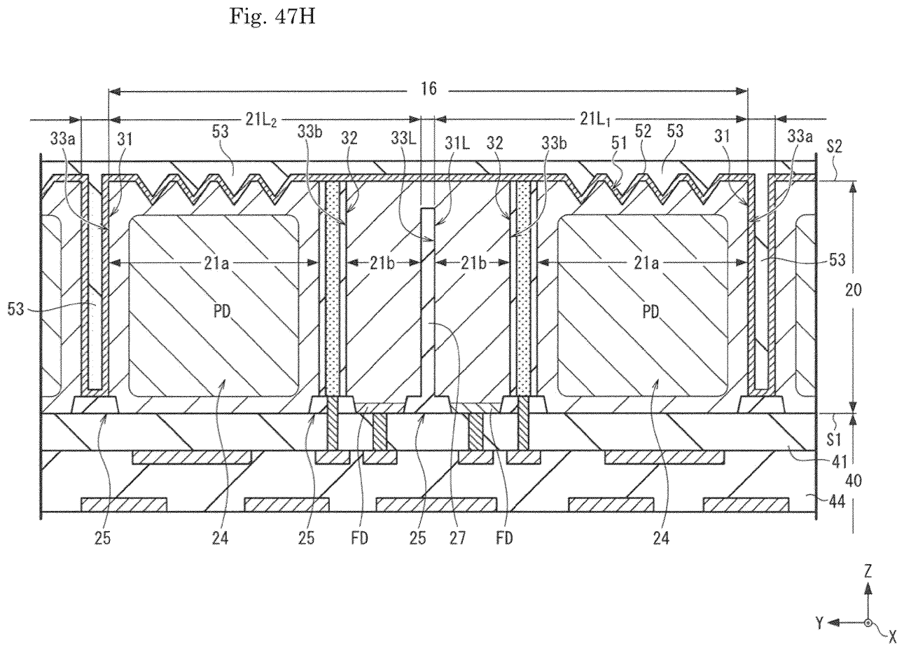

Next, a method of manufacturing the solid-state imaging device 1L according to the 12th embodiment of the present technology will be described with reference to FIGS. 47A to 47H.

In this 12th embodiment, manufacturing of the in-cell inter-pixel separation area 31L included in the method of manufacturing the solid-state imaging device 1L will be particularly described.

First, as illustrated in FIG. 47A, in the semiconductor layer 20, dug parts 33a and 33b extending from the first face S1 of the semiconductor layer 20 toward the second face S2 are formed.

The dug part 33a partitions the photoelectric conversion cell 16 including two photoelectric conversion areas 21L₁ and 21L₂ that are aligned to be adjacent to each other in the Y direction. In other words, the dug part 33a partitions the periphery of two photoelectric conversion areas 21L₁ and 21L₂ aligned to be adjacent to each other in the Y direction. The dug part 33b partitions each of the two photoelectric conversion areas 21L₁ and 21L₂ into a first area 21a and a second area 21b. Each of the dug parts 33a and 33b can be formed using a known photolithographic technology and an anisotropic dry etching technology.

In this process, the second areas 21b of the photoelectric conversion areas 21L₁ and 21L₂ are aligned to be adjacent to each other in the Y direction through a dug part formation area 33L₁ in which a dug part 33L (see FIG. 47C) is formed in a subsequent process. In other words, a space between the two photoelectric conversion areas 21L₁ and 21L₂ has not been partitioned yet, and the two photoelectric conversion areas 21L₁ and 21L₂ are connected to each other through the dug part formation area 33L₁.

In addition, in this process, in the first area 21a of each of the photoelectric conversion areas 21L₁ and 21L₂, the well region 22 of the p type, the semiconductor area 23 of the n type, the photoelectric conversion unit 24 (PD), and the like have already been formed. In the second area 21b of each of the photoelectric conversion areas 21L₁ and 21L₂, the well region 22 of the p type has already been formed.

Here, in the manufacturing of the solid-state imaging device 1L of this embodiment, a thinning process (see FIG. 47F) of decreasing the thickness of the semiconductor layer 20 is performed. Thus, a depth of each of the dug parts 33a and 33b in the Z direction (the thickness direction of the semiconductor layer 20) is formed to be deeper than a thinning line S3 representing the thickness of the semiconductor layer 20 formed in the thinning process.

Next, after each of the dug parts 33a and 33b is formed, a washing process is performed. In this washing process, a space between the second area 21b of one photoelectric conversion area 21L₁ and the second area 21b of the other photoelectric conversion area 21L₂ out of two photoelectric conversion areas 21L₁ and 21L₂ that are aligned to be adjacent to each other in the Y direction has not been partitioned yet, and the second areas are in the state of being connected to each other.

Next, after the washing process is performed, as illustrated in FIG. 47B, a separation insulating film 34 and a conductive material 35 are selectively formed inside of each of the dug parts 33a and 33b. The separation insulating film 34 is formed along the inner wall (the side wall and the bottom wall) of each of the dug parts 33a and 33b. The conductive material 35 is formed inside of each of the dug parts 33a and 33b through the separation insulating film 34. The separation insulating film 34 and the conductive material 35 of the inside of each of the dug parts 33a and 33b can be formed, for example, by forming the separation insulating film 34 and the conductive material 35 on the entire face on the first face S1 of the semiconductor layer 20 including the inner wall (the side wall and the bottom wall) of each of the dug parts 33a and 33b in this order and thereafter, selectively removing the conductive material 35 and the separation insulating film 34 disposed on the first face S1 of the semiconductor layer 20 in this order using a CMP method or the like. As the separation insulating film 34, for example, a silicon oxide film can be used.

As the conductive material 35, for example, a doped polysilicon film acquired by introducing impurities reducing a resistance value during deposition or after deposition can be used.

In this process, an in-pixel separation area 32 including the separation insulating film 34 and the conductive material 35 inside of the dug part 33b is formed. Then, the first area 21a and the second area 21b of each of the photoelectric conversion areas 21L₁ and 21L₂ are partitioned and separated by the in-pixel separation area 32.

Next, as illustrated in FIG. 47C, a dug part 33L extending from the first face S1 of the semiconductor layer 20 toward the second face S2 is formed in the dug part formation area 33L₁ of the inside of the photoelectric conversion cell 16. The dug part 33L is formed to be thinner than the depth of the dug parts 33a and 33b and is formed to be thinned than the thinning line S3 of the semiconductor layer 20. In other words, the dug part 33L is formed to have a depth separate from the thinning line S3 of the semiconductor layer 20. The dug part 33L can be formed using a known photolithographic technology and an anisotropic dry etching technology. In this process, the second area 21b of the photoelectric conversion area 21L₁ and the second area 21b of the photoelectric conversion area 21L₂ are partitioned and separated by the dug part 33L and are adjacent to each other through this dug part 33L.

In addition, in this process, the dug part 33L is formed in a process different from that of the dug parts 33a and 33b, and thus a width and a depth in a short-side direction can be formed to have sizes different from the dug parts 33a and 33b. In this embodiment, the width and the depth of the dug part 33L in the short-side direction are formed to have sizes smaller than the dug parts 33a and 33b.

Next, after the dug part 33L is formed, a washing process is performed. In this washing process, the separation insulating film 34 and the conductive material 35 have already been disposed in each of the dug parts 33a and 33b.

Next, after the washing process is performed, as illustrated in FIG. 47D, on the first face S1 side of the semiconductor layer 20, an element formation area 20a and an element separation area 25 are formed, and an in-cell inter-pixel separation area 31L in which the insulating film 27 is embedded inside of the dug part 33L is formed.

The element formation area 20a is partitioned by the element separation area 25 and, by forming this element separation area 25, is formed in the first area 21a of each of the photoelectric conversion areas 21L₁ and 21L₂.

Each of the element separation area 25 and the in-cell inter-pixel separation area 31L can be formed, for example, by forming a shallow groove part (a field groove part) 26 that is depressed from the first face S1 of the semiconductor layer 20 to the second face S2 side, thereafter forming an insulating film 27, for example, formed from a silicon oxide film on the entire face on the first face S1 side of the semiconductor layer 20 including the inside of the shallow groove part 26 and the inside of the dug part 33L, and thereafter removing the insulating film 27 disposed on the first face S1 of the semiconductor layer 20 using a CMP method such that the insulating film 27 remains inside of each of the shallow groove part 26 and the dug part 33L.

As the insulating film 27, for example, a silicon oxide film having a refractive index lower than a semiconductor material such as Si, SiGe, InGaAs, or the like is used.

In this process, an in-cell inter-pixel separation area 31L in which the insulating film 27 is disposed inside the dug part 33L and has a Z-direction length L₇ to be shorter than the Z-direction depth of the dug part 33a and the Z-direction length L₅ of the in-pixel separation area 32 is formed. The second area 2b of the photoelectric conversion area 21L₁ and the second area 21b of the photoelectric conversion area 21L₂ are partitioned and separated by the in-cell inter-pixel separation area 31L.

Although not illustrated in the drawing, pixel transistors (AMP, SEL, RST, and TRG) are formed in the element formation area 20a of each of the photoelectric conversion areas 21L₁ and 21L₂, and, as illustrated in FIG. 47D, a floating diffusion region FD is formed in the second area 21b of each of the photoelectric conversion areas 21L₁ and 21L₂. The floating diffusion region FD is formed on the first face S1 side of the semiconductor layer 20 in the second area 21b of each of the photoelectric conversion areas 21L₁ and 21L₂.

Next, as illustrated in FIG. 47E, a multilayer wiring layer 40 is formed on the first face S1 side of the semiconductor layer 20. Thereafter, a thinning process of decreasing the thickness of the semiconductor layer 20 by cutting the second face S2 side of the semiconductor layer 20, for example, using the CMP method is performed, and, as illustrated in FIG. 47F, the separation insulating film 34 and the conductive material 35 disposed inside the dug part 33a are exposed, and the separation insulating film 34 and the conductive material 35 of the in-pixel separation area 32 are exposed. The thinning of the semiconductor layer 20 is performed up to the thinning line S3 illustrated in FIG. 47E.

In this process, an in-cell inter-pixel separation area 31L that extends from the bottom face of the element separation area 25 of the first face S1 side of the semiconductor layer 20 to the second face S2 side of the semiconductor layer 20 and has a tip end to be separated from the second face S2 of the semiconductor layer 20 is formed.

In addition, in this process, an in-pixel separation area 32 that extends from the bottom face of the element separation area 25 of the first face S1 side of the semiconductor layer 20 toward the second face S2 side of the semiconductor layer 20 and has a tip end reaching the second face S2 of the semiconductor layer 20 is formed.

Next, as illustrated in FIG. 47G, in the first area 21a of each of the photoelectric conversion areas 21L₁ and 21L₂, a diffraction scattering section 51 is formed on the second face S2 side of the semiconductor layer 20, and the separation insulating film 34 and the conductive material 35 of the inside of the dug part 33a are selectively removed. Although the process of forming the diffraction scattering section 51 is performed in a process different from the removal process of selectively removing the separation insulating film 34 and the conductive material 35, any of the processes may be performed first. The separation insulating film 34 and the conductive material 35 of the inside of the dug part 33a can be selectively removed by using a known photolithographic technology and an anisotropic dry etching technology.

Next, as illustrated in FIG. 47H, a fixed charge film 52 is formed. The fixed charge film 52 is formed over the first area 21a and the second area 21b of each of the photoelectric conversion areas 21L₁ and 21L₂ on the second face S2 side of the semiconductor layer 20 and is formed along the side wall and the bottom wall of the dug part 33a and unevenness of the diffraction scattering section 51.

Next, after the fixed charge film 52 is formed, as illustrated in FIG. 47H, an insulating film 53 is formed on the entire face of the second face S2 side of the semiconductor layer 20 including the inside of the dug part 33a. For example, after a silicon oxide film is formed using a CVD method, by planarizing the surface side of this silicon oxide film using a CMP method through cutting, an insulating film 53 can be formed.

In this process, an inter-pixel separation area 31 in which the insulating film 53 is embedded inside of the dug part 33a through the fixed charge film 52 is formed, and a photoelectric conversion cell 16 of which the periphery is partitioned by this inter-pixel separation area 31 is formed. The inside of each photoelectric conversion cell 16 is separated into a first area 21a and a second area 21b in the Y direction by the in-pixel separation area 32, and each second area 21b includes two photoelectric conversion areas 21L₁ and 21L₂ that are adjacent to each other through the in-cell inter-pixel separation area 31L and are aligned in the Y direction.

Next, as illustrated in FIGS. 45 and 46B, a light blocking film 54 is formed on a side opposite to the semiconductor layer 20 side of the insulating film 53. The light blocking film 54 is formed to overlap the second area 21b of each of the two photoelectric conversion areas 21L₁ and 21L₂ and be continuous over the second area 21b of each thereof.

Thereafter, by forming a color filter 55 and a microlens 56 on a side opposite to the semiconductor layer 20 side of the light blocking film 54 in this order, a state illustrated in FIGS. 44 to 46B is formed.

In addition, also in the solid-state imaging device 1L according to this 12th embodiment, by dividing a semiconductor wafer including the semiconductor layer 20 and the multilayer wiring layer 40 for each chip formation area, the state of the semiconductor chip 2 illustrated in FIG. 1 is formed.

### <<Features of Photoelectric Conversion Cell>>

Next, features of the photoelectric conversion cell 16 will be described with reference to a comparative example.

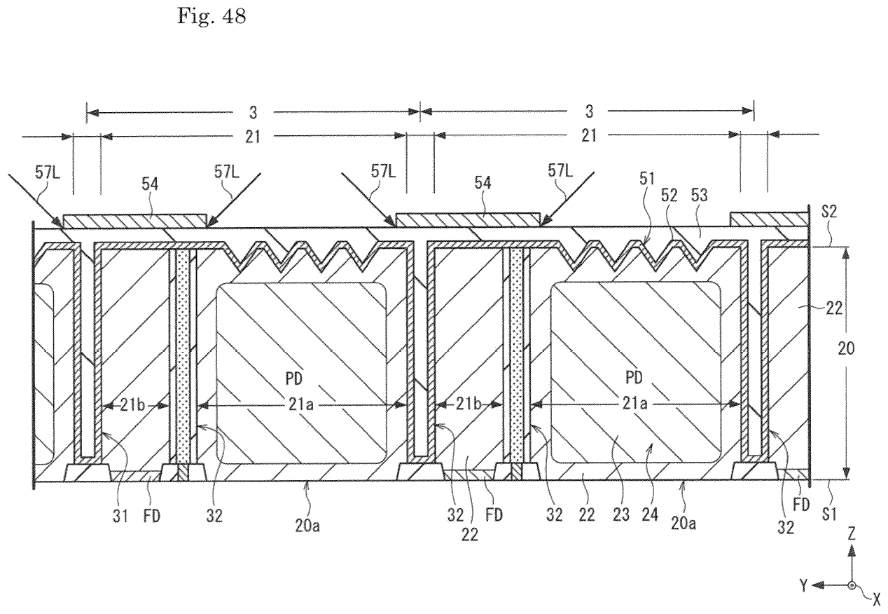

FIG. 48 is a longitudinal cross-sectional view schematically illustrating a penetration optical path of oblique light in Comparative Example 12-1.

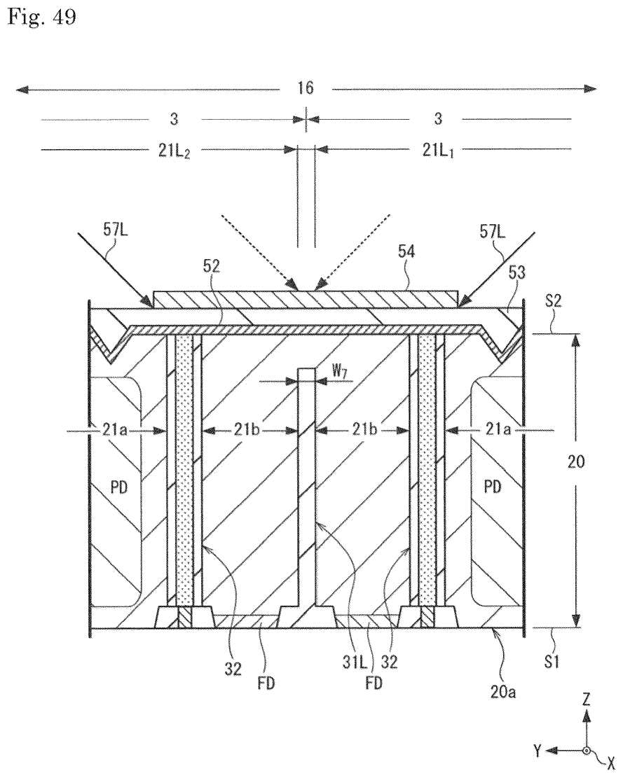

FIG. 49 is a longitudinal cross-sectional view schematically illustrating a penetration optical path of oblique light in a 12th embodiment.

As illustrated in FIG. 48, in a case in which the light blocking film 54 is disposed to overlap the second area 21b of the photoelectric conversion area 21, the oblique light, mainly, penetrates into the second area 21b immediately below the light blocking film 54 using an end portion side of the light blocking film 54 in a width direction (the Y direction) as a penetration optical path 57L. Since the light blocking film 54 has two end portions in the width direction (Y direction), there are also two penetration optical paths 57L in the Y direction for one light blocking film 54.

In Comparative Example 12-1, in each of two photoelectric conversion areas 21 aligned to be adjacent to each other in the Y direction, the disposition order in which the first area 21a and the second area 21b are aligned in the Y direction is the same. For this reason, there is one light blocking film 54 for each second area 21b, and there are two penetration optical paths 57L for each second area 21b.

In contrast to this, as illustrated in FIG. 49, in the photoelectric conversion cell 16 according to this 12th embodiment, in two photoelectric conversion areas 21L₁ and 21L₂ that are aligned to be adjacent to each other in the Y direction, the second area 21b of one photoelectric conversion area 21L₁ and the second area 21b of the other photoelectric conversion area 21L₂ are aligned to be adjacent to each other in the Y direction through the in-cell inter-pixel separation area 31L. For this reason, the light blocking film 54 can be disposed to be continuous over the second areas 21b of the two photoelectric conversion areas 21L₁ and 21L₂, one light blocking film 54 can be shared by these two second areas 21b. In the light blocking film 54 shared by these two second areas 21b, two penetration optical paths 57L are formed for two second areas 21b, and substantially one penetration optical paths 57L is formed for one second area 21b, whereby, compared to Comparative Example 12-1, penetration of oblique light into one second area 21b can be further more suppressed.

In addition, since the light blocking film 54 can be continuously disposed over the second area 21b of each of two photoelectric conversion areas 21L₁ and 21L₂, in the in-cell inter-pixel separation area 31L, out of insulating resistance and light blocking resistance, the insulating resistance may be emphasized, and thus, compared to an inter-pixel separation area 31 for which both the insulating resistance and the light blocking resistance need to be emphasized, the width W₇ in the short-side direction (a direction orthogonal to the extending direction) can be configured to be narrow.

Furthermore, the width W₇ of the in-cell inter-pixel separation area 31L can be configured to be narrow, a pixel pitch in the Y direction can be narrowed, and the area of the pixel array portion in the Y direction can be reduced, or the number of pixels in the Y direction within the same area can be increased. In accordance with this, an image sensor of a high resolution having a small size can be provided.

In addition, by randomly disposing the photoelectric conversion cell 16 by changing its orientation by 90°, the area of the pixel array portion in each of the X direction and the Y direction can be reduced.

In addition, since the light blocking film 54 can be continuously disposed over the second areas 21b of two photoelectric conversion areas 21L₁ and 21L₂, a configuration in which the in-cell inter-pixel separation area 31L is separated from the second face S2 of the light blocking film 54 side of the semiconductor layer 20 can be configured.

Furthermore, by forming the dug part 33L defining the length L₇ of the in-cell inter-pixel separation area 31L in the Z direction and the dug part 33a defining the length L₅ of the inter-pixel separation area 31 in the Z direction in different processes, the dug part 33L having a depth in the Z direction to be smaller than the depth of the dug part 33a in the Z direction can be formed, and the in-cell inter-pixel separation area 31L that is separated from the second face S2 of the light blocking film 54 side of the semiconductor layer 20 can be formed.

### <Advantages of Process>

Next, in the photoelectric conversion cell 16, advantages acquired in a case in which the dug part 33L and the dug part 33a are formed in different processes will be described with reference to Comparative Example 12-2.

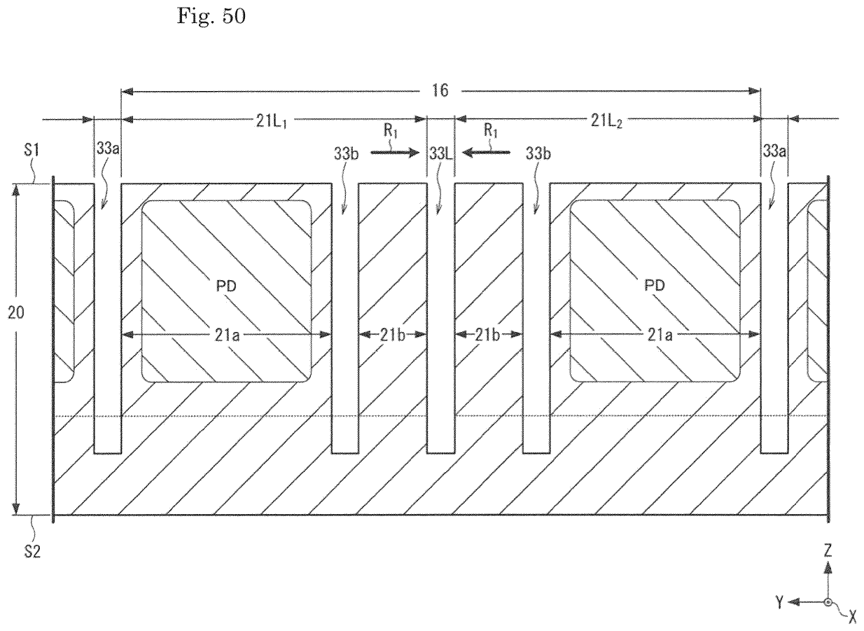

FIG. 50 is a longitudinal cross-sectional view illustrating a case in which a dug part (a third dug part) 33L defining the length L₇ of the in-cell inter-pixel separation area 31L in the Z direction and a dug part (a first dug part) 33a defining the length L₅ of the inter-pixel separation area 31 in the Z direction are formed in the same process in Comparative Example 12-2.

In addition, since the dug part 33b defining the length L₅ of the in-pixel separation area 32 in the Z direction is generally formed in the same process as the dug part 33a defining the length L₈ of the inter-pixel separation area 31 in the Z direction, description here will be omitted, and the dug parts 33L and 33a will be particularly described.

In addition, here, although the dug parts 33L and 33a will be described in a divisional manner, in a case in which the dug parts 33L and 33a are formed in the same process, the dug part 33L can be substituted with the dug part 33a.

As illustrated in FIG. 50, in a case in which the dug part 33L and the dug part 33a are formed in the semiconductor layer 20 in the same process, depths of the dug part 33L and the dug part 33a are almost the same. A space between two photoelectric conversion areas 21L₁ and 21L₂ that are aligned to be adjacent to each other in the Y direction is partitioned by the dug part 33L, and the periphery of each of these two photoelectric conversion areas 21L₁ and 21L₂ is partitioned by the dug part 33a.

After these dug parts 33L and 33a are formed, although not illustrated in the drawing, a washing process is performed.

In this washing process, in Comparative Example 12-2, out of two photoelectric conversion areas 21L₁ and 21L₂ that are aligned to be adjacent to each other in the Y direction, a space between the second area 21b of one photoelectric conversion area 21L₁ and the second area 21b of the other photoelectric conversion area 21L₂ is partitioned by the dug part 33L, and the periphery of each of these two photoelectric conversion areas 21L₁ and 21L₂ is partitioned by the dug part 33a. For this reason, in the washing process after formation of the dug part 33a in the semiconductor layer 20, in accordance with a capillary force (surface tension) due to evaporation of a cleaning solution, these two photoelectric conversion areas 21L₁ and 21L₂ that are aligned to be adjacent to each other in the Y direction are bent to fall to the dug part 33a side (a direction of an arrow R1 illustrated in FIG. 50) between the second area 21b of one of these two photoelectric conversion areas 21L₁ and 21L₂ and the second area 21b of the other. In accordance with this bending, a width narrowing phenomenon in which a width of an opening end side (the first face S1 side of the semiconductor layer 20) of the dug part 33a between the second area 21b of one of these two photoelectric conversion areas 21L₁ and 21L₂ and the second area 21b of the other becomes narrower than a designed value occurs. In a case in which this width narrowing phenomenon has occurred, it becomes difficult to embed a film into the inside of the dug part 33L, and the width narrowing phenomenon becomes a factor for reducing a product yield.

In recent years, in a device handling near-infrared light, in order to enhance the quantum efficiency QE, enlarging of the thickness of the semiconductor layer 20 and lengthening of the optical path length of the inside of the semiconductor layer 20 have been reviewed. However, the aspect ratio of the dug part increases (becomes higher) in accordance with an increase in the thickness of the semiconductor layer 20, and falling of the photoelectric conversion area 21 to the dug part 33a side becomes remarkable.

In contrast to this, in this 12th embodiment, as described above, formation of the dug part 33L and formation of the dug part 33a are performed in different processes.

In other words, as illustrated in FIG. 47A, when the dug part 33a is formed, the dug part 33L is not formed. After the dug part 33a is formed, similar to the comparative example, although the washing process is performed, in this washing process, between the second area 21b of one photoelectric conversion area 21L₁ out of two photoelectric conversion areas 21L₁ and 21L₂ and the second area 21b of the other photoelectric conversion area 21L₂, the dug part 33L is not formed. For this reason, in the washing process after formation of the dug part 33a in the semiconductor layer 20, bending (falling) of the photoelectric conversion areas 21L₁ and 21L₂ according to a capillary force (surface tension) due to evaporation of a cleaning solution can be suppressed.

When described with reference to FIG. 47C, after forming the dug part 33L between two photoelectric conversion areas 21L₁ and 21L₂ aligned to be adjacent to each other in the Y direction, when the washing process is performed, the separation insulating film 34 and the conductive material 35 have already been formed inside the dug part 33a, and thus bending (falling) of the photoelectric conversion areas 21L₁ and 21L₂ according to a capillary force (surface tension) due to evaporation of a cleaning solution can be suppressed.

Thus, in this 12th embodiment, compared to the case of Comparative Example 12-2, improvement of a manufacturing product yield can be achieved.

In addition, since the dug part 33L and the dug part 33a are formed in different processes, the depth of the dug part 33L can be configured to be shallow respect to the depth of the dug part 33a, and an in-cell inter-pixel separation area 31L of which the length L₇ in the Z direction is shorter than the length L₅ (see FIG. 46) of the inter-pixel separation area 31 in the Z direction can be formed. Furthermore, the width of the dug part 33L in the short-side direction can be configured to be narrower than the width of the dug part 33a in the short-side direction, and an in-cell inter-pixel separation area 31L of which the width W₇ in the short-side direction is narrower than the width W₈ of the inter-pixel separation area 31 in the short-side direction can be formed.

### Effects of 12th Embodiment

Next, main effects of this 12th embodiment will be described.

The solid-state imaging device 1L according to this 12th embodiment, similar to the solid-state imaging device 1A according to the first embodiment described above, includes the inter-pixel separation area 31, the in-cell inter-pixel separation area 31L, and the in-pixel separation area 32. Thus, also in the solid-state imaging device 1L according to this 12th embodiment, similar to the solid-state imaging device 1A according to the first embodiment described above, improvement of the quantum efficiency QE and high mixed color suppression (MTF) as pixel characteristics can be achieved, and improvement of transmission characteristics as pixel characteristics can be achieved.

In addition, the solid-state imaging device 1L according to this 12th embodiment, similar to the solid-state imaging device 1A according to the first embodiment described above, includes the light blocking film 54. Thus, also in the solid-state imaging device 1L according to this 12th embodiment, similar to the solid-state imaging device 1A according to the first embodiment described above, arrival (emission) of light at the floating diffusion region FD can be suppressed, and the parasitic light sensitivity characteristics (PLS) can be enhanced.

In addition, in the photoelectric conversion cell 16 according to this 12th embodiment, the second area 21b of one photoelectric conversion area 21L₁ out of two photoelectric conversion areas 21L₁ and 21L₂ that are aligned to be adjacent to each other in the Y direction and the second area 21b of the other photoelectric conversion area 21L₂ are disposed to be adjacent to each other in the Y direction through the in-cell inter-pixel separation area 31L. For this reason, the light blocking film 54 can be continuously disposed over the second area 21b of each of two photoelectric conversion areas 21L₁ and 21L₂, and one light blocking film 54 can be shared by the two second areas 21b. In the light blocking film 54 shared by the two second areas 21b, two penetration optical paths 57L are formed for the two second areas 21b, substantially one penetration optical path 57L is formed for one second area 21b, and thus, compared to Comparative Example 12-1, penetration of oblique light into one second area 21b can be further more suppressed. Thus, according to the solid-state imaging device 1L according to this 12th embodiment, in combination with an effect of enhancement of the parasitic light sensitivity characteristics according to light reflection of the light blocking film 54, further enhancement of the parasitic light sensitivity characteristics (PLS) can be achieved.

In addition, since the light blocking film 54 can be continuously disposed over the second area 21b of each of the two photoelectric conversion areas 21L₁ and 21L₂, in the in-cell inter-pixel separation area 31L, out of insulating resistance and light blocking resistance, the insulating resistance may be emphasized, and thus, compared to an inter-pixel separation area 31 for which both the insulating resistance and the light blocking resistance need to be emphasized, the width W₇ in the short-side direction (a direction orthogonal to the extending direction) can be configured to be narrow.

Furthermore, the width W₇ of the in-cell inter-pixel separation area 31L can be configured to be narrow, a pixel pitch in the Y direction can be narrowed, and the area of the pixel array portion in the Y direction can be reduced, or the number of pixels in the Y direction within the same area can be increased. In accordance with this, an image sensor of a high resolution having a small size can be provided.

In addition, by randomly disposing the photoelectric conversion cell 16 by changing its orientation by 90°, the area of the pixel array portion in each of the X direction and the Y direction can be reduced.

In addition, since the light blocking film 54 can be continuously disposed over the second areas 21b of two photoelectric conversion areas 21L₁ and 21L₂, a configuration in which the in-cell inter-pixel separation area 31L is separated from the second face S2 of the light blocking film 54 side of the semiconductor layer 20 can be configured.

Furthermore, by forming the dug part 33L defining the length L₇ of the in-cell inter-pixel separation area 31L in the Z direction and the dug part 33a defining the length La of the inter-pixel separation area 31 in the Z direction in different processes, bending (falling) of the photoelectric conversion areas 21L₁ and 21L₂ according to a capillary force (surface tension) due to evaporation of a cleaning solution can be suppressed. Thus, according to the method of manufacturing the solid-state imaging device 1L according to this 12th embodiment, improvement of a manufacturing production yield can be achieved.

### Modified Examples of 12th Embodiment

### Modified Example 12-1

In the 12th embodiment described above, although a case in which the in-cell inter-pixel separation area 31L including the insulating film 27 is used as the in-cell inter-pixel separation area has been described, the present technology is not limited to the in-cell inter-pixel separation area 31L of the 12th embodiment.

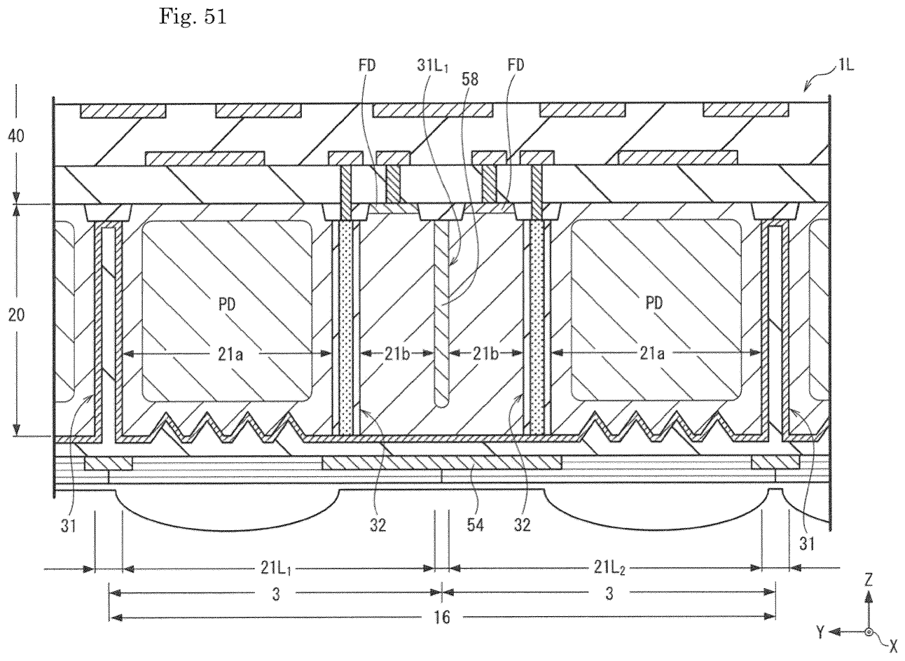

For example, as illustrated in FIG. 51, an in-cell inter-pixel separation area 31L₁ including a semiconductor area 58 of the n type that is a conductive type opposite to the well region of the p type may be used.

### Modified Example 12-2

In addition, although a case in which the light blocking film 54 is used in the 12th embodiment described above has been described, the present technology is not limited to the light blocking film 54 of the embodiment described above.

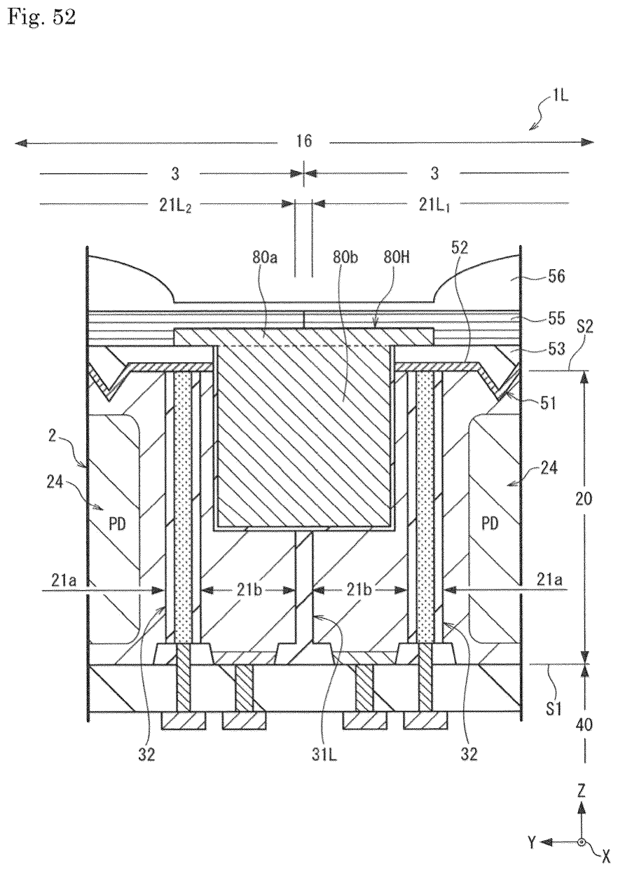

For example, as illustrated in FIG. 52, in place of the light blocking film 54, the light blocking body 80H of the above-described 8th embodiment illustrated in FIG. 20 can be used.

In this case, the light blocking body 80H is configured to include a first light blocking part 82a that is disposed on the outer side of the second face S2 of the semiconductor layer 20 and overlaps the second area 21b of each of two photoelectric conversion areas 21L₁ and 21L₂ in the plan view and a second light blocking part 82b that protrudes from this first light blocking part 82a to the inside of the second area 21b of each of the two photoelectric conversion areas 21L₁ and 21L₂.

### Modified Example 12-3

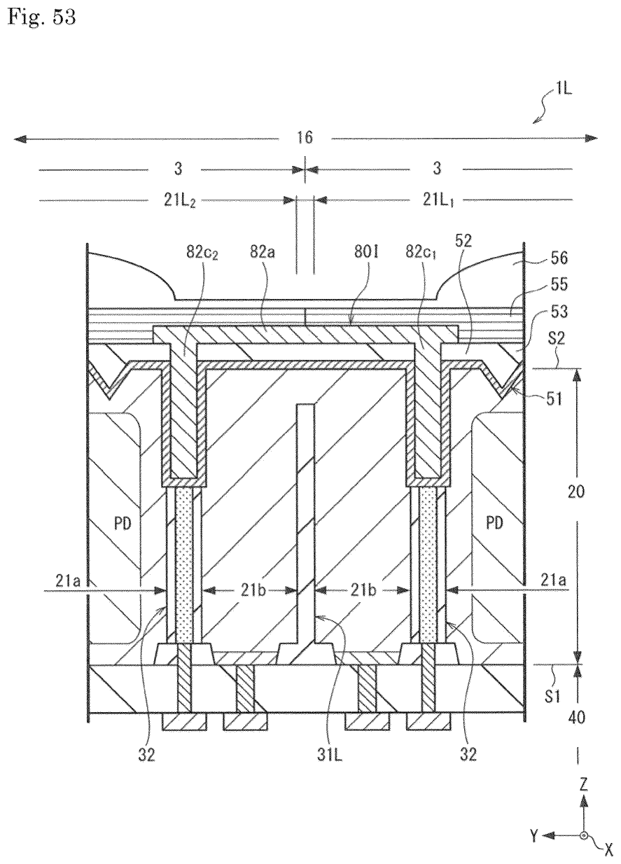

In addition, as illustrated in FIG. 53, in place of the light blocking film 54, the light blocking body 80I of the above-described ninth embodiment illustrated in FIG. 28 can be used.

In this case, the light blocking body 80I is configured to include a first light blocking part 82a that is disposed on the outer side of the second face S2 of the semiconductor layer 20 and overlaps the second area 21b of each of two photoelectric conversion areas 21L₁ and 21L₂ in the plan view, a second light blocking part 82c₁ that overlaps the in-pixel separation area 32 of one photoelectric conversion area 21L₁ out of the two photoelectric conversion areas 21L₁ and 21L₂ in the plan view and protrudes from the first light blocking part 82a to the inside of the semiconductor layer 20, and a second light blocking part 82c₂ that overlaps the in-pixel separation area 32 of the other photoelectric conversion area 21L₂ out of the two photoelectric conversion areas 21L₁ and 21L₂ in the plan view and protrudes from the first light blocking part 82a to the inside of the semiconductor layer 20.

### Modified Example 12-4

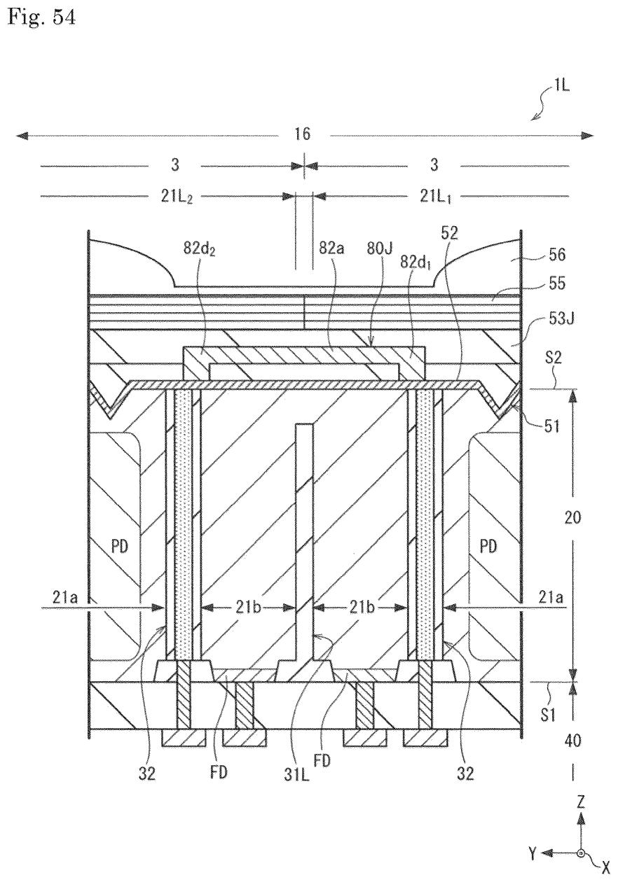

In addition, as illustrated in FIG. 54, in place of the light blocking film 54, the light blocking body 80J of the above-described 10th embodiment illustrated in FIG. 32 can be used.

In this case, the light blocking body 80J is configured to include a first light blocking part 82a that is disposed on a side opposite to the semiconductor layer 20 of the insulating film 53 and overlaps the second area 21b of each of two photoelectric conversion areas 21L₁ and 21L₂ in the plan view, a second light blocking part 82d₁ that overlaps the in-pixel separation area 32 of one photoelectric conversion area 21L₁ out of two photoelectric conversion areas 21L₁ and 21L₂ in the plan view and protrudes from the first light blocking part 82a to the inside of the insulating film 53, and a third light blocking part 82d₂ that overlaps the in-pixel separation area 32 of the other photoelectric conversion area 21L₂ out of the two photoelectric conversion areas 21L₁ and 21L₂ in the plan view, overlaps the inter-pixel separation area 31 in the plan view, and protrudes from the first light blocking part 82a to the inside of the insulating film 53.

### Modified Example 12-5

In addition, although not illustrated in the drawing, the light blocking film 54 and the light reflecting body 85K of the above-described 11th embodiment illustrated in FIG. 37B can be combined.

### Modified Example 12-6

In addition, in the 12th embodiment described above, although the solid-state imaging device 1L including the fixed charge film 52 has been described, the present technology can be applied also to the solid-state imaging device 1L not including the fixed charge film.

### 13th Embodiment

In this 13th embodiment, mainly, an in-pixel separation area will be described.

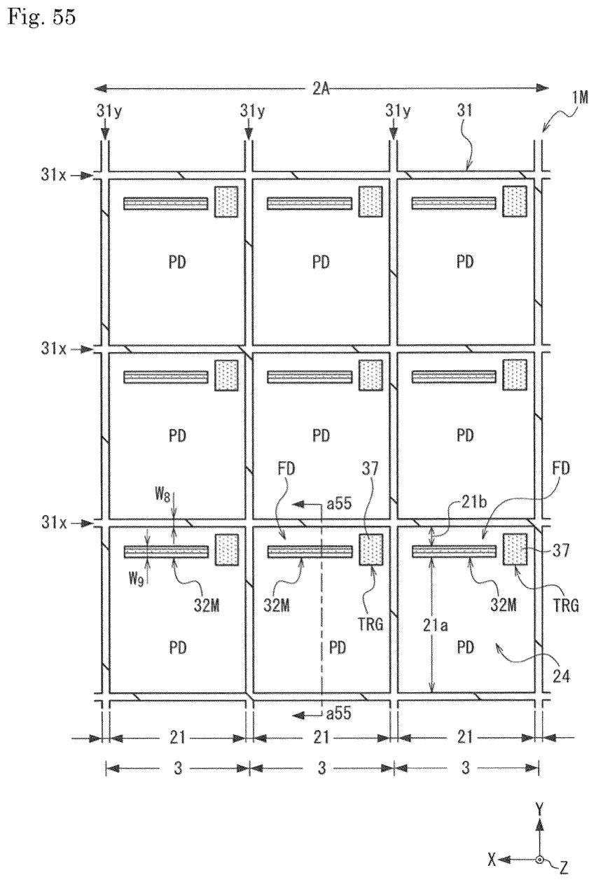

FIG. 55 is a plan view schematically illustrating a plane pattern of a separation area (an inter-pixel separation area and an in-pixel separation area) in a pixel array portion of a solid-state imaging device according to the 13th embodiment.

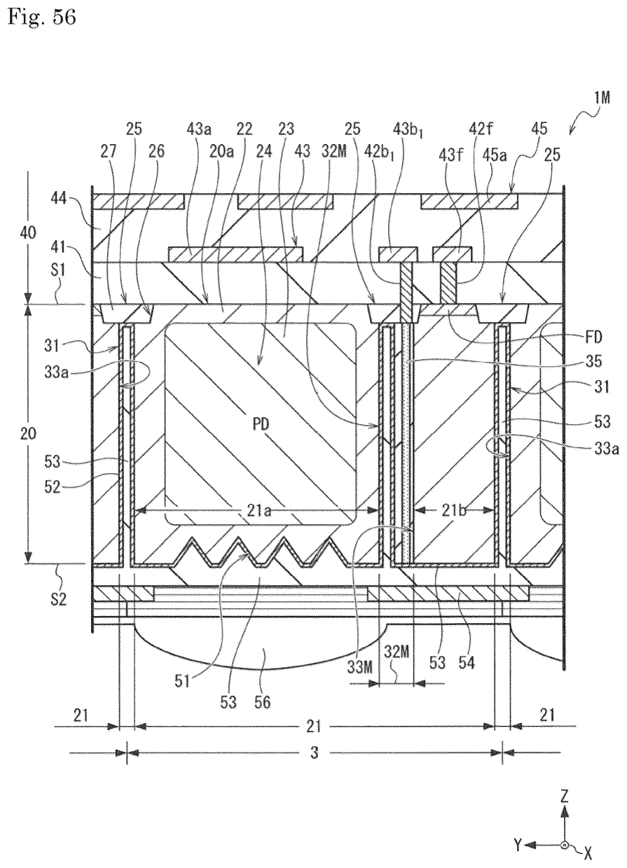

FIG. 56 is a longitudinal cross-sectional view schematically illustrating a longitudinal cross-sectional structure taken along line a55-a55 illustrated in FIG. 55.

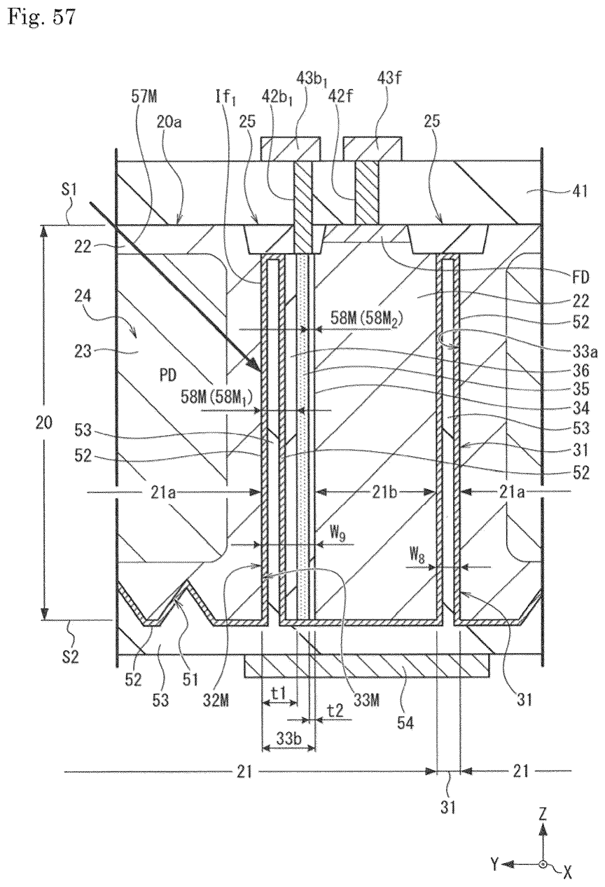

FIG. 57 is a longitudinal cross-sectional view in which a part of FIG. 56 is enlarged.

In this 13th embodiment, an inter-pixel separation area 31 corresponds to one specific example of “first separation area” of the present technology, and an in-pixel separation area 32M corresponds to one specific example of “second separation area” of the present technology. In addition, in this 13th embodiment, a first insulator 58M₁ and a second insulator 58M₂ correspond one specific example of “insulator” of the present technology. Furthermore, in this 12th embodiment, a dug part 33a and a dug part 33M respectively correspond to specific examples of “first dug part” and “second dug part”. In addition, a disposition direction of a first area 21a and a second area 21b of a photoelectric conversion area 21 corresponds to one specific example of “one direction” of the present technology.

### <<Configuration of Solid-state Imaging Device>>

As illustrated in FIGS. 55 to 57, the solid-state imaging device 1M according to the 13th embodiment of the present technology basically has a configuration similar to the solid-state imaging device 1A according to the first embodiment described above, and there are following different configurations.

In other words, as illustrated in FIGS. 55 to 57, the solid-state imaging device 1M according to this 13th embodiment, in place of the in-pixel separation area 32 of the above-described first embodiment illustrated in FIGS. 4 to 6, includes an in-pixel separation area 32M. The other configurations are similar to those of the first embodiment described above as a whole.

As illustrated in FIGS. 55 and 56, the in-pixel separation area 32M, similar to the in-pixel separation area 32 of the first embodiment described above, for example, is disposed to extend in the X direction in the plan view and is disposed to be separated from an inter-pixel separation area 31 (a first part 31x and a second part 31y). The in-pixel separation area 32M is disposed to deviate to the inter-pixel separation area 31 side from the center portion of the photoelectric conversion area 21 in the plan view in the Y direction and selectively separates (divides) the photoelectric conversion area 21 into two areas (a first area 21a and a second area 21b) of which widths in the Y direction in the plan view are relatively different from each other. Out of the two areas (the first area 21a and the second area 21b) separated by the in-pixel separation area 32M, a photoelectric conversion unit 24 is disposed in the first area 21a of which the width in the Y direction is wide, and a floating diffusion region FD is disposed in the second area 21b of which the width in the Y direction is narrow. In other words, the in-pixel separation area 32 separates the photoelectric conversion area 21 into the first area 21a and the second area 21b in one direction (the Y direction). The floating diffusion region FD is disposed on a first face S1 side of a semiconductor layer 20 in the second area 21b of the photoelectric conversion area 21.

The in-pixel separation area 32M extends in the thickness direction (the Z direction) of the semiconductor layer 20 and has a one-end side connected to an element separation area 25 and the other side reaching a second face S2 of the semiconductor layer 20. The in-pixel separation area 32M of this 13th embodiment has a configuration of a longitudinal cross-section to be different from that of the in-pixel separation area 32 of the first embodiment described above.

As illustrated in FIG. 57, the in-pixel separation area 32M includes an insulator 58M that is disposed along a side wall of the inside of a dug part 33M extending in the thickness direction (the Z direction) of the semiconductor layer 20 and has a refractive index lower than the semiconductor layer 20 and a conductive material 35 filling this dug part 33M through the insulator 58M. The insulator 58M is disposed in each of the first area 21a side and the second area 21b side of the conductive material 35 in a disposition direction (the Y direction) of the first area 21a and the second area 21b of the photoelectric conversion area 21.

Here, the insulator 58M of the first area 21a side of the conductive material 35 may be referred to as a first insulator 58M₁, and the insulator 58M of the second area 21b side of the conductive material 35 may be referred to as a second insulator 58M₂.

Each of the dug part 33M, the conductive material 35, and the insulator 58 extends from the element separation area 25 disposed on the first face side of the semiconductor layer 20 toward the second face S2 of the semiconductor layer 20.

As illustrated in FIG. 57, the conductive material 35 is electrically separated from the first area 21a through the first insulator 58M₁ disposed on the first area 21a side of the conductive material 35 in the Y direction. In addition, the conductive material 35 is electrically separated from the second area 21b through the second insulator 58M₂ disposed on the second area 21a side of the conductive material 35 in the Y direction.

The conductive material 35 of the in-pixel separation area 32M has a configuration that is similar to the conductive material 35 of the first embodiment described above. In other words, also the conductive material 35 of the in-pixel separation area 32M has one end side being electrically connected to a wiring 43b₁ through a contact electrode 42b₁. Also the conductive material 35 of the in-pixel separation area 32M is supplied with a second reference electric potential applied to the wiring 43b₁ through the contact electrode 42b₁ and has the electric potential being fixed to this second reference electric potential.

As illustrated in FIG. 57, in the in-pixel separation area 32M, a film thickness t1 of the first insulator 58M₁ on the first area 21a side of the conductive material 35 is larger than a film thickness t2 of the second insulator 58M₂ on the second area 21b side of the conductive material 35 (t1>t2). In other words, in the in-pixel separation area 32M, the film thickness t1 of the first insulator 58M₁ between the conductive material 35 and the first area 21a is larger than the film thickness of the second insulator 58M₂ between the conductive material 35 and the second area 21b in the plan view (t1>t2). In other words, in the in-pixel separation area 32M, inside the dug part 33M, the conductive material 35 is disposed to deviate to the second area 21b side from the first area 21a side in the plan view.

For example, the film thickness t1 of the first insulator 58M₁ is set to about 50 nm, and the film thickness t2 of the second insulator 58M₂ is set to about 10 nm, but the thicknesses are not limited thereto.

As illustrated in FIG. 57, the first insulator 58M₁, for example, has a multilayer structure including a fixed charge film 52, an insulating film 53, a fixed charge film 52, and an insulating film 36 aligned from the first area 21a side toward the second area 21b side in the Y direction but is not limited thereto. In contrast to this, the second insulator 58M₂ has a single-layer structure, for example, including one separation insulating film 34 in the Y direction.

Each of the insulating film 53, the separation insulating film 34, and the insulating film 36, for example, is composed of a silicon oxide film. This silicon oxide film has a refractive index lower than a semiconductor material such as Si, SiGe, InGaAs, or the like.

The fixed charge film 52, for example, includes a film of hafnium oxide (HfO₂), zirconium oxide (ZrO₂), tantalum oxide (Ta₂O₅), or the like as a dielectric film that generates negative fixed charge. Such a dielectric film has a refractive index lower than a semiconductor material such as Si, SiGe, InGaAs, or the like. In addition, a film thickness of the fixed charge film 52 is very small relative to the film thickness of the insulating film 53. In FIG. 57, in order to allow easy understanding of the configuration of the fixed charge film 52, the film thickness of the fixed charge film 52 is drawn to be larger than an actual ratio. Thus, the first insulator 58M₁ including the fixed charge film 52 together with the insulating films 53 and 36 can be regarded as a layer having a refractive index lower than the semiconductor layer 20.

In addition, as one example, for example, in the case of light of a wavelength of 940 nm, silicon, for example, has a refractive index of about 3.62, silicon oxide, for example, has a refractive index of about 1.45, and the air, for example, has a refractive index of about 1.00.

In addition, as another example, for example, in the case of light of a wavelength of 550 nm, silicon, for example, has a refractive index of about 4.08, silicon oxide, for example, has a refractive index of about 1.46, and the air, for example, has a refractive index of about 1.00.

As illustrated in FIGS. 55 and 57, the in-pixel separation area 32M and the inter-pixel separation area 31 have different widths in the short-side direction. More specifically, the width W₉ of the in-pixel separation area 32M is larger than the width W₈ of the inter-pixel separation area 31 (W₉>W₈).

### <<Method of Manufacturing Solid-state Imaging Device>>

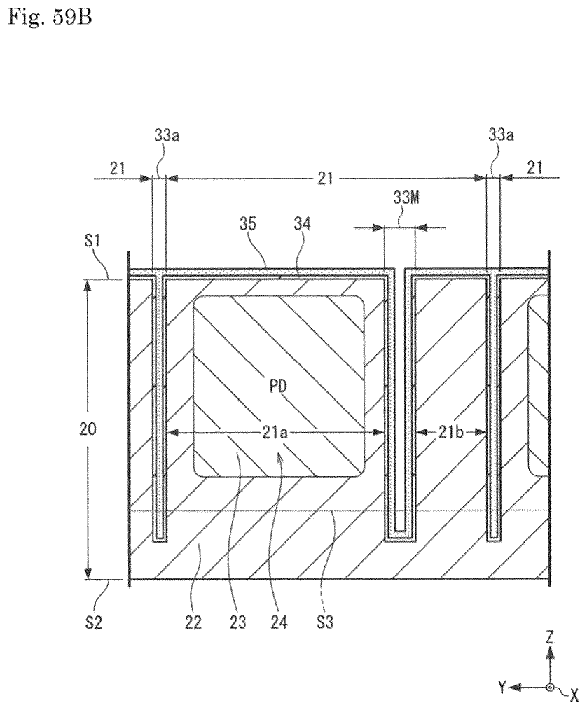

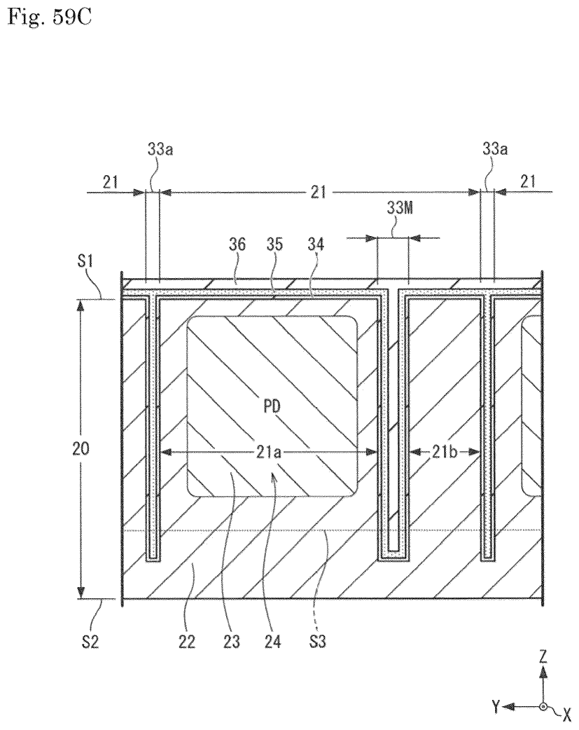

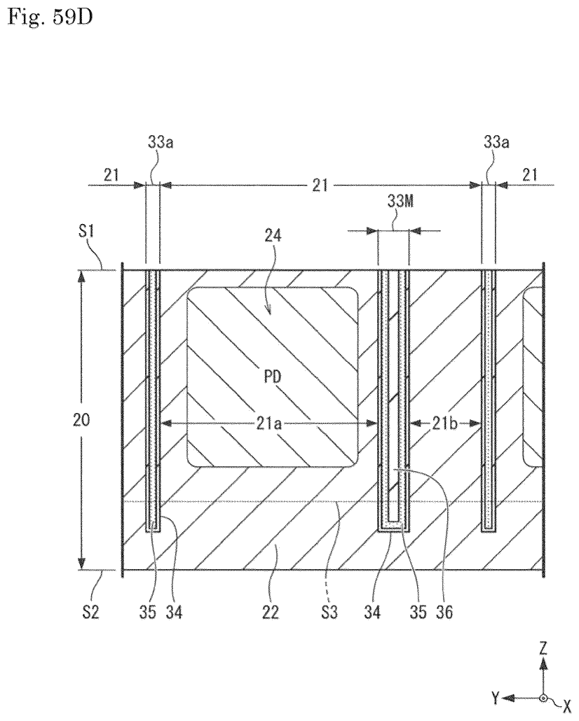

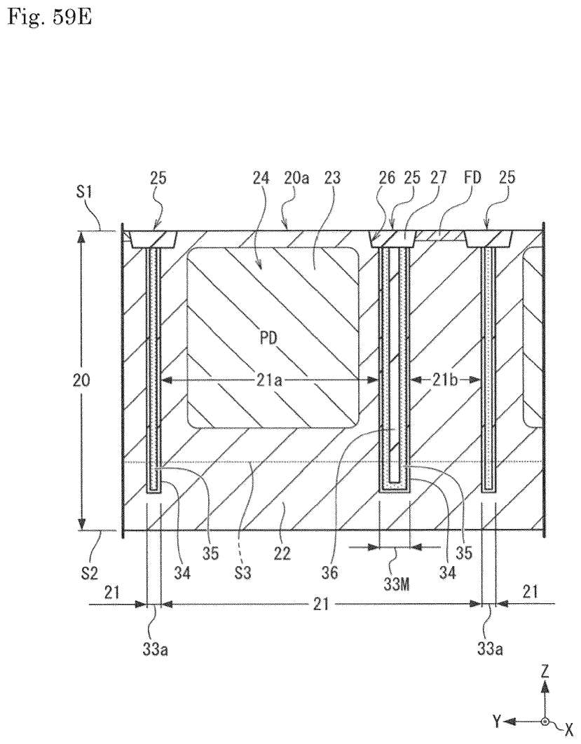

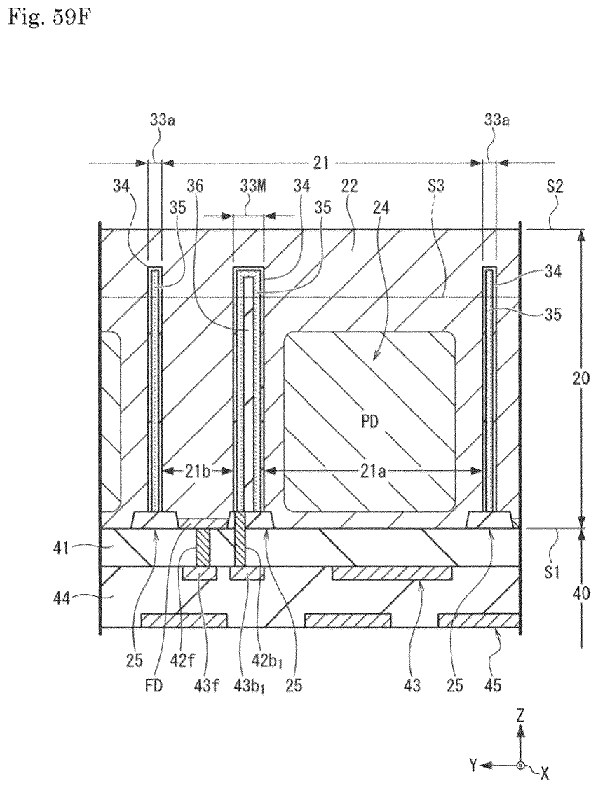

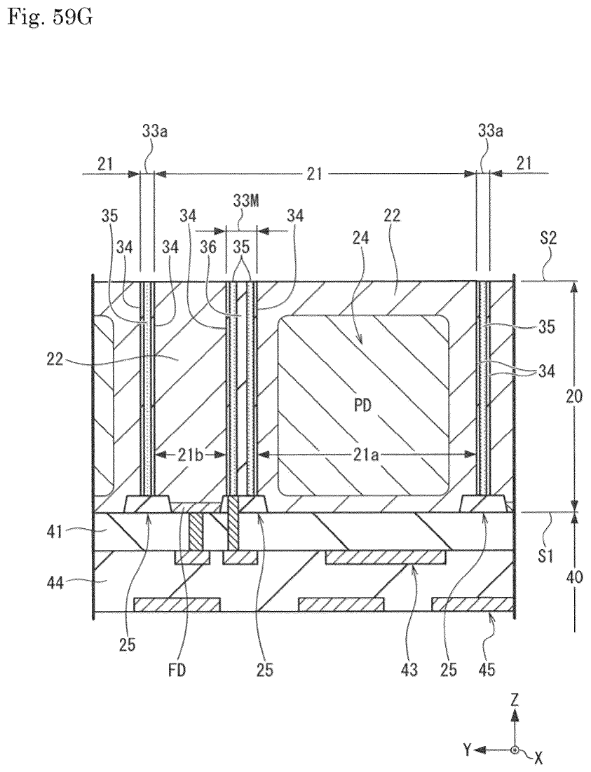

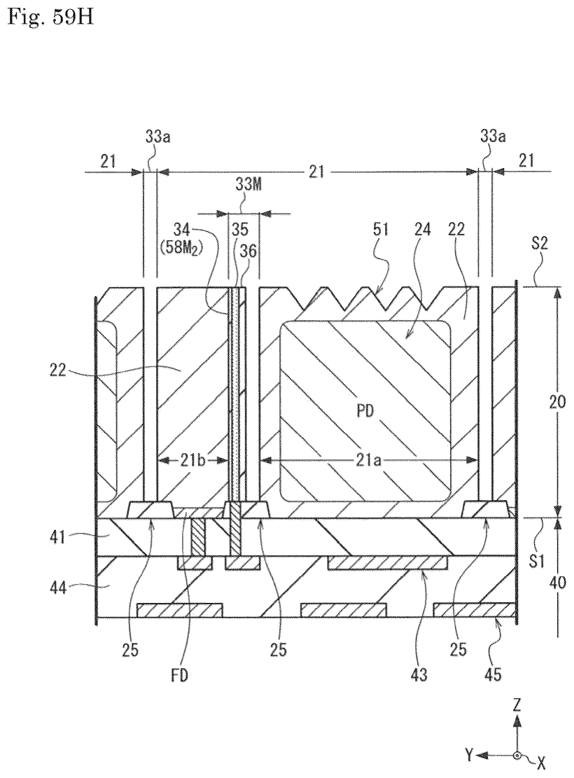

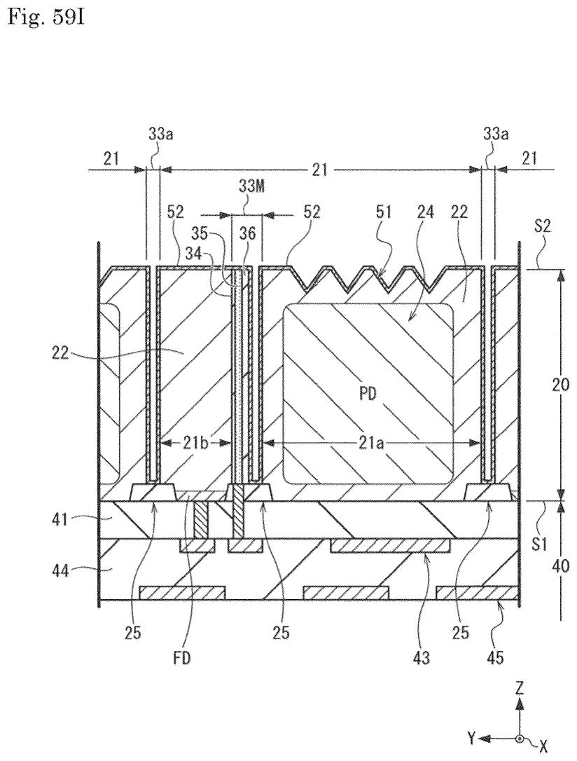

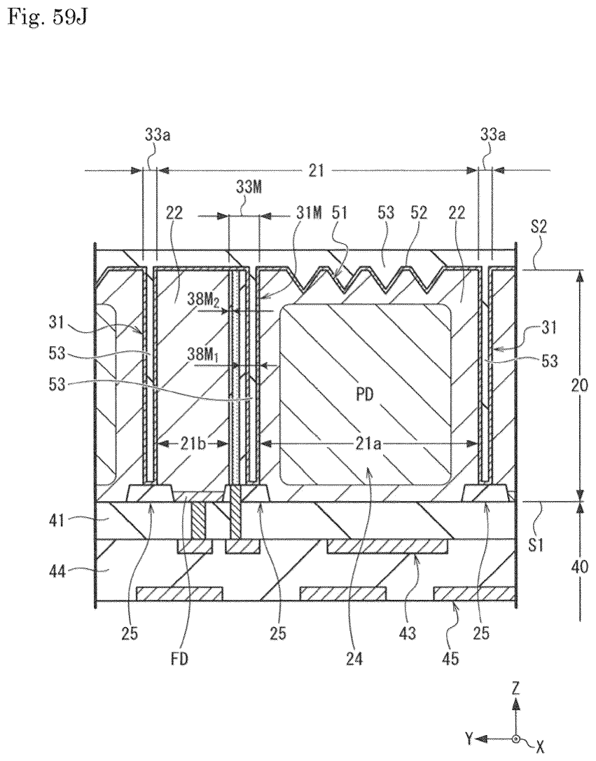

Next, a method of manufacturing the solid-state imaging device 1M according to the 13th embodiment of the present technology will be described with reference to FIGS. 59A to 59I. In this 13th embodiment, manufacturing of the in-pixel separation area 32M included in the method of manufacturing the solid-state imaging device 1M will be particularly described.

First, as illustrated in FIG. 59A, in the semiconductor layer 20, dug parts 33a and 33M extending from the first face S1 of the semiconductor layer 20 toward the second face S2 are formed.

The dug part 33a partitions the photoelectric conversion area 21L. The dug part 33M partitions the photoelectric conversion area 21 into a first area 21a and a second area 21b aligned in the Y direction. Each of the dug parts 33a and 33M can be formed using a known photolithographic technology and an anisotropic dry etching technology. A width of the dug part 33M in the short-side direction (the Y direction) is formed to be larger than a width of the dug part 33a in the short-side direction.

In this process, in the first area 21a of the photoelectric conversion area 21, the well region 22 of the p type, the semiconductor area 23 of the n type, the photoelectric conversion unit 24 (PD), and the like have already been formed. In the second area 21b of the photoelectric conversion area 21L, the well region 22 of the p type has already been formed.

Here, in the manufacturing of the solid-state imaging device 1M of this 13th embodiment, a thinning process (see FIG. 59F) of decreasing the thickness of the semiconductor layer 20 is performed. Thus, a depth of each of the dug parts 33a and 33M in the Z direction (the thickness direction of the semiconductor layer 20) is formed to be deeper than a thinning line S3 representing the thickness of the semiconductor layer 20 formed in the thinning process.

Next, after the dug parts 33a and 33M are formed, as illustrated in FIG. 59B, inside of each of the dug parts 33a and 33M, a separation insulating film 34 and a conductive material 35 are formed in this order. The separation insulating film 34 is formed to have a film thickness extending along a side wall and a bottom wall of the inside of each of the dug parts 33a and 33M. As the separation insulating film 34, for example, a silicon oxide film is deposited and formed using a CVD method. The conductive material 35 is formed with a film thickness for which the inside is embedded in the dug part 33a, and it extends along the side wall and the bottom wall of the inside in the dug part 33M. As the conductive material 35, for example, a doped polysilicon film into which impurities for reducing a resistance value have been introduced is deposited and formed using a CVD method. The separation insulating film 34 and the conductive material 35 are formed also on the first face S1 of the semiconductor layer 20.

In this process, inside the dug part 33M, from the first area 21a side of the photoelectric conversion area 21 toward the second area 21b side, a separation insulating film 34, a conductive material 35, a space portion (a gap portion), a conductive material 35, and a separation insulating film 34 are aligned and disposed in a multilayer shape.

Next, after the separation insulating film 34 and the conductive material 35 are formed, as illustrated in FIG. 59C, inside of the dug part 33M, an insulating film 36 is formed through the separation insulating film 34 and the conductive material 35. As the insulating film 36, for example, a silicon oxide film is deposited and formed with a film thickness for embedding the inside of the dug part 33M using a CVD method. The insulating film 36 is formed also on the first face S1 of the semiconductor layer 20.

In this process, inside the dug part 33M, from the first area 21a side of the photoelectric conversion area 21 toward the second area 21b side, a separation insulating film 34, a conductive material 35, an insulating film 36, a conductive material 35, and a separation insulating film 34 are aligned and disposed in a multilayer shape. The conductive material 35 of the first area 21a side is used as an assist electrode. The separation insulating film 34 of the first area 21a side is used as a second insulator 58M₂.

Next, after the insulating film 34 is formed, as illustrated in FIG. 59D, each of the insulating film 36, the conductive material 35, and the separation insulating film 34 on the first face S1 of the semiconductor layer 20 is selectively removed such that the separation insulating film 34 and the conductive material 35 remain inside of each of the dug parts 33a and 33M. The insulating film 36, the conductive material 35, and the separation insulating film 34 can be selectively removed using a CMP method or an etching-back method.

Next, after each of the insulating film 36, the conductive material 35, and the separation insulating film 34 is selectively removed, as illustrated in FIG. 59E, an element formation area 20a and an element separation area 25 are formed on the first face S1 of the semiconductor layer 20. The element formation area 20a is partitioned by the element separation area 25 and is formed in the first area 21a of the photoelectric conversion area 21.

The element separation area 25, for example, can be formed by forming a shallow groove part (a field groove part) 26 depressed from the first face S1 of the semiconductor layer 20 to the second face S2 side, thereafter, forming an insulating film 27, for example, formed from a silicon oxide film on the entire face on the first face S1 of the semiconductor layer 20 including the inside of the shallow groove part 26, and thereafter selectively removing the insulating film 27 on the first face S1 of the semiconductor layer 20 using the CMP method such that the insulating film 27 remains inside of the shallow groove part 26. As the insulating film 27, for example, a silicon oxide film of which a refractive index is lower than that of a semiconductor material such as Si, SiGe, InGaAs, or the like can be used.

In this process, the element separation area 25 is formed to overlap each of the dug part 33a and the dug part 33M in the plan view.

Next, after the element formation area 20a and the element separation area 25 are formed, although not illustrated in the drawing, pixel transistors (AMP, SEL, RST, and TRG) are formed in the element formation area 20a, and as illustrated in FIG. 59E, a floating diffusion region FD is formed in the second area 21b of the photoelectric conversion area 21. The floating diffusion region FD is formed on the first face S1 side of the semiconductor layer 20 in the second area 21b of the photoelectric conversion area 21.

Next, as illustrated in FIG. 59F, a multilayer wiring layer 40 is formed on the first face S1 side of the semiconductor layer 20. Thereafter, by vertically inverting the semiconductor layer 20 and performing a thinning process of decreasing the thickness of the semiconductor layer 20 by cutting the second face S2 side of the semiconductor layer 20, for example, using a CMP method, as illustrated in FIG. 59G, the separation insulating film 34 and the conductive material 35 disposed inside the dug part 33a are exposed, and the separation insulating film 34 and the conductive material 35 disposed inside the dug part 33M are exposed. The thinning of the semiconductor layer 20 is performed up to a thinning line S3 illustrated in FIG. 59F.

Next, as illustrated in FIG. 59H, a diffraction scattering section 51 is formed on the second face S2 side of the semiconductor layer 20 in the first area 21a of the photoelectric conversion area 21, and the separation insulating film 34 and the conductive material 35 disposed inside of the dug part 33a and the separation insulating film 34 and the conductive material 35 of the first area 21a side of the inside of the dug part 33M are selectively removed. Although the process of forming the diffraction scattering section 51 is performed separately from the process of selectively removing the separation insulating film 34 and the conductive material 35, any one of the processes may be performed first. The separation insulating film 34 and the conductive material 35 can be selectively removed using a known photolithographic technology and an anisotropic dry etching technology.

In this process, the insulating film 36 disposed inside of the dug part 33M is etched on the second area 21b side, and a film thickness thereof becomes slightly thin.

Next, as illustrated in FIG. 59I, a fixed charge film 52 is formed. The fixed charge film 52 is formed over the first area 21a and the second area 21b of the photoelectric conversion area 21 on the second face S2 side of the semiconductor layer 20 and is formed in accordance with the side wall and the bottom wall of the inside of each of the dug parts 33a and 33M and unevenness of the diffraction scattering section 51.

Next, after the fixed charge film 52 is formed, as illustrated in FIG. 59J, an insulating film 53 is formed on the entire face of the second face S2 side of the semiconductor layer 20 including the inside of each of the dug parts 33a and 33M. For example, after a silicon oxide film is formed using a CVD method, by planarizing the surface side of this silicon oxide film using a CMP method through cutting, an insulating film 53 can be formed.

In this process, an inter-pixel separation area 31 including the fixed charge film 52 and the insulating film 53 is formed inside the dug part 33a.

In addition, in this process, when described with reference to FIG. 57, a first insulator 58M₁ that includes an insulating film 36, a fixed charge film 52, an insulating film 53, and a fixed charge film 52 sequentially aligned in a multilayer shape from the conductive material 35 side toward the second area 21a side on the first area 21a side of the conductive material 35 inside the dug part 33M and has a film thickness t1 to be larger than the film thickness t2 of the second insulator 58M₂ is formed. Then, an in-pixel separation area 32M including a first insulator 58M₁, a conductive material 35, and a second insulator 58M₂ sequentially aligned in a multilayer shape from the first area 21a side to the second area 21b side is formed.

In addition, in this process, the in-pixel separation area 32M has a width W₉ in the short-side direction to be larger than a width W₈ of the inter-pixel separation area 31 in the short-side direction.

Next, as illustrated in FIGS. 56 and 57B, a light blocking film 54 is formed on a side opposite to the semiconductor layer 20 side of the insulating film 53. The light blocking film 54 is formed to overlap the second area 21b of the photoelectric conversion area 21L.

Thereafter, by forming a color filter 55 and a microlens 56 on a side opposite to the semiconductor layer 20 side of the light blocking film 54 in this order, a state illustrated in FIGS. 44 to 46B is formed.

In addition, also in the solid-state imaging device 1M according to this 13th embodiment, by dividing a semiconductor wafer including the semiconductor layer 20 and the multilayer wiring layer 40 for each chip formation area, the state of the semiconductor chip 2 illustrated in FIG. 1 is formed.

### <<Light Reflection Function of In-pixel Separation Area>>

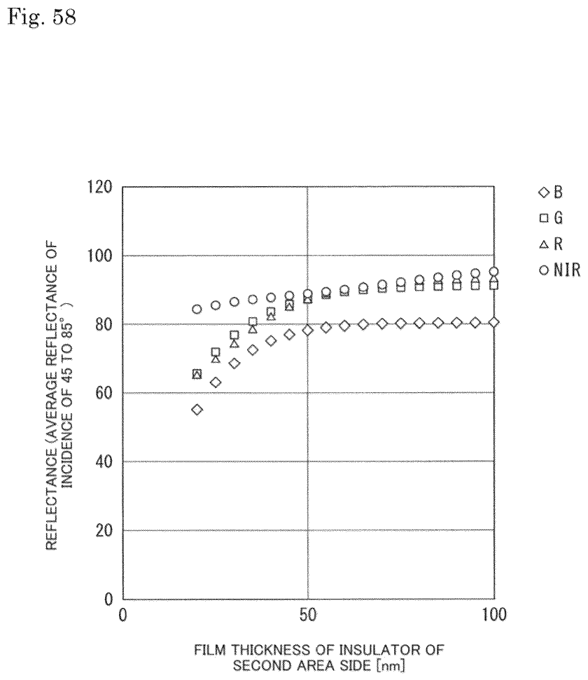

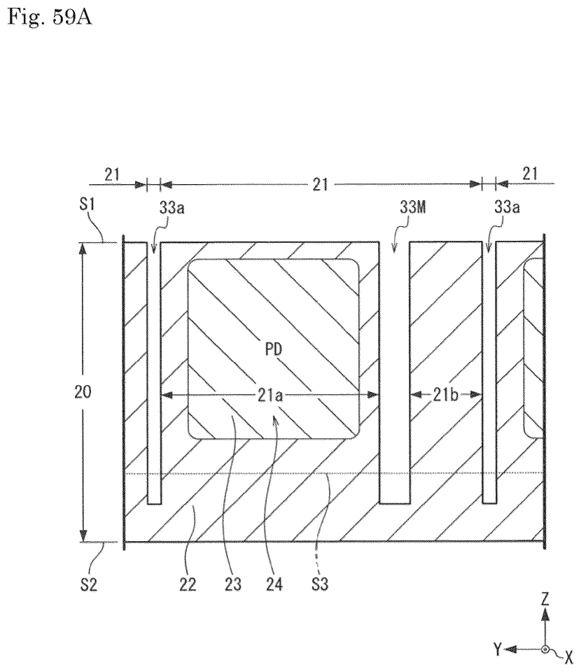

Next, a light reflection function of the in-pixel separation area 32M will be described with reference to FIGS. 57 and 58.

FIG. 58 is a diagram illustrating a correlation between an optical reflectance at an interface part If₁ between the first area 21a of the photoelectric conversion area 21 and the in-pixel separation area 32M and a film thickness t1 of the first insulator 58M₁ on the first area 21a side of the in-pixel separation area 32M. Here, the reflectance of the vertical axis is a reflectance of a case in which incidence light is emitted to the interface part If₁ between the first area 21a of the photoelectric conversion area 21 and the in-pixel separation area 32M with 45° to 85°. In FIG. 58, B is data of light of a blue wavelength band, G is data of light of a green wavelength band, R is data of light of a red wavelength band, and NIR is data of light of a near-infrared wavelength band.

As illustrated in FIG. 57, generally, light 57M incident from the second face S2 side (a light incident face side) of the semiconductor layer 20 has an incidence angle of 45° or more with respect to the interface part If₁ between the first area 21a of the photoelectric conversion area 21 and the in-pixel separation area 32. In addition, the photoelectric conversion area 21 is formed using a semiconductor material (for example, silicon) absorbing light and, generally, has a large (high) refractive index. In this way, in the case of light reflection having a large incidence angle in a medium of a high refractive index, total reflection conditions are satisfied. Actually, silicon (Si) having a transmittance of “n=3 to 4” and silicon oxide (SiO₂) having a transmittance of “n=1.5” satisfy total reflection conditions for an incidence angle of 20 to 30° or more. Although, in a case in which the thickness t1 of the first insulator 58M₁ of the in-pixel separation area 32M is small with respect to the wavelength of light 57M, an evanescent component is transmitted and penetrates into the second area 21b side, as the film thickness t1 of the first insulator 58M₁ on the first area 21a side of the conductive material 35 becomes thicker, the evanescent component becomes smaller.

On the other hand, when signal electric charge that has been photoelectrically converted by the photoelectric conversion unit 24 is transmitted to the floating diffusion region FD, by changing the potential of the semiconductor layer 20 of the side wall of the in-pixel separation area 32M by applying a positive electric potential to the conductive material 35 of the in-pixel separation area 32M, the in-pixel separation area 32M functions as an assistance electrode assisting transmission of signal electric charge to the floating diffusion region FD (a transmission performance in the second area 21b). In order to improve the transmission performance in this second area 21b, it is preferable that the film thickness t2 of the second insulator 58M₂ on the second area 21b side of the conductive material 35 be small.

Thus, by configuring the film thickness t1 of the first insulator 58M₁ positioned on the first area 21a side of the conductive material 35 to be larger than the film thickness t2 of the second insulator 58M₂ positioned on the second area 21b side of the conductive material 35, the reflectance at the interface part If₁ between the first area 21a of the photoelectric conversion area 21 and the in-pixel separation area 32M is improved, and transmission of signal electric charge that has been photoelectrically converted by the photoelectric conversion unit 24 of the first area 21a to the floating diffusion region FD can be improved.

As illustrated in FIG. 58, in the case of any wavelength band, the optical reflectance at the interface part If₁ is improved by depending on the film thickness t1 of the first insulator 58M₁. The improvement of the optical reflectance is saturated when the film thickness t1 of the first insulator 58M₁ is near 50 nm. Although the larger the film thickness t1 of the first insulator 58M₁, the better, when the film thickness t1 of the first insulator 58M₁ becomes larger, the volume of the second area 21a (the photoelectric conversion unit 24 (PD)) of the photoelectric conversion area 21 becomes smaller, and thus there is an influence on reduction of sensitivity. Thus, the film thickness t1 of the first insulator 58M₁ is preferably about 50 nm.

A difference between the film thickness t1 of the first insulator 58M₁ and the film thickness t2 of the second insulator 58M₂ is different from a dimension error due to processing irregularity during a manufacturing process.

In addition, in this 13th embodiment, although the first insulator 58M₁ includes the fixed charge film 52, also in a case in which the fixed charge film 52 is not included or a case in which a dielectric such as a silicon nitride (Si₃N₄) film, an air layer or the like is included, a similar effect of improvement of an optical reflectance can be acquired.

### Main Effects of 13th Embodiment

Next, main effects of this 13th embodiment will be described.

The solid-state imaging device 1M according to this 13th embodiment, similar to the solid-state imaging device 1A according to the first embodiment described above, includes the inter-pixel separation area 31 and the in-pixel separation area 32M. Thus, also in the solid-state imaging device 1M according to this 13th embodiment, similar to the solid-state imaging device 1A according to the first embodiment described above, improvement of the quantum efficiency QE and high mixed-color suppression (MTF) as pixel characteristics can be achieved, and improvement of transmission characteristics as pixel characteristics can be achieved.

In addition, the solid-state imaging device 1L according to this 13th embodiment, similar to the solid-state imaging device 1A according to the first embodiment described above, includes the light blocking film 54. Thus, also in the solid-state imaging device 1M according to this 12th embodiment, similar to the solid-state imaging device 1A according to the first embodiment described above, arrival (emission) of light at the floating diffusion region FD can be suppressed, and the parasitic light sensitivity characteristics (PLS) can be enhanced.

Furthermore, in the in-pixel separation area 32M of this 13th embodiment, the film thickness t1 of the first insulator 58M₁ on the first area 21a side of the conductive material 35 is configured to be larger than the film thickness t2 of the second insulator 58M₂ on the second area 21b side of the conductive material 35. In accordance with this, since the optical reflectance at the interface part If₁ between the first area 21a of the photoelectric conversion area 21 and the in-pixel separation area 32M is improved, the amount of light absorbed by the photoelectric conversion unit 24 (PD) of the first area 21a increases, and improvement of the quantum efficiency QE (sensitivity) can be achieved, penetration of light into the second area 21b can be suppressed, and arrival (emission) of light at the floating diffusion region FD can be suppressed. Thus, according to the solid-state imaging device 1M according to this 13th embodiment, in combination with the effect of enhancement of the parasitic light sensitivity characteristics according to light blocking of the light blocking film 54, further more enhancement of the parasitic light sensitivity characteristics (PLS) can be achieved, and improvement of the quantum efficiency QE (sensitivity) can be achieved.

### Modified Example of 13th Embodiment

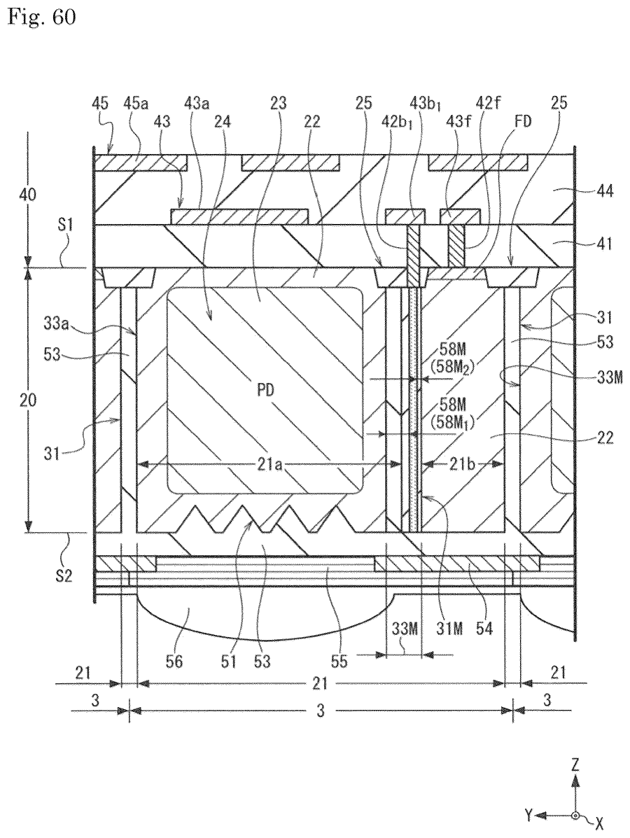

In the 13th embodiment described above, although the first insulator 58M₁ including the fixed charge film 52 has been described, as illustrated in FIG. 60, the first insulator 58M₁ may be configured not to include the fixed charge film 52.

In addition, in the 13th embodiment described above, although the solid-state imaging device 1M including the fixed charge film 52 has been described, the present technology can be applied also to a solid-state imaging device 1M not including the fixed charge film.

### 14th Embodiment

In this 14th embodiment, mainly, an example in which the present technology is applied to a solid-state imaging device performing photoelectric conversion of near-infrared light will be described.

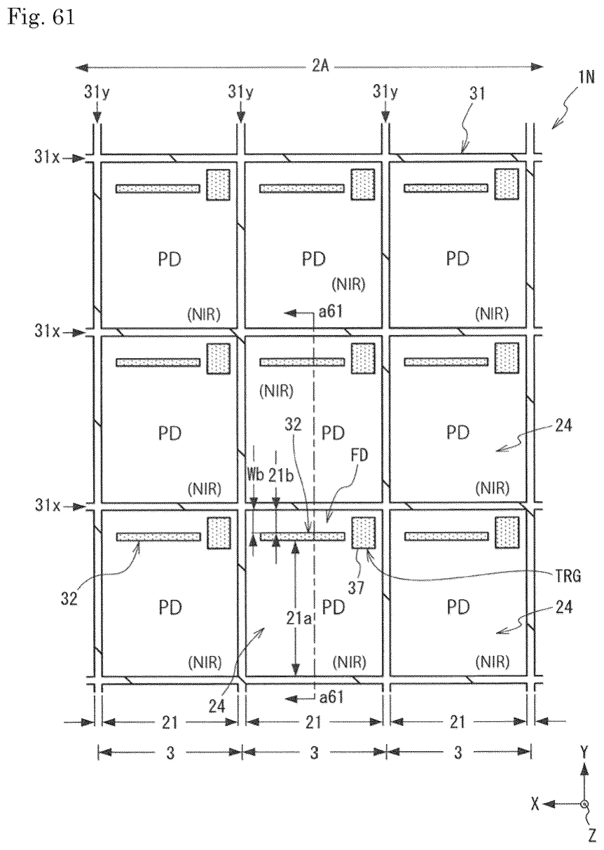

FIG. 61 is a plan view schematically illustrating a plane pattern of a separation area (an inter-pixel separation area 31 and an in-pixel separation area 32) in a pixel array portion 2A of a solid-state imaging device IN according to the 14th embodiment of the present technology.

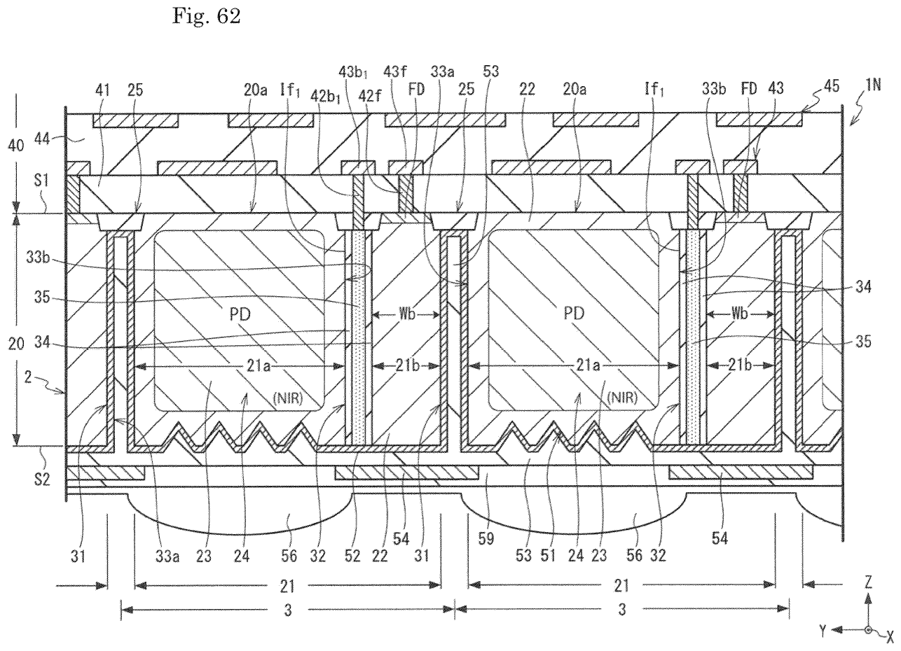

FIG. 62 is a longitudinal cross-sectional view schematically illustrating a longitudinal cross-sectional structure taken along line a61-a61 illustrated in FIG. 61.

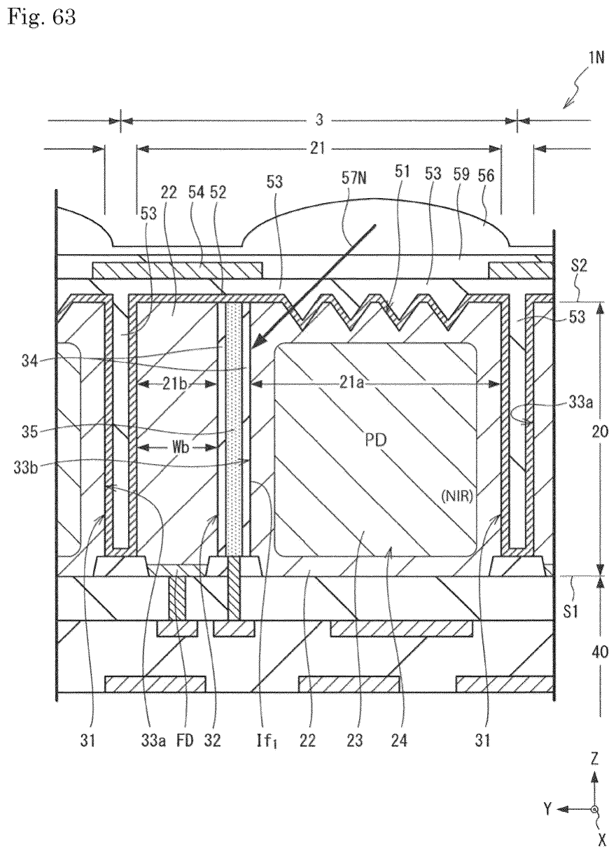

FIG. 63 is a longitudinal cross-sectional view in which a part of FIG. 62 is enlarged and is inverted vertically.

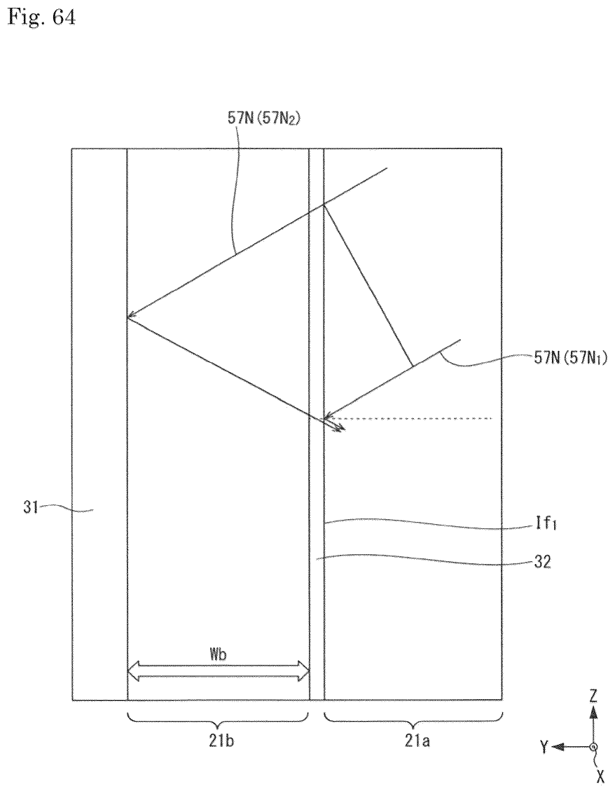

FIG. 64 is a diagram schematically illustrating an interference between reflection light 57N₁ reflected in the in-pixel separation area 32 and return light 57N₂ reflected in the inter-pixel separation area 31.

### <<Configuration of Solid-state Imaging Device>>

As illustrated in FIGS. 61 and 62, the solid-state imaging device IN according to the 14th embodiment of the present technology has a configuration that is basically similar to the solid-state imaging device 1A according to the first embodiment described above and has a different configuration of a photoelectric conversion area 21.

In other words, in the photoelectric conversion area 21 of this 14th embodiment illustrated in FIGS. 61 and 62, a width Wb of a second area 21b in the Y direction is set in accordance with a type (a wavelength) of light that has been photoelectrically converted by a photoelectric conversion unit 24 (PD) of a first area 21a. The width Wb of the second area 21b is set such that an optical reflectance in an interface part If₁ between the first area 21a of the photoelectric conversion area 21 and a side wall of the in-pixel separation area 32 rises.

Here, the width Wb of the second area 21b in the Y direction is a width in a disposition direction of the first area 21a and the second area 21a of the photoelectric conversion area 21.

More specifically, as illustrated in FIG. 63, incidence light 57N that has been incident (penetrated) in the first area 21a of the photoelectric conversion area 21 from the second face S2 of the semiconductor layer 20 reaches an interface part If₁ (a side wall of the first area 21a side of the in-pixel separation area 32) between the first area 21a and the in-pixel separation area 32. As the incidence light 57N reaching this interface part If₁, as illustrated in FIG. 64, there are reflection light 57N₁ reflected on the interface part If₁ and return light 57N₂ that is transmitted through the in-pixel separation area 32, is further reflected on the inter-pixel separation area 31, and returns to the first area 21a. By setting the width Wb of the second area 21b of the photoelectric conversion area 21 such that a phase difference between this reflection light 57N₁ and the return light 57N₂ becomes an integer multiple (24n) of the incidence light 57N, an optical reflectance at the interface part If₁ between the first area 21a of the photoelectric conversion area 21 and the side wall of the in-pixel separation area 32 rises.

In this 14th embodiment, for example, in all the photoelectric conversion area 21, the photoelectric conversion unit 24 (PD) photoelectrically converts near-infrared light (NIR) of the wavelength of 800 nm into signal electric charge but is not limited thereto. The solid-state imaging device IN according to this 14th embodiment, as illustrated in FIGS. 62 and 63, does not include the color filter 55 of the above-described first embodiment illustrated in FIGS. 5 and 6. The solid-state imaging device IN according to this 14th embodiment includes a planarization film 59 disposed to cover the light blocking film 54 between the insulating film 53 and the microlens 56.

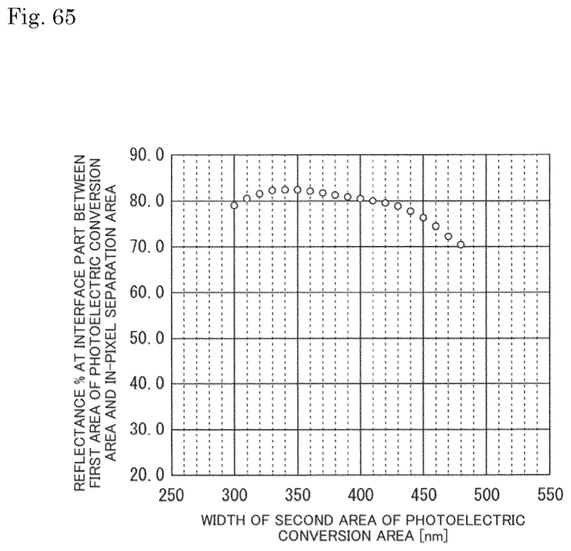

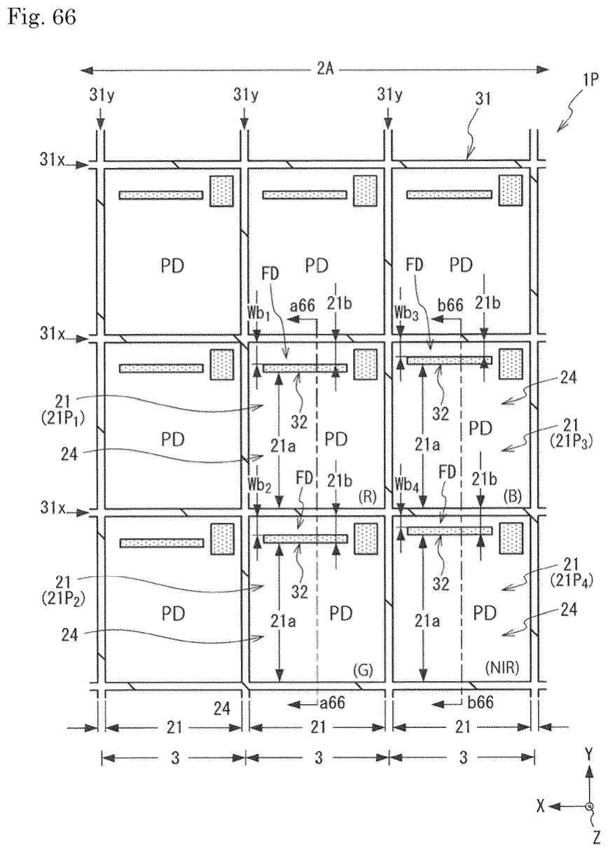

FIG. 65 is a diagram illustrating a correlation between a width Wb of the second area 21b of the photoelectric conversion area 21 and an optical reflectance at a side wall of the first area 21a of the in-pixel separation area 32 (the interface part If₁ between the first area 21a of the photoelectric conversion area 21 and the side wall of the in-pixel separation area 32) in near-infrared light.

A relation between the width Wb of the second area 21b of the photoelectric conversion area 21 and the optical reflectance at the interface part If₁ is as illustrated in FIG. 65, and the optical reflectance at the interface part If₁ is a maximum when the width Wb of the second area 21b is 350 nm.

Thus, by setting the width Wb of the second area 21b of the photoelectric conversion area 21 such that a phase difference between this reflection light 57N₁ and the return light 57N₂ becomes an integer multiple (24n) of the incidence light 57N, the optical reflectance of the incidence light 57N at the interface part If₁ between the first area 21a of the photoelectric conversion area 21 and the side wall of the in-pixel separation area 32 can be raised.

In addition, since the optical reflectance at the interface part If₁ between the first area 21a of the photoelectric conversion area 21 and the side wall of the in-pixel separation area 32 can be raised, a light component absorbed by the photoelectric conversion unit 24 (PD) disposed in the first area 21a of the photoelectric conversion area 21 increases, and improvement of the sensitivity of the solid-state imaging device IN can be achieved. Furthermore, since the optical reflectance at the interface part If₁ between the first area 21a of the photoelectric conversion area 21 and the side wall of the in-pixel separation area 32 can be raised, arrival (emission) of the incidence light 57N at the floating diffusion region FD disposed in the second area can be suppressed, and, in combination with the effect of enhancing the parasitic light sensitivity characteristics according to light blocking of the light blocking film 54, further more enhancement of the parasitic light sensitivity characteristics (PLS) can be achieved.

In addition, as illustrated in FIG. 63, the in-pixel separation area 32 has a configuration in which the separation insulating film 34 is disposed in each of the first area 21a side and the second area 21b side of the conductive material 35. Similar to the 13th embodiment described above, this separation insulating film 34 can be regarded as a single insulator. Thus, the in-pixel separation area 32 has a configuration in which the conductive material 35 is disposed in each of the first area side and the second area side of the inside of the dug part 33b through an insulator including the separation insulating film 34.

### 15th Embodiment

In the 14th embodiment described above, although the solid-state imaging device IN that mainly performs photoelectric conversion of near-infrared light has been described, in this 15th embodiment, an example in which the present technology is applied to a solid-state imaging device that performs photoelectric conversion of light of a wavelength of red, light of a wavelength of green, light of a wavelength of blue, and near-infrared light will be described.

FIG. 66 is a plan view schematically illustrating a plane pattern of a separation area (an inter-pixel separation area 31 and an in-pixel separation area 32) of a pixel array portion 2A of the solid-state imaging device 1P according to the 15th embodiment of the present technology.

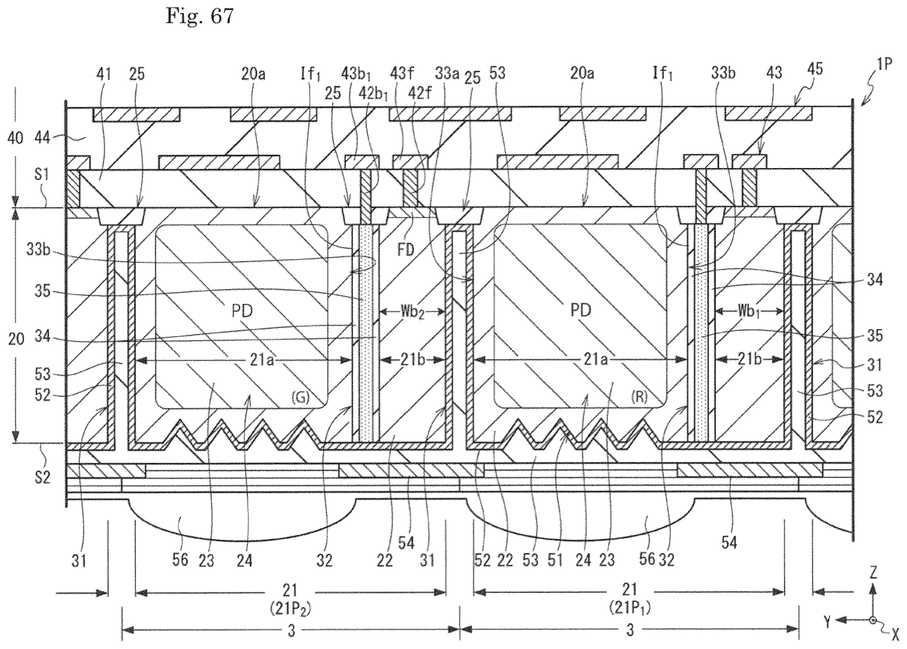

FIG. 67 is a longitudinal cross-sectional view schematically illustrating a longitudinal cross-sectional structure taken along line a66-a66 illustrated in FIG. 66.

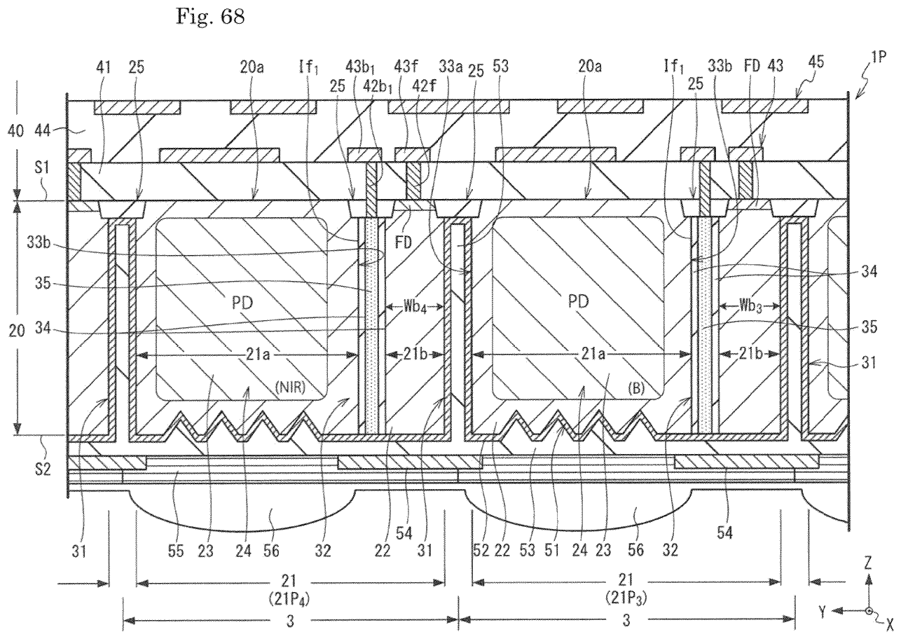

FIG. 68 is a longitudinal cross-sectional view schematically illustrating a longitudinal cross-sectional structure taken along line b66-b66 illustrated in FIG. 66.

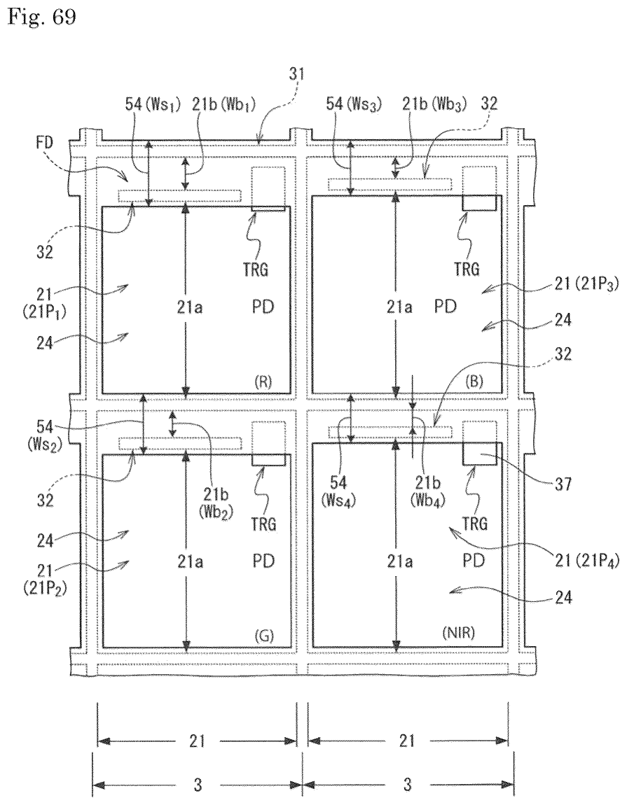

FIG. 69 is a plan view schematically illustrating a plane pattern of a light blocking body.

### <<Configuration of Solid-state Imaging Device>>

As illustrated in FIGS. 66 and 68, the solid-state imaging device 1P according to the 15th embodiment of the present technology has a configuration that is basically similar to the solid-state imaging device 1A according to the first embodiment described above and has a different configuration of a pixel array portion 2A.

As illustrated in FIG. 66, the pixel array portion 2A of this 15th embodiment includes a plurality of photoelectric conversion areas 21 disposed in correspondence with a plurality of pixels 3 disposed in a matrix pattern. The plurality of photoelectric conversion areas 21 include two or more types of photoelectric conversion areas 21 of which widths of the second areas 21b in the Y direction are different from each other. In this 15th embodiment, the plurality of photoelectric conversion areas 21 include four types of photoelectric conversion areas 21 (21P₁, 21P₂, 21P₃, and 21P₄) of which widths of the second areas 21b in the Y direction are different from each other but are not limited thereto.

The photoelectric conversion area 21P₁ illustrated in FIGS. 66 and 67 performs photoelectric conversion of light of the wavelength of red (R) using a photoelectric conversion unit 24 (PD) of a first area 21a. In this photoelectric conversion area 21P₁, the width Wb₁ of the second area 21b in the Y direction is set such that the optical reflectance with which light of the wavelength of red is reflected in an interface part If₁ between the first area 21a and the side wall of the in-pixel separation area 32 is raised.

The photoelectric conversion area 21P₂ illustrated in FIGS. 66 and 67 performs photoelectric conversion of light of the wavelength of green (G) using a photoelectric conversion unit 24 (PD) of a first area 21a. In this photoelectric conversion area 21P₂, the width Wb₂ of the second area 21b in the Y direction is set such that the optical reflectance with which light of the wavelength of green is reflected in an interface part If₁ between the first area 21a and the side wall of the in-pixel separation area 32 is raised. The width Wb₂ of the second area 21b of this photoelectric conversion area 21P₂ is smaller than the width Wb₁ of the second area 21b of the photoelectric conversion area 21P₁ (Wb₂<Wb₁).

The photoelectric conversion area 21P₃ illustrated in FIGS. 66 and 68 performs photoelectric conversion of light of the wavelength of blue (B) using a photoelectric conversion unit 24 (PD) of a first area 21a. In this photoelectric conversion area 21P₃, the width Wb₃ of the second area 21b in the Y direction is set such that the optical reflectance with which light of the wavelength of blue is reflected in the interface part If between the first area 21a and the side wall of the in-pixel separation area 32 is raised. The width Wb₃ of the second area 21b of this photoelectric conversion area 21P₃ is smaller than the width Wb₂ of the second area 21b of the photoelectric conversion area 21P₂ (Wb₃<Wb₂).

The photoelectric conversion area 21P₄ illustrated in FIGS. 66 and 68 performs photoelectric conversion of near-infrared light (NIR) using a photoelectric conversion unit 24 (PD) of a first area 21a. In this photoelectric conversion area 21P₄, the width Wb₄ of the second area 21b in the Y direction is set such that the optical reflectance with which near-infrared light is reflected in the interface part If₁ between the first area 21a and the side wall of the in-pixel separation area 32 is raised. The width Wb₄ of the second area 21b of this photoelectric conversion area 21P₄ is smaller than the width Wb₃ of the second area 21b of the photoelectric conversion area 21P₂ (Wb₄<Wb₃).

In other words, widths (Wb₁, Wb₂, Wb₃, and Wb₄) of the second areas 21b of the photoelectric conversion areas 21P₁ to 21P₄ are set such that the optical reflectance at the interface part If₁ is raised. The widths of the second areas 21b (Wb₁>Wb₂>Wb₃>Wb₄) of the photoelectric conversion areas 21P₁ to 21P₄ are different from each other.

Regarding the optical reflectance at the interface part If₁ of each of the photoelectric conversion areas 21P₁ to 21P₄, when described with reference to FIG. 64 of the 14th embodiment described above, similar to the first embodiment described above, by setting the width (Wb₁, Wb₂, Wb₃, and Wb₄) of the second area 21b of the photoelectric conversion area 21 such that a phase difference between reflection light 57N₁ and return light 57N₂ becomes an integer multiple (24n) of the incidence light 57N, the optical reflectance at the interface part If₁ between the first area 21a of the photoelectric conversion area 21 and the side wall of the in-pixel separation area 32 rises.

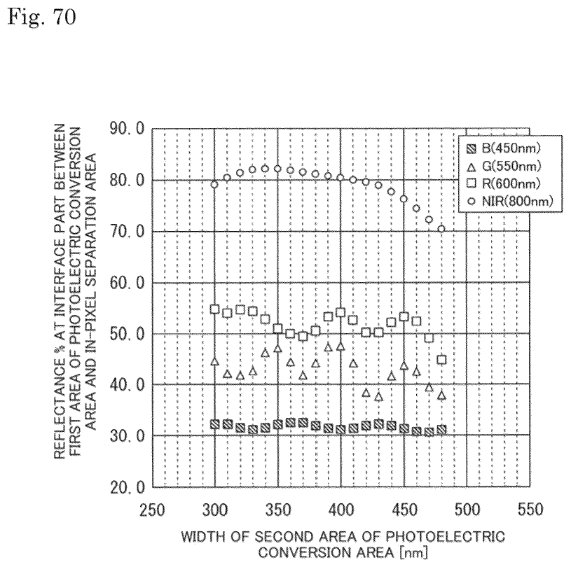

FIG. 70 is a diagram illustrating a correlation between a width (Wb₁, Wb₂, Wb₃, and Wb₄) of the second area 21b of the photoelectric conversion area 21 and an optical reflectance at a side wall of the first area 21a side of the in-pixel separation area 32 (an interface part If₁ between the first area 21a of the photoelectric conversion area 21 and the side wall of the in-pixel separation area 21b) in light (R) of the wavelength of red, light (G) of the wavelength of green, light (B) of the wavelength of blue, and near-infrared light (NIR).

In the photoelectric conversion areas 21P₁ to 21P₄, relations between widths (Wb₁, Wb₂, Wb₃, and Wb₄) of the second areas 21b and the optical reflectance at the interface part If₁ are as illustrated in FIG. 69, the optical reflectance of the interface part If₁ in the photoelectric conversion area 21P₁ is a maximum when the width Wb₁ of the second area 21b is 400 nm, the optical reflectance of the interface part If₁ in the photoelectric conversion area 21P₂ is a maximum when the width Wb₂ of the second area 21b is 390 nm, the optical reflectance of the interface part If₁ in the photoelectric conversion area 21P₃ is a maximum when the width Wb₃ of the second area 21b is 360 nm, and the optical reflectance of the interface part If₁ in the photoelectric conversion area 21P₄ is a maximum when the width Wb₄ of the second area 21b is 400 nm.

Thus, in the photoelectric conversion areas 21P₁ to 21P₄, by setting the width (Wb₁, Wb₂, Wb₃, and Wb₄) of the second area 21b of each of the photoelectric conversion areas 21 such that a phase difference between the reflection light 57N₁ and the return light 57N₂ becomes an integer multiple (24n) of the incidence light 57N, the optical reflectance of the incidence light 57N at the interface part If₁ between the first area 21a of the photoelectric conversion area 21 and the side wall of the in-pixel separation area 32 of the first area 21a of the photoelectric conversion area 21 can be raised. In the photoelectric conversion area 21P₁ to 21P₄, the widths (Wb₁, Wb₂, Wb₃, and Wb₄) of the second areas 21b in the Y direction are different from each other.

In addition, in the photoelectric conversion areas 21P₁ to 21P₄, since the optical reflectance at the interface part If₁ between the first area 21a and the side wall of the in-pixel separation area 32 can be raised, the component of light absorbed by the photoelectric conversion unit 24 (PD) disposed in the first area 21a of the photoelectric conversion area 21 increases, and the improvement of the sensitivity of the solid-state imaging device 1P can be achieved. In addition, since the optical reflectance at the interface part If₁ between the first area 21a of the photoelectric conversion area 21 and the side wall of the in-pixel separation area 32 can be raised, arrival (emission) of incidence light 57N at the floating diffusion region FD disposed in the second area can be suppressed, and, in combination with an effect of enhancement of the parasitic light sensitivity characteristics according to light reflection of the light blocking film 54, further more enhancement of the parasitic light sensitivity characteristics (PLS) can be achieved.

Here, as illustrated in FIG. 69, it is preferable that also the width of the light blocking film 54 in the Y direction be changed in accordance with the width (Wb₁, Wb₂, Wb₃, or Wb₄) of the second area 21b of each of the photoelectric conversion areas 21P₁ to 21P₄ in the Y direction. In this 15th embodiment, since the widths of the second areas 21b of the photoelectric conversion areas 21P₁ to 21P₄ are formed to be Wb₁>Wb₂>Wb₃>Wb₄, when the width of the light blocking film 54 in the photoelectric conversion area 21P₁ is denoted as Ws₁, the width of the light blocking film 54 in the photoelectric conversion area 21P₂ is denoted as Ws₂, the width of the light blocking film 54 in the photoelectric conversion area 21P₃ is denoted as Ws₃, and the width of the light blocking film 54 in the photoelectric conversion area 21P₄ is denoted as Ws₄, the widths of the light blocking films 54 of the photoelectric conversion area 21p₁ to 21p4 are formed to be Wb₁>Wb₂>Wb₃>Wb₄.

In addition, as illustrated in FIGS. 67 and 68, also in this 15th embodiment, the in-pixel separation area 32 is formed to have a configuration in which a separation insulating film 34 is disposed in each of the first area 21a side and the second area 21b side of the conductive material 35. Similar to the 13th embodiment described above, this separation insulating film 34 can be regarded as a single insulator. Thus, the in-pixel separation area 32 is formed to have a configuration in which a conductive material 35 is disposed through an insulator including the separation insulating film 34 in each of the first area side and the second area side of the inside of the dug part 33b.

In addition, in this 15th embodiment, although the solid-state imaging device 1P including the in-pixel separation area 32 as a second separation area has been described, the present technology can be applied also to a solid-state imaging device including an in-pixel separation area 32M of the above-described 14th embodiment illustrated in FIG. 57.

### 16th Embodiment

In this 16th embodiment, a protrusion part protruding from an in-pixel separation area to a second area side of a photoelectric conversion area will be described as a dielectric in which an insulating film is disposed in a dug part extending in a depth direction of a semiconductor layer through a fixed charge film.

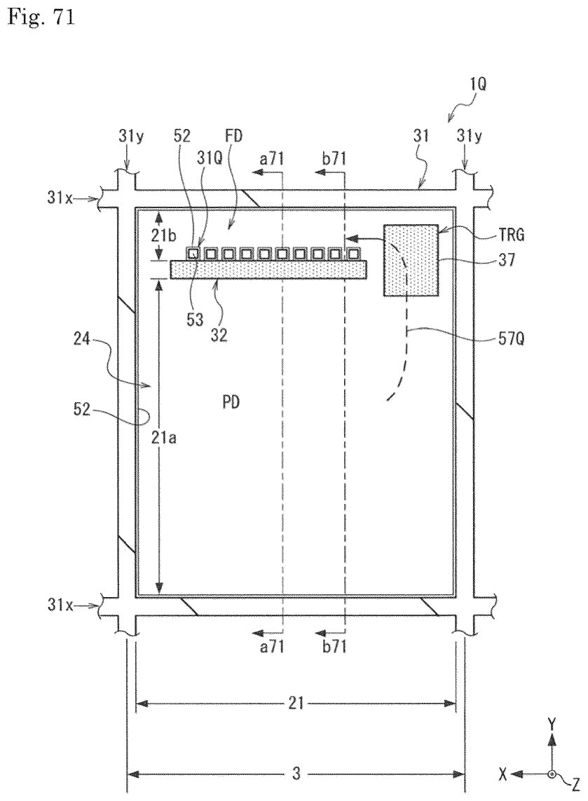

FIG. 71 is a plan view schematically illustrating a plane pattern of a separation area in a pixel array portion of a solid-state imaging device according to a 16th embodiment of the present technology.

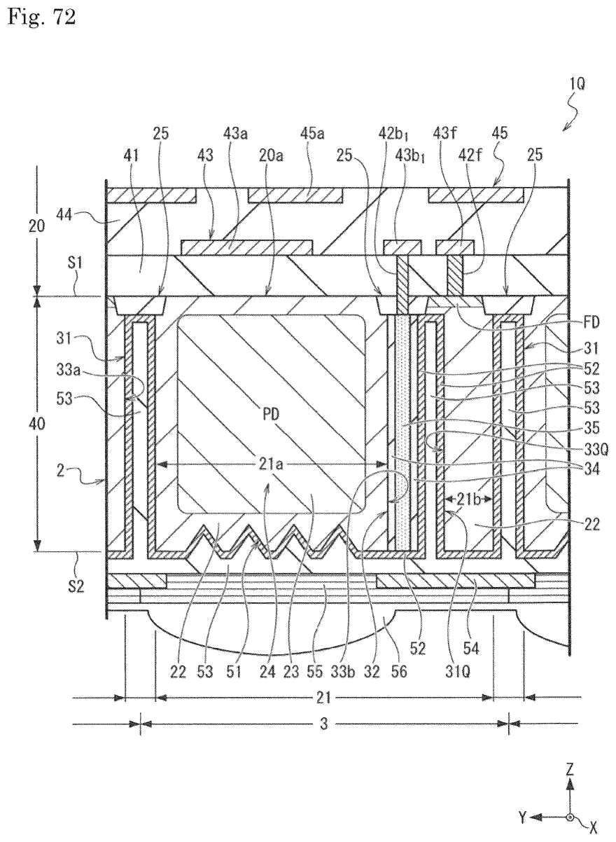

FIG. 72 is a longitudinal cross-sectional view schematically illustrating a longitudinal cross-sectional structure taken along line a71-a71 illustrated in FIG. 71.

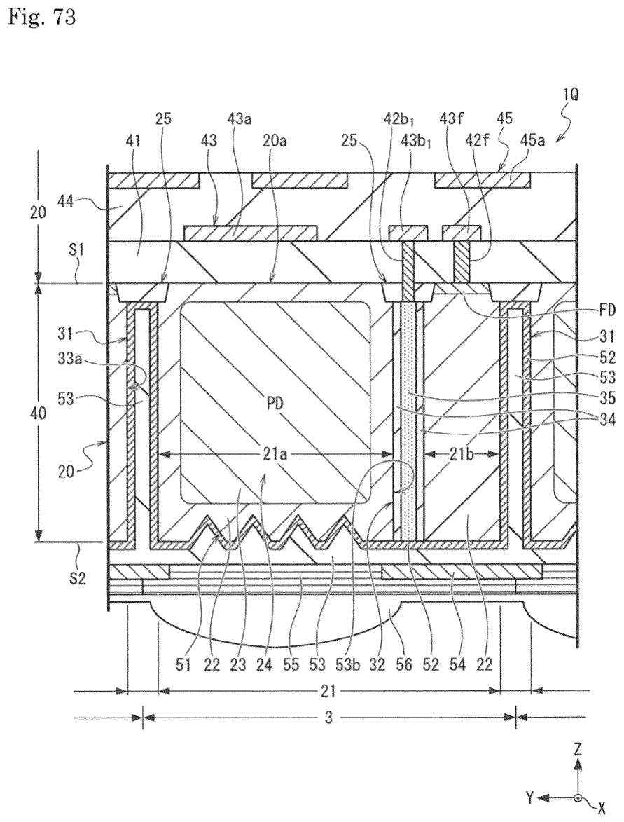

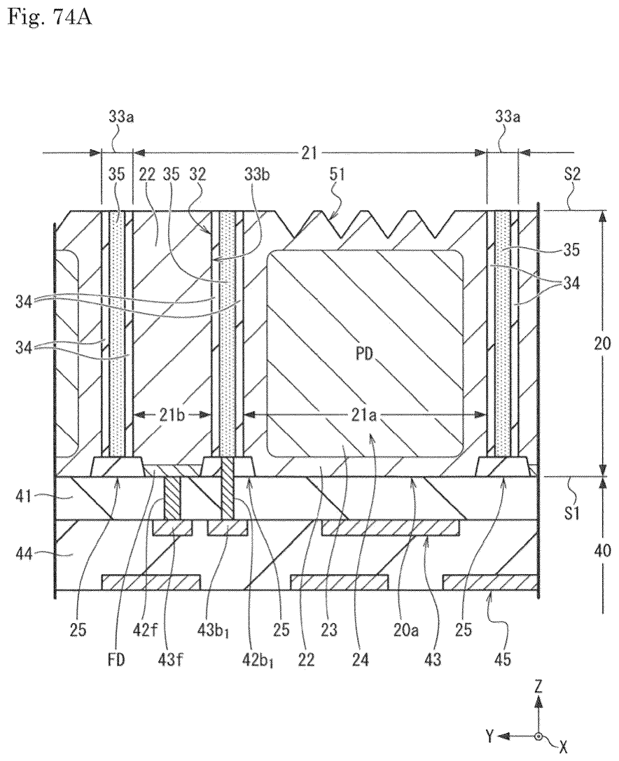

FIG. 73 is a longitudinal cross-sectional view schematically illustrating a longitudinal cross-sectional structure taken along line b71-b71 illustrated in FIG. 71.

In this 16th embodiment, an inter-pixel separation area 31 corresponds to one specific example of “first separation area” of the present technology, and an in-pixel separation area 32 corresponds to one specific example of “second separation area” of the present technology. In addition, in this 16th embodiment, a dug part 33a, a dug part 33b, and a dug part 33Q respectively correspond to specific examples of “first dug part”, “second dug part”, and “third dug part” of the present technology. Furthermore, in this 16th embodiment, a disposition direction of a first area 21a and a second area 21b of a photoelectric conversion area 21 corresponds to one specific example of “one direction” of the present technology, and a protrusion part 31Q corresponds to one specific example of “dielectric” of the present technology.

### <<Configuration of Solid-state Imaging Device>>

As illustrated in FIGS. 71 to 73, a solid-state imaging device 1Q according to the 16th embodiment of the present technology basically has a configuration similar to the solid-state imaging device 1A according to the first embodiment described above, and there are following different configurations.

In other words, as illustrated in FIGS. 71 to 73, the solid-state imaging device 1Q according to the 16th embodiment of the present technology further includes the protrusion part 31Q as a dielectric protruding from the in-pixel separation area 32 to the second area 21b side of the photoelectric conversion area 21. The other configurations are similar to those of the first embodiment described above as a whole.

As illustrated in FIGS. 71 to 73, the protrusion part 31Q is repeatedly disposed with a predetermined disposition pitch in a longitudinal direction (the X direction) in which the in-pixel separation area 32 extends in a two-dimensional plane. In other words, on the in-pixel separation area 32 side of the second area 21b, the protrusion parts 31Q protruding from the in-pixel separation area 32 are scattered along the longitudinal direction of the in-pixel separation area 32. In other words, the second area 21b side of the in-pixel separation area 32 has an uneven shape in which a part between the protrusion parts 31Q becomes a concave part.

As illustrated in FIG. 72, the protrusion part 31Q includes a fixed charge film 52 disposed along an inner wall (a side wall and a bottom wall) of a dug part 33Q inside the dug part 33Q extending in a thickness direction (the Z direction) of a semiconductor layer 20 and an insulating film 53 disposed inside the dug part 33Q through the fixed charge film 52.

The protrusion part 31Q extends in the thickness direction (the Z direction) of the semiconductor layer 20 and has one end side connected to an element separation area 25 and the other end side reaching a second face S2 of the semiconductor layer 20. The protrusion part 31Q has a configuration of a longitudinal cross-section that is similar to the inter-pixel separation area 31. The dug part 33Q is connected to the dug part 33b of the in-pixel separation area 32 to be integrated therewith.

The fixed charge film 52 is disposed over the inter-pixel separation area 31, a diffraction diffusion section 51, and the protrusion part 31Q. The fixed charge film 52 of the protrusion part 31Q is disposed on the in-pixel separation area 32 side and the second area 21b side of the insulating film 53 in a disposition direction (the Y direction) of the first area 21a and the second area 21b of the photoelectric conversion area 21. In addition, the fixed charge film 52 of the protrusion part 31Q, as illustrated in FIG. 71, is disposed on both sides of the insulating film 53 in the longitudinal direction (the X direction) of the in-pixel separation area 32 in the plan view.

In other words, the fixed charge film 52 of the protrusion part 31Q is disposed on both sides of the insulating film 53 in the X direction and both sides in the Y direction in the plan view and surrounds the periphery of the insulating film 53. The fixed charge film 52 of the protrusion part 31Q is adjacent to the semiconductor layer 20 on three sides acquired by excluding the first area 21a side (the in-pixel separation area 32 side) from four sides of the insulating film 53 in the X direction and the Y direction in the plan view.

In this way, by disposing the protrusion part 31Q on the second area 21b side of the in-pixel separation area 32, in the second area 21b of the photoelectric conversion area 21, the area of the fixed charge film 52 that is adjacent to (faces) the semiconductor layer 20 is increased. In other words, an area of an interface part of the semiconductor layer 20 and the fixed charge film 52 is increased.

A reference sign 57Q represented in FIG. 71 is an electric charge transmission line through which the transfer transistor TRG transmits signal electric charge from the first area 21a to the second area 21b.

In addition, the width of the second area of the photoelectric conversion area 21 in the Y direction is smaller on a side on which no protrusion part 31Q is present than a side on which the protrusion part 31Q is present.

### <<Method of Manufacturing Solid-state Imaging Device>>

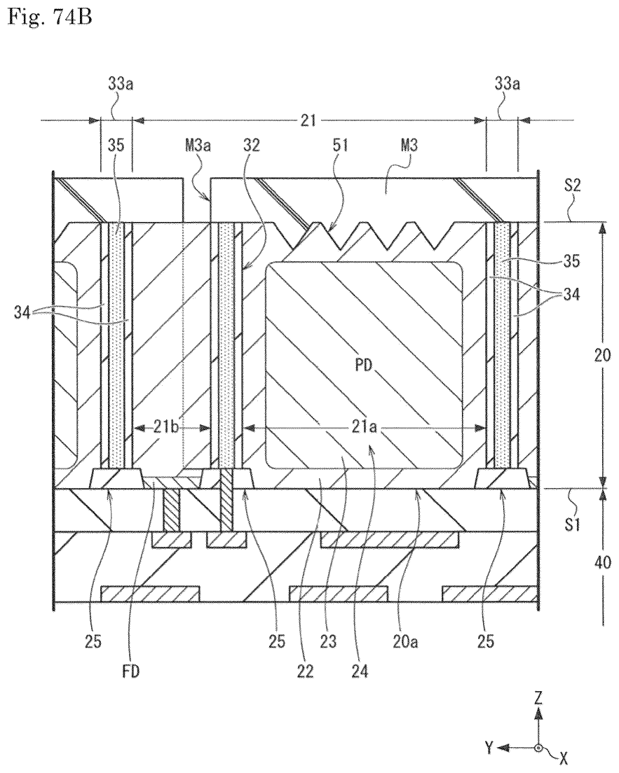

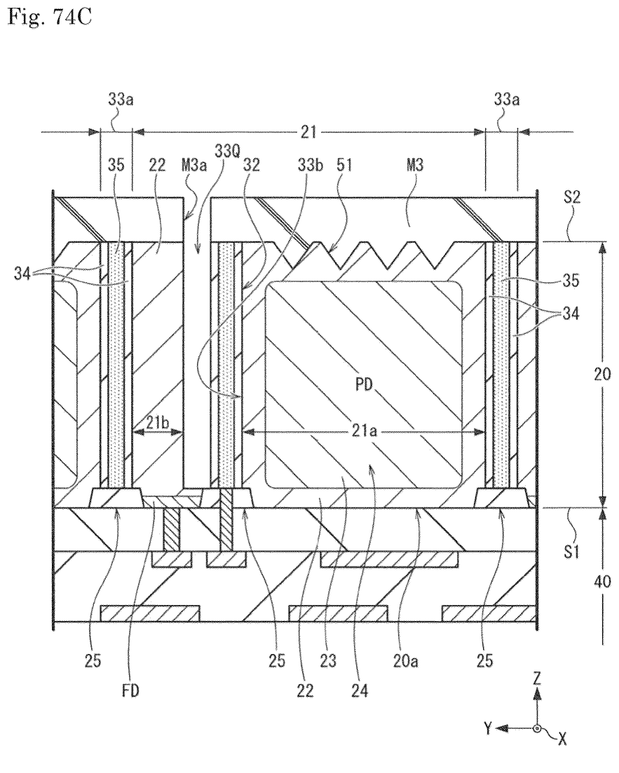

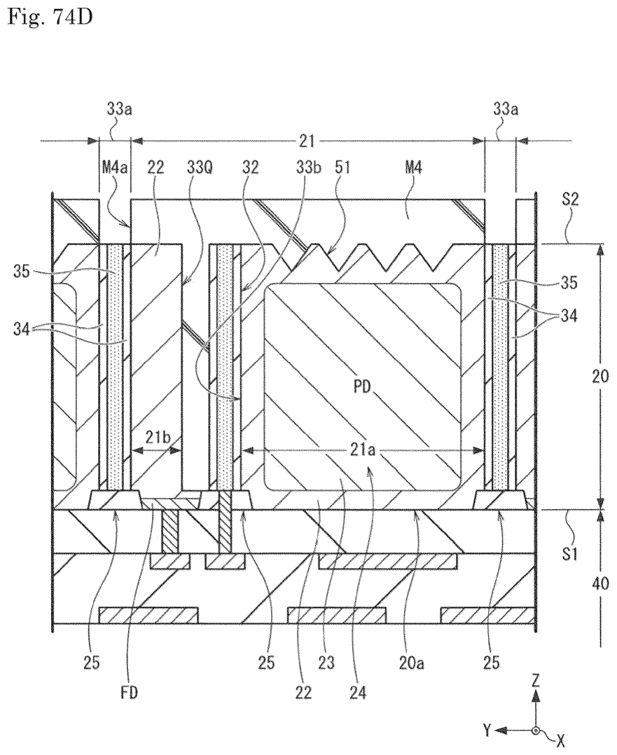

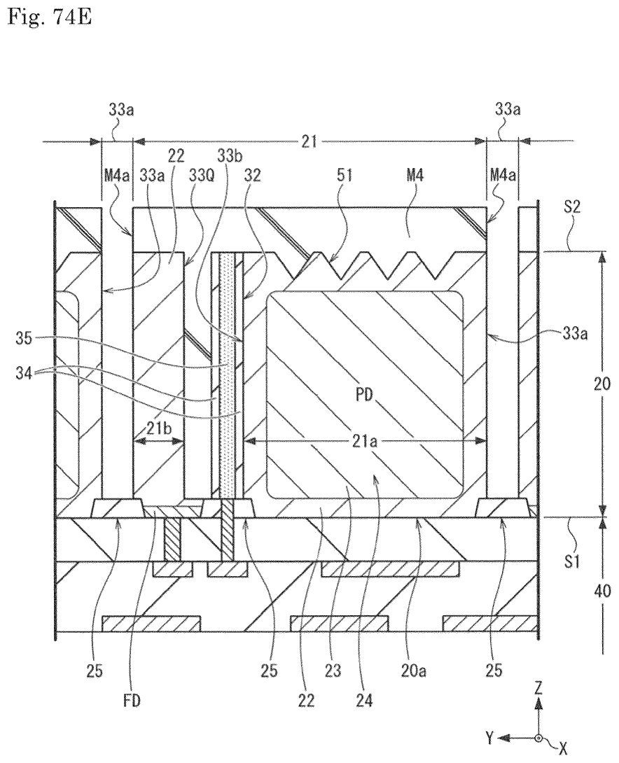

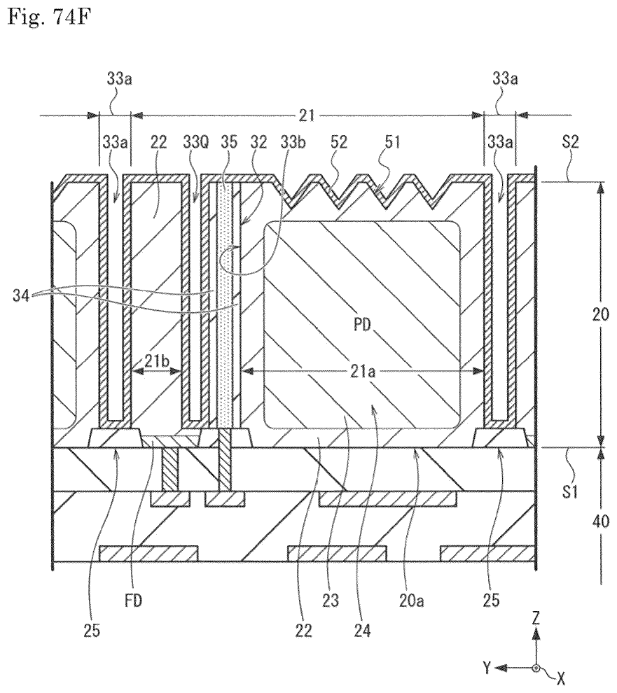

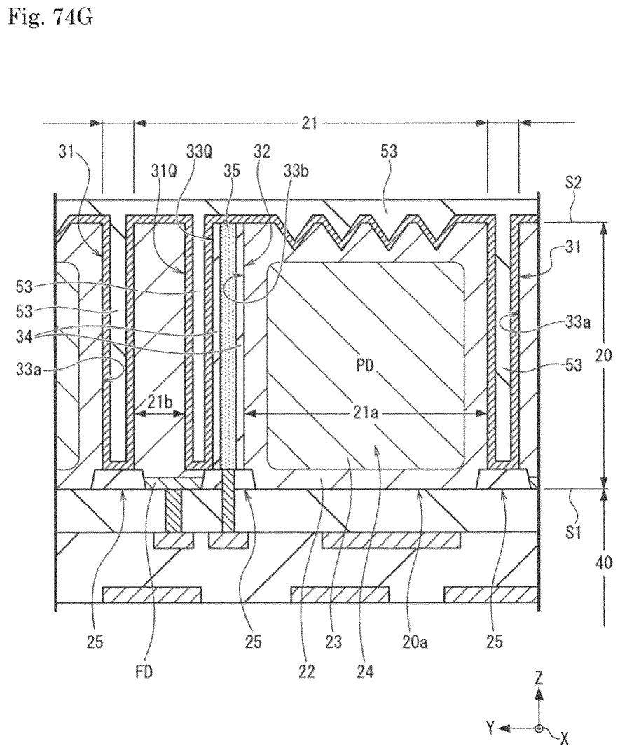

Next, a method of manufacturing the solid-state imaging device 1Q according to the 16th embodiment of the present technology will be described with reference to FIGS. 74A to 74G. In this 16th embodiment, manufacturing of the protrusion part 31Q included in the method of manufacturing the solid-state imaging device 1Q will be particularly described.

First, a process similar to that of the 8th embodiment described above is performed, and as illustrated in FIG. 74A, components up to a diffraction scattering section 51 are formed in the second face S2 of the semiconductor layer 20 in the first area 21a of the photoelectric conversion area 21.

Next, after a diffraction scattering section 51 is formed, as illustrated in FIG. 74B, a mask M3 having an opening part M3a exposing the in-pixel separation area 32 side of the second area 21b of the photoelectric conversion area 21 is formed on the second face S2 side of the semiconductor layer 20, for example, using a photolithographic technology. The second face S2 side of the semiconductor layer 20 of the photoelectric conversion area 21 except for a part of the second area 21b is covered with the mask M3.

Next, after the mask M3 is formed, by using the mask M3 as an etching mask, the second area 21b exposed from the opening part M3a of the mask M3 is selectively etched, and as illustrated in FIG. 74C, a dug part 33Q is formed. The dug part 33Q protrudes from the in-pixel separation area 32 to the second area 21b side of the photoelectric conversion area 21 and is formed with a depth reaching the element separation area 25 of the first face S1 side from the second face S2 side of the semiconductor layer 20. In addition, a plurality of dug parts 33Q are formed to be scattered in the longitudinal direction (the X direction) of the in-pixel separation area 32. In addition, the dug part 33Q is connected to and integrated with the dug part 33b of the in-pixel separation area 32 such that the separation insulating film 34 of the in-pixel separation area 32 is exposed from the inside of the dug part 33Q.

Next, after the mask M3 is removed, as illustrated in FIG. 74D, a mask M4 having an opening part M4a in which the separation insulating film 34 and the conductive material 35 of the inside of the dug part 33a are exposed is formed on the second face S2 side of the semiconductor layer 20, for example, using a photolithographic technology. In each of the first area 21a and the second area 21b of the photoelectric conversion area 21, the second face S2 side of the semiconductor layer 20 is covered with the mask M4, and the inside of the dug part 33Q is filled in a part of the mask M4.

Next, by using the mask M4 as an etching mask, as illustrated in FIG. 74E, the separation insulating film 34 and the conductive material 35 of the inside of the dug part 33a are selectively removed. The separation insulating film 34 and the conductive material 35 of the inside of the dug part 33a can be selectively removed using a known photolithographic technology and an anisotropic dry etching technology.

Next, after the mask M4 is removed, as illustrated in FIG. 74F, a fixed charge film 52 that extends along the inner wall (the side wall and the bottom wall) of the inside of each of the dug parts 33a and 33Q and covers the second face S2 of the semiconductor layer 20 is formed. The fixed charge film 52, on the second face S2 side of the semiconductor layer 20, is formed over the first area 21a and the second area 21b of the photoelectric conversion area 21, and the diffraction scattering section 51 of the first area 21a is covered with the fixed charge film 52.

Next, after the fixed charge film 52 is formed, as illustrated in FIG. 74G, an insulating film 53 is formed on the entire face of the second face S2 side of the semiconductor layer 20 including the inside of each of the dug parts 33a and 33Q. For example, after a silicon oxide film is formed using a CVD method, by planarizing the surface side of this silicon oxide film using a CMP method through cutting, an insulating film 53 can be formed.

In this process, an inter-pixel separation area 31 in which the insulating film 53 is embedded in the inside of the dug part 33a through the fixed charge film 52 is formed, and a photoelectric conversion area 21 of which the periphery is partitioned by this inter-pixel separation area 31 and the inside is separated into a first area 21a and a second area 21b by the in-pixel separation area 32 is formed.

In addition, in this process, a protrusion part 31Q that protrudes from the in-pixel separation area 32 to the second area 21b side of the photoelectric conversion area 21 in the plan view and in which the insulating film 53 is embedded inside the dug part 33Q through the fixed charge film 52 is formed.

Next, after the insulating film 53 is formed, on a side opposite to the semiconductor layer 20 side of this insulating film 53, by forming the light blocking film 54, the color filter 55, the microlens 56, and the like in this order, a state illustrated in FIGS. 31 and 32 is formed.

In addition, also in the solid-state imaging device 1Q according to this 16th embodiment, by dividing a semiconductor wafer including the semiconductor layer 20 and the multilayer wiring layer 40 for each chip formation area, the state of the semiconductor chip 2 illustrated in FIG. 1 is formed.

### Main Effects of 16th Embodiment

Next, the main effects of this 16th embodiment will be described.

Similar to the solid-state imaging device 1A according to the first embodiment described above, the solid-state imaging device 1Q according to this 16th embodiment includes the inter-pixel separation area 31 and the in-pixel separation area 32. Thus, also in the solid-state imaging device 1Q according to this 16th embodiment, similar to the solid-state imaging device 1A according to the first embodiment described above, improvement of the quantum efficiency QE and high mixed color suppression (MTF) as pixel characteristics can be achieved, and improvement of transmission characteristics as pixel characteristics can be achieved.

In addition, the solid-state imaging device 1Q according to this 16th embodiment includes the light blocking film 54 that is disposed on the outer side of the second face S2 of the semiconductor layer 20 and overlaps the second area 21b of the photoelectric conversion area 21 in the plan view. Thus, similar to the solid-state imaging device 1A of the first embodiment described above, light that has penetrated into the second area 21b from the second face S2 side (the light incidence face side) of the semiconductor layer 20 in the second area 21b of the photoelectric conversion area 21 is blocked by the light blocking film 54, and arrival of light to the floating diffusion region FD can be suppressed, whereby the parasitic light sensitivity characteristics (PLS) can be enhanced.

In addition, the solid-state imaging device 1Q according to this 16th embodiment includes the protrusion part 31Q that protrudes from the in-pixel separation area 32 to the second area 21b side of the photoelectric conversion area 21 in the plan view. In the protrusion part 31Q, the insulating film 53 is disposed in the dug part 33Q extending in the thickness direction of the semiconductor layer 20 through the fixed charge film 52. For this reason, in the second area 21b of the photoelectric conversion area 21, an area of the fixed charge film 52 that is adjacent to (faces) the semiconductor layer 20 can be increased, and the electric charge accumulation capacity for temporarily storing signal electric charge in the second area 21b of the photoelectric conversion area 21 can be increased.

In recent years, a high-resolution image sensor is requested in the market, and development of an image sensor in which pixels 3 are miniaturized has been progressed. For miniaturization of the pixels 3, the photoelectric conversion area 21 of the semiconductor layer 20 needs to be miniaturized. However, in accordance with miniaturization of the photoelectric conversion area 21, the area of the second area 21b decreases, and the electric charge accumulation capacity of the second area 21b is decreased. Thus, in order to maintain the area of the second area 21b, the area of the first area 21a decreases, and the volume of the photoelectric conversion unit 24 (PD) disposed in the first area 21a decreases. In accordance with the decrease in the volume of the photoelectric conversion unit 24, the saturation signal amount Qs decreases. In other words, there is a relation of tradeoff between the saturation signal amount Qs in the first area 21a and the electric charge accumulation capacity of the second area 21b.

In contrast to this, in this solid-state imaging device 1Q of this 16th embodiment, by disposing the protrusion part 31Q on the second area 21b side of the in-pixel separation area 32, the electric charge accumulation capacity of the second area 21b is increased. In other words, without enlarging the area of the second area 21b, the electric charge accumulation capacity can be increased, and thus the tradeoff between the saturation signal amount Qs in the first area 21a and the electric charge accumulation capacity of the second area 21b can be alleviated. Thus, the present technology is effective also for realizing a high-resolution image sensor.

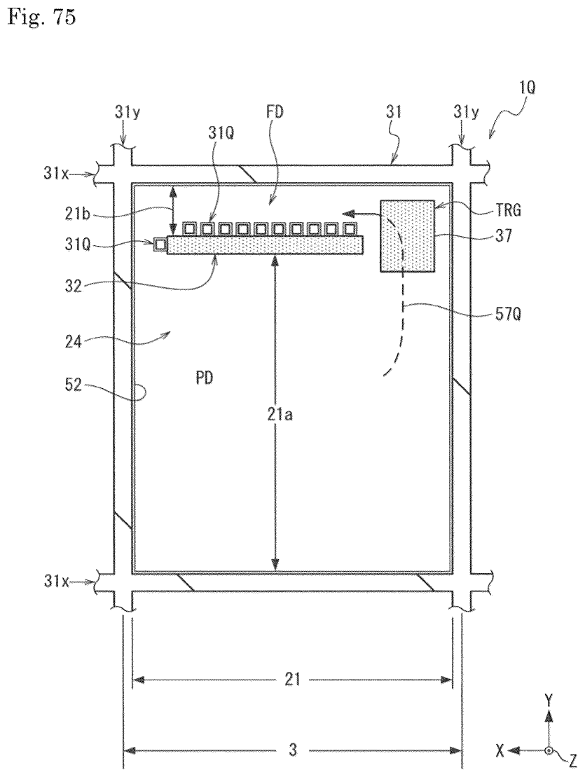

In addition, as illustrated in FIG. 75, the protrusion part 31Q may be disposed at an end part of the other side that is a side opposite to an end part of one side in which the transfer transistor TRG is disposed out of both end parts in the longitudinal direction (the X direction) of the in-pixel separation area 32 in the plan view.

### 17th Embodiment

In this 17th embodiment, as a dielectric in which an insulating film is disposed in a dug part extending in a depth direction of a semiconductor layer through a fixed charge film, a protrusion part that protrudes from an inter-pixel separation area to a second area side of a photoelectric conversion area will be described.

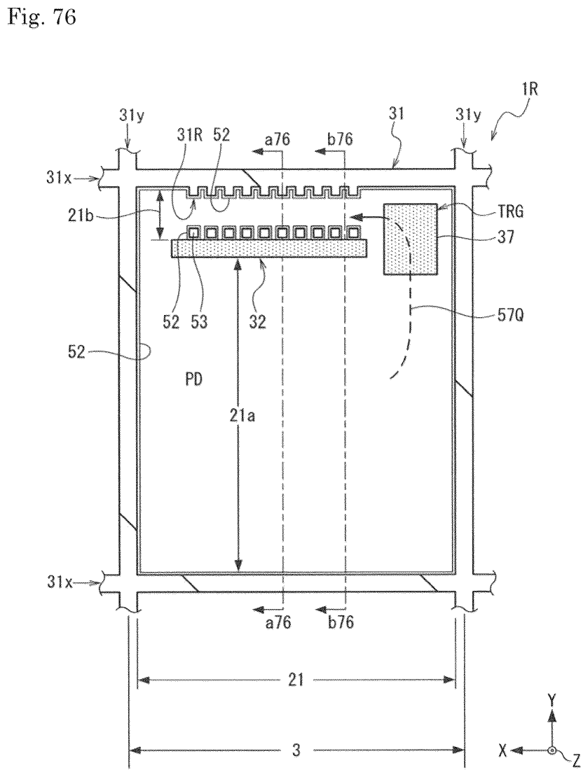

FIG. 76 is a plan view schematically illustrating a plane pattern of a separation area in a pixel array portion of a solid-state imaging device according to a 17th embodiment of the present technology.

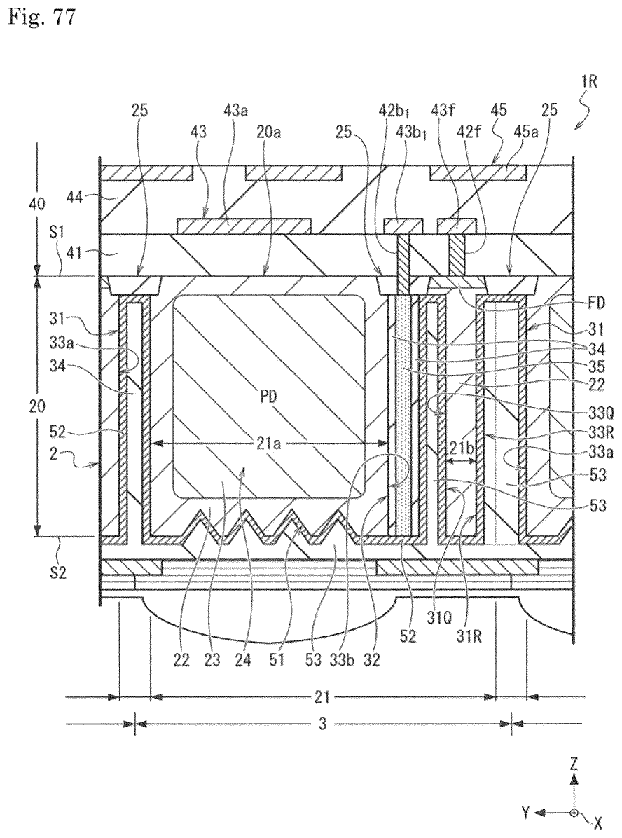

FIG. 77 is a longitudinal cross-sectional view schematically illustrating a longitudinal cross-sectional structure taken along line a76-a76 illustrated in FIG. 76.

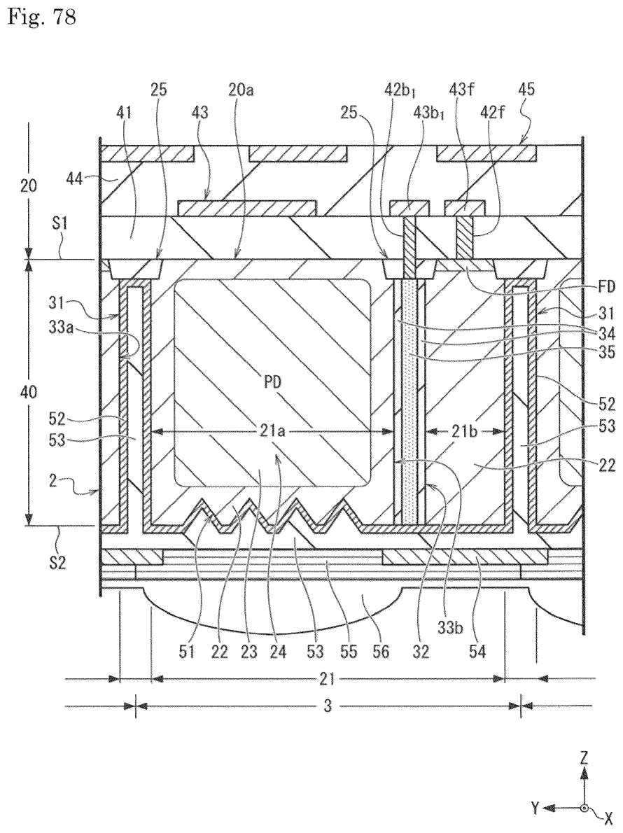

FIG. 78 is a longitudinal cross-sectional view schematically illustrating a longitudinal cross-sectional structure taken along line b76-b76 illustrated in FIG. 76.

In this 17th embodiment, an inter-pixel separation area 31 corresponds to one specific example of “first separation area” of the present technology, and an in-pixel separation area 32 corresponds to one specific example of “second separation area” of the present technology. In addition, in this 16th embodiment, a dug part 33a, a dug part 33b, and a dug part 33R respectively correspond to specific examples of “first dug part”, “second dug part”, and “third dug part” of the present technology. In addition, in this 17th embodiment, a disposition direction of a first area 21a and a second area 21b of the photoelectric conversion area 21 corresponds to one specific example of “one direction” of the present technology, and a protrusion part 31R corresponds to one specific example of “dielectric” of the present technology.

As illustrated in FIGS. 76 to 78, the solid-state imaging device 1R according to the 17th embodiment of the present technology basically has a configuration similar to the solid-state imaging device 1Q according to the 16th embodiment described above, and there are following different configurations.

In other words, as illustrated in FIGS. 76 to 78, the solid-state imaging device 1R according to the 17th embodiment of the present technology, in the photoelectric conversion area 21, further includes a protrusion part 31R protruding from the inter-pixel separation area 31 on a side opposite to the in-pixel separation area 32 side of the second area 21b to the second area 21b side. The other configurations are similar to those according to the 16th embodiment as a whole.

As illustrated in FIGS. 76 to 78, the protrusion part 31R is repeatedly disposed with a predetermined disposition pitch in a longitudinal direction (the X direction) in which the inter-pixel separation area 31 extends in a two-dimensional plane. In other words, in the disposition direction (the Y direction) of the first area 21a and the second area 21b of the photoelectric conversion area 21, on the inter-pixel separation area 31 side of the second area 21b, the protrusion parts 31R protruding from the inter-pixel separation area 31 to the second area 21b side are scattered along the longitudinal direction (the X direction) of the inter-pixel separation area 31. In other words, the second area 21b side of the inter-pixel separation area 31 is formed to have an uneven shape in which a space between the protrusion parts 31R becomes a concave part.

As illustrated in FIG. 77, the protrusion part 31R includes a fixed charge film 52 disposed along the inner wall (the side wall and the bottom wall) of the inside of the dug part 33R extending in the thickness direction (the Z direction) of the semiconductor layer 20 and an insulating film 53 disposed inside the dug part 33R through the fixed charge film 52. The fixed charge film 52 of the protrusion part 31R is continuously formed with being integrated with the fixed charge film 52 of the inter-pixel separation area 31. Also the insulating film 53 of the protrusion part 31R is continuously formed with being integrated with the insulating film 53 of the inter-pixel separation area 31.

The protrusion part 31R extends in the thickness direction (the Z direction) of the semiconductor layer 20 and has one end side connected to an element separation area 25 and the other end side reaching a second face S2 of the semiconductor layer 20.

The dug part 33R is connected to the dug part 33a of the inter-pixel separation area 31 to be integrated therewith.

The fixed charge film 52 is disposed over the inter-pixel separation area 31, a diffraction diffusion section 51, and the protrusion parts 31Q and 31R. The fixed charge film 52 of the protrusion part 31R is disposed on the second area 21b side of the insulating film 53 in the disposition direction (the Y direction) of the first area 21a and the second area 21b of the photoelectric conversion area 21. In addition, the fixed charge film 52 of the protrusion part 31R, as illustrated in FIG. 76, is disposed on both sides of the insulating film 53 in the longitudinal direction (the X direction) of the inter-pixel separation area 31 in the plan view. In other words, the fixed charge film 52 of the protrusion part 31R is adjacent to (faces) the semiconductor layer 20 on three sides acquired by excluding the inter-pixel separation area 31 side from four sides of the insulating film 53 in the X direction and the Y direction in the plan view.

In this way, by disposing the protrusion part 31R on the second area 21b side in the inter-pixel separation area 31 on a side opposite to the inter-pixel separation area 32 of the second area 21b of the photoelectric conversion area 21, in the second area 21b of the photoelectric conversion area 21, the area of the fixed charge film 52 that is adjacent to (faces) the semiconductor layer 20 can be increased. Thus, according to the solid-state imaging device 1R according to this 17th embodiment, in combination with a face increase of the interface part between the semiconductor layer 20 and the fixed charge film 52 according to the protrusion part 31Q, the electric charge accumulation capacity of the second area 21b of the photoelectric conversion area 21 can be further more increased.

In addition, in this 17th embodiment, although a case in which both the protrusion part 31Q and the protrusion part 31R are disposed has been described, it is apparent that only the protrusion part 31R may be disposed.

In addition, in this 17th embodiment, a case in which the protrusion part 31R is disposed in the inter-pixel separation area 31 on a side opposite to the in-pixel separation area 32 side of the second area 21b of the photoelectric conversion area 21 has been described. However, the protrusion part 31R may be in the second area 21b of the photoelectric conversion area 21. In addition, out of both end parts of the in-pixel separation area 32 in the longitudinal direction (the X direction) in the plan view, the protrusion part 31R may be disposed in the inter-pixel separation area 31 that is adjacent to the other end portion of a side opposite to an end portion of one side on which the transfer transistor TRG is disposed in the plan view.

### 18th Embodiment

In this 18th embodiment, as a dielectric in which an insulating film is disposed in a dug part extending in a depth direction of a semiconductor layer through a fixed charge film, an island part that is separate from each of an inter-pixel separation area and an in-pixel separation area will be described.

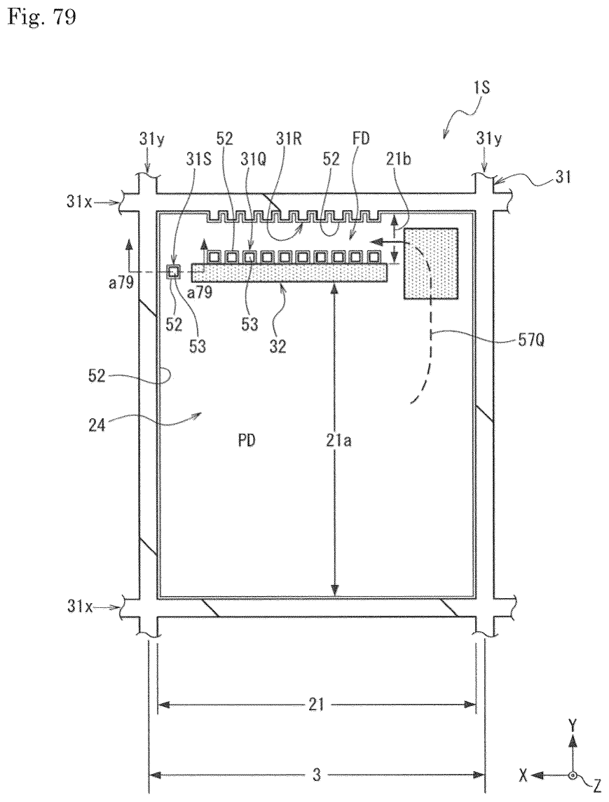

FIG. 79 is a plan view schematically illustrating a plane pattern of a separation area in a pixel array portion of a solid-state imaging device according to the 18th embodiment of the present technology.

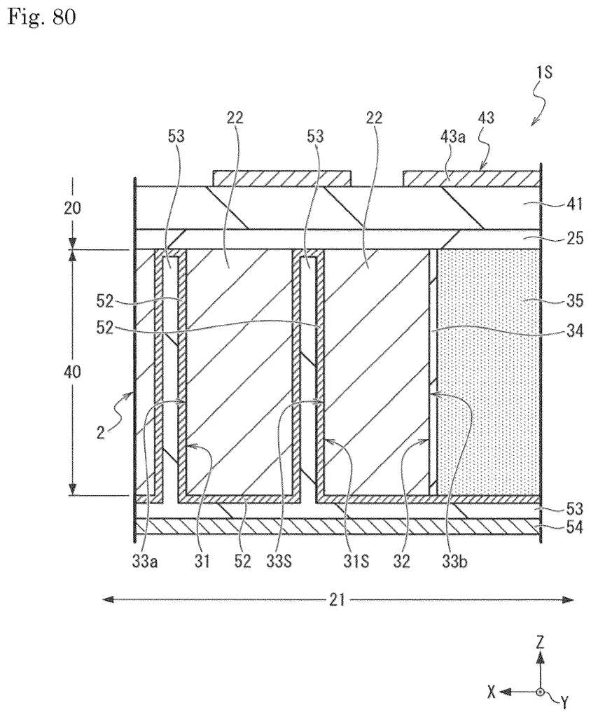

FIG. 80 is a longitudinal cross-sectional view schematically illustrating a longitudinal cross-sectional structure taken along line a79-a79 illustrated in FIG. 79.

In this 18th embodiment, an inter-pixel separation area 31 corresponds to one specific example of “first separation area” of the present technology, and an in-pixel separation area 32 corresponds to one specific example of “second separation area” of the present technology. In addition, in this 18th embodiment, a dug part 33a, a dug part 33b, and a dug part 33S respectively correspond to specific examples of “first dug part”, “second dug part”, and “third dug part” of the present technology. In addition, in this 18th embodiment, a disposition direction of a first area 21a and a second area 21b of the photoelectric conversion area 21 corresponds to one specific example of “one direction” of the present technology, and an island part 31S corresponds to one specific example of “dielectric” of the present technology.

As illustrated in FIGS. 79 and 80, the solid-state imaging device 1S according to the 18th embodiment of the present technology basically has a configuration similar to the solid-state imaging device 1R according to the 17th embodiment described above, and there are following different configurations.

In other words, as illustrated in FIGS. 79 and 80, the solid-state imaging device 1S according to the 18th embodiment of the present technology, in the photoelectric conversion area 21, further includes island parts 31S that are separate from each of the inter-pixel separation area 31 and the in-pixel separation area 32. The other configurations are similar to those according to the 17th embodiment as a whole.

As illustrated in FIGS. 79 to 80, the island parts 31S are disposed to be scattered between an end portion of the other side that is a side opposite to an end portion of one side on which a transfer transistor TRG is disposed in the plan view out of both end portions of the in-pixel separation area 32 in the longitudinal direction (the X direction) in the plan view and the inter-pixel separation area 31 that is adjacent to the end portion of the other side.

As illustrated in FIG. 80, the island part 31S includes a fixed charge film 52 disposed along the inner wall (the side wall and the bottom wall) of the inside of the dug part 33S extending in the thickness direction (the Z direction) of the semiconductor layer 20 and an insulating film 53 disposed inside the dug part 33S through the fixed charge film 52. The fixed charge film 52 of the island part 31S is continuously formed with being integrated with the fixed charge film 52 of each of the inter-pixel separation area 31 and the in-pixel separation area 32. The island part 31S is separated from the dug parts 33a and 33b of each of the inter-pixel separation area 31 and the in-pixel separation area 32.

The island part 31S extends in the thickness direction (the Z direction) of the semiconductor layer 20 and has one end side connected to an element separation area 25 and the other end side reaching a second face S2 of the semiconductor layer 20.

The fixed charge film 52 is disposed over the inter-pixel separation area 31, a diffraction diffusion section 51, the protrusion parts 31Q and 31R, and the island part 31S. The fixed charge film 52 of the island part 31S is disposed on the second area 21b side of the insulating film 53 in the disposition direction (the Y direction) of the first area 21a and the second area 21b of the photoelectric conversion area 21. In addition, the fixed charge film 52 of the island part 31S, as illustrated in FIG. 79, is disposed on both sides of the insulating film 53 in the longitudinal direction (the X direction) of the inter-pixel separation area 31 in the plan view. In other words, the fixed charge film 52 of the island part 31S is adjacent to (faces) the semiconductor layer 20 on four sides of the insulating film 53 in the X direction and the Y direction in the plan view.

In this way, by disposing the island part 31S between the other end side of the in-pixel separation area 32 in the longitudinal direction (the X direction) and the inter-pixel separation area 31 in the plan view, in the second area 21b of the photoelectric conversion area 21, the area of the fixed charge film 52 that is adjacent to (faces) the semiconductor layer 20 can be increased. Thus, according to the solid-state imaging device 1S according to this 18th embodiment, in combination with a face increase of the interface part between the semiconductor layer 20 and the fixed charge film 52 according to the protrusion parts 31Q and 31R, the electric charge accumulation capacity of the second area 21b of the photoelectric conversion area 21 can be further more increased.

In addition, in this 18th embodiment, although a case in which the island part 31S and both the protrusion part 31Q and the protrusion part 31R are disposed has been described, any one of the protrusion part 31Q and the protrusion part 31R and the island part 31S may be combined together. Furthermore, only the island part 31S may be disposed.

In addition, the island part 31S may be disposed inside the second area 21b of the photoelectric conversion area 21 in the plan view.

### 19th Embodiment

In this 19th embodiment, a solid-state imaging device of a two-level structure in which two semiconductor layers are stacked will be described.

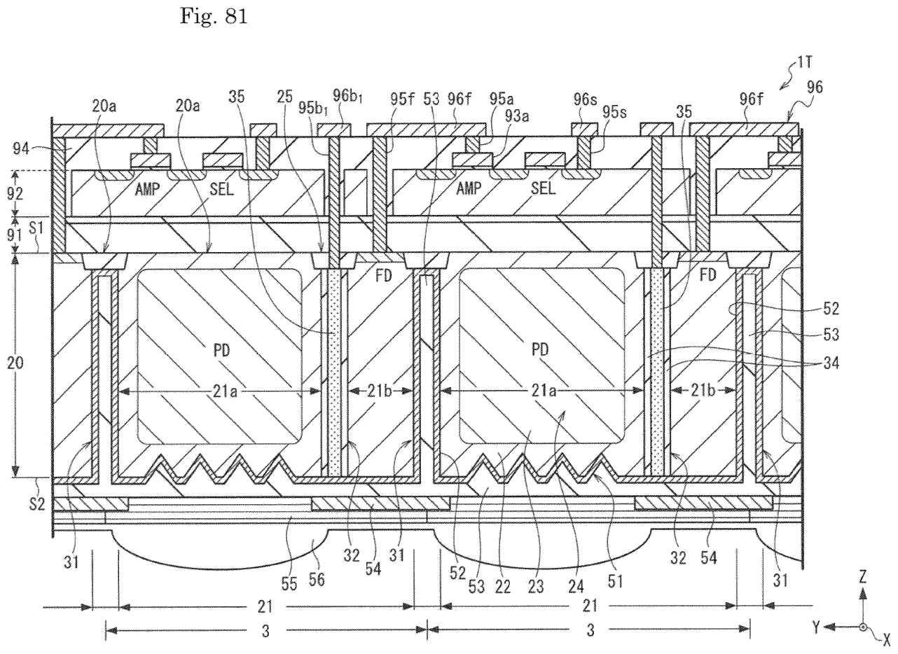

FIG. 81 is a longitudinal cross-sectional view schematically illustrating a longitudinal cross-sectional structure of a solid-state imaging device 1T according to the 19th embodiment of the present technology.

In this 19th embodiment, a semiconductor layer 20 corresponds to one specific example of “first semiconductor layer” of the present technology, and a semiconductor layer 92 corresponds to one specific example of “second semiconductor layer” of the present technology.

### <<Configuration of Solid-state Imaging Device>>

As illustrated in FIG. 81, the solid-state imaging device 1T according to the 19th embodiment of the present technology basically has a configuration similar to the solid-state imaging device 1A according to the first embodiment described above, and there are following different configurations.

In other words, as illustrated in FIG. 5, the solid-state imaging device 1A according to the first embodiment described above includes the multilayer wiring layer 40 on the first face S1 side of the semiconductor layer 20. The pixel transistors (AMP, SEL, and RST) included in the reading circuit 15 illustrated in FIG. 3 are disposed in the photoelectric conversion area 21 of the semiconductor layer 20.

In contrast to this, as illustrated in FIG. 81, the solid-state imaging device 1T according to the 19th embodiment of the present technology, on a first face S1 side of the semiconductor layer 20 as a first semiconductor layer, includes the semiconductor layer 92 as a second semiconductor layer through an insulating layer 91. The pixel transistors (AMP, SEL, and RST) included in the reading circuit 15 illustrated in FIG. 3 are disposed in the semiconductor layer 92. In FIG. 81, the amplification transistor AMP and the selection transistor SEL among the pixel transistors included in the reading circuit 15 are illustrated.

As illustrated in FIG. 81, on a side opposite to the insulating layer 91 side of the semiconductor layer 92, an interlayer insulating film 94 is disposed. The semiconductor layer 92 is covered with the interlayer insulating film 94. Each of the pixel transistors (AMP, SEL, and RST) included in the reading circuit 15 (see FIG. 3) is disposed on an element formation face on a side opposite to the insulating layer 91 side of the semiconductor layer 92 and is covered with the interlayer insulating film 94.

On a side opposite to the semiconductor layer 92 side of the interlayer insulating film 94, a wiring layer 96 is disposed. In the wiring layer 96, various wirings are formed. In FIG. 81, wirings 96b₁, 96f, and 96s are illustrated.

As illustrated in FIG. 81, the wiring 96b₁ passes through the interlayer insulating film 94, the semiconductor layer 92, the insulating layer 91, and the element separation area 25, is electrically connected to a contact electrode (through plug) 95b₁ reaching the conductive material 35 of the in-pixel separation area 32, and is further electrically connected to the conductive material 35 of the in-pixel separation area 32 through this contact electrode 95b₁. This wiring 96b₁ is supplied with a second reference electric potential of a positive electric potential higher than a first reference electric potential applied to a well region 22 of the p type as a power source electric potential. In other words, the conductive material 35 of the in-pixel separation area 32 is supplied with the second reference electric potential applied to the wiring 96b₁ through the contact electrode 95b₁ and has an electric potential being fixed to this second reference electric potential. As the second reference electric potential, for example, 2.7 V is applied. The contact electrode 95b₁ passes through a through hole of the semiconductor layer 92 and is electrically insulated and separated from the semiconductor layer 92 through the interlayer insulating film 94 inside the through hole.

As illustrated in FIG. 81, the wiring 96f is electrically connected to the contact electrode (through plug) 95f reaching the floating diffusion region FD of the second area 21b of the photoelectric conversion area 21 by passing through the interlayer insulating film 94, the semiconductor layer 92, and the insulating layer 91 and is further electrically connected to the floating diffusion region FD through this contact electrode 95f. In addition, the wiring 96f is electrically connected to a gate electrode 93a of the amplification transistor AMP through the contact electrode 95a embedded in the interlayer insulating film 94. In other words, the floating diffusion region FD is electrically connected to an input stage side (the gate electrode 93a of the amplification transistor AMP and a source region of the reset transistor RST) of the reading circuit 15. The contact electrode 95f passes through the through hole of the semiconductor layer 92 and is electrically insulated and separated from the semiconductor layer 92 through the interlayer insulating film 94 of the inside of the through hole.

As illustrated in FIG. 81, the wiring 96s is electrically connected to a source region of the selection transistor SEL through a contact electrode 95s embedded in the interlayer insulating film 94. The wiring 96s is electrically connected to a vertical signal line 11 (VSL) illustrated in FIG. 3.

Also in the solid-state imaging device 1T of the two-level structure according to this 19th embodiment, effects similar to those of the solid-state imaging device 1A according to the first embodiment described above can be acquired.

In addition, in this 19th embodiment, although a case in which the present technology is applied to a solid-state imaging device of a two-level structure in which two semiconductor layers are stacked has been described, the present technology can be applied also to a solid-state imaging device of a multi-level structure in which three or more semiconductor layers are stacked. Furthermore, the present technology according to the second embodiment to the 18th embodiment can be also applied to a solid-state imaging device in which two or more semiconductor layers are stacked.

### 20th Embodiment

In this 20th embodiment, one example in which a light reflecting body of the present technology is applied to a solid-state imaging device of a two-level structure in which two semiconductor layers are stacked will be described.

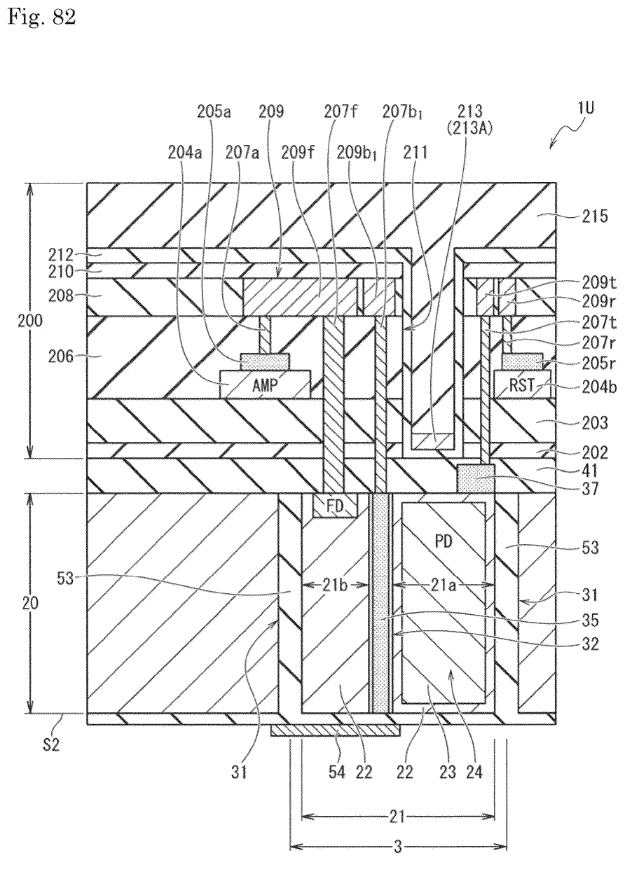

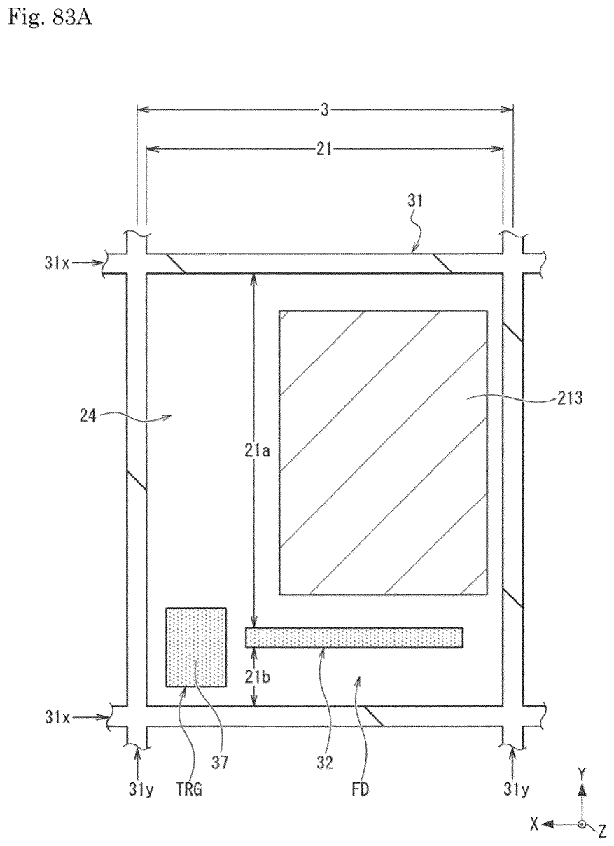

FIG. 82 is a longitudinal cross-sectional view schematically illustrating a longitudinal cross-sectional structure of a solid-state imaging device according to the 20th embodiment of the present technology.

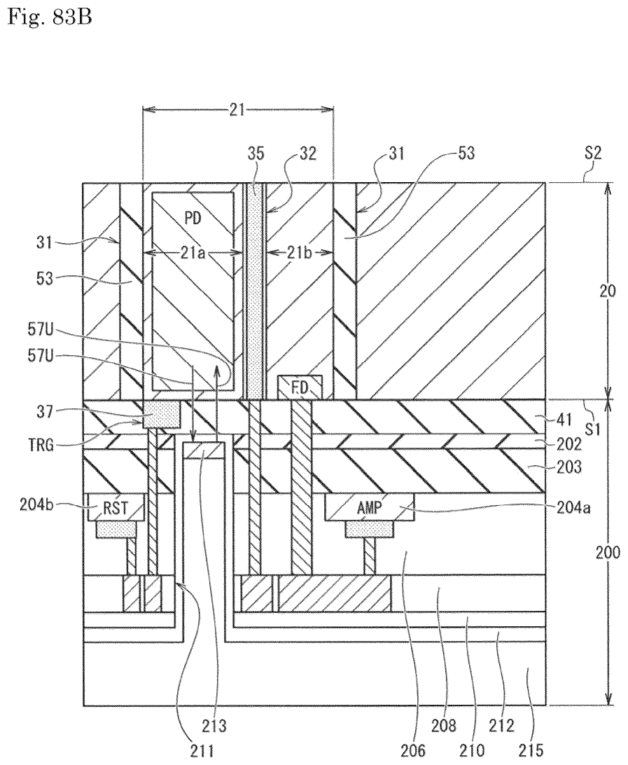

FIG. 83A is a plan view schematically illustrating a plane pattern of a light reflecting body illustrated in FIG. 82.

FIG. 83B is a longitudinal cross-sectional view schematically illustrating reflection of light according to the light reflecting body.

In FIGS. 82 and 83B, for easy viewing of the drawings, hatching representing a cross-section is partly omitted.

In addition, in FIGS. 82 and 83B, although a gate electrode 37 of a transfer transistor TRG is illustrated, for easy understanding of the configuration, the position of this gate electrode 37 is intentionally changed with respect to that illustrated in FIG. 83A.

In FIG. 82, illustration of the diffraction diffusion section 51, the fixed charge film 52, the color filter 55, the microlens 56, and the like illustrated in FIGS. 5 and 6 is omitted.

In addition, FIG. 83B is vertically inverted with respect to FIG. 82.

In this 20th embodiment, a semiconductor layer 20 corresponds to one specific example of “first semiconductor layer” of the present technology, and semiconductor sections 204a and 204b of an island shape correspond to one specific example of “second semiconductor layer” of the present technology.

### <<Configuration of Solid-state Imaging Device>>

As illustrated in FIG. 82, the solid-state imaging device 1U according to the 20th embodiment of the present technology basically has a configuration similar to the solid-state imaging device 1A according to the first embodiment described above, and there are following different configurations.

In other words, as illustrated in FIG. 5, the solid-state imaging device 1A according to the first embodiment described above includes the multilayer wiring layer 40 on the first face S1 side of the semiconductor layer 20. The pixel transistors (AMP, SEL, and RST) included in the reading circuit 15 illustrated in FIG. 3 are disposed in the photoelectric conversion area 21 of the semiconductor layer 20.

In contrast to this, as illustrated in FIG. 82, the solid-state imaging device 1U according to the 20th embodiment of the present technology includes a multilayer body (a lamination body) 200 disposed on a first face S1 side of a semiconductor layer 20 as a first semiconductor layer through an interlayer insulating film 41. The pixel transistors (AMP, SEL, and RST) included in the reading circuit 15 illustrated in FIG. 3 are disposed in the multilayer body 200.

As illustrated in FIG. 82, the multilayer body 200 includes a light reflecting body 213 disposed to overlap a first area 21a of the photoelectric conversion area 21 in the plan view and semiconductor sections 204a and 204b of an island shape as a second semiconductor layer that are disposed on a side opposite to the semiconductor layer 20 side of this light reflecting body 213. In other words, the solid-state imaging device 1U according to this 20th embodiment has a two-level structure in which the semiconductor layer 20 that is a first semiconductor layer and the semiconductor sections 204a and 204b of the island shape that form a second semiconductor layer are stacked.

In addition, the multilayer body 200 further includes a stopper film 202 that is disposed on a side opposite to the semiconductor layer 20 side of the interlayer insulating film 41 and an insulating film 203 that is disposed on a side opposite to the interlayer insulating film 41 side of this stopper film 202. The semiconductor sections 204a and 204b of the island shape are disposed on a side opposite to the stopper film 202 side of the insulating film 203.

In addition, the multilayer body 200 further includes an insulating film 206 that is disposed on a side opposite to the stopper film 202 side of the insulating film 203 such that it covers the semiconductor sections 204a and 204b of the island shape and an insulating film 208 that is disposed on the insulating film 203 side of this insulating film 206.

Furthermore, the multilayer body 200 includes a wiring layer 209 that is disposed in the insulating film 208 and a cap film 210 that is disposed on a side opposite to the insulating film 206 side of the insulating film 208 such that it covers the wiring layer 209.

In addition, the multilayer body 200 includes a protection film 212 that is disposed on a side opposite to the insulating film 208 side of the cap film 210 and is disposed along an inner wall (a side wall and a bottom wall) of an opening part (dug part) 211 extending from the insulating film 210 toward the semiconductor layer 20 and an insulating film 215 that is disposed on a side opposite to the cap film 210 side of this separation insulating film 217 and is disposed to embed the inside of the opening part 211.

Although not illustrated in detail, the interlayer insulating film 41 illustrated in FIG. 82 is disposed on the first face S1 side of the semiconductor layer 20 such that it covers the gate electrode 37 of the transfer transistor TRG.

The semiconductor sections 204a and 204b of the island shape illustrated in FIG. 82 are formed in the same layer. In other words, the semiconductor sections 204a and 204b are formed by patterning one semiconductor layer. As the semiconductor layer (the semiconductor sections 204a and 204b), a semiconductor of a Si substrate, a SiGe substrate, an InGaAs substrate, or the like can be used. In this 20th embodiment, for example, a semiconductor substrate of the p type formed from monocrystalline silicon is used.

In the semiconductor section 204a of the island shape, as a pixel transistor included in the reading circuit 15, for example, an amplification transistor AMP is disposed. In addition, in the semiconductor section 204b of the island shape, as a pixel transistor included in the reading circuit 15, for example, a reset transistor RST is disposed. Although not illustrated in the drawing, a selection transistor as a pixel transistor included in the reading circuit 15 may be disposed in the semiconductor section 204a of the island shape with serial connection to the amplification transistor AMP or may be disposed in another semiconductor section of an island shape.

In the wiring layer 209 illustrated in FIG. 82, various wirings are formed. In FIG. 82, wirings 209b₁, 209f, 209r, and 209t are illustrated.

As illustrated in FIG. 82, the wiring 209b₁ is electrically connected to a contact electrode (through plug) 207b₁ that passes through the insulating films 206 and 203, the stopper film 202, and the interlayer insulating film 41 and reaches the conductive material 35 of the in-pixel separation area 32 and is further electrically connected to the conductive material 35 of the in-pixel separation area 32 through this contact electrode 207b₁. A second reference electric potential of a positive electric potential higher than a first reference electric potential applied to the well region 22 of the p type is applied to this wiring 209b₁ as a power source electric potential. In other words, the conductive material 35 of the in-pixel separation area 32 is supplied with the second reference electric potential applied to the wiring 96b₁ through the contact electrode 95b₁ and has an electric potential fixed to this second reference electric potential. As the second reference electric potential, for example, 2.7 V is applied.

As illustrated in FIG. 82, the wiring 209f is electrically connected to a contact electrode (through plug) 207f that passes through the insulating films 206 and 203, the stopper film 202, and the interlayer insulating film 41 and reaches the floating diffusion region FD of the second area 21b of the photoelectric conversion area 21 and is further electrically connected to the floating diffusion region FD through this contact electrode 207f. In addition, the wiring 209f is electrically connected to the gate electrode 205a of the amplification transistor AMP through a contact electrode (embedded plug) 207a embedded in the insulating film 206. In other words, the floating diffusion region FD is electrically connected to an input stage side of the reading circuit 15 (the gate electrode 205a of the amplification transistor AMP and a source region of the reset transistor RST).

The wiring 209r is electrically connected to the gate electrode 205r of the reset transistor RST through the contact electrode 207r embedded in the insulating film 206.

The wiring 209t is electrically connected to the contact electrode (through plug) 207t that passes through the insulating films 206 and 203, the stopper film 202, and the interlayer insulating film 41 and reaches the gate electrode 37 of the transfer transistor TRG and is further electrically connected to the gate electrode 37 of the transfer transistor TRG through this contact electrode 207t.

As illustrated in FIG. 82, the light reflecting body 213 is disposed inside the opening part 211 with overlapping the first area 21a of the photoelectric conversion area 21 in the plan view. The light reflecting body 213, in the thickness direction (Z direction) of the semiconductor layer 20, is positioned on a semiconductor layer 20 side of the semiconductor sections 204a and 204b of the island shape and is positioned on a further semiconductor sections 204a and 204b side of the island shape than the semiconductor layer 20 side. In other words, the light reflecting body 213 is disposed in a layer between the semiconductor layer 20 and the semiconductor sections 204a and 204b of the island shape in terms of a layer shape (layers). As illustrated in FIG. 83A, the light reflecting body 213 has a plate shape that extends in a two-dimensional shape.

As the light reflecting body 213, it is preferable to include a metal material having an optical reflectance higher than an insulating material included in the inter-pixel separation area 31. In addition, as the light reflecting body 213, it is preferable to include a metal material having an optical reflectance higher than the semiconductor sections 204a and 204b of the island shape that are the second semiconductor layer and having a low light absorption rate. As such metal materials, for example, there are copper (Cu), aluminum (Al), and the like. Each of Cu and Al has an optical reflectance higher than silicon oxide or silicon and have low light absorption rates. In this 20th embodiment, for example, the light reflecting body 213 including Cu is used.

The light reflecting body 213, as illustrated in FIG. 83B, reflects light 57T that has been incident from the second face S2 (the light incident face) of the semiconductor layer 20 and has been transmitted through the first area 21a of the photoelectric conversion area 21 to the first area 21a. In other words, light 57U that has been incident from the second face S2 of the semiconductor layer 20 and has been transmitted (passed) through the first area 21a of the photoelectric conversion area 21 is reflected on the light reflecting body 213 and returns to the first area 21a of the photoelectric conversion area 21. In the first area 21a of the photoelectric conversion area, the photoelectric conversion unit 24 (PD) is disposed.

### <<Method of Manufacturing Solid-state Imaging Device>>

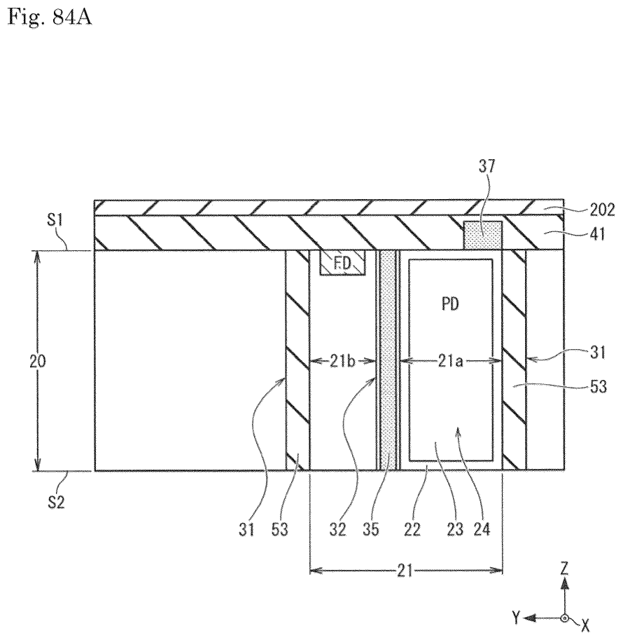

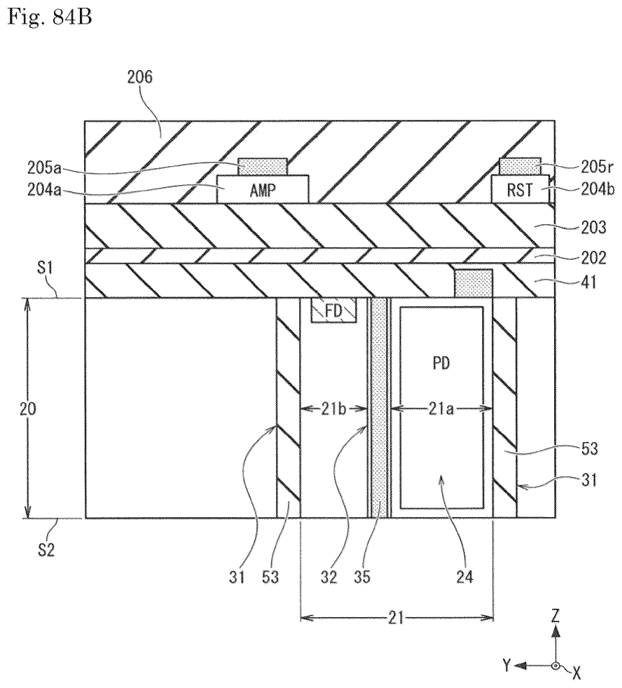

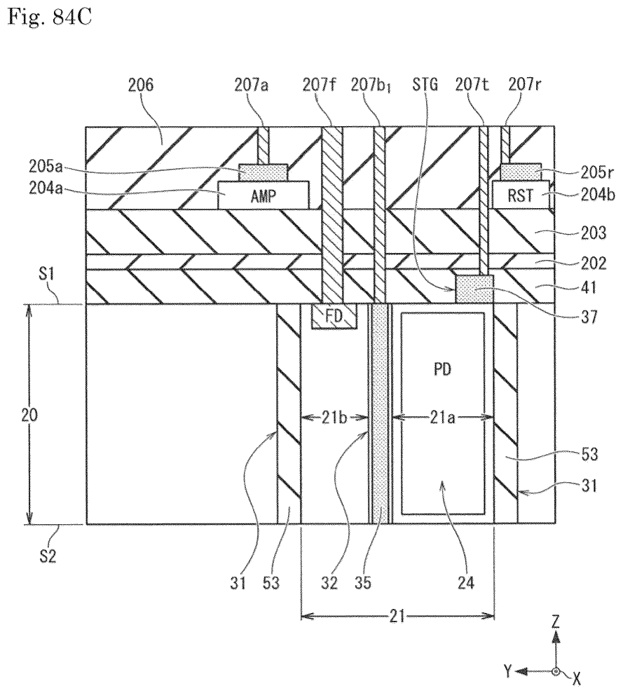

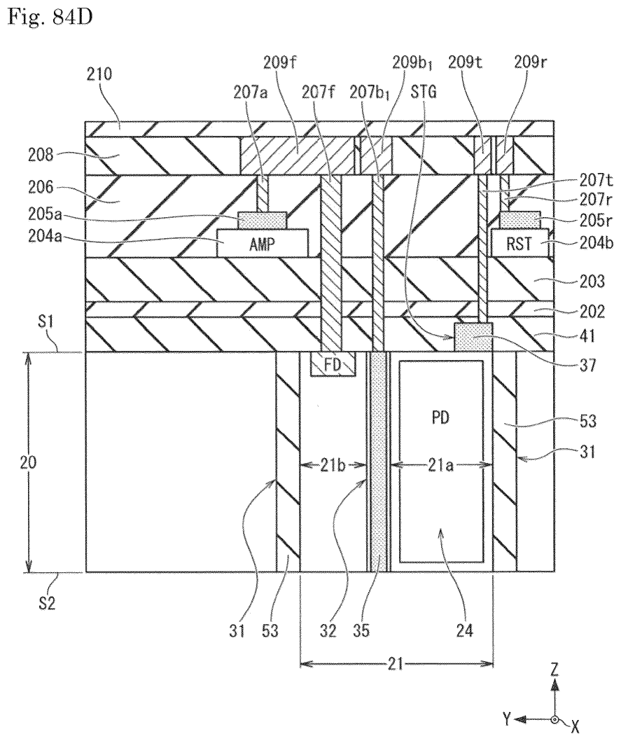

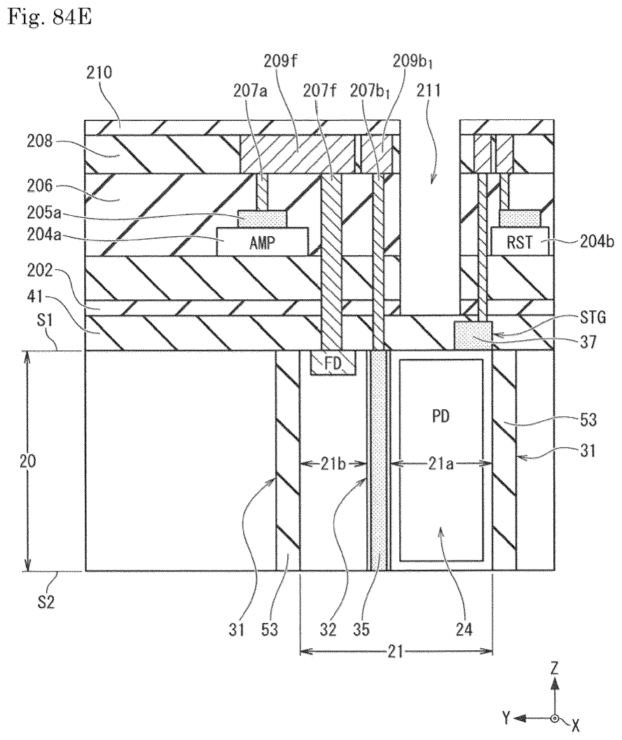

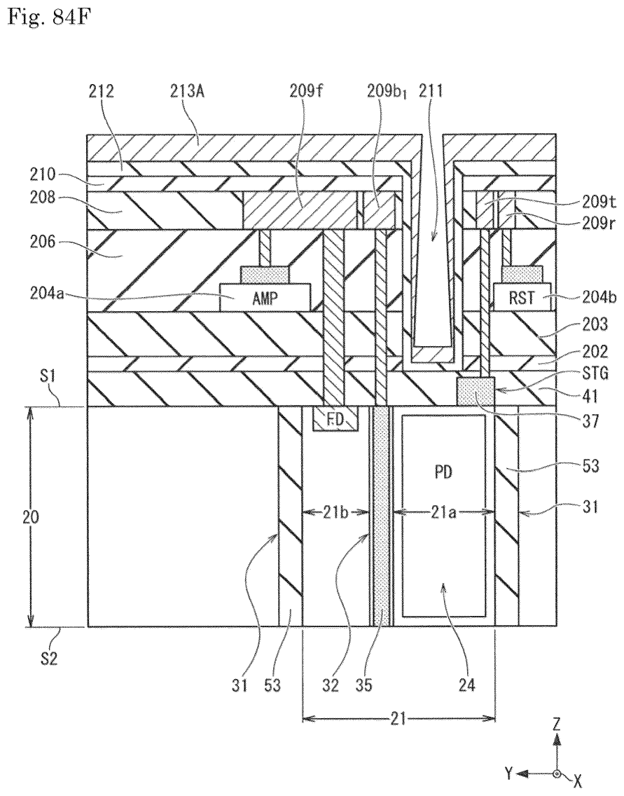

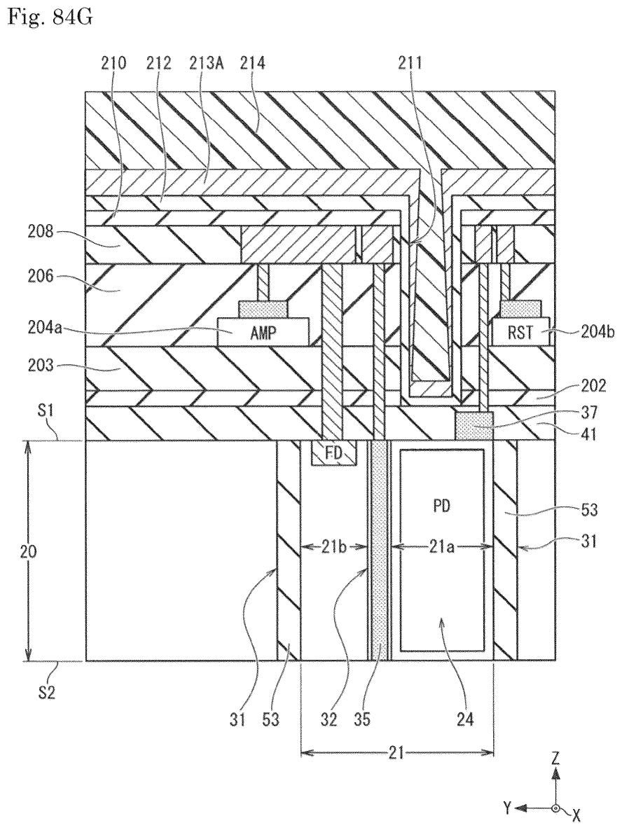

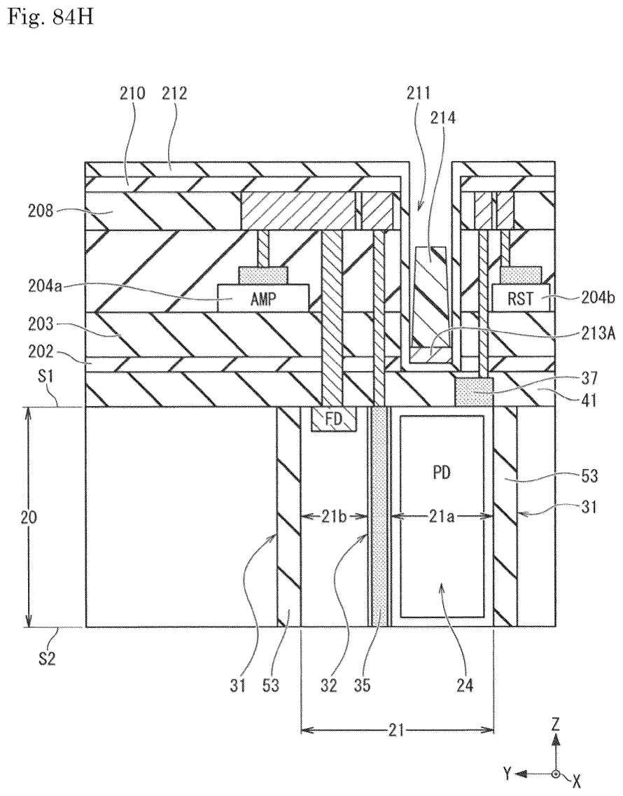

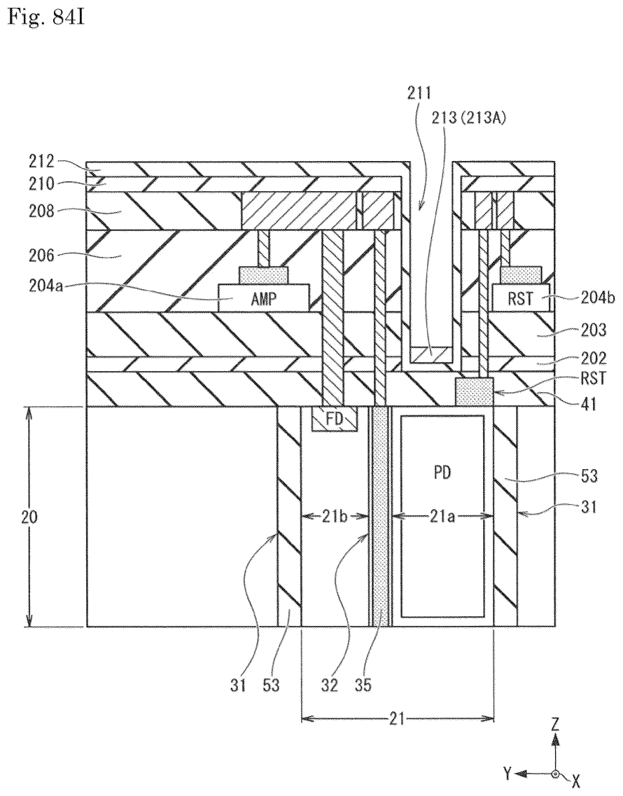

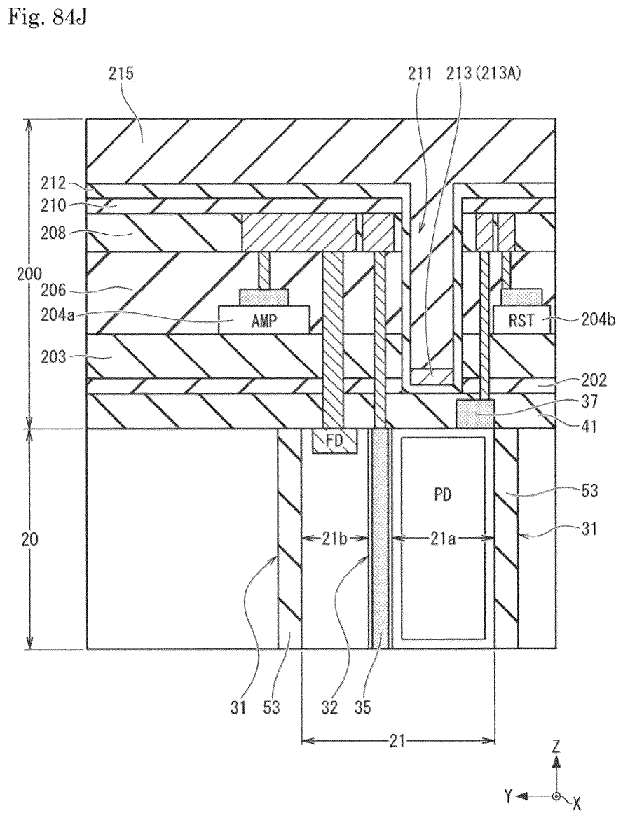

Next, a method of manufacturing the solid-state imaging device 1U according to the 20th embodiment of the present technology will be described using FIGS. 84A to 84J.

Also in FIGS. 84A to 84J, for easy viewing of the drawings, hatching representing a cross-section is partly omitted.

In addition, also in FIGS. 84 to 84J, although a gate electrode 37 of a transfer transistor TRG is illustrated, for easy understanding of the configuration, the position of this gate electrode 37 is intentionally changed with respect to that illustrated in FIG. 83A.

In this 20th embodiment, manufacturing of the light reflecting body 213 included in the method of manufacturing the solid-state imaging device 1U will be particularly described.

First, when described with reference to FIG. 5 of the first embodiment described above, in the semiconductor layer 20, a photoelectric conversion area 21, an inter-pixel separation area 31, an in-pixel separation area 32, a floating diffusion region FD, a transfer transistor TRG (not illustrated), and the like are formed.

Next, as illustrated in FIG. 84A, on the first face S1 side of the semiconductor layer 20, an interlayer insulating film 41 and a stopper film 202 are formed in this order. As the interlayer insulating film 41, for example, a silicon oxide film is used. As the stopper film 202, for example, a silicon nitride (SiN) film or a silicon oxynitride (SiON) film having transparency and having selectivity for a silicon oxide film in a case in which the silicon oxide film is etched is used. The silicon oxide film, the silicon nitride film, and the silicon oxynitride film, for example, can be formed using a CVD method.

Next, as illustrated in FIG. 84B, on a side opposite to the semiconductor layer 20 side of the stopper film 202, an insulating film 203, semiconductor sections 204a and 204b of an island shape, and an insulating film 206 are formed in this order. The insulating film 203, for example, is formed using a silicon oxide film. The semiconductor sections 204a and 204b of the island shape can be formed by, first, for example, preparing a semiconductor base in which the insulating film 203 is disposed on a side opposite to the element formation face of a semiconductor layer, for example, formed from a p type monocrystalline silicon substrate, thereafter, bonding the insulating film 203 side of this semiconductor base to the stopper film 202, thereafter, thinning the thickness of the semiconductor layer of the semiconductor base, for example, using a CMP method, and thereafter, patterning this semiconductor layer using a known photolithographic technology and an anisotropic dry etching technology. The insulating film 206 is formed to cover the semiconductor sections 204a and 204b of the island shape on a side opposite to the semiconductor layer 20 of the insulating film 203.

In addition, before an insulating film 206 is formed, pixel transistors (AMP, SEL, and RST) are formed in the semiconductor section of the island shape. FIG. 84B illustrates a state in which an amplification transistor AMP having a gate electrode 205a is formed in the semiconductor section 204a of the island shape, and a reset transistor RST having a gate electrode 205r is formed in the semiconductor section 204b of the island shape.

Next, as illustrated in FIG. 84C, a contact electrode 207b₁ reaching the conductive material 35 of the in-pixel separation area 32 from an upper face of the insulating film 206, a contact electrode 207f reaching the floating diffusion region FD from the upper face of the insulating film 206, a contact electrode 207t reaching the gate electrode 37 of the transfer transistor from the upper face of the insulating film 206, a contact electrode 207a reaching the gate electrode 205a of the amplification transistor AMP from the upper face of the insulating film 206, and a contact electrode 207r reaching the gate electrode 205r of the reset transistor RST from the upper face of the insulating film 206 are respectively formed.

The contact electrodes 207b₁, 207f, 207t, 207a, and 207r can be formed by forming respective contact holes in the insulating layer including the insulating films 206 and 203, the stopper film 202, the interlayer insulating film 41, and the like, thereafter, for example, sequentially forming a titanium (Ti) film for connection and a titanium nitride (TiN) film as a barrier film on the inner walls of the respective contact holes, thereafter, after forming a tungsten (W) film as a conductive material such that it embeds the respective contact holes, selectively removing the tungsten film, the titanium nitride film, and the titanium film disposed on the upper face of the insulating layer (on the upper face of the insulating film 206), for example, using a CMP method such that the tungsten film, the titanium nitride film, and the titanium film inside the respective contact holes selectively remain.

Next, as illustrated in FIG. 84D, an insulating film 208, a wiring layer 209 including the wirings 209b₁, 209f, 209t, 209a, and 209r, and a cap film 210 are formed.

The insulating film 208 is formed on a side opposite to the semiconductor layer 20 side of the insulating film 206. As the insulating film 208, for example, a silicon oxide film is used.

The wiring layer 209 including the wirings 209b₁, 209f, 209t, 209a, and 209r is formed in the insulating film 208, for example, using a single damascene method. As a material of the wiring layer 209, for example, Cu is used.

The cap film 210 is formed on a side opposite to the insulating film 206 side of the insulating film 208 such that it covers the wiring layer 209. The cap film 210, for example, can be formed by forming a film of SiN, SiCN, SiC, or the like, for example, using the CVD method.

In this process, the conductive material 35 of the in-pixel separation area 32 is electrically connected to the wiring 209b₁ through the contact electrode 20761. In addition, the floating diffusion region FD disposed in the second area 21b of the photoelectric conversion area 21 is electrically connected to the wiring 209f through the contact electrode 207f. The gate electrode 37 of the transfer transistor TRG disposed in the first area 21a of the photoelectric conversion area 21 is electrically connected to the wiring 209t through the contact electrode 207t. In addition, the gate electrode 37 of the amplification transistor AMP disposed in the semiconductor section 204a of the island shape is electrically connected to the wiring 209a through the contact electrode 207a. Furthermore, the gate electrode 205r of the reset transistor RST disposed in the semiconductor section 204b of the island shape is electrically connected to the wiring 209r through the contact electrode 207r.

Next, as illustrated in FIG. 84E, an opening part 211 that extends from the upper face of the cap film 210 toward the semiconductor layer 20 and overlaps the first area 21a of the photoelectric conversion area 21 in the plan view is formed. The opening part 211 is formed with a depth for reaching the stopper film 202 from the upper face of the cap film 210. The opening part 211 is used for installing the light reflecting body 213 to be described below, and the planar size of the light reflecting body 213 is determined in accordance with the opening size of this opening part 211. The opening part 211 can be formed using a known photolithographic technology and an anisotropic dry etching technology. The depth of the opening part 211 can be controlled using the stopper film 202.

Next, as illustrated in FIG. 84F, a protection film 212 used for protecting the cap film 210 from a chemical solution or the like at the time of etching and a Cu film 213A as a conductive material are formed. The protection film 212 is formed by depositing a silicon oxide film having transparency using an ALD method or a CVD method. The protection film 212 is formed with a film thickness along the upper face of the cap film 210 and the inner wall (the side wall and the bottom wall) of the opening part 211.

The Cu film 213A is formed using a sputtering method such that a film thickness in the bottom wall of the inside of the opening part 211 is about 50 nm. The film thickness of the Cu film 213A needs to be 5 nm or more for which an optical reflectance occurs, and it is more preferable that the film thickness be 50 nm or more for causing a difficulty in penetration. The Cu film 213A inside of the opening part 211 is formed to have an overhanging shape.

In addition, for adhesion between the Cu film and an insulating film and prevention of Cu diffusion, as a barrier metal layer, titanium (Ti), tantalum (Ta), each nitride film, and a lamination film with a nitride film may be thinly disposed. The film thickness is preferably about 5 nm for which it is difficult to receive an optical influence.

Next, as illustrated in FIG. 84G, a resin film 214 having high fluidity is formed on the entire face on the Cu film 213A to embed the opening part 211 using a spin-coating method. As the resin film 214, for example, a Novolac resin-based material can be used. This resin film 214 is appropriate for embedding the opening part 211 having a high aspect ratio. The resin film 214 is used for selectively removing a surplus Cu film 213A in subsequent processes.

Next, the resin film 214 of a flat section on the protection film 212 is removed using anisotropic dry etching such as reactive ion etching (IRE) or the like, and thereafter the Cu film 213A of the flat section on the protection film 212 is removed using a chemical solution of nitric acid or the like. In accordance with this process, as illustrated in FIG. 84H, the Cu film 213A selectively remains in the state of being protected by the resin film 214 on the bottom wall of the inside of the opening part 211.

Next, as illustrated in FIG. 84I, the surplus resin film 214 inside the opening part 211 is removed using RIE and a chemical solution. In accordance with this process, a light reflecting body 213 that overlaps the first area 21a of the photoelectric conversion area 21 in the plan view and is formed from the Cu film 213A is formed on the bottom wall of the opening part 211.

Next, as illustrated in FIG. 84J, the inside of the opening part 211 is embedded with the insulating film 215. As the insulating film 215, for example, a silicon oxide film that is formed using a CVD method, a bias CVD method in which a high-frequency wave is applied to a substrate, or the like can be used. In accordance with this process, a multilayer body 200 including the light reflecting body 213 overlapping the first area 21a of the photoelectric conversion area 21 in the plan view and the semiconductor sections 204a and 204b of the island shape that form a second semiconductor layer is formed on the first face S1 side of the semiconductor layer 20.

Thereafter, the wiring layer that is a wafer process is further formed.

### Main Effects of 20th Embodiment

Next, main effects of this 20th embodiment will be described.

Similar to the solid-state imaging device 1A according to the first embodiment described above, the solid-state imaging device 1U according to this 20th embodiment includes the inter-pixel separation area 31 and the in-pixel separation area 32. Thus, also in the solid-state imaging device 1U according to this 20th embodiment, similar to the solid-state imaging device 1A according to the first embodiment described above, improvement of the quantum efficiency QE and high mixed color suppression (MTF) as pixel characteristics can be achieved, and improvement of transmission characteristics as pixel characteristics can be achieved.

In addition, the solid-state imaging device 1U according to this 20th embodiment includes the light blocking film 54 that is disposed on the outer side of the second face S2 of the semiconductor layer 20 and overlaps the second area 21b of the photoelectric conversion area 21 in the plan view. Thus, similar to the solid-state imaging device 1A of the first embodiment described above, light that has penetrated into the second area 21b from the second face S2 side (the light incidence face side) of the semiconductor layer 20 in the second area 21b of the photoelectric conversion area 21 is blocked by the first light blocking part 82a, and arrival of light to the floating diffusion region FD can be suppressed, whereby the parasitic light sensitivity characteristics (PLS) can be enhanced.

Furthermore, the solid-state imaging device 1U according to this 20th embodiment includes the multilayer body 200 disposed on the first face S1 side of the semiconductor layer 20. The multilayer body 200 includes the light reflecting body 213 disposed to overlap the first area 21a of the photoelectric conversion area 21. For this reason, light 57U that has been incident from the second face S2 of the semiconductor layer 20 and has been transmitted (passed) through the first area 21a of the photoelectric conversion area 21 is reflected on the light reflecting body 213 and returns to the first area 21a of the photoelectric conversion area. Thus, according to the solid-state imaging device 1U according to this 20th embodiment, improvement of efficiency of use of light can be achieved.

In addition, in the 20th embodiment described above, although a manufacturing process using the Cu film 213A as a conductive material of the light reflecting body 213 has been described, a similar manufacturing process can be applied also to a case in which an Al film is used as a conductive material of the light reflecting body 213.

### 21st Embodiment

In this 21st embodiment, one example in which a light absorbing body of the present technology is applied to a solid-state imaging device of a two-level structure in which two semiconductor layers are stacked will be described.

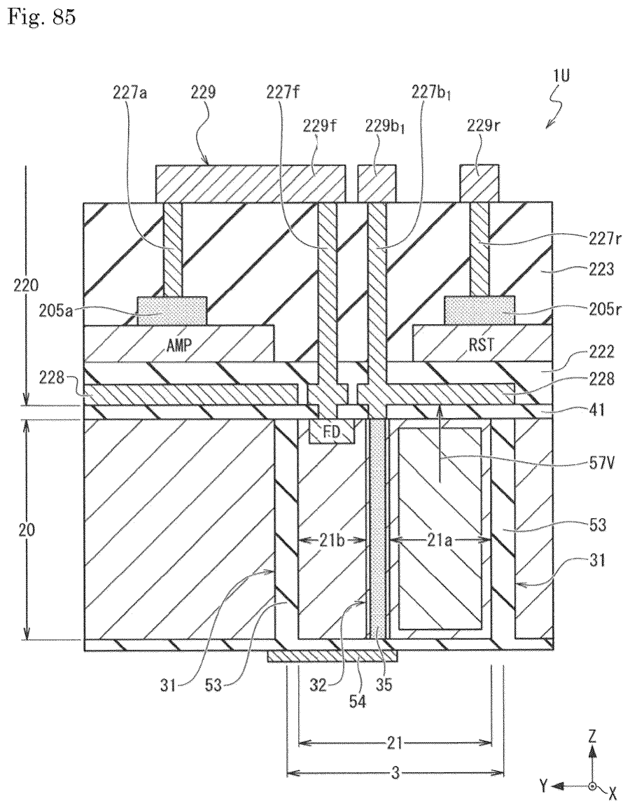

FIG. 85 is a longitudinal cross-sectional view schematically illustrating a longitudinal cross-sectional structure of the solid-state imaging device according to the 21st embodiment of the present technology.

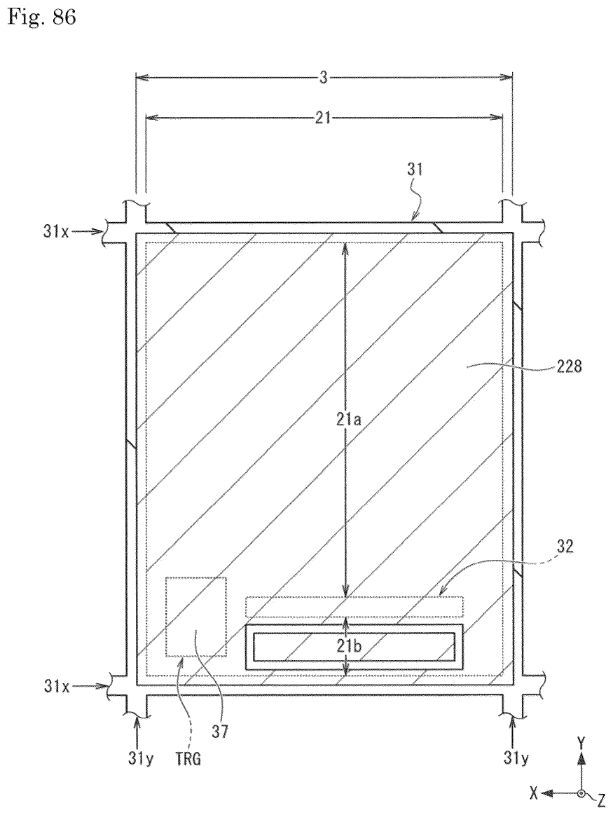

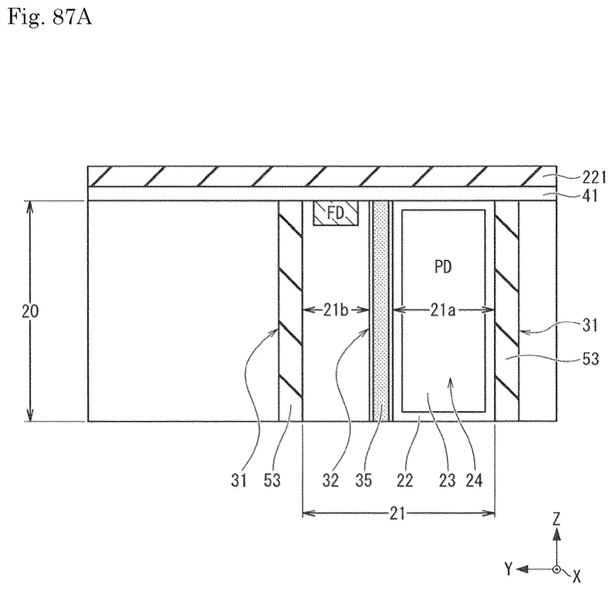

FIG. 86 is a plan view schematically illustrating a plane pattern of the light absorbing body illustrated in FIG. 85.

In FIG. 85, for easy viewing of the drawing, hatching representing a cross-section is partly omitted.

In FIG. 85, illustration of the diffraction diffusion section 51, the fixed charge film 52, the color filter 55, the microlens 56, and the like illustrated in FIGS. 5 and 6 is omitted.

In this 21st embodiment, a semiconductor layer 20 corresponds to one specific example of “first semiconductor layer” of the present technology, and semiconductor sections 204a and 204b of an island shape correspond to one specific example of “second semiconductor layer” of the present technology.

### <<Configuration of Solid-state Imaging Device>>

As illustrated in FIG. 85, a solid-state imaging device 1V according to the 21st embodiment of the present technology basically has a configuration similar to the solid-state imaging device 1A according to the first embodiment described above, and the following configurations are different.

In other words, as illustrated in FIG. 5, the solid-state imaging device 1A according to the first embodiment described above includes a multilayer wiring layer 40 on the first face side of the semiconductor layer 20. The pixel transistors (AMP, SEL, and RST) included in the reading circuit 15 illustrated in FIG. 3 are disposed in the photoelectric conversion area 21 of the semiconductor layer 20.

In contrast to this, as illustrated in FIG. 85, the solid-state imaging device 1V according to the 21 st embodiment of the present technology includes a multilayer body (lamination body) 220 disposed on a first face S1 side of a semiconductor layer 20 as a first semiconductor layer through an interlayer insulating film 41. The pixel transistors (AMP, SEL, and RST) included in the reading circuit 15 illustrated in FIG. 3 are disposed in the multilayer body 220.

As illustrated in FIG. 85, the multilayer body 220 includes a light absorbing body 228 disposed to overlap a first area 21a of the photoelectric conversion area 21 in the plan view and semiconductor sections 204a and 204b of an island shape as a second semiconductor layer disposed on a side opposite to the semiconductor layer 20 side of this light absorbing body 228. In other words, the solid-state imaging device 1V according to this 21st embodiment has a two-level structure in which the semiconductor layer 20 that is a first semiconductor layer and the semiconductor sections 204a and 204b of the island shape that form the second semiconductor layer are stacked.

In addition, the multilayer body 220 further includes an insulating film 222 that is disposed on a side opposite to the semiconductor layer 20 side of the interlayer insulating film 41, an insulating film 223 that is disposed on a side opposite to the interlayer insulating film 41 of this insulating film 222, and a wiring layer 229 disposed on a side opposite to the insulating film 222 side of this insulating film 223.

Although not illustrated in detail, the interlayer insulating film 41, similar to the 20th embodiment described above, is disposed on the first face S1 side of the semiconductor layer 20 such that it covers a gate electrode 37 (see FIG. 4) of a transfer transistor TRG disposed in the photoelectric conversion area 21.

The semiconductor sections 204a and 204b of the island shape are disposed on a side opposite to the interlayer insulating film 41 side of the insulating film 222 and is covered with the insulating film 223. Similar to the 20th embodiment described above, each of the semiconductor sections 204a and 204b of the island shape is formed in the same semiconductor layer. As the semiconductor layer, a Si substrate, a SiGe substrate, an InGaAs substrate, or the like can be used. In this 21st embodiment, similar to the 20th embodiment described above, for example, a semiconductor substrate of a p type formed from monocrystalline silicon is used.

In the semiconductor section 204a of the island shape, similar to the 20th embodiment described above, as a pixel transistor included in the reading circuit 15, for example, an amplification transistor AMP is disposed. In addition, in the semiconductor section 204b of the island shape, as a pixel transistor included in the reading circuit 15, for example, a reset transistor RST is disposed. Although not illustrated in the drawing, a selection transistor as a pixel transistor included in the reading circuit 15 may be disposed in the semiconductor section 204a of the island shape with serial connection to the amplification transistor AMP or may be disposed in another semiconductor section of an island shape.

In the wiring layer 229, various wirings are formed. In FIG. 85, wirings 229b₁, 229f, and 229r are illustrated.

As illustrated in FIG. 85, the wiring 229b₁ is electrically connected to a contact electrode (through plug) 227b₁ that passes through the insulating film 223, the insulating film 222, and the interlayer insulating film 41 and reaches the conductive material 35 of the in-pixel separation area 32 and is further electrically connected to the conductive material 35 of the in-pixel separation area 32 through this contact electrode 227b₁. Similar to the 20th embodiment described above, a second reference electric potential of a positive electric potential higher than a first reference electric potential applied to the well region 22 of the p type is applied to this wiring 229b₁ as a power source electric potential. In other words, the conductive material 35 of the in-pixel separation area 32 is supplied with the second reference electric potential applied to the wiring 96b₁ through the contact electrode 95b₁ and has an electric potential fixed to this second reference electric potential.

As illustrated in FIG. 85, the wiring 229f is electrically connected to a contact electrode (through plug) 227f that passes through the insulating film 223, the insulating film 222, and the interlayer insulating film 41 and reaches the floating diffusion region FD of the second area 21b of the photoelectric conversion area 21 and is further electrically connected to the floating diffusion region FD through this contact electrode 227f. In addition, the wiring 229f is electrically connected to a gate electrode 205a of the amplification transistor AMP through the contact electrode (embedded plug) 227a embedded in the insulating film 223. In other words, the floating diffusion region FD is electrically connected to an input stage side of the reading circuit 15 (the gate electrode 205a of the amplification transistor AMP and a source region of the reset transistor RST).

The wiring 229r is electrically connected to the gate electrode 205r of the reset transistor RST through the contact electrode 227r embedded in the insulating film 203.

As illustrated in FIG. 85, the light absorbing body 228 overlaps the first area 21a of the photoelectric conversion area 21 in the plan view, is disposed on a side opposite to the semiconductor layer 20 side of the interlayer insulating film 41, and is covered with the insulating film 222 of an upper layer. The light absorbing body 228, in the thickness direction (the Z direction) of the semiconductor layer 20, is positioned on a semiconductor layer 20 side of the semiconductor sections 204a and 204b of the island shape and is positioned on a further side of the semiconductor sections 204a and 204b of the island shape than the semiconductor layer 20 side. In addition, the light absorbing body 228 is disposed between the semiconductor layer 20 that is a first semiconductor layer and the semiconductor sections 204a and 204b of the island shape that form a second semiconductor layer. In other words, the light absorbing body 228 is disposed in a layer between the semiconductor layer 20 and the semiconductor sections 204a and 204b of the island shape in terms of a layer shape (layers). As illustrated in FIG. 86, the light reflecting body 213 has a plate shape that extends in a two-dimensional shape. In this 21st embodiment, the light absorbing body 228 overlaps also the inter-pixel separation area and the in-pixel separation area in the plan view.

As the light absorbing body 228, it is preferable to include a metal material of which a light absorption rate is higher than those of the semiconductor layer 20 and the semiconductor sections 204a and 204b of the island shape as the second semiconductor layer. More specifically, as the light absorbing body 228, it is preferable to include a metal material of which the light absorption rate is higher than those of semiconductor materials such as Si, SiGe, InGaAa, and the like. As a such metal material, for example, tungsten (W) is effective. In this 21st embodiment, for example, the light absorbing body 228 including tungsten is used.

As illustrated in FIG. 85, the light absorbing body 228 is incident from the second face S2 (the light incidence face) of the semiconductor layer 20, is transmitted through the first area 21a of the photoelectric conversion area 21, and absorbs light 57V that has reached its own light absorbing body 228. In other words, the light 57V that has been incident from the second face S2 (the light incidence face) of the semiconductor layer 20, has been transmitted through the first area 21a of the photoelectric conversion area 21, and has reached the light absorbing body 228 is absorbed by the light absorbing body 228.

### <<Method of Manufacturing Solid-state Imaging Device>>

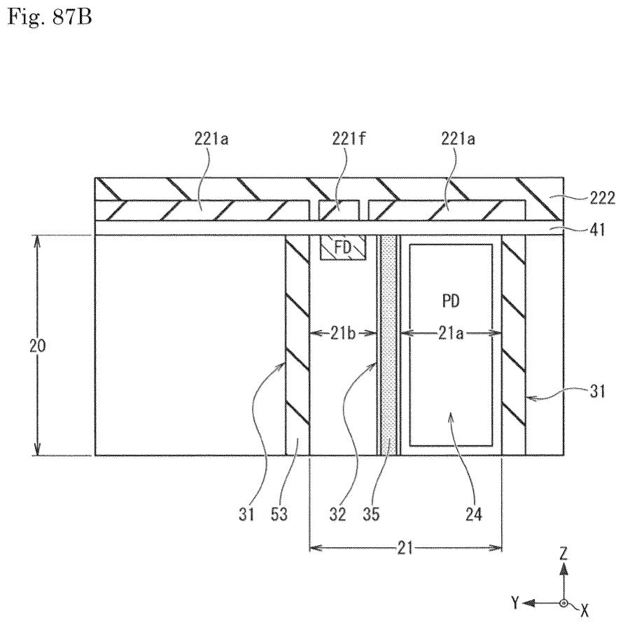

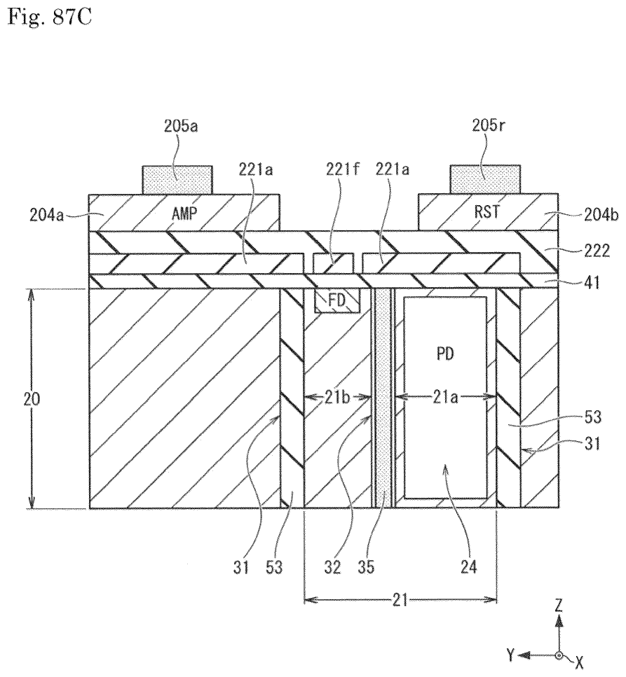

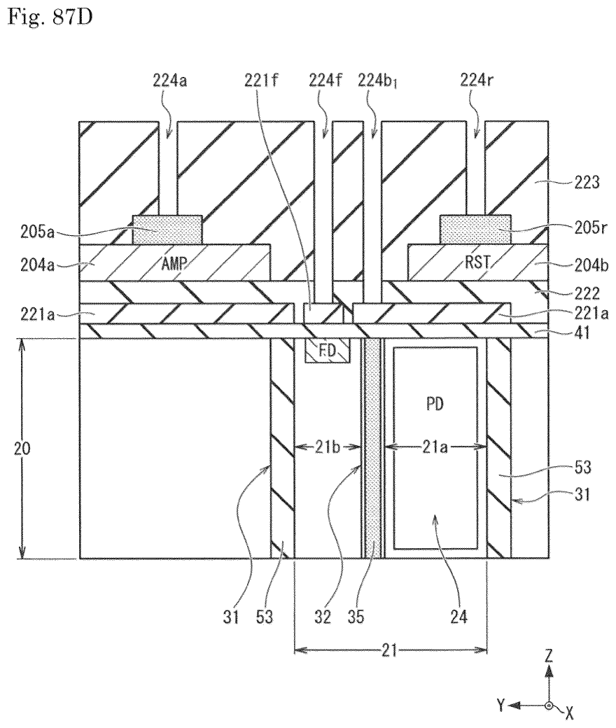

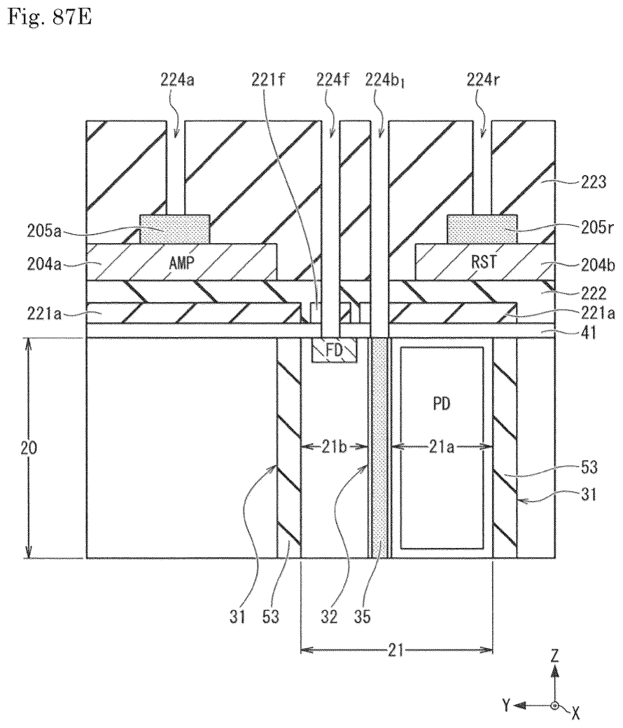

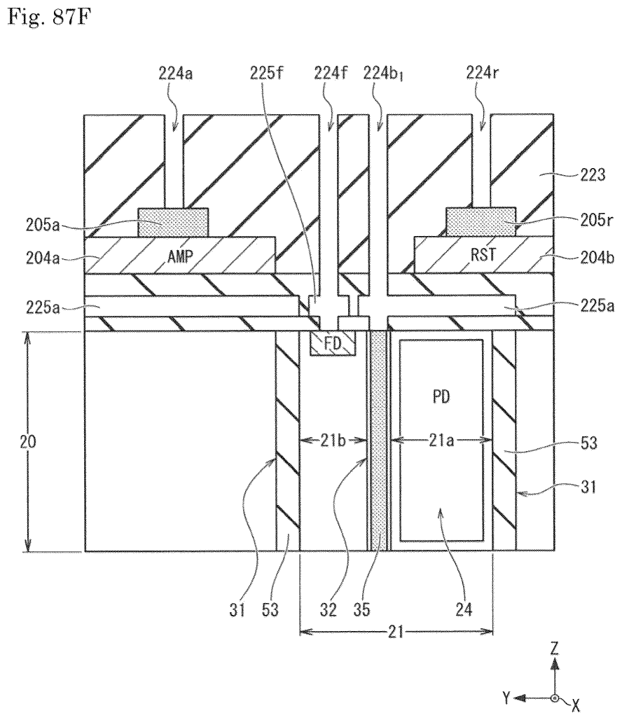

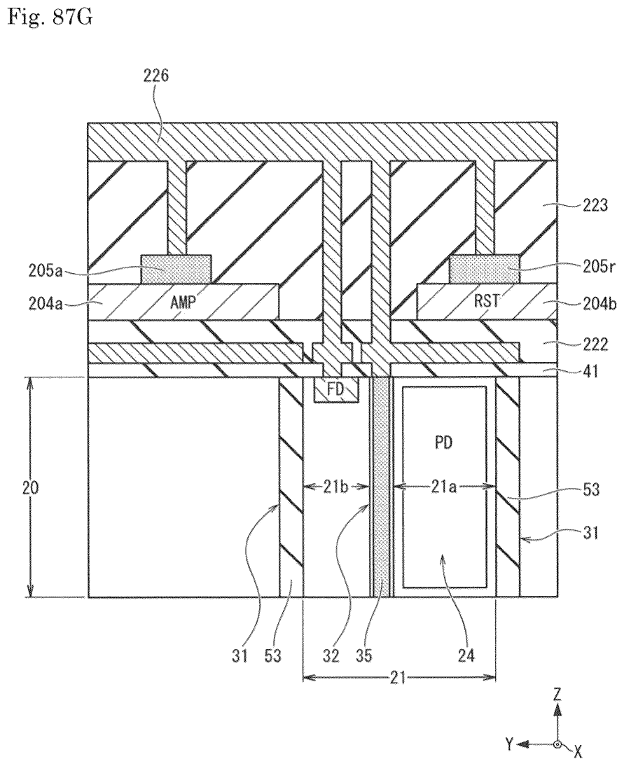

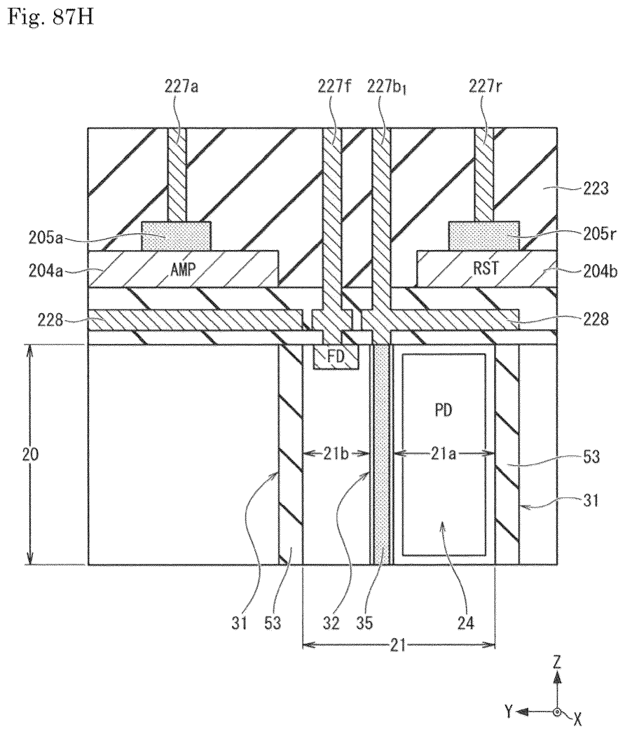

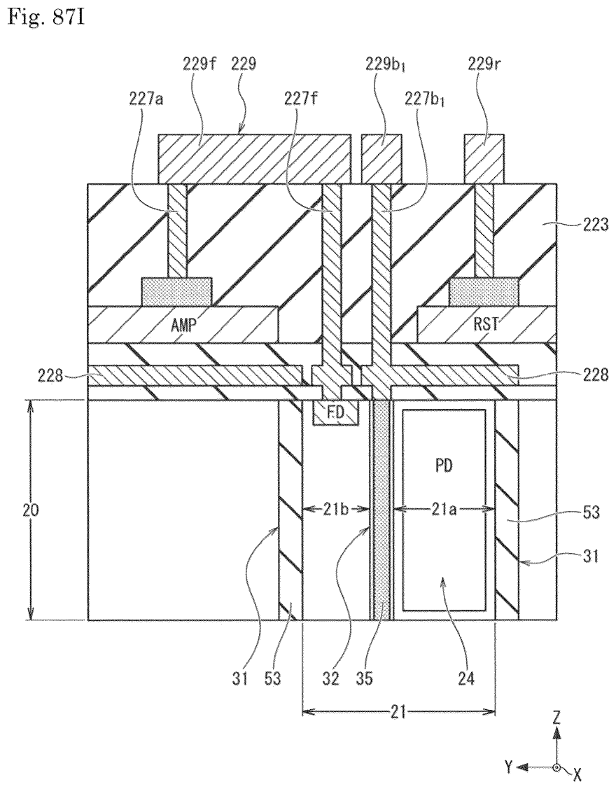

Next, a method of manufacturing the solid-state imaging device 1V according to the 21st embodiment of the present technology will be described using FIGS. 87A to 87J.

Also in FIGS. 87A to 87I, for easy viewing of the drawings, hatching representing a cross-section is partly omitted.

In this 21st embodiment, manufacturing of the light absorbing body 228 included in the method of manufacturing the solid-state imaging device 1V will be particularly described.

First, similar to the 20th embodiment described above, in the semiconductor layer 20, a photoelectric conversion area 21, an inter-pixel separation area 31, an in-pixel separation area 32, a floating diffusion region FD, a transfer transistor TRG (not illustrated), and the like are formed.

Next, as illustrated in FIG. 87A, on the first face S1 side of the semiconductor layer 20, an interlayer insulating film 41 and a sacrificial film 221 are formed in this order. As the interlayer insulating film 41, for example, a silicon oxide film is used. As the sacrificial film 221, for example, a silicon nitride film having selectivity for a silicon oxide film is used. Although not illustrated in FIG. 87A, when described with reference to FIG. 86, the interlayer insulating film 41 is formed to cover the gate electrode 37 of the transfer transistor TRG formed in the photoelectric conversion area 21. The sacrificial film 221 is used for forming a cavity part by selectively removing this sacrificial film 221.

Next, as illustrated in FIG. 87B, by patterning the sacrificial film 221, a first pattern part 221a overlapping the first area 21a of the photoelectric conversion area 21 in the plan view and a second pattern part 221f overlapping the second area 21b of the photoelectric conversion area 21 in the plan view are formed. The patterning of this sacrificial film 221 is performed using a known photolithographic technology and an anisotropic dry etching technology.

Next, as illustrated in FIG. 87B, a space between the first pattern part 221a and the second pattern part 221f is embedded on a side opposite to the semiconductor layer 20 side of the interlayer insulating film 41, and an insulating film 222 covering the first pattern part 221a and the second pattern part 221f is formed. As the insulating film 222, a silicon oxide film that is formed using a CVD method, a bias CVD method in which a high-frequency wave is applied to a substrate, or the like can be used.

Next, as illustrated in FIG. 87C, semiconductor sections 204a and 204b of the island shape as a second semiconductor layer are formed on a side opposite to the semiconductor layer 20 side of the insulating film 222, and thereafter, an amplification transistor AMP is formed in the semiconductor section 204a of the island shape, and a reset transistor RST is formed in the semiconductor section 204b of the island shape. The semiconductor sections 204a and 204b of the island shape are formed using a method similar to that of the 20th embodiment described above. In addition, here, among the pixel transistors (AMP, SEL, and RST) included in the reading circuit 15, although the amplification transistor AMP and the reset transistor RST will be described, also the selection transistor SEL is formed in one of the semiconductor sections 204a and 204b of the island shape or the other semiconductor section of the island shape.

Next, as illustrated in FIG. 87D, on a side opposite to the semiconductor layer 20 side of the insulating film 222, an insulating film 223 is formed such that it covers the semiconductor sections 204a and 204b of the island shape and the like. As the insulating film 223, for example, a silicon oxide film formed using a CVD method is used.

Next, as illustrated in FIG. 87D, a contact hole 224b₁ reaching the first pattern part 221a from the upper face of the insulating film 223 and overlapping the in-pixel separation area 32 in the plan view, a contact hole 224f reaching the second pattern part 221f from the upper face of the insulating film 223 and overlapping the floating diffusion region FD in the plan view, a contact hole 224a reaching the gate electrode 205a of the amplification transistor AMP from the upper side of the insulating film 223, and a contact hole 22r reaching the gate electrode 205r of the reset transistor RST from the upper face of the insulating film 223 are formed. Such contact holes 224b₁, 224f, 224a, and 224r can be formed using a known photolithographic technology and an anisotropic dry etching technology.

Next, as illustrated in FIG. 87E, by sequentially etching the first pattern part 221a and the interlayer insulating film 41 through the contact hole 224b₁, the contact hole 224b₁ is caused to reach the conductive material 35 of the in-pixel separation area 32, and by sequentially etching the second pattern part 221f and the interlayer insulating film 41 through the contact hole 224f, the contact hole 224f is caused to reach the floating diffusion region FD of the second area 21b of the photoelectric conversion area 21.

Next, as illustrated in FIG. 87F, a first cavity part 225a is formed by selectively removing the first pattern part 221a, and a second cavity part 225f is formed by selectively removing the second pattern part 221f. The first and second pattern parts 221a and 221f can be selectively removed by supplying phosphoric acid solutions to the first and second pattern parts 221a and 221f respectively through the contact holes 224b₁ and 224f.

Next, for example, a titanium (Ti) film for connection and a titanium nitride (TiN) film as a barrier film are sequentially formed on the inner wall of each of the contact holes 224b₁, 224f, 224a, and 224r and the inner wall of each of the first and second cavity parts 225a and 225f on the upper face of the insulating film 223 (a side opposite to the insulating film 222 side). The Ti film and the TiN film can be formed using a sputtering method and a CVD method.

Next, as illustrated in FIG. 87G, for example, a tungsten (W) film 226 as a conductive material is formed to embed the first and second cavity parts 225a and 225f and the contact holes 224b₁, 224f, 224a, and 224r. The W film 226 can be formed using a sputtering method or a CVD method.

Next, as illustrated in FIG. 87H, the W film 226, the TiN film, and the Ti film on the upper face of the insulating film 223 are selectively removed, for example, using a CMP method.

In accordance with this process, in the first cavity part 225a, a light absorbing body 228 that includes the Ti film, the TiN film, and the W film 226, is electrically connected to the conductive material 35 of the in-pixel separation area 32, overlaps the first area 21a of the photoelectric conversion area 21 in the plan view, and is positioned between the first area 21a of the photoelectric conversion area 21 and the semiconductor sections 204a and 204b of the island shape can be formed.

In addition, in the contact hole 224f and the second cavity part 225f, a contact electrode 227b₁ that includes the Ti film, the TiN film, and the W film 226 and is electrically connected to the floating diffusion region FD of the second area 21b of the photoelectric conversion area 21 can be formed.

Furthermore, in the contact hole 224a, a contact electrode 227a that includes the Ti film, the TIN film, and the W film 226 and is electrically connected to the gate electrode 205a of the amplification transistor AMP can be formed.

In addition, in the contact hole 224r, a contact electrode 227r that includes the Ti film, the TIN film, and the W film 226 and is electrically connected to the gate electrode 205r of the reset transistor RST can be formed.

Next, as illustrated in FIG. 87I, a wiring layer 229 including a wiring 229b₁, a wiring 229f, a wiring 229a, and a wiring 229r is formed on a side opposite to the semiconductor layer 20 side of the insulating film 223.

Thereafter, a wiring layer that is a wafer process is further formed.

### Main Effects of 21 st Embodiment

Similar to the solid-state imaging device 1A according to the first embodiment described above, the solid-state imaging device 1V according to this 21st embodiment includes the inter-pixel separation area 31, the in-pixel separation area 32, and the light blocking film 54. Thus, also in the solid-state imaging device 1V according to this 21st embodiment, effects similar to those of the solid-state imaging device 1A according to the first embodiment described above can be acquired.

In addition, the solid-state imaging device 1V according to this 21st embodiment includes the multilayer body 220 disposed on the first face S1 side of the semiconductor layer 20. The multilayer body 220 includes the light absorbing body 228 that is disposed to overlap the first area 21a of the photoelectric conversion area 21 and has a light absorption rate higher than the semiconductor layer 20. For this reason, light 57V that has been incident from the second face S2 (light incidence face) of the semiconductor layer 20 and has been transmitted through the first area 21a of the photoelectric conversion area 21 can be absorbed by the light absorbing body 228, and incidence of light in the second semiconductor layer including the semiconductor sections 204a and 204b of the island shape can be suppressed. In accordance with this, scattering and stray light can be suppressed.

In addition, according to the manufacturing method of this 21st embodiment, the light absorbing body 228 can be formed between the first area 21a of the photoelectric conversion area 21 and the semiconductor sections 204a and 204b of the island shape, and thus an installation area of the semiconductor sections 204a and 204b of the island shape can be widely taken.

### 22nd Embodiment

In this 22nd embodiment, one example in which a light reflecting body of the present technology is applied to a solid-state imaging device of a two-level structure in which two semiconductor layers are stacked will be described.

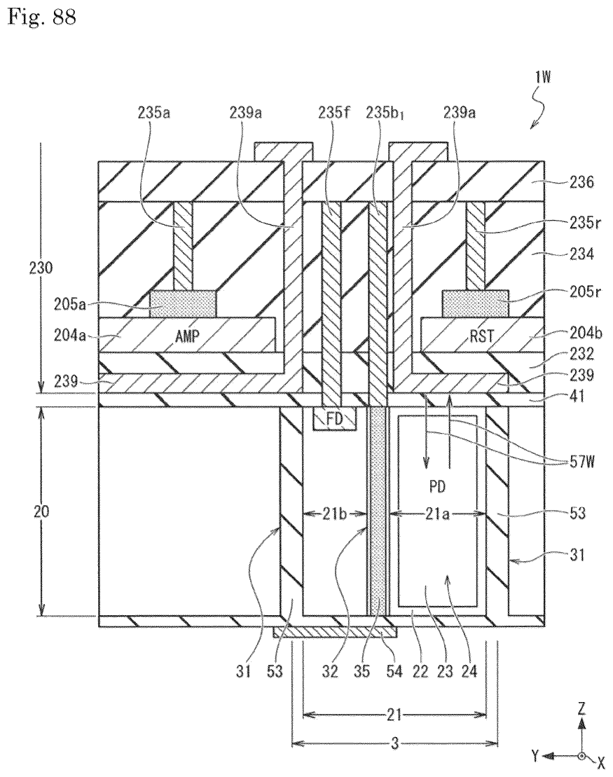

FIG. 88 is a longitudinal cross-sectional view schematically illustrating a longitudinal cross-sectional structure of a solid-state imaging device according to a 22nd embodiment of the present technology.

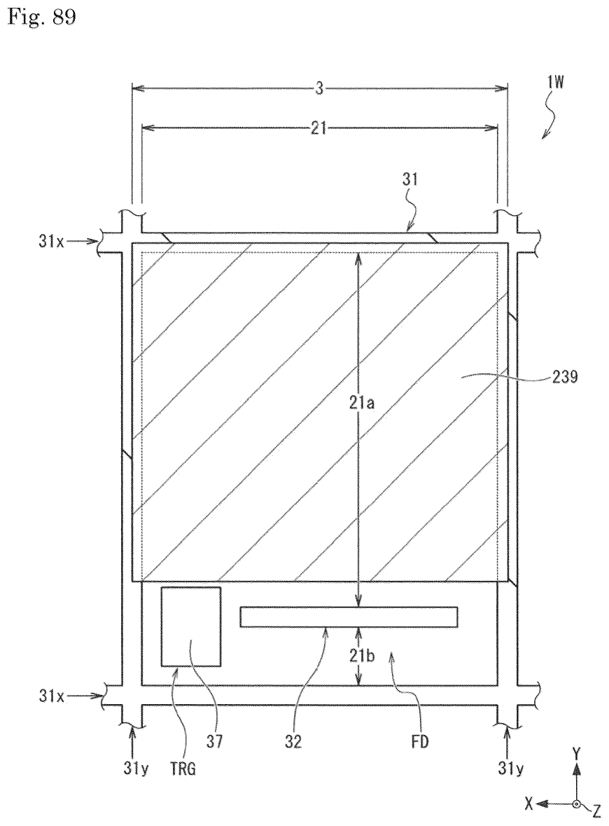

FIG. 89 is a plan view schematically illustrating a plane pattern of a light reflecting body illustrated in FIG. 88.

In FIG. 88, for easy viewing of the drawing, hatching representing a cross-section is partly omitted.

In FIG. 88, illustration of the diffraction diffusion section 51, the fixed charge film 52, the color filter 55, the microlens 56, and the like illustrated in FIGS. 5 and 6 is omitted.

In this 22nd embodiment, a semiconductor layer 20 corresponds to one specific example of “first semiconductor layer” of the present technology, and semiconductor sections 204a and 204b of an island shape correspond to one specific example of “second semiconductor layer” of the present technology.

### <<Configuration of Solid-state Imaging Device>>

As illustrated in FIG. 88, a solid-state imaging device 1W according to the 22nd embodiment of the present technology basically has a configuration similar to the solid-state imaging device 1A according to the first embodiment described above, and the following configurations are different.

In other words, as illustrated in FIG. 5, the solid-state imaging device 1A according to the first embodiment described above includes a multilayer wiring layer 40 on the first face side of the semiconductor layer 20. The pixel transistors (AMP, SEL, and RST) included in the reading circuit 15 illustrated in FIG. 3 are disposed in the photoelectric conversion area 21 of the semiconductor layer 20.

In contrast to this, as illustrated in FIG. 88, the solid-state imaging device 1W according to the 22nd embodiment of the present technology includes a multilayer body (lamination body) 230 disposed on a first face S1 side of a semiconductor layer 20 as a first semiconductor layer that is disposed through an interlayer insulating film 41. The pixel transistors (AMP, SEL, and RST) included in the reading circuit 15 illustrated in FIG. 3 are disposed in the multilayer body 230.

As illustrated in FIG. 88, the multilayer body 220 includes a light reflecting body 239 disposed to overlap a first area 21a of the photoelectric conversion area 21 in the plan view and semiconductor sections 204a and 204b of an island shape as a second semiconductor layer disposed on a side opposite to the semiconductor layer 20 side of this light reflecting body 239. In other words, the solid-state imaging device 1W according to this 22nd embodiment has a two-level structure in which the semiconductor layer 20 that is a first semiconductor layer and the semiconductor sections 204a and 204b of the island shape that form the second semiconductor layer are stacked.

In addition, the multilayer body 230 further includes an insulating film 232 that is disposed on a side opposite to the semiconductor layer 20 side of the interlayer insulating film 41, an insulating film 234 that is disposed on a side opposite to the interlayer insulating film 41 of this insulating film 232, and an insulating film 236 disposed on a side opposite to the insulating film 232 side of this insulating film 234.

Although not illustrated in detail, the interlayer insulating film 41, similar to the 20th embodiment described above, is disposed on the first face S1 side of the semiconductor layer 20 such that it covers a gate electrode 37 (see FIG. 4) of a transfer transistor TRG disposed in the photoelectric conversion area 21.

The semiconductor sections 204a and 204b of the island shape are disposed on a side opposite to the interlayer insulating film 41 side of the insulating film 232 and is covered with the insulating film 234. Similar to the 20th embodiment described above, each of the semiconductor sections 204a and 204b of the island shape is formed in the same layer. As the semiconductor layer 20, a Si substrate, a SiGe substrate, an InGaAs substrate, or the like can be used. In this 22nd embodiment, similar to the 20th embodiment described above, for example, a semiconductor substrate of a p type formed from monocrystalline silicon is used.

In the semiconductor section 204a of the island shape, similar to the 20th embodiment described above, as a pixel transistor included in the reading circuit 15, for example, an amplification transistor AMP is disposed. In addition, in the semiconductor section 204b of the island shape, as a pixel transistor included in the reading circuit 15, for example, a reset transistor RST is disposed. Although not illustrated in the drawing, a selection transistor as a pixel transistor included in the reading circuit 15 may be disposed in the semiconductor section 204a of the island shape with serial connection to the amplification transistor AMP or may be disposed in another semiconductor section of an island shape.

As illustrated in FIG. 88, a contact electrode 235b₁ reaching the conductive material 35 from the upper face of the insulating film 234 is electrically connected to the conductive material 35 of the in-pixel separation area 32 of the photoelectric conversion area 21. Similar to the first embodiment described above, a second reference electric potential of a positive electric potential higher than a first reference electric potential applied to the well region 22 of the p type is applied to this contact electrode 235b₁ as a power source electric potential. In other words, the conductive material 35 of the in-pixel separation area 32 is supplied with the second reference electric potential applied to the contact electrode 235b₁ and has an electric potential fixed to this second reference electric potential.

A contact electrode 235f reaching the floating diffusion region FD from the upper face of the insulating film 234 is electrically connected to the floating diffusion region FD of the second area 21b of the photoelectric conversion area 21. Although not illustrated in FIG. 88, this contact electrode 235f is electrically connected to the gate electrode 205a of the amplification transistor AMP. In other words, the floating diffusion region FD is electrically connected to an input stage side of the reading circuit 15 (the gate electrode 205a of the amplification transistor AMP and a source region of the reset transistor RST).

A contact electrode 235a reaching the gate electrode 205a from the upper face of the insulating film 234 is electrically connected to the gate electrode 205a of the amplification transistor AMP. A contact electrode 235r reaching the floating diffusion region FD from the upper face of the insulating film 234 is electrically connected to the gate electrode of the reset transistor RST.

As illustrated in FIG. 88, the light reflecting body 239 overlaps the first area 21a of the photoelectric conversion area 21 in the plan view, is disposed on a side opposite to the semiconductor layer 20 side of the interlayer insulating film 41, and is covered with the insulating film 232 of an upper layer. The light reflecting body 239, in the thickness direction (the Z direction) of the semiconductor layer 20, is positioned on a semiconductor layer 20 side of the semiconductor sections 204a and 204b of the island shape, and is positions on a further semiconductor sections 204a and 204b side of the island shape than the semiconductor layer 20 side. In addition, the light reflecting body 239 is disposed between the semiconductor layer 20 that is a first semiconductor layer and the semiconductor sections 204a and 204b of the island shape as a second semiconductor layer. In other words, the light reflecting body 239 is disposed in a layer between the semiconductor layer 20 and the semiconductor sections 204a and 204b of the island shape in terms of a layer shape (layers). As illustrated in FIG. 89, the light reflecting body 239 has a plate shape that extends in a two-dimensional shape.

As illustrated in FIG. 88, the light reflecting body 239 is formed integrally with a runner metal body 239a extending from the upper face of the insulating film 236 toward the semiconductor layer 20.

As the light reflecting body 239, it is preferable to include a metal material having an optical reflectance higher than an insulating material included in the inter-pixel separation area 31. In addition, as the light reflecting body 213, it is preferable to include a metal material having an optical reflectance higher than the semiconductor sections 204a and 204b of the island shape that are the second semiconductor layer and having a low light absorption rate. As such metal materials, for example, there are copper (Cu), aluminum (Al), and the like. Each of Cu and Al has an optical reflectance higher than silicon oxide or silicon and have low light absorption rates. In this 22nd embodiment, for example, the light reflecting body 239 including Al is used.

The light reflecting body 239, as illustrated in FIG. 88, reflects light 57W that has been incident from the second face S2 (the light incident face) of the semiconductor layer 20 and has been transmitted through the first area 21a of the photoelectric conversion area 21 to the first area 21a. In other words, light 57W that has been incident from the second face S2 of the semiconductor layer 20 and has been transmitted (passed) through the first area 21a of the photoelectric conversion area 21 is reflected on the light reflecting body 239 and returns to the first area 21a of the photoelectric conversion area 21. In the first area 21a of the photoelectric conversion area, the photoelectric conversion unit 24 (PD) is disposed.

### <<Method of Manufacturing Solid-state Imaging Device>>

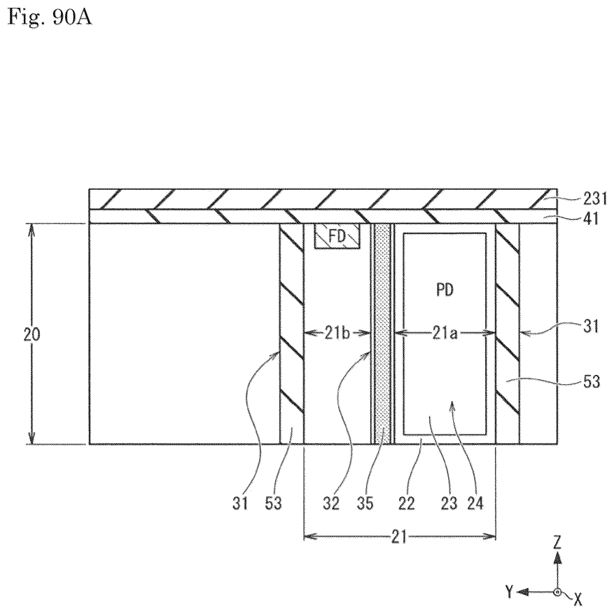

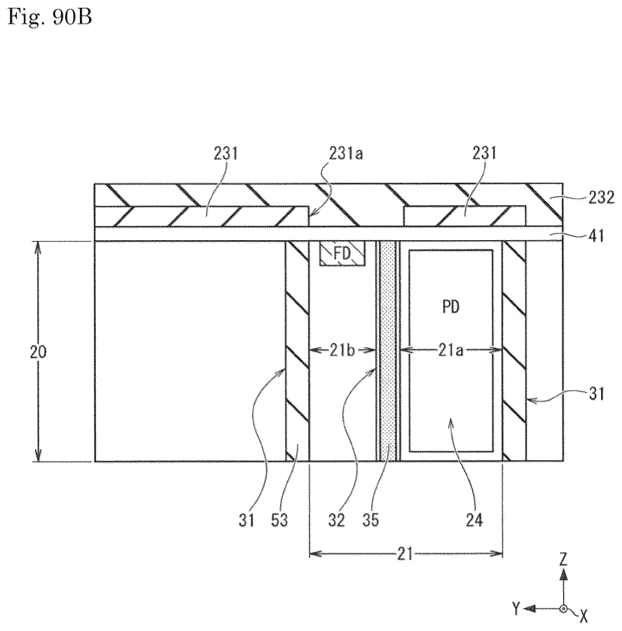

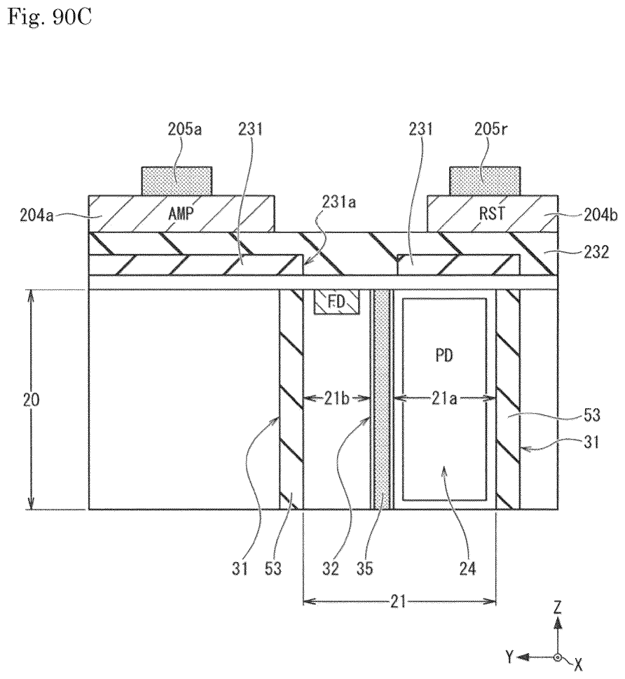

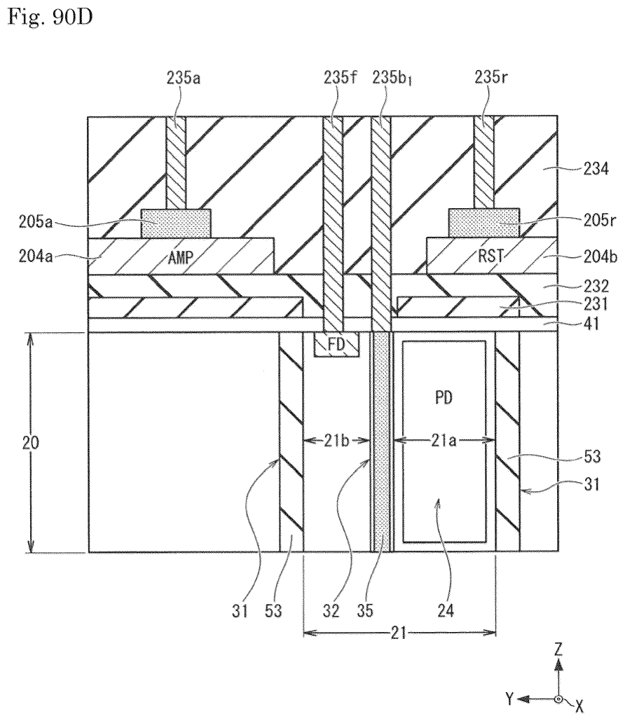

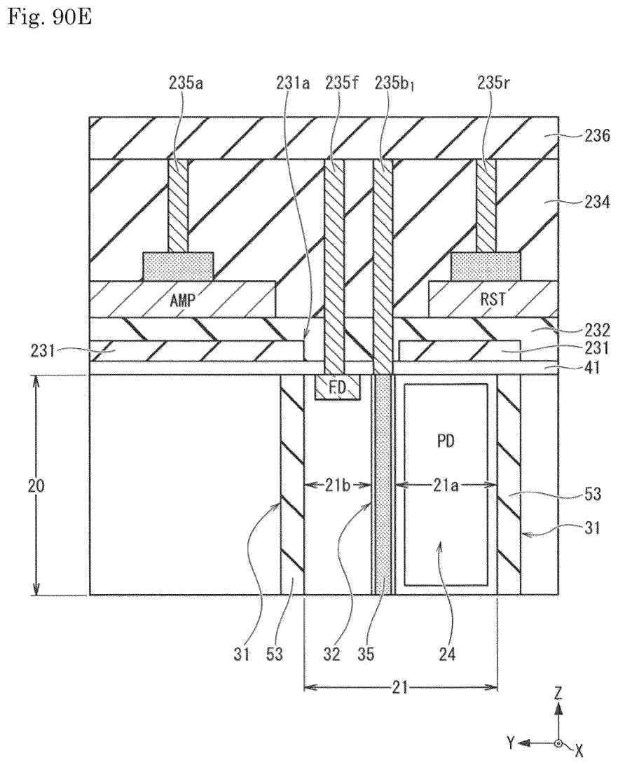

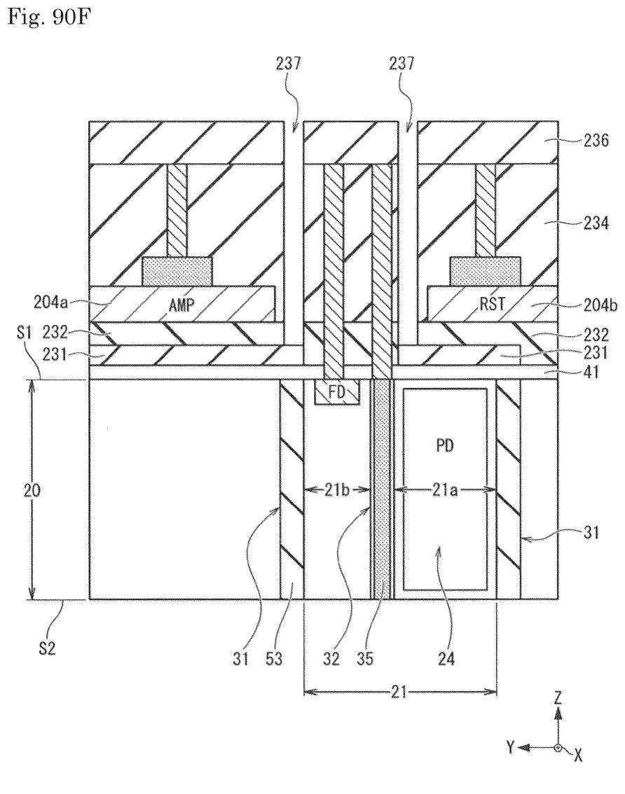

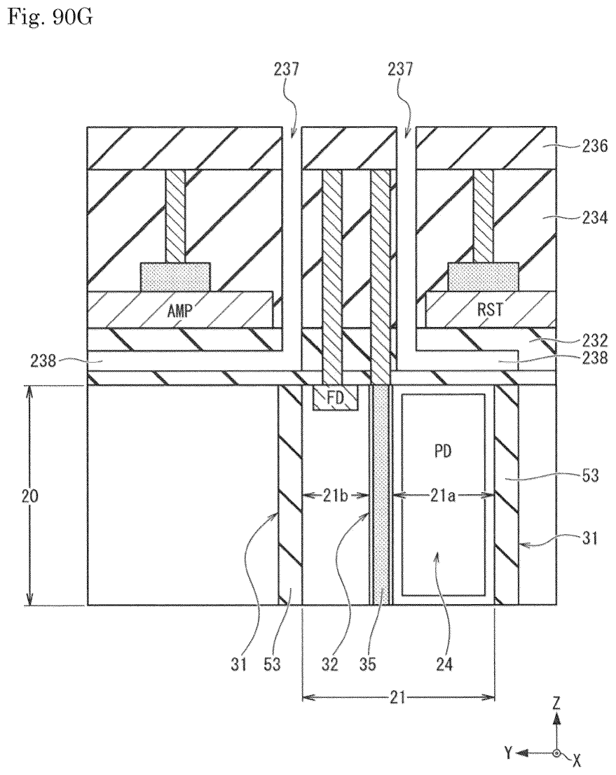

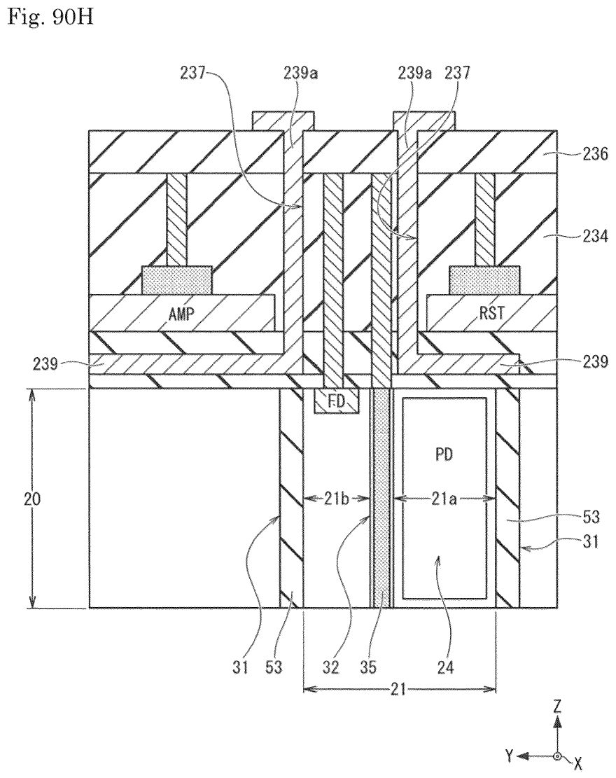

Next, a method of manufacturing the solid-state imaging device 1W according to the 22nd embodiment of the present technology will be described using FIGS. 90A to 90H.

Also in FIGS. 90A to 90H, for easy viewing of the drawings, hatching representing a cross-section is partly omitted.

In this 22nd embodiment, manufacturing of the light reflecting body 239 included in the method of manufacturing the solid-state imaging device 1W will be particularly described.

First, similar to the 20th embodiment described above, in the semiconductor layer 20, a photoelectric conversion area 21, an inter-pixel separation area 31, an in-pixel separation area 32, a floating diffusion region FD, a transfer transistor TRG (not illustrated), and the like are formed.

Next, as illustrated in FIG. 90A, on the first face S1 side of the semiconductor layer 20, an interlayer insulating film 41 and a sacrificial film 231 are formed in this order. As the interlayer insulating film 41, for example, a silicon oxide film is used. As the sacrificial film 231, for example, a silicon nitride film having selectivity for a silicon oxide film is used. Although not illustrated in FIG. 90A, when described with reference to FIG. 89, the interlayer insulating film 41 is formed to cover the gate electrode 37 of the transfer transistor TRG formed in the photoelectric conversion area 21. The sacrificial film 231 is used for forming a cavity part by selectively removing this sacrificial film 221.

Next, as illustrated in FIG. 90B, by patterning the sacrificial film 231, an opening part 231a overlapping the second area 21a of the photoelectric conversion area 21 in the plan view is formed. The patterning of this sacrificial film 221 is performed using a known photolithographic technology and an anisotropic dry etching technology.

Next, as illustrated in FIG. 90B, an insulating film 232 that embeds the opening part 231a and covers the sacrificial film 231 is formed on a side opposite to the semiconductor layer 20 side of the interlayer insulating film 41. As the insulating film 232, a silicon oxide film that is formed using a CVD method, a bias CVD method in which a high-frequency wave is applied to a substrate, or the like can be used.

Next, as illustrated in FIG. 90C, semiconductor sections 204a and 204b of the island shape as a second semiconductor layer are formed on a side opposite to the semiconductor layer 20 side of the insulating film 232, and thereafter, an amplification transistor AMP is formed in the semiconductor section 204a of the island shape, and a reset transistor RST is formed in the semiconductor section 204b of the island shape. The semiconductor sections 204a and 204b of the island shape are formed using a method similar to that of the 20th embodiment described above. In addition, here, among the pixel transistors (AMP, SEL, and RST) included in the reading circuit 15, although the amplification transistor AMP and the reset transistor RST will be described, also the selection transistor SEL is formed in one of the semiconductor sections 204a and 204b of the island shape or the other semiconductor section of the island shape.

Next, as illustrated in FIG. 87D, on a side opposite to the semiconductor layer 20 side of the insulating film 222, an insulating film 234 is formed such that it covers the semiconductor sections 204a and 204b of the island shape and the like. As the insulating film 234, for example, a silicon oxide film formed using a CVD method is used.

Next, as illustrated in FIG. 90D, a contact electrode 235b₁ reaching the conductive material 35 of the in-pixel separation area 32 from an upper face of the insulating film 234, a contact electrode 235f reaching the floating diffusion region FD from the upper face of the insulating film 234, a contact electrode 235a reaching the gate electrode 205a of the amplification transistor AMP from the upper face of the insulating film 206, and a contact electrode 235r reaching the gate electrode 205r of the reset transistor RST from the upper face of the insulating film 206 are respectively formed. The contact electrodes 235b₁, 235f, 235a, and 2335s are formed using a method similar to that of the 20th embodiment described above.

Next, as illustrated in FIG. 90E, in order to protect each of the contact electrodes, an insulating film 236 covering each of the contact electrodes 235b₁, 235f, 235a, and 235r is formed on a side opposite to the semiconductor layer 20 side of the insulating film 234.

Next, as illustrated in FIG. 90F, an opening part 237 reaching the sacrificial film 231 from the upper face of the insulating film 236 is formed. The opening part 237 can be formed by using a known photolithographic technology and an anisotropic dry etching technology.

Next, as illustrated in FIG. 90G, a cavity part 238 connected to the opening part 237 is formed by selectively removing the sacrificial film 231. The sacrificial film 231 can be selectively removed by supplying a phosphoric acid-based solution to the sacrificial film 231 through the opening part 237.

Next, for example, an aluminum (Al) film as a conductive material is formed to embed each of the cavity part 238 and the opening part 237, and thereafter, as illustrated in FIG. 90H, the aluminum film on the insulating film 236 is selectively removed using an etching-back method or a CMP method. As the method for forming the aluminum film, a sputtering method or a CVD method can be used. In the case of the CVD method, for stable growth, initially, a Ti film or a TiN film may be formed.

In accordance with this process, in the cavity part 238, a light reflecting body 239 that includes the Al film, overlaps the first area 21a of the photoelectric conversion area 21 in the plan view, and is positioned between the first area 21a of the photoelectric conversion area 21 and the semiconductor sections 204a and 204b of the island shape can be formed.

In addition, in the opening part 237, a runner metal body 239a that includes an Al film and is connected to the light reflecting body 239 is formed as well.

Thereafter, a wiring layer that is a wafer process is further formed.

### Main Effects of 22nd Embodiment

Similar to the solid-state imaging device 1A according to the first embodiment described above, the solid-state imaging device 1W according to this 22nd embodiment includes the inter-pixel separation area 31, the in-pixel separation area 32, and the light blocking film 54. Thus, also in the solid-state imaging device 1W according to this 21st embodiment, effects similar to those of the solid-state imaging device 1A according to the first embodiment described above can be acquired.

In addition, the solid-state imaging device 1W according to this 22nd embodiment includes the multilayer body 230 disposed on the first face S1 side of the semiconductor layer 20. The multilayer body 230 includes the light reflecting body 239 that is disposed to overlap the first area 21a of the photoelectric conversion area 21. For this reason, light 57W that has been incident from the second face S2 of the semiconductor layer 20 and has been transmitted (passed) through the first area 21a of the photoelectric conversion area 21 is reflected on the light reflecting body 213 and returns to the first area 21a of the photoelectric conversion area. Thus, according to the solid-state imaging device 1W according to this 22nd embodiment, improvement of efficiency of use of light can be achieved.

In addition, according to the manufacturing method of this 22nd embodiment, the light reflecting body 239 can be formed between the first area 21b of the photoelectric conversion area 21 and the semiconductor sections 204a and 204b of the island shape, and thus an installation area of the semiconductor sections 204a and 204b of the island shape can be widely taken.

In addition, since the Al film has light absorption lower than the W film and has a high reflectance, improvement of efficiency of use of light can be achieved.

### 23rd Embodiment

### Example of Application to Electronic Device

The present technology (technology according to the present disclosure), for example, may be applied to various electronic devices such as an imaging device such as a digital still camera and a digital video camera, a mobile phone having an imaging function, or other devices having an imaging function.

FIG. 91 is a diagram illustrating a schematic configuration of an electronic device (for example, a camera) according to the eighth embodiment of the present technology.

As illustrated in FIG. 91, the electronic device 300 includes a solid-state imaging device 301, an optical lens 302, a shutter device 303, a drive circuit 304, and a signal processing circuit 305. This electronic device 300 illustrates an embodiment of a case in which each of the solid-state imaging devices according to the first embodiment to the fourth embodiment of the present technology as the solid-state imaging device 301 is used in an electronic device (for example, a camera).

The optical lens 302 forms image light (incidence light 306) from a subject on an imaging surface of the solid-state imaging device 301. In accordance with this, signal electric charge is accumulated in the solid-state imaging device 301 over a constant period. The shutter device 303 controls a light emission period and light blocking period for the solid-state imaging device 301. The drive circuit 304 supplies drive signals that control the transfer operation of the solid-state imaging device 301 and the shutter operation of the shutter device 303. The drive signal (timing signal) supplied by the drive circuit 304 performs the signal transfer of the solid-state imaging device 301. The signal processing circuit 305 performs various kinds of signal processing on signals (pixel signals) output from the solid-state imaging device 301. An image signal having been subjected to signal processing is stored in a storage medium such as a memory or output to a monitor.

In accordance with such a configuration, in the electronic device 300 of the 23rd embodiment, improvement of pixel characteristics is achieved in the solid-state imaging device 301, and thus improvement of image quality can be achieved.

The electronic device 300 to which the solid-state imaging device of the embodiment described above can be applied is not limited to the camera but can be applied also to other electronic devices. For example, the solid-state imaging device may be applied to an imaging device such as a camera module for a mobile device such as a mobile phone or a tablet terminal.

In addition, the present technology can be applied to a general light detection device including a distance measuring sensor measuring a distance also called a time of flight (ToF) sensor and the like in addition to the above-described solid-state imaging device as an image sensor. The distance measuring sensor is a sensor that emits irradiation light to an object, detects reflection light acquired by reflecting the irradiation light on the surface of the object to return, and calculates a distance to the object on the basis of a flight time until the reflection light is received after emission of the irradiation light. As a structure of an element separation area of this distance measuring sensor, the structure of the element separation area described above can be employed.

Here, the present technology may have the following configurations.

(1)

A light detecting device including: a semiconductor layer; and first and second separation areas disposed in the semiconductor layer, in which the first separation area includes an insulating material that fills a first dug part extending in a thickness direction of the semiconductor layer and of which a refractive index is lower than that of the semiconductor layer, and the second separation area includes a conductive material filling a second dug part extending in the thickness direction of the semiconductor layer.

(2)

The light detecting device described above in (1), in which the conductive material is electrically connected to a wiring to which an electric potential is applied.

(3)

The light detecting device described above in (1) or (2), further including a photoelectric conversion area partitioned by the first separation area, in which the photoelectric conversion area includes: the second separation area separated from the first separation area; an electric charge maintaining section and a photoelectric conversion unit separated by the second separation area; and a transfer transistor transmitting signal electric charge acquired through photoelectric conversion by the photoelectric conversion unit to the electric charge maintaining section.

(4)

The light detecting device described above in (3), in which the photoelectric conversion unit photoelectrically converts light of a wavelength of visible region or light of a wavelength of an infrared region.

(5)

The light detecting device described above in (1) or (2), further including: a first photoelectric conversion area partitioned by the first separation area; and a second photoelectric conversion area partitioned by the second separation area, in which the first photoelectric conversion area and the second photoelectric conversion area are adjacent to each other through the first and second separation areas adjacent to each other.

(6)

The light detecting device described above in (5), in which each of the first and second photoelectric conversion areas includes an electric charge maintaining section, a photoelectric conversion unit, and a transfer transistor transmitting signal electric charge acquired through photoelectric conversion by the photoelectric conversion unit to the electric charge maintaining section.

(7)

The light detecting device described above in (6), in which the photoelectric conversion unit of the first photoelectric conversion area performs photoelectric conversion of light of a wavelength of an infrared region, and the photoelectric conversion unit of the second photoelectric conversion area performs photoelectric conversion of light of a wavelength of a visible region.

(8)

The light detecting device described above in (1) or (2), further including first and second photoelectric conversion areas partitioned to be adjacent to each other by the first separation area, in which the second separation area is disposed in at least one of the first and second photoelectric conversion areas while being separated from the first separation area.

(9)

The light detecting device described above in (8), in which, out of the first and second photoelectric conversion areas, one photoelectric conversion area including the second separation area performs photoelectric conversion of light of a wavelength of an infrared region, and the other photoelectric conversion area not including the second separation area performs photoelectric conversion of light of a wavelength of visible region.

(10)

The light detecting device described above in (1), further including an element separation area on a face of a side opposite to a light incidence face of the semiconductor layer, and in which each of the first and second separation areas has one end side being connected to the element separation area and the other end side reaching the light incidence face of the semiconductor layer.

(11)

The light detecting device described above in (1) or (2), further including: a first photoelectric conversion area partitioned by the first separation area; a second photoelectric conversion area partitioned by the second separation area; and a third separation area including a conductive material filling a third dug part extending in the thickness direction of the semiconductor layer, in which the third separation area is disposed to be separate from the first separation area in the first photoelectric conversion area and is disposed to be separate from the second separation area in the second photoelectric conversion area.

(12)

The light detecting device described above in (11), in which the conductive material of the third separation area is electrically connected to a wiring to which an electric potential is applied.

(13)

The light detecting device described above in (11) or (12), in which each of the first and second photoelectric conversion area further includes: an electric charge maintaining section and a photoelectric conversion unit partitioned by the third separation area; and a transfer transistor transmitting signal electric charge acquired through photoelectric conversion by the photoelectric conversion unit to the electric charge maintaining section.

(14)

The light detecting device described above in (13), in which the photoelectric conversion unit of the first photoelectric conversion area performs photoelectric conversion of light of a wavelength of an infrared region, and the photoelectric conversion unit of the second photoelectric conversion area performs photoelectric conversion of light of a wavelength of a visible region.

(15)

The light detecting device described above in any one of (11) to (14), further including an element separation area on a face of a side opposite to a light incidence face of the semiconductor layer, and in which each of the first, second, and third separation areas has one end side being connected to the element separation area and the other end side reaching the light incidence face of the semiconductor layer.

(16)

The light detecting device described above in (1), further including: a photoelectric conversion area including a first area and a second area that are partitioned by the first separation area and are separated in the second separation area; a photoelectric conversion unit disposed in the first area; an electric charge maintaining section disposed on the second area side of the semiconductor layer in the second area; and a light blocking body disposed to overlap the electric charge maintaining section on the first face side of the semiconductor layer.

(17)

The light detecting device described above in (3), in which the semiconductor layer is set as a first semiconductor layer, the light detecting device further including: a second semiconductor layer disposed on the first face side of the first semiconductor layer; and a reading circuit electrically connected to the electric charge maintaining section, a pixel transistor included in a pixel circuit is disposed in the second semiconductor layer.

(18)

A light detecting device including: a semiconductor layer having a first face and a second face positioned on opposite sides in a thickness direction; a first separation area including an insulating material that is disposed in a first dug part extending in the thickness direction of the semiconductor layer and of which a refractive index is lower than that of the semiconductor layer; a photoelectric conversion area partitioned by the first separation area; a second separation area including a conductive material disposed in a second dug part extending in the thickness direction of the semiconductor layer and separating the photoelectric conversion area into a first area and a second area in one direction; a photoelectric conversion unit disposed in the first area; an electric charge maintaining section disposed on the first face side of the semiconductor layer in the second area; and a light blocking body disposed on the second face side of the semiconductor layer and overlapping the second area in a plan view.

(19)

The light detecting device described above in (18), in which the light blocking body is disposed over inside and outside of the second area.

(20)

The light detecting device described above in (18) or (19), in which the light blocking body includes: a first light blocking part that is disposed outside of the second face of the semiconductor layer and overlaps the second area in the plan view; and a second light blocking part that protrudes from the first light blocking part over the inside of the second area.

(21)

The light detecting device described above in (20), in which the second light blocking part transverses the second face of the semiconductor layer in the thickness direction of the semiconductor layer.

(22)

The light detecting device described above in (20) or (21), in which the second light blocking part is separate from each of the first separation area and the second separation area.

(23)

The light detecting device described above in any one of (20) to (22), further including an insulating film disposed on the second face side of the semiconductor layer, in which the first light blocking part is disposed on a side opposite to the semiconductor layer side of the insulating film, and the second light blocking part goes through the insulating film.

(24)

The light detecting device described above in (18), in which the light blocking body overlaps the second separation area in the plan view and is disposed over the inside and outside of the semiconductor layer on the second face side of the semiconductor layer.

(25)

The light detecting device described above in (24), in which the light blocking body includes: a first light blocking part that is disposed outside of the second face of the semiconductor layer and overlaps the second area in the plan view; and a second light blocking part that overlaps the second separation area in the plan view and protrudes from the first light blocking part to the inside of the semiconductor layer.

(26)

The light detecting device described above in (25), in which the second light blocking part is disposed in a third dug part extending from the second face side of the semiconductor layer toward the second dug part.

(27)

The light detecting device described above in (25) or (26), in which the second light blocking part and the second separation area have different widths in a direction along the one direction.

(28)

The light detecting device described above in (18), further including an insulating film disposed on the second face side of the semiconductor layer, the light blocking body is disposed over the inside and outside of the insulating film in a thickness direction of the insulating film.

(29)

The light detecting device described above in (28), in which the light blocking body includes: a first light blocking part disposed on a side opposite to the semiconductor layer side of the insulating film and overlapping the second area in the plan view; a second light blocking part overlapping the first separation area in the plan view and protruding from the first light blocking part to the inside of the insulating film; and a third light blocking part overlapping the second separation area in the plan view and protruding from the first light blocking part to the inside of the insulating film.

(30)

The light detecting device described above in (28) or (29), in which the light blocking body overlaps each of the first and second separation areas in the plan view and is positioned on a second area side of the first area of the photoelectric conversion area in the one direction.

(31)

The light detecting device described above in any one of (18) to (30), in which the light blocking body extends over two photoelectric conversion areas that are adjacent to each other in another direction orthogonal to the one direction inside a two-dimensional plane.

(32)

The light detecting device described above in any one of (18) to (31), in which the photoelectric conversion unit photoelectrically converts light incident from the second face side of the semiconductor layer into signal electric charge, and the electric charge maintaining section maintains the signal electric charge acquired through photoelectric conversion by the photoelectric conversion unit.

(33)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit disposed in the first area; an electric charge maintaining section disposed on the first face side of the semiconductor layer in the second area; a light blocking body that is disposed on the second face side of the semiconductor layer and is disposed to overlap the second area in the plan view; and a light reflecting body that is disposed to overlap the second separation area in the plan view on the second face side of the semiconductor layer and of which a refractive index is lower than that of the semiconductor layer.

(34)

The light detecting device described above in (33), in which the light reflecting body is disposed in a third dug part that overlaps the second dug part in the plan view and extends from the second face side of the semiconductor layer to the first face side.

(35)

The light detecting device described above in (33) or (34), in which the light reflecting body is disposed on a first area side of the second separation area in the one direction, and the conductive material of the second separation area is disposed between the light reflecting body and the second area.

(36)

The light detecting device described above in any one of (33) to (35), in which the light reflecting body is an oxide film or the air.

(37)

The light detecting device described above in any one of (33) to (36), in which a depth of the light reflecting body from the second face of the semiconductor layer toward the first face is 1.5 μm or more.

(38)

The light detecting device described above in any one of (33) to (37), in which the photoelectric conversion unit photoelectrically converts light incident from the second face side of the semiconductor layer into signal electric charge, and the electric charge maintaining section maintains the signal electric charge acquired through photoelectric conversion by the photoelectric conversion unit.

(39)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; first and second photoelectric conversion areas partitioned to be aligned in one direction by the first separation area; a second separation area that includes a conductive material disposed in a second dug part extending in the thickness direction of the semiconductor layer and separates each of the first and second photoelectric conversion areas into a first area and a second area in the one direction; a photoelectric conversion unit disposed in the first area of each of the first and second photoelectric conversion areas; and an electric charge maintaining section disposed in the second area of each of the first and second photoelectric conversion areas, in which the second areas of the first and second photoelectric conversion areas are aligned to be adjacent to each other in the one direction through the third separation area in the plan view.

(40)

The light detecting device described above in (39), in which a width of the third separation area in a short-side direction is smaller than a width of the first separation area in a short-side direction.

(41)

The light detecting device described above in (39) or (40), in which a length of the third separation area in the thickness direction of the semiconductor layer is shorter than that of the second separation area.

(42)

The light detecting device described above in any one of (39) to (41), in which the third separation area includes an insulating material that is disposed in a third dug part extending in the thickness direction of the semiconductor layer and of which a refractive index is lower than that of the semiconductor layer.

(43)

The light detecting device described above in any one of (39) to (42), in which the third separation area is composed of a semiconductor area extending in the thickness direction of the semiconductor layer.

(44)

The light detecting device described above in any one of (39) to (43), further including a light blocking body disposed on the second face side of the semiconductor layer, the light blocking body is disposed to overlap the second areas of the first and second photoelectric conversion areas and be continuous over the second areas.

(45)

The light detecting device described above in any one of (39) to (44), in which the photoelectric conversion unit photoelectrically converts light incident from the second face side of the semiconductor layer into signal electric charge, and the electric charge maintaining section maintains the signal electric charge acquired through photoelectric conversion by the photoelectric conversion unit.

(46)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer through an insulator of which a refractive index is lower than that of the semiconductor layer and separates the photoelectric conversion area into a first area and a second area in one direction; a photoelectric conversion unit disposed in the first area; and an electric charge maintaining section disposed in the second area, in which, in the second separation area, a film thickness of the insulator on the first area side of the conductive material is larger than a film thickness of the insulator on the second area side of the conductive material.

(47)

The light detecting device described above in (46), in which the conductive material deviates from the first area side to the second area side in the plan view.

(48)

The light detecting device described above in (46) or (47), in which a width of the second separation area in the one direction is larger than a width of the first separation area in the one direction.

(49)

The light detecting device described above in any one of (46) to (48), in which the photoelectric conversion unit photoelectrically converts light incident from the second face side of the semiconductor layer into signal electric charge, and the electric charge maintaining section maintains the signal electric charge acquired through photoelectric conversion by the photoelectric conversion unit, the light detecting device further including a transfer transistor transmitting the signal electric charge acquired through photoelectric conversion by the photoelectric conversion unit to the electric charge maintaining section.

(50)

A light detecting device including: a semiconductor layer having a first face and a second face positioned on opposite sides; a photoelectric conversion area disposed in the semiconductor layer with being partitioned by a first separation area; a second separation area that separates each photoelectric conversion area of the photoelectric conversion area into a first area and a second area aligned in one direction; a photoelectric conversion unit that is disposed in the first area and performs photoelectric conversion of light incident from the second face side of the semiconductor layer; and an electric charge maintaining section that is disposed in the second area and maintains the signal electric charge acquired through photoelectric conversion by the photoelectric conversion unit, in which the first separation area includes an insulating material that is disposed in a first dug part extending in the thickness direction of the semiconductor layer and of which a refractive index is lower than that of the semiconductor layer the second separation area includes a conductive material that is disposed in a second dug part extending in the thickness direction of the semiconductor layer through a separation insulating film of which a refractive index is lower than that of the semiconductor layer, and the width of the second area in the one direction is set such that, out of incidence light incident in the first area from the second face side of the semiconductor layer, a phase difference between reflection light reflected on a side face part of the second separation area and return light acquired in accordance with the incidence light being transmitted through the second separation area and the second area, being reflected on the first separation area, and returning to the first area becomes an integer multiple of the incidence light.

(51)

The light detecting device described above in (50), further including a light blocking film that is disposed on the second face side of the semiconductor layer to overlap the electric charge maintaining section in the plan view.

(52)

The light detecting device described above in (50) or (51), in which the electric charge maintaining section is disposed on the second face side of the semiconductor layer.

(53)

The light detecting device described above in any one of (50) to (52), further including a transfer transistor transmitting the signal electric charge acquired through photoelectric conversion by the photoelectric conversion unit to the electric charge maintaining section.

(54)

A light detecting device including: a semiconductor layer having a first face and a second face positioned on opposite sides; a plurality of photoelectric conversion areas disposed in the semiconductor layer with being partitioned by a first separation area; a second separation area that separates each of the plurality of photoelectric conversion areas into a first area and a second area aligned in one direction; a photoelectric conversion unit that is disposed in the first area and performs photoelectric conversion of light incident from the second face side of the semiconductor layer; and an electric charge maintaining section that is disposed in the second area and maintains the signal electric charge acquired through photoelectric conversion by the photoelectric conversion unit, in which the first separation area includes an insulating material that is disposed in a first dug part extending in the thickness direction of the semiconductor layer and of which a refractive index is lower than that of the semiconductor layer, in which the second separation area includes a conductive material that is disposed in a second dug part extending in the thickness direction of the semiconductor layer through a separation insulating film of which a refractive index is lower than that of the semiconductor layer, and in which the plurality of photoelectric conversion areas include two or more types of photoelectric conversion areas of which widths of the second areas in the one direction are different from each other.

(55)

The light detecting device described above in (54), further including a light blocking film that is disposed on the second face side of the semiconductor layer to overlap the second area in the plan view.

(56)

The light detecting device described above in (54) or (55), in which the width of the light blocking film in the one direction is different in accordance with a width of the photoelectric conversion area.

(57)

The light detecting device described above in any one of (54) to (56), in which the electric charge maintaining section is disposed on the first face side of the semiconductor layer.

(58)

The light detecting device described above in any one of (54) to (57), further including a transfer transistor transmitting the signal electric charge acquired through photoelectric conversion by the photoelectric conversion unit to the electric charge maintaining section.

(59)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and photoelectrically converts light incident from the second face side of the semiconductor layer into signal electric charge; an electric charge maintaining section that is disposed in the second area and maintains the signal electric charge acquired through photoelectric conversion by the photoelectric conversion unit; and a dielectric in which an insulating film is disposed in a third dug part extending in a depth direction of the semiconductor layer through a fixed charge film.

(60)

The light detecting device described above in (59), in which the dielectric is a protrusion part protruding from the second separation area to the second area side.

(61)

The light detecting device described above in (59), in which the dielectric is a protrusion part protruding from the first separation area to the second area side.

(62)

The light detecting device described above in (59), in which the dielectric is an island part that is separated from each of the first and second separation areas.

(63)

The light detecting device described above in any one of (59) to (62), in which the electric charge maintaining section is disposed on the first face side of the semiconductor layer.

(64)

The light detecting device described above in any one of (59) to (63), further including a light blocking film that is disposed on the second face side of the semiconductor layer to overlap the second area in the plan view.

(65)

The light detecting device described above in any one of (59) to (64), further including a transfer transistor transmitting the signal electric charge acquired through photoelectric conversion by the photoelectric conversion unit to the electric charge maintaining section.

(66)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and performs photoelectric conversion of light incident from the second face side of the semiconductor layer; an electric charge maintaining section that is disposed in the second area and maintains the signal electric charge acquired through photoelectric conversion by the photoelectric conversion unit; and a multilayer body disposed on the first face side of the semiconductor layer, in which the multilayer body includes a light reflecting body disposed to overlap the first area.

(67)

The light detecting device described above in (66), in which the semiconductor layer is set as a first semiconductor layer, and in which the multilayer body further includes a second semiconductor layer disposed to overlap the light reflecting body in the plan view on a side opposite to the first semiconductor layer side of the light reflecting body.

(68)

The light detecting device described above in (66) or (67), in which the light reflecting body includes a metal material of which an optical reflectance is higher than that of the insulating material of the first separation area.

(69)

The light detecting device described above in (66) or (67), in which the light reflecting body includes a metal material of which an optical reflectance is higher than that of the second semiconductor layer and has a low light absorption rate.

(70)

The light detecting device described above in any one of (67) to (69), further including a reading circuit that is electrically connected to the electric charge maintaining section, in which a pixel transistor included in the reading circuit is disposed in the second semiconductor layer.

(71)

A light detecting device including: a semiconductor layer having a first face and a second face positioned on opposite sides in a thickness direction; a first separation area that includes an insulating material disposed in a first dug part extending in the thickness direction of the semiconductor layer and of which a refractive index is lower than that of the semiconductor layer; a photoelectric conversion area partitioned by the first separation area; a second separation area that includes a conductive material disposed in a second dug part extending in the thickness direction of the semiconductor layer and separates the photoelectric conversion area into a first area and a second area in one direction; a photoelectric conversion unit that is disposed in the first area and performs photoelectric conversion of light incident from the second face side of the semiconductor layer; an electric charge maintaining section that is disposed in the second area and maintains the signal electric charge acquired through photoelectric conversion by the photoelectric conversion unit; and a multilayer body disposed on the first face side of the semiconductor layer, in which the multilayer body includes a light absorbing body disposed to overlap the first area and of which a light absorption rate is higher than that of the semiconductor layer.

(72)

An electronic device including: the light detecting device according to any one of (1) to (71) described above; an optical lens forming an image of image light from a subject on an imaging surface of the light detecting device; and a signal processing circuit performing signal processing on a signal output from the light detecting device.

The scope of the present technology is not limited to the illustrated and described exemplary embodiments, but includes all embodiments that provide equivalent effects sought after with the present technology. In addition, the scope of the present technology is not limited to combinations of features of the invention defined by the claims, but can be defined by any desired combination of specific features among all disclosed features.

### REFERENCE SIGNS LIST

1A, 1B, 1C, 1D, 1E, 1F, 1G, 1H, 1I, 1J, 1K, 1L, 1M, IN, 1P, 1Q, 1R, 1S, 1T, 1U, 1V, 1W Solid-state imaging device
2 Semiconductor chip
2A Pixel array portion
2B Peripheral portion
3 Pixel
4 Vertical drive circuit
5 Column signal processing circuit
6 Horizontal drive circuit
7 Output circuit
8 Control circuit
10 Pixel drive line
11 Vertical signal line
13 Logic circuit
14 Bonding pad
15 Reading circuit
20 Semiconductor layer
21 Photoelectric conversion area
21A First photoelectric conversion area
21B Second photoelectric conversion area
21a First area
21b Second area
22 Well region of p type
23 Well region of n type
24 Photoelectric conversion unit
24a First photoelectric conversion unit
24b Second photoelectric conversion unit
25 Element separation area (field separation area)
26 Shallow groove part
27 Insulating film
31 Inter-pixel separation area (first separation area)
31a First inter-pixel separation area (first separation area)
31b Second inter-pixel separation area (second separation area)
31L In-cell inter-pixel separation area
31Q, 31R Protrusion part
31x First part
31y Second part
32 In-pixel separation area (second separation area)
33a Dug part (First dug part)
33b Dug part (Second dug part)
33a₁ Dug part (First dug part)
33a₂ Dug part (Second dug part)
33h, 33i, 33K Dug part
33h₁ Insulating film
33L Dug part
33L₁ dug part formation area
33M, 33Q, 33R Dug part
34 Separation insulating film
35 Silicon film (conductive material)
36 Insulating film
37 Gate electrode
40 Multilayer wiring layer
41 Interlayer insulating film
42b, 42b₁, 42b₂, 43c Contact electrode
43 Wiring layer
43a, 43b, 43f, 43f₁, 43f₂ Wiring
44 Interlayer insulating film
45 Wiring layer
51 Diffraction scattering section
52 Fixed charge film
53, 53J Insulating film
53d₁, 53d₂ Dug part
54 Light blocking film
55 Color filter
56 Microlens
57H, 57I Irradiation light
57H₁, 57H₂, 57I₁, 5712, 57J₁, 57J₂, 57K₁, 57K₂ Oblique light
57L Penetration optical path
57M, 57T, 57U, 57V, 57W Light
57N Incidence light
57N₁, 57N₂ Reflection light
57Q Electric charge transmission line
58M Insulator
58M₁ First insulator
58M₂ Second insulator
60 Pixel
61 Photoelectric conversion unit
62 First transfer transistor (TRG)
63 Second transfer transistor (TRG)
64 Memory unit
65 Floating diffusion (FD) region
66 Amplification transistor (AMP)
67 Selection transistor (SEL)
68 Reset transistor (RST)
80H, 80I, 80J Light blocking body
80K Light reflecting body
81x First linear part
82 Light blocking film
82a First light blocking part
82b, 82c, 82d₁ Second light blocking part
82d₂ Third light blocking part
82y Second linear part
85K Light reflecting body
200, 220, 230 Multilayer body
202 Stopper film
204a, 204b Semiconductor section (second semiconductor layer)
207a, 207b₁, 207f, 207r, 207t Contact electrode
209 Wiring layer
209a, 209b₁, 209f, 209r, 209t Wiring
210 Cap film
212 Protection film
213 Light reflecting body
225a First cavity part
225f Second cavity part
227a, 227b₁, 227f, 227f Contact electrode
228 Light absorbing body
229 Wiring layer
229b₁, 229f, 229r Wiring
235a, 235b₁, 235f Contact electrode
239 Light reflecting body
AMP Amplification transistor
FD Floating diffusion region
If₁, If₂ Interface part
RST Reset transistor
SEL Selection transistor
STG Transfer transistor

What is claimed is:

1. A light detecting device, comprising:
a semiconductor layer; and
first and second separation areas disposed in the semiconductor layer,
wherein the first separation area includes an insulating material that fills a first dug part extending in a thickness direction of the semiconductor layer and of which a refractive index is lower than that of the semiconductor layer, and
wherein the second separation area includes a conductive material filling a second dug part extending in the thickness direction of the semiconductor layer.

2. The light detecting device according to claim 1, wherein the conductive material is electrically connected to a wiring to which an electric potential is applied.

3. The light detecting device according to claim 1, further comprising a photoelectric conversion area partitioned by the first separation area,
wherein the photoelectric conversion area includes:
the second separation area separated from the first separation area;
an electric charge maintaining section and a photoelectric conversion unit separated by the second separation area; and
a transfer transistor transmitting signal electric charge acquired through photoelectric conversion by the photoelectric conversion unit to the electric charge maintaining section.

4. The light detecting device according to claim 3, wherein the photoelectric conversion unit photoelectrically converts light of a wavelength of visible region or light of a wavelength of an infrared region.

5. The light detecting device according to claim 1, further comprising:
a first photoelectric conversion area partitioned by the first separation area; and
a second photoelectric conversion area partitioned by the second separation area,
wherein the first photoelectric conversion area and the second photoelectric conversion area are adjacent to each other through the first and second separation areas adjacent to each other.

6. The light detecting device according to claim 5, wherein each of the first and second photoelectric conversion areas includes an electric charge maintaining section, a photoelectric conversion unit, and a transfer transistor transmitting signal electric charge acquired through photoelectric conversion by the photoelectric conversion unit to the electric charge maintaining section.

7. The light detecting device according to claim 6,
wherein the photoelectric conversion unit of the first photoelectric conversion area performs photoelectric conversion of light of a wavelength of an infrared region, and
wherein the photoelectric conversion unit of the second photoelectric conversion area performs photoelectric conversion of light of a wavelength of a visible region.

8. The light detecting device according to claim 1, further comprising first and second photoelectric conversion areas partitioned to be adjacent to each other by the first separation area,
wherein the second separation area is disposed in at least one of the first and second photoelectric conversion areas while being separated from the first separation area.

9. The light detecting device according to claim 8, wherein, out of the first and second photoelectric conversion areas, one photoelectric conversion area including the second separation area performs photoelectric conversion of light of a wavelength of an infrared region, and the other photoelectric conversion area not including the second separation area performs photoelectric conversion of light of a wavelength of visible region.

10. The light detecting device according to claim 1, further comprising an element separation area on a face of a side opposite to a light incidence face of the semiconductor layer, and
wherein each of the first and second separation areas has one end side being connected to the element separation area and the other end side reaching the light incidence face of the semiconductor layer.

11. The light detecting device according to claim 1, further comprising:
a first photoelectric conversion area partitioned by the first separation area;
a second photoelectric conversion area partitioned by the second separation area; and
a third separation area including a conductive material filling a third dug part extending in the thickness direction of the semiconductor layer,
wherein the third separation area is disposed to be separate from the first separation area in the first photoelectric conversion area and is disposed to be separate from the second separation area in the second photoelectric conversion area.

12. The light detecting device according to claim 11, wherein the conductive material of the third separation area is electrically connected to a wiring to which an electric potential is applied.

13. The light detecting device according to claim 11, wherein each of the first and second photoelectric conversion area further includes:
an electric charge maintaining section and a photoelectric conversion unit partitioned by the third separation area; and
a transfer transistor transmitting signal electric charge acquired through photoelectric conversion by the photoelectric conversion unit to the electric charge maintaining section.

14. The light detecting device according to claim 13,
wherein the photoelectric conversion unit of the first photoelectric conversion area performs photoelectric conversion of light of a wavelength of an infrared region, and
wherein the photoelectric conversion unit of the second photoelectric conversion area performs photoelectric conversion of light of a wavelength of a visible region.

15. The light detecting device according to claim 11, further comprising an element separation area on a face of a side opposite to a light incidence face of the semiconductor layer, and
wherein each of the first, second, and third separation areas has one end side being connected to the element separation area and the other end side reaching the light incidence face of the semiconductor layer.

16. The light detecting device according to claim 1, further comprising:
a photoelectric conversion area including a first area and a second area that are partitioned by the first separation area and are separated in the second separation area;
a photoelectric conversion unit disposed in the first area;
an electric charge maintaining section disposed on the second area side of the semiconductor layer in the second area; and
a light blocking body disposed to overlap the electric charge maintaining section on the first face side of the semiconductor layer.

17. The light detecting device according to claim 3, wherein the semiconductor layer is set as a first semiconductor layer, the light detecting device further comprising:
a second semiconductor layer disposed on the first face side of the first semiconductor layer; and
a reading circuit electrically connected to the electric charge maintaining section,
wherein a pixel transistor included in a pixel circuit is disposed in the second semiconductor layer.

18. A light detecting device, comprising:
a semiconductor layer having a first face and a second face positioned on opposite sides in a thickness direction;
a first separation area including an insulating material that is disposed in a first dug part extending in the thickness direction of the semiconductor layer and of which a refractive index is lower than that of the semiconductor layer;
a photoelectric conversion area partitioned by the first separation area;
a second separation area including a conductive material disposed in a second dug part extending in the thickness direction of the semiconductor layer and separating the photoelectric conversion area into a first area and a second area in one direction;
a photoelectric conversion unit disposed in the first area;
an electric charge maintaining section disposed on the first face side of the semiconductor layer in the second area; and
a light blocking body disposed on the second face side of the semiconductor layer and overlapping the second area in a plan view.

19. The light detecting device according to claim 18, wherein the light blocking body is disposed over inside and outside of the second area.

20. The light detecting device according to claim 19, wherein the light blocking body includes:
a first light blocking part that is disposed outside of the second face of the semiconductor layer and overlaps the second area in the plan view; and
a second light blocking part that protrudes from the first light blocking part over the inside of the second area.

21. The light detecting device according to claim 20, wherein the second light blocking part transverses the second face of the semiconductor layer in the thickness direction of the semiconductor layer.

22. The light detecting device according to claim 20, wherein the second light blocking part is separate from each of the first separation area and the second separation area.

23. The light detecting device according to claim 20, further comprising an insulating film disposed on the second face side of the semiconductor layer,
wherein the first light blocking part is disposed on a side opposite to the semiconductor layer side of the insulating film, and
wherein the second light blocking part goes through the insulating film.

24. The light detecting device according to claim 18, wherein the light blocking body overlaps the second separation area in the plan view and is disposed over the inside and outside of the semiconductor layer on the second face side of the semiconductor layer.

25. The light detecting device according to claim 24, wherein the light blocking body includes:
a first light blocking part that is disposed outside of the second face of the semiconductor layer and overlaps the second area in the plan view; and
a second light blocking part that overlaps the second separation area in the plan view and protrudes from the first light blocking part to the inside of the semiconductor layer.

26. The light detecting device according to claim 25, wherein the second light blocking part is disposed in a third dug part extending from the second face side of the semiconductor layer toward the second dug part.

27. The light detecting device according to claim 24, wherein the second light blocking part and the second separation area have different widths in a direction along the one direction.

28. The light detecting device according to claim 18, further comprising an insulating film disposed on the second face side of the semiconductor layer,
wherein the light blocking body is disposed over the inside and outside of the insulating film in a thickness direction of the insulating film.

29. The light detecting device according to claim 28, wherein the light blocking body includes:
a first light blocking part disposed on a side opposite to the semiconductor layer side of the insulating film and overlapping the second area in the plan view;
a second light blocking part overlapping the first separation area in the plan view and protruding from the first light blocking part to the inside of the insulating film; and
a third light blocking part overlapping the second separation area in the plan view and protruding from the first light blocking part to the inside of the insulating film.

30. The light detecting device according to claim 28, wherein the light blocking body overlaps each of the first and second separation areas in the plan view and is positioned on a second area side of the first area of the photoelectric conversion area in the one direction.

31. The light detecting device according to claim 18, wherein the light blocking body extends over two photoelectric conversion areas that are adjacent to each other in another direction orthogonal to the one direction inside a two-dimensional plane.

32. The light detecting device according to claim 18,
wherein the photoelectric conversion unit photoelectrically converts light incident from the second face side of the semiconductor layer into signal electric charge, and
wherein the electric charge maintaining section maintains the signal electric charge acquired through photoelectric conversion by the photoelectric conversion unit.

33. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
a photoelectric conversion area partitioned by the first separation area;
a second separation area that includes a conductive material disposed in a second dug part extending in the thickness direction of the semiconductor layer and separates the photoelectric conversion area into a first area and a second area in one direction;
a photoelectric conversion unit disposed in the first area;
an electric charge maintaining section disposed on the first face side of the semiconductor layer in the second area;
a light blocking body that is disposed on the second face side of the semiconductor layer and is disposed to overlap the second area in the plan view; and
a light reflecting body that is disposed to overlap the second separation area in the plan view on the second face side of the semiconductor layer and of which a refractive index is lower than that of the semiconductor layer.

34. The light detecting device according to claim 33, wherein the light reflecting body is disposed in a third dug part that overlaps the second dug part in the plan view and extends from the second face side of the semiconductor layer to the first face side.

35. The light detecting device according to claim 33, wherein the light reflecting body is disposed on a first area side of the second separation area in the one direction, and the conductive material of the second separation area is disposed between the light reflecting body and the second area.

36. The light detecting device according to claim 33, wherein the light reflecting body is an oxide film or the air.

37. The light detecting device according to claim 33, wherein a depth of the light reflecting body from the second face of the semiconductor layer toward the first face is 1.5 μm or more.

38. The light detecting device according to claim 33,
wherein the photoelectric conversion unit photoelectrically converts light incident from the second face side of the semiconductor layer into signal electric charge, and
wherein the electric charge maintaining section maintains the signal electric charge acquired through photoelectric conversion by the photoelectric conversion unit.

39. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
first and second photoelectric conversion areas partitioned to be aligned in one direction by the first separation area;
a second separation area that includes a conductive material disposed in a second dug part extending in the thickness direction of the semiconductor layer and separates each of the first and second photoelectric conversion areas into a first area and a second area in the one direction;
a photoelectric conversion unit disposed in the first area of each of the first and second photoelectric conversion areas; and
an electric charge maintaining section disposed in the second area of each of the first and second photoelectric conversion areas,
wherein the second areas of the first and second photoelectric conversion areas are aligned to be adjacent to each other in the one direction through the third separation area in the plan view.

40. The light detecting device according to claim 39, wherein a width of the third separation area in a short-side direction is smaller than a width of the first separation area in a short-side direction.

41. The light detecting device according to claim 39, wherein a length of the third separation area in the thickness direction of the semiconductor layer is shorter than that of the second separation area.

42. The light detecting device according to claim 39, wherein the third separation area includes an insulating material that is disposed in a third dug part extending in the thickness direction of the semiconductor layer and of which a refractive index is lower than that of the semiconductor layer.

43. The light detecting device according to claim 39, wherein the third separation area is composed of a semiconductor area extending in the thickness direction of the semiconductor layer.

44. The light detecting device according to claim 39, further comprising a light blocking body disposed on the second face side of the semiconductor layer,
wherein the light blocking body is disposed to overlap the second areas of the first and second photoelectric conversion areas and be continuous over the second areas.

45. The light detecting device according to claim 39,
wherein the photoelectric conversion unit photoelectrically converts light incident from the second face side of the semiconductor layer into signal electric charge, and
wherein the electric charge maintaining section maintains the signal electric charge acquired through photoelectric conversion by the photoelectric conversion unit.

46. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
a photoelectric conversion area partitioned by the first separation area;
a second separation area that includes a conductive material disposed in a second dug part extending in the thickness direction of the semiconductor layer through an insulator of which a refractive index is lower than that of the semiconductor layer and separates the photoelectric conversion area into a first area and a second area in one direction;
a photoelectric conversion unit disposed in the first area; and
an electric charge maintaining section disposed in the second area,
wherein, in the second separation area, a film thickness of the insulator on the first area side of the conductive material is larger than a film thickness of the insulator on the second area side of the conductive material.

47. The light detecting device according to claim 46, wherein the conductive material deviates from the first area side to the second area side in the plan view.

48. The light detecting device according to claim 46, wherein a width of the second separation area in the one direction is larger than a width of the first separation area in the one direction.

49. The light detecting device according to claim 46,
wherein the photoelectric conversion unit photoelectrically converts light incident from the second face side of the semiconductor layer into signal electric charge, and
wherein the electric charge maintaining section maintains the signal electric charge acquired through photoelectric conversion by the photoelectric conversion unit,
the light detecting device further comprising a transfer transistor transmitting the signal electric charge acquired through photoelectric conversion by the photoelectric conversion unit to the electric charge maintaining section.

50. A light detecting device, comprising:
a semiconductor layer having a first face and a second face positioned on opposite sides;
a photoelectric conversion area disposed in the semiconductor layer with being partitioned by a first separation area;
a second separation area that separates each photoelectric conversion area of the photoelectric conversion area into a first area and a second area aligned in one direction;
a photoelectric conversion unit that is disposed in the first area and performs photoelectric conversion of light incident from the second face side of the semiconductor layer; and
an electric charge maintaining section that is disposed in the second area and maintains the signal electric charge acquired through photoelectric conversion by the photoelectric conversion unit,
wherein the first separation area includes an insulating material that is disposed in a first dug part extending in the thickness direction of the semiconductor layer and of which a refractive index is lower than that of the semiconductor layer,
wherein the second separation area includes a conductive material that is disposed in a second dug part extending in the thickness direction of the semiconductor layer through a separation insulating film of which a refractive index is lower than that of the semiconductor layer, and
wherein the width of the second area in the one direction is set such that, out of incidence light incident in the first area from the second face side of the semiconductor layer, a phase difference between reflection light reflected on a side face part of the second separation area and return light acquired in accordance with the incidence light being transmitted through the second separation area and the second area, being reflected on the first separation area, and returning to the first area becomes an integer multiple of the incidence light.

51. The light detecting device according to claim 50, further comprising a light blocking film that is disposed on the second face side of the semiconductor layer to overlap the electric charge maintaining section in the plan view.

52. The light detecting device according to claim 50, wherein the electric charge maintaining section is disposed on the second face side of the semiconductor layer.

53. The light detecting device according to claim 50, further comprising a transfer transistor transmitting the signal electric charge acquired through photoelectric conversion by the photoelectric conversion unit to the electric charge maintaining section.

54. A light detecting device, comprising:
a semiconductor layer having a first face and a second face positioned on opposite sides;
a plurality of photoelectric conversion areas disposed in the semiconductor layer with being partitioned by a first separation area;
a second separation area that separates each of the plurality of photoelectric conversion areas into a first area and a second area aligned in one direction;
a photoelectric conversion unit that is disposed in the first area and performs photoelectric conversion of light incident from the second face side of the semiconductor layer; and
an electric charge maintaining section that is disposed in the second area and maintains signal electric charge acquired through photoelectric conversion by the photoelectric conversion unit,
wherein the first separation area includes an insulating material that is disposed in a first dug part extending in the thickness direction of the semiconductor layer and of which a refractive index is lower than that of the semiconductor layer,
wherein the second separation area includes a conductive material that is disposed in a second dug part extending in the thickness direction of the semiconductor layer through a separation insulating film of which a refractive index is lower than that of the semiconductor layer, and
wherein the plurality of photoelectric conversion areas include two or more types of photoelectric conversion areas of which widths of the second areas in the one direction are different from each other.

55. The light detecting device according to claim 54, further comprising a light blocking film that is disposed on the second face side of the semiconductor layer to overlap the second area in the plan view.

56. The light detecting device according to claim 54, wherein the width of the light blocking film in the one direction is different in accordance with a width of the photoelectric conversion area.

57. The light detecting device according to claim 54, wherein the electric charge maintaining section is disposed on the first face side of the semiconductor layer.

58. The light detecting device according to claim 54, further comprising a transfer transistor transmitting the signal electric charge acquired through photoelectric conversion by the photoelectric conversion unit to the electric charge maintaining section.

59. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
a photoelectric conversion area partitioned by the first separation area;
a second separation area that includes a conductive material disposed in a second dug part extending in the thickness direction of the semiconductor layer and separates the photoelectric conversion area into a first area and a second area in one direction;
a photoelectric conversion unit that is disposed in the first area and photoelectrically converts light incident from the second face side of the semiconductor layer into signal electric charge;
an electric charge maintaining section that is disposed in the second area and maintains the signal electric charge acquired through photoelectric conversion by the photoelectric conversion unit; and
a dielectric in which an insulating film is disposed in a third dug part extending in a depth direction of the semiconductor layer through a fixed charge film.

60. The light detecting device according to claim 59, wherein the dielectric is a protrusion part protruding from the second separation area to the second area side.

61. The light detecting device according to claim 59, wherein the dielectric is a protrusion part protruding from the first separation area to the second area side.

62. The light detecting device according to claim 59, wherein the dielectric is an island part that is separated from each of the first and second separation areas.

63. The light detecting device according to claim 59, wherein the electric charge maintaining section is disposed on the first face side of the semiconductor layer.

64. The light detecting device according to claim 59, further comprising a light blocking film that is disposed on the second face side of the semiconductor layer to overlap the second area in the plan view.

65. The light detecting device according to claim 59, further comprising a transfer transistor transmitting the signal electric charge acquired through photoelectric conversion by the photoelectric conversion unit to the electric charge maintaining section.

66. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
a photoelectric conversion area partitioned by the first separation area;
a second separation area that includes a conductive material disposed in a second dug part extending in the thickness direction of the semiconductor layer and separates the photoelectric conversion area into a first area and a second area in one direction;
a photoelectric conversion unit that is disposed in the first area and performs photoelectric conversion of light incident from the second face side of the semiconductor layer;
an electric charge maintaining section that is disposed in the second area and maintains the signal electric charge acquired through photoelectric conversion by the photoelectric conversion unit; and
a multilayer body disposed on the first face side of the semiconductor layer,
wherein the multilayer body includes a light reflecting body disposed to overlap the first area.

67. The light detecting device according to claim 66,
wherein the semiconductor layer is set as a first semiconductor layer, and
wherein the multilayer body further includes a second semiconductor layer disposed to overlap the light reflecting body in the plan view on a side opposite to the first semiconductor layer side of the light reflecting body.

68. The light detecting device according to claim 66, wherein the light reflecting body includes a metal material of which an optical reflectance is higher than that of the insulating material of the first separation area.

69. The light detecting device according to claim 66, wherein the light reflecting body includes a metal material of which an optical reflectance is higher than that of the second semiconductor layer and has a low light absorption rate.

70. The light detecting device according to claim 66, further comprising a reading circuit that is electrically connected to the electric charge maintaining section,
wherein a pixel transistor included in the reading circuit is disposed in the second semiconductor layer.

71. A light detecting device, comprising:
a semiconductor layer having a first face and a second face positioned on opposite sides in a thickness direction;
a first separation area that includes an insulating material disposed in a first dug part extending in the thickness direction of the semiconductor layer and of which a refractive index is lower than that of the semiconductor layer;
a photoelectric conversion area partitioned by the first separation area;
a second separation area that includes a conductive material disposed in a second dug part extending in the thickness direction of the semiconductor layer and separates the photoelectric conversion area into a first area and a second area in one direction;
a photoelectric conversion unit that is disposed in the first area and performs photoelectric conversion of light incident from the second face side of the semiconductor layer;
an electric charge maintaining section that is disposed in the second area and maintains the signal electric charge acquired through photoelectric conversion by the photoelectric conversion unit; and
a multilayer body disposed on the first face side of the semiconductor layer,
wherein the multilayer body includes a light absorbing body disposed to overlap the first area and of which a light absorption rate is higher than that of the semiconductor layer.

72. An electronic device, comprising:
a light detecting device;
an optical lens forming an image of image light from a subject on an imaging surface of the light detecting device; and
a signal processing circuit performing signal processing on a signal output from the light detecting device,
wherein the light detecting device includes:
a semiconductor layer;
a first separation area in which an insulating material of which a refractive index is lower than that of the semiconductor layer fills a first dug part extending in a thickness direction of the semiconductor layer; and
a second separation area in which a conductive material fills a second dug part extending in the thickness direction of the semiconductor layer.
